(19) United States
(12) Patent Application Publication
(10) Pub. No.: US 2025/0120307 A1
(43) Pub. Date: Apr. 10, 2025

(54) ORGANIC ELECTRIC ELEMENT USING COMPOUND FOR ORGANIC ELECTRIC ELEMENT, AND ELECTRONIC DEVICE THEREOF

(71) Applicants: DUK SAN NEOLUX CO., LTD., Chungcheongnam-do (KR); SAMSUNG DISPLAY CO., LTD., Gyeonggi-do (KR)

(72) Inventors: MI KYUNG KIM, Gyeonggi-do (KR); JI HYUN SEO, Gyeonggi-do (KR); BYUNG HEE PARK, Gyeonggi-do (KR); SANG WON SEO, Gyeonggi-do (KR); NAM WOO KIM, Gyeonggi-do (KR); SUNG MO KOO, Gyeonggi-do (KR); HYUN WOO LEE, Gyeonggi-do (KR); KI HO SO, Chungcheongnam-do (KR); HYUNG DONG LEE, Chungcheongnam-do (KR); SUN HEE LEE, Chungcheongnam-do (KR); YONG WOOK PARK, Chungcheongnam-do (KR); SOUNG YUN MUN, Chungcheongnam-do (KR)

(21) Appl. No.: 18/730,916

(22) PCT Filed: Dec. 29, 2022
(86) PCT No.: PCT/KR2022/021647

§ 371 Date: Jul. 22, 2024

(30) Foreign Application Priority Data
Jan. 20, 2022 (KR) 10-2022-0008450

(51) Int. Cl. H10K 85/60; H10K 50/13; H10K 50/15; H10K 50/16

(52) U.S. Cl. CPC H10K 85/633; H10K 50/13; H10K 50/15; H10K 50/16; H10K 85/622; H10K 85/6574; H10K 85/6576

(57) ABSTRACT

An organic electric element includes a first electrode, a second electrode, and an organic material layer formed between the first electrode and the second electrode, wherein a first light-emitting auxiliary layer adjacent to a hole transport layer contains a compound represented by Formula 1, and a second light-emitting auxiliary layer adjacent to the light-emitting layer contains a compound represented by Formula 2, thereby the driving voltage of an organic electric element can be lowered and the efficiency and lifespan can be improved.

### CROSS REFERENCE TO RELATED APPLICATIONS AND CLAIM OF PRIORITY

This application claims benefit under 35 U.S.C. 119, 120, 121, or 365(c), and is a National Stage entry from International Application No. PCT/KR2022/021647 filed on Dec. 29, 2022, which claims priority to the benefit of Korean Patent Application No. 10-2022-0008450 filed in the Korean Intellectual Property Office on Jan. 20, 2022, the entire contents of which are incorporated herein by reference.

### BACKGROUND

### 1. Technical Field

The present invention relates to organic electric element using compound for an organic electric element and electronic device thereof.

### 2. Background Art

In general, an organic light-emitting phenomenon refers to a phenomenon in which electric energy is converted into light energy of an organic material. An organic electric element utilizing the organic light-emitting phenomenon usually has a structure including an anode, a cathode, and an organic material layer interposed therebetween. In many cases, the organic material layer has a multi-layered structure having respectively different materials in order to improve efficiency and stability of an organic electric element, and for example, may comprise a hole injection layer, a hole transport layer, a light-emitting layer, an electron transport layer, an electron injection layer, or the like.

The most important issues in organic electroluminescent element are life and efficiency, and as the display becomes larger, these efficiency and life problems must be solved.

Efficiency, life span, driving voltage, and the like are correlated with each other. If efficiency is increased, then driving voltage is relatively lowered, and the crystallization of an organic material due to Joule heating generated during operation is reduced as driving voltage is lowered, as a result of which life span shows a tendency to increase. However, efficiency cannot be maximized only by simply improving the organic material layer. This is because long life span and high efficiency can be simultaneously achieved when energy levels and T1 values among the respective layers included in the organic material layer, inherent material properties (mobility, interfacial properties, etc.) and the like are optimal combination.

Therefore, in order to fully demonstrate the excellent characteristics of organic electric element, research and development on the materials that make up an organic layer is needed, in particular, research and development on the composition and constituent materials of a light-emitting auxiliary layer is necessary, taking into account the thickness of a light-emitting auxiliary layer and the hole mobility in a light-emitting auxiliary layer.

### SUMMARY

The objection of the present invention is to provide organic electric element and electronic device thereof, employing compound capable of lowering a driving voltage and improving luminous efficiency and lifetime of the element as material for a light-emitting auxiliary layer.

In one aspect, the present invention provides an organic electric element of which compounds of the following Formulas 1 and 2 are applied to the light-emitting auxiliary layer.

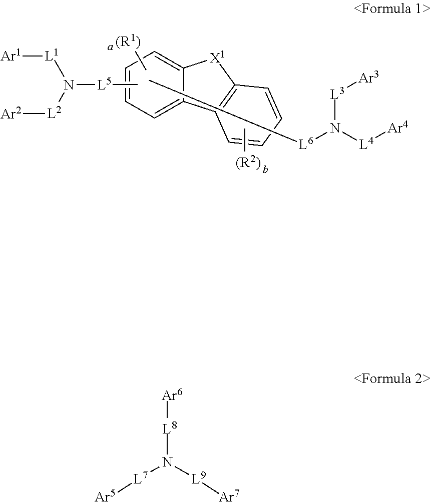

In another aspect, the present invention provides an electronic device including the organic electric element.

According to the present invention, the driving voltage of the element can be lowered, and the luminous efficiency and lifespan can be improved.

### BRIEF DESCRIPTION OF THE DRAWINGS

FIGS. 1 to 3 illustrate an example of organic electroluminescent element according to the present invention.

### DETAILED DESCRIPTION

Unless otherwise stated, the term “aryl group” or “arylene group” as used herein has, but not limited to, 6 to 60 carbon atoms. The aryl group or arylene group in the present invention may comprise a monocyclic ring, ring assemblies, a fused polycyclic system, a spiro compound and the like.

As used herein, the term “fluorenyl group” refers to a substituted or unsubstituted fluorenyl group, and “fluorenylene group” refers to a substituted or unsubstituted fluorenylene group. The fluorenyl group or fluorenylene group used in the present invention comprises a spiro compound formed by combining R and R′ with each other in the following structure, and also comprises compound formed by combining adjacent R″s to each other. “Substituted fluorenyl group”, “substituted fluorenylene group” means that at least one of R, R′, R″ in the following structure is a substituent other than hydrogen, and R″ may be 1 to 8 in the following formula. In this specification, a fluorene group and a fluoreneylene group may be referred to as a fluorene group or fluorene regardless of the valence.

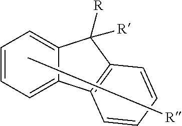

The term “spiro compound” as used herein has a spiro union which means union having one atom as the only common member of two rings. At this time, the atom shared between the two rings is called a ‘spiro atom’. The compounds are called ‘monospiro-’, ‘dispiro-’ or ‘trispiro-’ compound, respectively, depending on the number of spiro atoms in one compound.

The term “heterocyclic group” used in the specification comprises a non-aromatic ring as well as an aromatic ring like “heteroaryl group” or “heteroarylene group”. Unless otherwise stated, the term “heterocyclic group” means, but not limited to, a ring containing one or more heteroatoms and having 2 to 60 carbon atoms. Unless otherwise stated, the term “heteroatom” as used herein represents, for example, N, O, S, P or Si and may comprise a heteroatom group such as SO2, P═O etc. instead of carbon forming a ring such as the following compound. In the specification, “heterocyclic group” comprises a monocyclic, ring assemblies, a fused polycyclic system, a spiro-compound and the like.

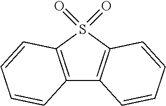 [SMILES: O=S1(=O)c2ccccc2-c2ccccc21]

The term “aliphatic ring group” as used herein refers to a cyclic hydrocarbon except for aromatic hydrocarbons, and comprises a monocyclic ring, ring assemblies, a fused polycyclic system, a spiro-compound and the like, and unless otherwise specified, it means a ring of 3 to 60 carbon atoms, but not limited thereto. For example, a fused ring of benzene being an aromatic ring and cyclohexane being a non-aromatic ring corresponds to aliphatic ring group.

In this specification, a ‘group name’ corresponding to an aryl group, an arylene group, a heterocyclic group, and the like exemplified for each symbol and its substituent may be written in the name of functional group reflecting the valence, and may also be described as the name of a parent compound. For example, in the case of phenanthrene which is a kind of aryl group, it may be described by distinguishing valence such as ‘phenanthryl(group)’ when it is ‘monovalent group’, and ‘phenanthrylene (group)’ when it is ‘divalent group’, and it may also be described as a parent compound name, ‘phenanthrene’, regardless of its valence. Similarly, in the case of pyrimidine, it may be described as ‘pyrimidine’ regardless of its valence, and it may also be described as the name of corresponding functional group such as pyrimidinyl(group) when it is ‘monovalent group’, and ‘pyrimidylene (group)’ when it is ‘divalent group’.

In addition, in the present specification, the numbers and alphabets indicating a position may be omitted when describing a compound name or a substituent name. For example, pyrido[4,3-d]pyrimidine, benzofuro[2,3-d]pyrimidine and 9,9-dimethyl-9H-fluorene can be described as pyridopyrimidine, benzofuropyrimidine and dimethylfluorene, respectively. Therefore, both benzo[g]quinoxaline and benzo[f]quinoxaline can be described as benzoquinoxaline.

In addition, unless otherwise expressed, where any formula of the present invention is represented by the following formula, the substituent according to the index may be defined as follows.

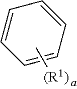

Here, when a is an integer of 0, the substituent R1 is absent, which means that all hydrogen is bonded to the carbon forming the benzene ring, and is the same as the case where R1 is hydrogen and a is an integer of 1 to 5. At this time, hydrogen bonded to carbon can be described without its indication.

When a is an integer of 1, one substituent R1 is bonded to any one of the carbons forming the benzene ring, when a is an integer of 2 or 3, R1 can be bonded as follows, for example, and when a is an integer of 4 to 6, R1 is bonded to the carbon of the benzene ring in a similar way. When a is an integer of 2 or more, R1s may be the same or different from each other.

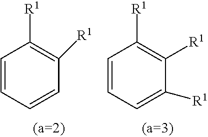

In addition, unless otherwise specified in the present specification, when referring to a condensed/fused ring, the number in the ‘number-condensed/fused ring’ indicates the number of condensed/fused rings. For example, a form in which three rings are condensed/fused with each other, such as anthracene, phenanthrene, and benzoquinazoline, may be represented by a 3-condensed/fused ring.

In addition, unless otherwise described herein, in the case of expressing a ring in the form of a ‘number-membered’ such as a 5-membered ring or a 6-membered ring, the number in the ‘number-membered’ represents the number of atoms forming the ring. For example, thiophene or furan may correspond to a 5-membered ring, and benzene or pyridine may correspond to a 6-membered ring.

In addition, unless otherwise specified in the present specification, when adjacent groups are linked to each other to form a ring, the ring may be selected from the group consisting of a C6-C60 aromatic ring group, a fluorenyl group, a C2-C60 heterocyclic group containing at least one heteroatom selected from the group consisting of O, N, S, Si and P, and a C3-C60 aliphatic ring.

Unless otherwise stated, the term “adjacent groups”, for example, in case of the following Formulas, comprises not only “R1 and R2”, “R2 and R3”, “R3 and R4”, “R5 and R6”, but also “R7 and R8” sharing one carbon, and may comprise “substituents” attached to atom(carbon or nitrogen) consisting different ring, such as “R1 and R7”, “R1 and R8”, or “R4 and R5” and the like. That is, where there are substituents bonded to adjacent elements constituting the same ring, the substituents may be correspond “adjacent groups”, and even if there are no adjacent substituents on the same ring, substituents attached to the adjacent ring may correspond to “adjacent groups”. In the following Formula, when the substituents bonded to the same carbon, such as R7 and R8, are linked to each other to form a ring, a compound containing a spiro-moiety may be formed.

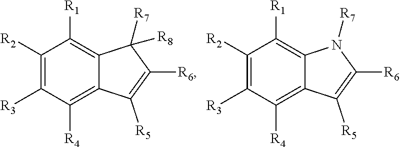

In addition, in the present specification, the expression ‘adjacent groups may be linked to each other to form a ring’ is used in the same sense as ‘adjacent groups are linked selectively to each other to form a ring’, and a case where at least one pair of adjacent groups may be bonded to each other to form a ring.

In addition, unless otherwise specified in the present specification, an aryl group, an arylene group, a fluorenyl group, a fluorenylene group, a heterocyclic group, an aliphatic ring group, an alkyl group, an alkenyl group, an alkynyl group, an alkoxyl group, an aryloxyl group, and a ring formed by adjacent groups may be each optionally substituted with one or more substituents selected from the group consisting of deuterium, halogen, an amino group unsubstituted or substituted with a C1-C20 alkyl group or a C6-C20 aryl group, a silane group unsubstituted or substituted with a C1-C20 alkyl group or a C6-C20 aryl group, a phosphine oxide group unsubstituted or substituted with a C1-C20 alkyl group or a C6-C20 aryl group, siloxane group, a cyano group, a nitro group, a C1-C20 alkylthio group, a C1-C20 alkoxyl group, a C6-C20 aryloxy group, a C6-C20 arylthio group, a C1-C20 alkyl group, a C2-C20 alkenyl group, a C2-C20 alkynyl group, a C6-C20 aryl group, a fluorenyl group, a C2-C20 heterocyclic group containing at least one heteroatom of O, N, S, Si and P, and a C3-C20 aliphatic ring group.

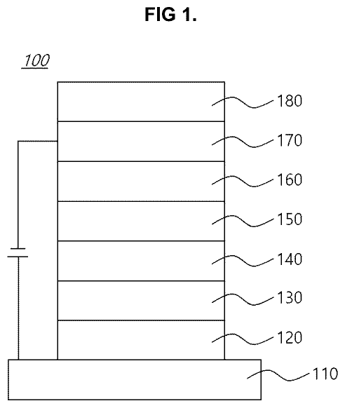

Hereinafter, referring to FIGS. 1 to 3, a lamination structure of an organic electric element including the compound of the present invention will be described.

In designation of reference numerals to components in respective drawings, it should be noted that the same elements will be designated by the same reference numerals although they are shown in different drawings. In addition, in the following description of the present invention, a detailed description of known functions and configurations incorporated herein will be omitted when it may make the subject matter of the present invention rather unclear.

Terms, such as first, second, A, B, (a), (b) or the like may be used herein when describing components of the present invention. Each of these terminologies is not used for defining an essence, order or sequence of a corresponding component but used merely to distinguish the corresponding component from other component(s). It will be understood that the expression ‘one component is “connected,” “coupled” or “joined” to another component’ comprises the case where a third component may be “connected,” “coupled” or “joined” between a first component and a second component as well as the case where the first component may be directly connected, coupled or joined to the second component.

In addition, it will be understood that when an element such as a layer, film, region or substrate is referred to as being “on” or “over” another element, it can be directly on the other element or intervening elements may also be present. In contrast, when an element is referred to as being “directly on” another element, there are no intervening elements present.

The FIGS. 1 to 3 show an example of an organic electric element according to an embodiment of the present invention, respectively.

Referring to the FIG. 1, an organic electric element 100 according to an embodiment of the present invention includes a first electrode 110 formed on a substrate (not shown), a second electrode 170, and an organic material layer between the first electrode 110 and the second electrode 170.

The first electrode 110 may be an anode (positive electrode), and the second electrode 170 may be a cathode (negative electrode). In the case of an inverted organic electric element, the first electrode may be a cathode, and the second electrode may be an anode.

The organic material layer may include a hole transport zone, a light-emitting layer, and an electron transport zone sequentially formed on the first electrode 110, and the hole transport zone includes a hole injection layer 120, a hole transport layer 130, and a light-emitting auxiliary layer(not shown), etc., and the electron transport band may include an electron transport layer 150 and an electron injection layer 160.

In addition, a layer for improving the luminous efficiency 180 may be formed one side of sides of the first electrode 110 and the second electrode 170, wherein the one side is not facing the organic material layer. When a layer for improving the luminous efficiency 180 is formed, the luminous efficiency of an organic electric element can be improved.

For example, the light efficiency improving layer 180 may be formed on the second electrode 170, as a result, in the case of a top emission organic light-emitting element, the optical energy loss due to Surface Plasmon Polaritons (SPPs) at the second electrode 170 may be reduced and in the case of a bottom emission organic light-emitting element, the light efficiency improving layer 180 may serve as a buffer for the second electrode 170.

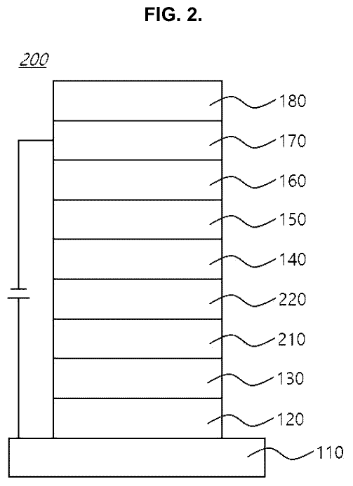

A buffer layer 210 or an emission-auxiliary layer 220 may be further formed between the hole transport layer 130 and the light-emitting layer 140, which will be described with reference to FIG. 2.

Referring to FIG. 2, the organic electric element 200 according to another embodiment of the present invention may comprise a hole injection layer 120, a hole transport layer 130, a buffer layer 210, an emission-auxiliary layer 220, a light-emitting layer 140, the electron transport layer 150, the electron injection layer 160, and a second electrode 170 formed on a first electrode 110 in sequence, and a layer for improving light efficiency 180 may be formed on the second electrode 170. Although not shown in FIG. 2, an electron transport auxiliary layer may be further formed between the light-emitting layer 140 and the electron transport layer 150.

The light-emitting auxiliary layer 220 may be formed of a single layer or a plurality of two or more layers, and preferably a plurality of layers consisting of/including a first light-emitting auxiliary layer adjacent to the hole transport layer and a second light-emitting auxiliary layer adjacent to the light-emitting layer. When a light-emitting auxiliary layer is formed of multiple layers, the hole mobility and T1 energy level in each light-emitting auxiliary layer are taken into consideration, and the thickness of each layer is appropriately considered to form each light-emitting auxiliary layer, thereby improving the characteristics of the organic electric element.

The thickness of a light-emitting auxiliary layer varies depending on the color. In the case of a top emission element, the light generated in the light-emitting layer passes through the hole transport region and is reflected at the anode, and the reflected light passes through the hole transport region and combines with the light generated in the emitting layer to transmit light to the outside through the electron transport layer. At this time, if the front light-emitting element is designed to use constructive interference that is a microcavity phenomenon, light efficiency, color purity and lifespan of an element are improved.

In other words, since the wavelength is different for each color, the microcavity phenomenon must be used by adjusting the thickness of the hole transport region between the anode and the thickness of the hole transport region changes in order to use the microcavity phenomenon. For example, when the sum of the thicknesses of the hole transport region excluding the light-emitting auxiliary layer is 1,000 to 1,500 Å, it is preferable that the thickness of the light-emitting auxiliary layer is 600 to 900 Å for red, 300 to 500 Å for green, and 50 to 100 Å for blue. The hole transport region may include a hole injection layer, a hole transport layer, and a light-emitting auxiliary layer.

As described above, a light-emitting auxiliary layer may be formed of a plurality of layers including/composed of a first light-emitting auxiliary layer adjacent to a hole transport layer and a second light-emitting auxiliary layer adjacent to a light-emitting layer. In this case, it appears that a first light-emitting auxiliary layer mainly plays the role of injecting holes from the hole transport layer to a light-emitting auxiliary layer and transporting the injected holes, and a second light-emitting auxiliary layer mainly plays the role of hole injection from a light-emitting auxiliary layer to host and electron blocking from host to a light-emitting auxiliary layer.

In this way, the charge balance of the device can be appropriately adjusted by appropriately adjusting the hole injection characteristics in a first and a second light-emitting auxiliary layers, which can affect the efficiency and lifespan of the device.

In addition, the hole mobility of a first light-emitting auxiliary layer affects the hole transport role of the first light-emitting auxiliary layer and can play a significant role in improving the driving voltage characteristics of the element, and a second light-emitting auxiliary layer can play the role of electron blocking to the host based on high LUMO and high T1 and minimize damage to the hole transport layer, which can affect the lifespan. Since a second light-emitting auxiliary layer should be designed so as not to affect the hole transport role of a first light-emitting auxiliary layer as much as possible, it is preferable that the thickness of a second light-emitting auxiliary layer is thin.

For example, the thickness of a first light-emitting auxiliary layer is preferably 25 to 900 Å, 25 to 75 Å, preferably 25 to 50 Å for a blue organic electric element, 100 to 450 Å, preferably 250 to 450 Å for a green organic electric element, and 500 to 900 Å, preferably 650 to 850 Å for a red organic electric element, and the thickness of a second light-emitting auxiliary layer is 10 to 300 Å, preferably 20 to 100 Å, and more preferably 25 to 75 Å.

The hole mobility of a first light-emitting auxiliary layer can be confirmed through HOD (Hole Only Device), and HOD can be confirmed through an element configuration as follows.

After a hole injection layer is formed by vacuum depositing 1,4,5,8,9,11-hexaazatriphenylenehexacarbonitrile (hereinafter referred to as HAT-CN) to a thickness of 5 nm on the ITO layer (anode) formed on the glass substrate, a hole transport zone layer is formed by vacuum depositing a hole transport compound (target compound) to a thickness of 300 nm on the hole injection layer. Then, HAT-CN is vacuum deposited to a thickness of 1 nm on the hole transport zone layer to form a hole blocking layer, and then Al is deposited to a thickness of 100 nm on the hole blocking layer to form a cathode.

HOD of the element manufactured as described above can be measured by the J-V Curve (Current Density-Voltage Curve) using I-V-L measurement equipment manufactured by Mc Science.

At this time, the hole mobility can be checked by calculating based on SCLC (Space Charge Limited Current) in the J-V Curve. SCLC is the point where the main emission begins and refers to the section in dynamic balance (space charge) where the charge is filled in the trap.

The hole mobility (μ) can be calculated through Child's Law and Poole-Frenkel Emission equation.

Equation 1 below is Child's Law, and Equation 2 below is the equation for Poole-Frenkel Emission.

$$J = \frac{9}{8} ε μ \frac{{V}^{2}}{{d}^{3}} \qquad [ Equation 1 ]$$

J: current density (A/Cm2)
ε: dielectric constant of organic material (2.655×10−13 A·sN·cm)
d: thickness of thin film (cm)
V: applied voltage (V)

$$μ ( E ) = {μ}_{0} exp ( β \sqrt{E} ) \qquad [ Equation 2 ]$$

E: electric field (V/cm)
μo: mobility of Poole-frenkel (cm2N-s)
β: constant of Poole-frenkel

Combining Equation 1 and Equation 2 above gives Equation 3 below.

$$ln \frac{J}{{E}^{2}} = β \sqrt{E} + ln ( \frac{9}{8} ε \frac{{μ}_{0}}{d} ) \qquad [ Equation 3 ]$$

Here, β and μ0 can be calculated by referring to the J-V Curve since they are different for each material of an element and a configuration of an element. Therefore, by introducing the calculated β and μ0 into Equation 2, the hole mobility (μ) can be calculated. At this time, the hole mobility for the material can be calculated by calculating the range of hole mobility for the section of the SCLC or by calculating the hole mobility (μ0) of the zero field (i.e., when E is 0). In this specification, the hole mobility of the compound means the hole mobility of the zero field.

The hole mobility of a first light-emitting auxiliary layer according to the present invention is 5.1×10−5 to 1.3×10−3 cmV·S, preferably, 1.6×10−4 to 1.3×10−3 cmV·S.

In addition, it is preferable that the HOMO energy levels of a first light-emitting auxiliary layer and a second light-emitting auxiliary layer satisfy Equation 4 below.

$$HOMOP 1 > HOMOP 2 \qquad [ Equation 4 ]$$

HOMOP1 is the HOMO of a first light-emitting auxiliary layer, and HOMOP2 is the HOMO of a second light-emitting auxiliary layer.

When the HOMO energy levels of the first emission auxiliary layer and the second emission auxiliary layer satisfy Equation 4 above, hole injection and hole transport from the hole transport layer to the host are performed well as a cascade structure. In particular, when the HOMO energy level of a second light-emitting auxiliary layer is low, hole injection into the host occurs smoothly, which may affect the increase in efficiency.

The T1 energy level of a second light-emitting auxiliary layer according to the present invention is preferably 2.3 to 3.0, for a red organic electric element, 2.3 to 2.9, preferably 2.5 to 2.8, and for green organic electric element, 2.6 to 2.8. 2.9, preferably 2.7 to 2.9.

When the T1 energy level of a second light-emitting auxiliary layer is within the above range, triplet electrons can be effectively prevented from moving from the dopant to the hole transport layer, which can have an effect on improving the efficiency and lifespan of the element.

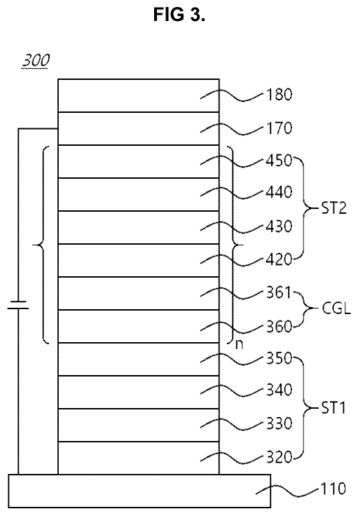

According to another embodiment of the present invention, the organic material layer may be a form consisting of multiple stacks, wherein the stacks comprise a hole transport layer, a light-emitting layer, and an electron transport layer, respectively. This will be described with reference to FIG. 3.

Referring to FIG. 3, two or more sets of stacks of the organic material layers ST1 and ST2 may be formed between the first electrode 110 and the second electrode 170 in the organic electric element 300 according to another embodiment of the present invention, wherein the organic material layers are consisted of multiple layers, respectively, and the charge generation layer CGL may be formed between the stacks of the organic material layer.

Specifically, the organic electric element according to the embodiment of the present invention may comprise a first electrode 110, a first stack ST1, a charge generation layer CGL, a second stack ST2, and a second electrode 170 and a layer for improving light efficiency 180.

The first stack ST1 is an organic layer formed on the first electrode 110, and the first stack ST1 may comprise the first hole injection layer 320, the first hole transport layer 330, a light-emitting auxiliary layer(not shown), the first light-emitting layer 340 and the first electron transport layer 350 and the second stack ST2 may comprise a second hole injection layer 420, a second hole transport layer 430, a light-emitting auxiliary layer(not shown), a second light-emitting layer 440 and a second electron transport layer 450. As such, the first stack and the second stack may be the organic layers having the same or different stacked structures.

The charge generation layer CGL may be formed between the first stack ST1 and the second stack ST2. The charge generation layer CGL may comprise a first charge generation layer 360 and a second charge generation layer 361. The charge generating layer CGL is formed between the first light-emitting layer 340 and the second light-emitting layer 440 to increase the current efficiency generated in each light-emitting layer and to smoothly distribute charges.

A first light-emitting layer 340 may comprise a light-emitting material comprising a blue host doped with a blue fluorescent dopant and a second light-emitting layer 440 may comprise a light-emitting material comprising a green host doped with a greenish yellow dopant and a red dopant together.

In FIG. 3, n may be an integer of 1 to 5 and the charge generation layer CGL and the third stack may be further stacked on the second stack ST2 when n is 2.

When multiple light-emitting layers are formed in a multi-layer stack structure as shown in FIG. 3, it is possible to manufacture an organic electroluminescent element that emits not only white light but also various colors, wherein the white light is emitted by the mixing effect of light emitted from each light-emitting layer.

The organic electric element according to an embodiment of the present invention may be manufactured using various deposition methods. The organic electric element according to an embodiment of the present invention may be manufactured using a PVD (physical vapor deposition) method or CVD (chemical vapor deposition) method. For example, the organic electric element may be manufactured by depositing a metal, a conductive metal oxide, or a mixture thereof on the substrate to form the anode 110, forming the organic material layer comprising the hole injection layer 120, the hole transport layer 130, the light-emitting layer 140, the electron transport layer 150, and the electron injection layer 160 thereon, and then depositing a material, which can be used as the cathode 170, thereon. Also, an emission-auxiliary layer 220 may be formed between a hole transport layer 130 and a light-emitting layer 140, and an electron transport auxiliary layer(not shown) may be further formed between a light-emitting layer 140 and an electron transport layer 150 and, as described above, a stack structure may be formed.

Also, the organic material layer may be manufactured in such a manner that the fewer layers are formed using various polymer materials by a soluble process or solvent process, for example, spin coating, nozzle printing, inkjet printing, slot coating, dip coating, roll-to-roll, doctor blading, screen printing, or thermal transfer, instead of deposition. Since the organic material layer according to the present invention may be formed in various ways, the scope of protection of the present invention is not limited by a method of forming the organic material layer.

The organic electric element according to an embodiment of the present invention may be of a top emission type, a bottom emission type, or a dual emission type depending on the material used.

In addition, the organic electric element according to an embodiment of the present invention may be selected from the group consisting of an organic electroluminescent element, an organic solar cell, an organic photo conductor, an organic transistor, an element for monochromatic illumination and an element for quantum dot display.

Another embodiment of the present invention provides an electronic device including a display device which includes the above described organic electric element, and a control unit for controlling the display device. Here, the electronic device may be a wired/wireless communication terminal which is currently used or will be used in the future, and covers all kinds of electronic devices including a mobile communication terminal such as a cellular phone, a navigation unit, a game player, various kinds of TVs, and various kinds of computers.

Hereinafter, an organic electric element according to one aspect of the present invention will be described.

An organic electric element according to one aspect of the present invention includes a first electrode, a second electrode, and an organic material layer formed between the first electrode and the second electrode, wherein the organic material layer includes a light-emitting layer, a hole transport layer formed between the light-emitting layer and the first electrode, and a plurality of light-emitting auxiliary layers formed between the hole transport layer and the light-emitting layer, and the plurality of light-emitting auxiliary layers include a first light-emitting auxiliary layer adjacent to the hole transport layer and a second light-emitting auxiliary layer adjacent to the light-emitting layer. Here, the first light-emitting auxiliary layer includes a compound represented by the following Formula 1, and the second light-emitting auxiliary layer includes a compound represented by the following Formula 2.

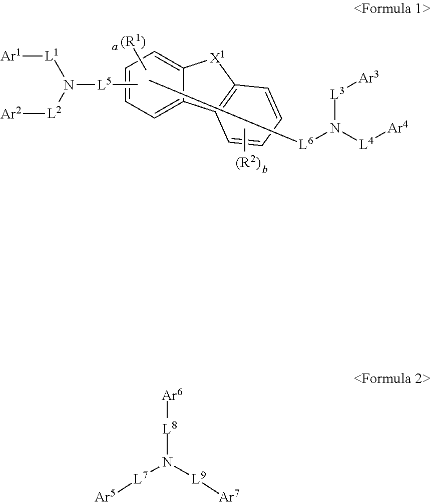

In Formula 1 and Formula 2, each of symbols may be defined as follows.

Ar1 to Ar7 are each independently selected from the group consisting of a C6-C60 aryl group, a fluorenyl group, a C2-C60 heterocyclic group containing at least one heteroatom of O, N, S, Si and P, and a C3-C60 aliphatic ring group. With the proviso that at least one of Ar1 to Ar4 is Formula 3, and Formula 3 is bonded to one of L1 to L4 of Formula 1.

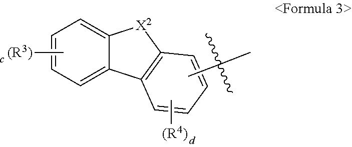

X1 and X2 are each independently O or S.

L1 to L9 are each independently selected from the group consisting of a single bond, a C6-C60 arylene group, a fluorenylene group, a C2-C60 heterocyclic group containing at least one heteroatom of O, N, S, Si and P, and a C3-C60 aliphatic ring group.

R1 to R4 are each independently selected from the group consisting of hydrogen, deuterium, halogen, a cyano group, a nitro group, a C6-C60 aryl group, a fluorenyl group, a C2-C60 heterocyclic group containing at least one heteroatom of O, N, S, Si and P, a C3-C60 aliphatic ring group, a C1-C20 alkyl group, a C2-C20 alkenyl group, a C2-C20 alkynyl group, a C1-C20 alkoxyl group, and a C6-C20 aryloxy group, and adjacent groups may be bonded to each other to form a ring.

a and d are each an integer of 0 to 3, b and c are each an integer of 0 to 4, and when each of these is an integer of 2 or more, each of R1, each of R2, each of R3, each of R4 are the same as or different from each other, and adjacent groups may be bonded to each other to form a ring.

Adjacent groups may be, for example, adjacent R1 groups, adjacent R2 groups, adjacent R3 groups, adjacent R4 groups, and when at least one pair of neighboring groups bonds to each other to form a ring, the ring may be selected from the group consisting of a C6-C60 aromatic ring group, a fluorene group, a C2-C60 heterocyclic group containing at least one heteroatom of O, N, S, Si and P, and a C3-C60 aliphatic ring group.

When an aromatic ring group is formed by adjacent group, the aromatic ring group may be a C6-C30, a C6-C20, a C6-C16, a C6-C14, a C6-C10 or a C6 aromatic ring group, specifically, it may be an aromatic ring such as benzene, naphthalene, phenanthrene, etc.

When at least one of Ar1 to Ar7, R1 to R4 is an aryl group, the aryl group may be, for example, a C6-C30, a C6-C29, a C6-C28, a C6-C27, a C6-C26, a C6-C25, a C6-C24, a C6-C23, a C6-C22, a C6-C21, a C6-C20, a C6-C19, a C6-C18, a C6-C17, a C6-C16, a C6-C15, a C6-C14, a C6-C13, a C6-C12, a C6-C11, a C6-C10, a C6, a C10, a C12, a C13, a C14, a C15, a C16, a C17, a C18, a C19, a C20, a C21, a C22, a C23, a C24, a C25, a C26, a C27, a C28, a C29, a C30 aryl group, specifically, phenyl, biphenyl, naphthyl, terphenyl, phenanthrene, triphenylene or the like.

When at least one of L1 to L9 is an arylene group, the arylene group may be, for example, a C6-C30, a C6-C29, a C6-C28, a C6-C27, a C6-C26, a C6-C25, a C6-C24, a C6-C23, a C6-C22, a C6-C21, a C6-C20, a C6-C19, a C6-C18, a C6-C17, a C6-C16, a C6-C15, a C6-C14, a C6-C13, a C6-C12, a C6-C11, a C6-C10, a C6, a C10, a C12, a C13, a C14, a C15, a C16, a C17, a C18, a C19, a C20, a C21, a C22, a C23, a C24, a C25, a C26, a C27, a C28, a C29, a C30 arylene group, specifically, phenylene, biphenyl, naphthylene, terphenyl, phenanthrene, triphenylene or the like.

When at least one of Ar1 to Ar7, R1 to R4, L1 to L9 is a heterocyclic group, the heterocyclic group may be, for example, a C2-C30, a C2-C29, a C2-C28, a C2-C27, a C2-C26, a C2-C25, a C2-C24, a C2-C23, a C2-C22, a C2-C21, a C2-C20, a C2-C19, a C2-C18, a C2-C17, a C2-C16, a C2-C15, a C2-C14, a C2-C13, a C2-C12, a C2-C11, a C2-C10, a C2-C9, a C2-C8, a C2-C7, a C2-C6, a C2-C5, a C2-C4, a C2-C3, a C2, a C3, a C4, a C5, a C6, a C7, a C8, a C9, a C10, a C11, a C12, a C13, a C14, a C15, a C16, a C17, a C18, a C19, a C20, a C21, a C22, a C23, a C24, a C25, a C26, a C27, a C28, a C29 or C30 heterocyclic group, specifically, pyridine, pyrimidine, pyrazine, pyridazine, triazine, furan, pyrrole, silole, indene, indole, phenyl-indole, benzoindole, phenyl-benzoindole, pyrazinoindol, quinoline, isoquinoline, benzoquinoline, pyridoquinoline, quinazoline, benzoquinazoline, dibenzoquinazoline, phenanthroquinazoline, quinoxaline, benzoquinoxaline, dibenzoquinoxaline, benzofuran, naphthobenzofuran, dibenzofuran, dinaphthofuran, thiophene, benzothiophene, dibenzothiophene, naphthobenzothiophene, dinaphthothiophene, carbazole, phenyl-carbazole, benzocarbazole, phenyl-benzocarbazole, naphthyl-benzocarbazole, dibenzocarbazole, indolocarbazole, benzofuropyridine, benzothienopyridine, benzofuropyridine, benzothienopyrimidine, benzofuropyrimidine, benzothienopyrazine, benzofuropyrazine, benzoimidazole, benzothiazole, benzooxazole, benzosiloe, phenanthroline, dihydro-phenylphenazine, 10-phenyl-10H-phenoxazine, phenoxazine, phenothiazine, dibenzodioxin, benzodibenzodioxin, thianthrene, 9,9-dimethyl-9H-xantene, 9,9-dimethyl-9H-thioxantene, dihydrodimethylphenylacridine, spiro[fluorene-9,9′-xanthene]and the like.

When at least one of Ar1 to Ar7, R1 to R4 is a fluorenyl group or at least one of L1 to L9 is a fluorenylene group, the fluorenyl group or the fluorenylene group may be, for example, 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl)9-phenyl-9H-fluorene, (1 r,5R,7S)-spiro[adamantane-2,9′-fluorene]and the like.

When at least one of Ar1 to Ar7, R1 to R4, L1 to L9 is an aliphatic ring group, the aliphatic ring group may be, for example, a C6-C30, a C6-C29, a C6-C28, a C6-C27, a C6-C26, a C6-C25, a C6-C24, a C6-C23, a C6-C22, a C6-C21, a C6-C20, a C6-C19, a C6-C18, a C6-C17, a C6-C16, a C6-C15, a C6-C14, a C6-C13, a C6-C12, a C6-C11, a C6-C10, a C3, a C4, a C5, a C6, a C7, a C8, a C9, a C10, a C11, a C12, a C13, a C14, a C15, a C16, a C17, a C18, a C19, a C20, a C21, a C22, a C23, a C24, a C25, a C26, a C27, a C28, a C29, or a C30 aliphatic ring group, specifically, cyclohexyl group, norbornyl group, adamantyl group, etc.

When at least one of R1 to R4 is an alkyl group, the alkyl group may be, for example, a C1-C20, a C1-C10, a C1-C4, a C1, a C2, a C3 and a C4 alkyl group, specifically, methyl, ethyl, propyl, butyl, t-butyl, etc.

The aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by adjacent groups may be each optionally substituted with one or more substituents selected from the group consisting of deuterium, halogen, a silane group unsubstituted or substituted with a C1-C20 alkyl group or a C6-C20 aryl group, a phosphine oxide group unsubstituted or substituted with a C1-C20 alkyl group or a C6-C20 aryl group, siloxane group, a cyano group, a nitro group, a C1-C20 alkylthio group, a C1-C20 alkoxyl group, a C6-C20 aryloxy group, a C6-C20 arylthio group, a C1-C20 alkyl group, a C2-C20 alkenyl group, a C2-C20 alkynyl group, a C6-C30 aryl group, a fluorenyl group, a C2-C30 heterocyclic group comprising at least one heteroatom selected from the group consisting of O, N, S, Si and P, a C3-C30 aliphatic ring group, and —L′—N(Ra)(Rb).

L′ is selected from the group consisting of a single bond, a C6-C30 arylene group, a fluorenylene group, a C2-C30 heterocyclic group containing at least one heteroatom of O, N, S, Si and P, and a C3-C30 aliphatic ring group.

Ra and Rb are each independently selected from the group consisting of a C6-C30 aryl group, a fluorenyl group, a C2-C30 heterocyclic group containing at least one heteroatom of O, N, S, Si and P, and a C3-C30 aliphatic ring group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with an aryl group, the aryl group may be, for example, a C6-C30, a C6-C29, a C6-C28, a C6-C27, a C6-C26, a C6-C25, a C6-C24, a C6-C23, a C6-C22, a C6-C21, a C6-C20, a C6-C19, a C6-C18, a C6-C17, a C6-C16, a C6-C15, a C6-C14, a C6-C13, a C6-C12, a C6-C11, a C6-C10, a C6, a C10, a C12, a C13, a C14, a C15, a C16, a C17, a C18, a C19, a C20, a C21, a C22, a C23, a C24, a C25, a C26, a C27, a C28, a C29, a C30 aryl group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with a heterocyclic group, the heterocyclic group may be, for example, a C2-C30, a C2-C29, a C2-C28, a C2-C27, a C2-C26, a C2-C25, a C2-C24, a C2-C23, a C2-C22, a C2-C21, a C2-C20, a C2-C19, a C2-C18, a C2-C17, a C2-C16, a C2-C15, a C2-C14, a C2-C13, a C2-C12, a C2-C11, a C2-C10, a C2-C9, a C2-C8, a C2-C7, a C2-C6, a C2-C5, a C2-C4, a C2-C3, a C2, a C3, a C4, a C5, a C6, a C7, a C8, a C9, a C10, a C11, a C12, a C13, a C14, a C15, a C16, a C17, a C18, a C19, a C20, a C21, a C22, a C23, a C24, a C25, a C26, a C27, a C28, a C29 or a C30 heterocyclic group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with a fluorenyl group, the fluorenyl group may be, for example, 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl)9-phenyl-9H-fluorene, (1 r,5R,7S)-spiro[adamantane-2,9′-fluorene], etc.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with an alkyl group, the alkyl group may be, for example, a C1-C20, a C1-C10, a C1-C4, a C1, a C2, a C3, a C4 alkyl group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with an alkoxyl group, the alkoxyl group may be, for example, a C1-C20, a C1-C10, a C1-C4, a C1, a C2, a C3, a C4 alkoxyl group.

When at least one of the aryl group, the fluorenyl group, the heterocyclic group, the aliphatic ring group, the aromatic ring group, the fluorene group, the alkyl group, the alkenyl group, the alkynyl group, the alkoxyl group, the aryloxyl group, the arylene group, the fluorenylene group, and the ring formed by adjacent groups is substituted with an aliphatic ring group, the aliphatic ring group may be, for example, a C3-C30, a C3-C29, a C3-C28, a C3-C27, a C3-C26, a C3-C25, a C3-C24, a C3-C23, a C3-C22, a C3-C21, a C3-C20, a C3-C19, a C3-C18, a C3-C17, a C3-C16, a C3-C15, a C3-C14, a C3-C13, a C3-C12, a C3-C11, a C3-C10, a C3, a C4, a C5, a C6, a C7, a C8, a C9, a C10, a C11, a C12, a C13, a C14, a C15, a C16, a C17, a C18, a C19, a C20, a C21, a C22, a C23, a C24, a C25, a C26, a C27, a C28, a C29 or a C30 aliphatic ring group, specifically, cyclohexyl group, norbornyl group, adamantyl group, etc.

Formula 3 may be represented by one of Formula 3-1 to Formula 3-4.

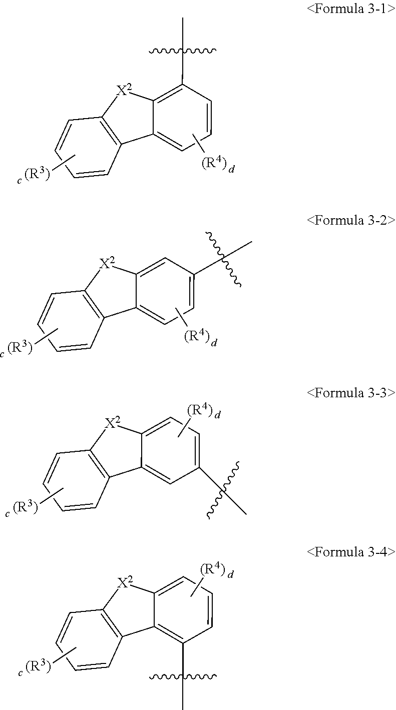

In Formula 3-1 to Formula 3-4, X2, R3, R4, c, d are the same as defined for Formula 3.

At least one of L1 to L9 may be one of Formula L-1 to Formula L-12.

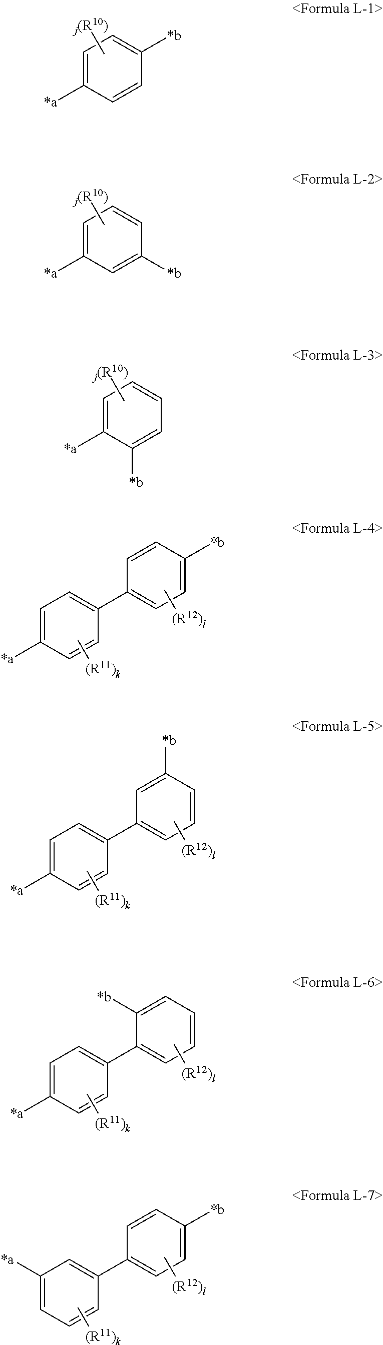

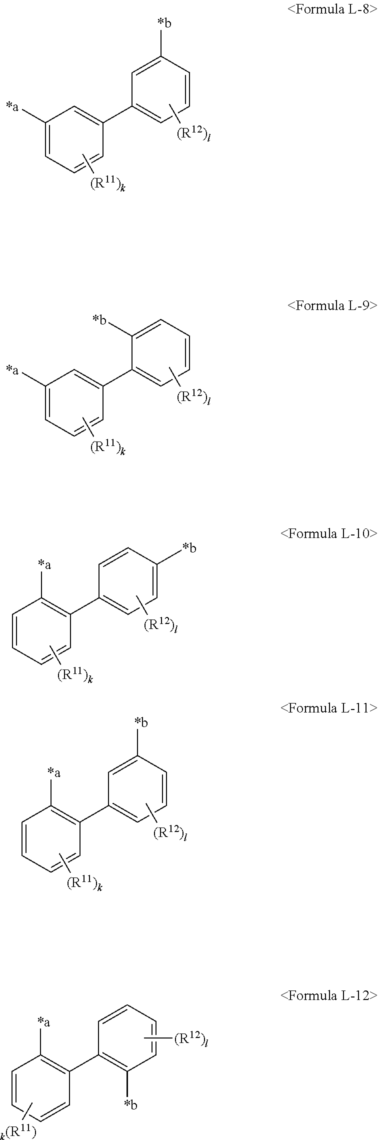

In Formula L-1 to Formula L-12, each of symbols may be defined as follows.

R10 to R12 are each independently selected from the group consisting of hydrogen, deuterium, halogen, a silane group unsubstituted or substituted with a C1-C20 alkyl group or a C6-C20 aryl group, a phosphine oxide group unsubstituted or substituted with a C1-C20 alkyl group or a C6-C20 aryl group, siloxane group, a cyano group, a nitro group, a C1-C20 alkylthio group, a C1-C20 alkoxyl group, a C6-C20 aryloxy group, a C6-C20 arylthio group, a C1-C20 alkyl group, a C2-C20 alkenyl group, a C2-C20 alkynyl group, a C6-C30 aryl group, a fluorenyl group, a C2-C30 heterocyclic group comprising at least one heteroatom selected from the group consisting of O, N, S, Si and P, a C3-C30 aliphatic ring group, and —L′—N(Ra)(Rb), and adjacent groups may be bonded to each other to form a ring.

j, k and I are each an integer of 0 to 4, and when each of these is an integer of 2 or more, each of R10, each of R11, each of R12 are the same as or different from each other, and adjacent groups may be bonded to each other to form a ring.

Adjacent groups may be, for example, adjacent R10 groups, adjacent R11 groups, adjacent R12 groups, and when at least one pair of neighboring groups bonds to each other to form a ring, the ring may be selected from the group consisting of a C6-C60 aromatic ring group, a fluorene group, a C2-C60 heterocyclic group containing at least one heteroatom of O, N, S, Si and P, and a C3-C60 aliphatic ring group.

When an aromatic ring group is formed by adjacent group, the aromatic ring group may be a C6-C30, a C6-C20, a C6-C16, a C6-C14, a C6-C10 or a C6 aromatic ring group, specifically, it may be an aromatic ring such as benzene, naphthalene, phenanthrene, etc.

*a and *b indicate binding positions. Each of L1 to L9 serves as a linker which connects an amine group and one of Ar1 to Ar7, or an amine group and the benzene ring of the 3-condensed ring containing X1.

For example, when L1 connecting the nitrogen atom of the amine group and Ar1 is one of the above Formulas L-1 to L-12, *a is connected to the nitrogen atom of the amine group, and *b is connected to Ar1. Similarly, when at least one of L2 to L4, L7 to L9 is one of Formula L-1 to L-12, *a is connected to the nitrogen atom of the amine group, and *b is connected to each of Ar2 to Ar7. In addition, when L5 and/or L6 are one of the above Formulas L-1 to L-12, *a is connected to the nitrogen atom of the amine group, and *b is connected to the benzene ring of the 3-condensed ring containing X1, that is, a benzene ring substituted with R1 or a benzene ring substituted with R2.

L′ is selected from the group consisting of a single bond, a C6-C30 arylene group, a fluorenylene group, a C2-C30 heterocyclic group containing at least one heteroatom of O, N, S, Si and P, and a C3-C30 aliphatic ring group.

Ra and Rb are each independently selected from the group consisting of a C6-C30 aryl group, a fluorenyl group, a C2-C30 heterocyclic group containing at least one heteroatom of O, N, S, Si and P, and a C3-C30 aliphatic ring group.

Formula 1 may be represented by one of Formula 1-1 to Formula 1-9.

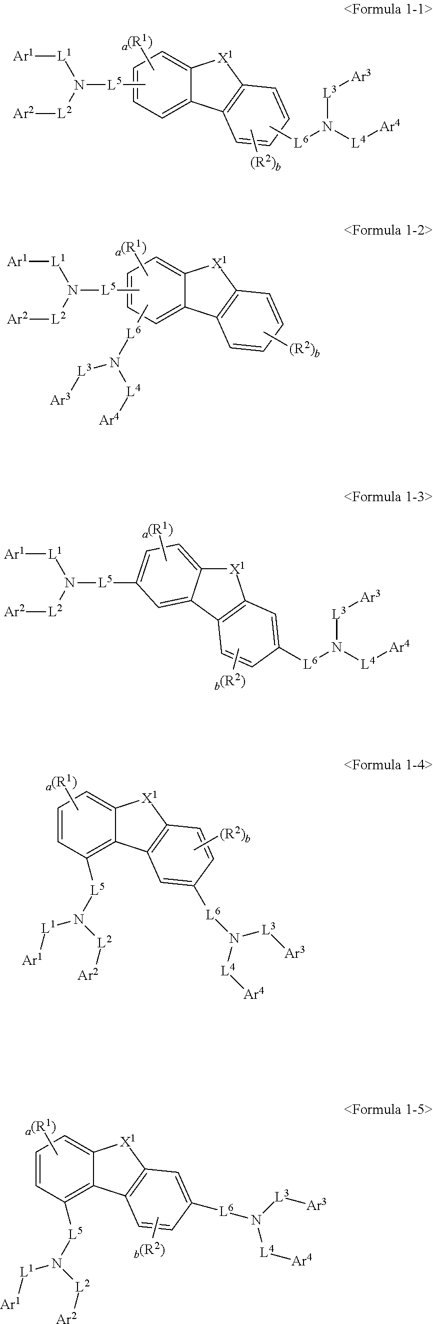

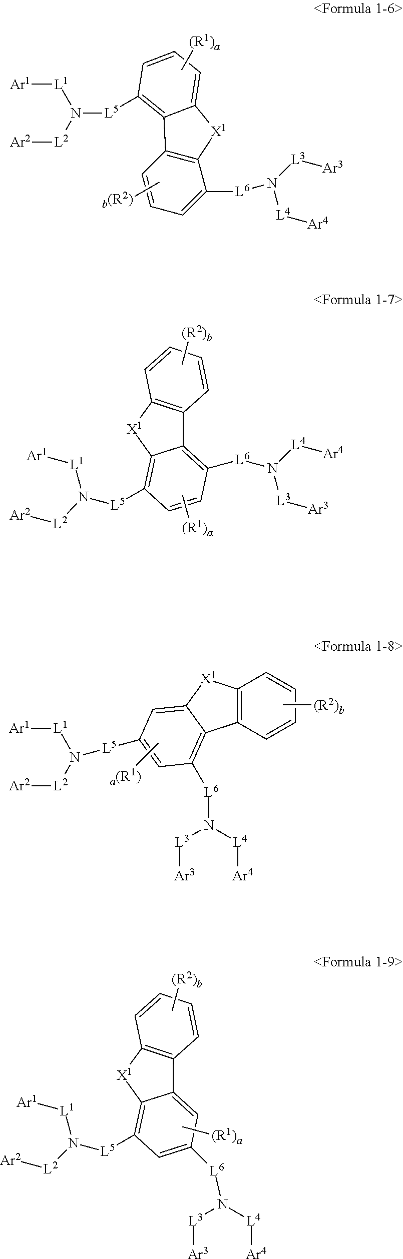

In Formula 1-1 to Formula 1-9, X1, R1, R2, a, b, L1-L6, Ar1-Ar4 are the same as defined for Formula 1.

Ar5 in Formula 2 may be one of Formula b to Formula d, but there is no limitation thereto.

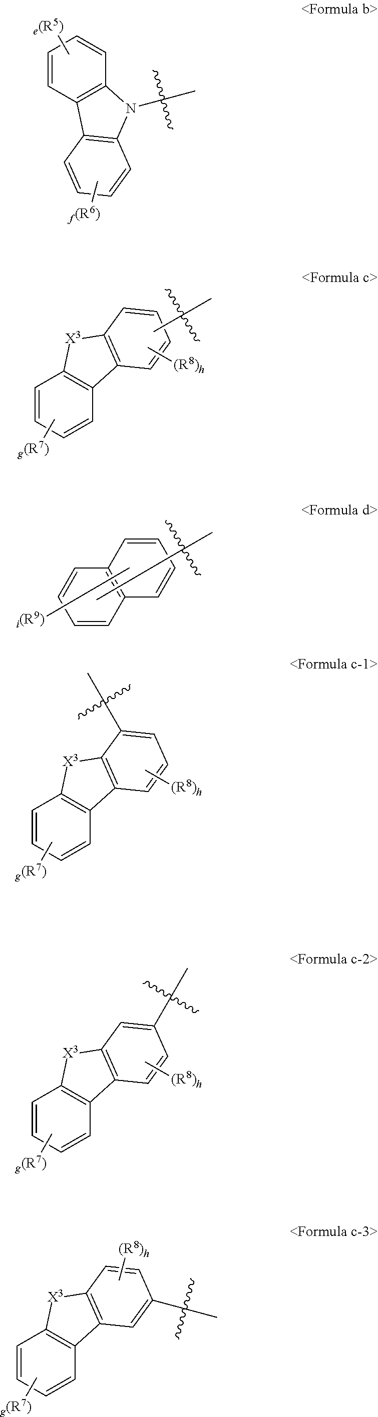

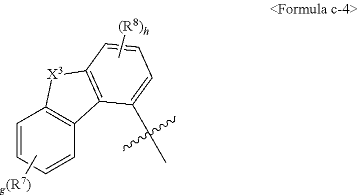

In Formula b to Formula d, Formula c-1 to Formula c-4, each of symbols may be defined as follows.

X3 is O or S.

R5 to R9 are each independently selected from the group consisting of hydrogen, deuterium, halogen, a silane group unsubstituted or substituted with a C1-C20 alkyl group or a C6-C20 aryl group, a phosphine oxide group unsubstituted or substituted with a C1-C20 alkyl group or a C6-C20 aryl group, siloxane group, a cyano group, a nitro group, a C1-C20 alkylthio group, a C1-C20 alkoxyl group, a C6-C20 aryloxy group, a C6-C20 arylthio group, a C1-C20 alkyl group, a C2-C20 alkenyl group, a C2-C20 alkynyl group, a C6-C30 aryl group, a fluorenyl group, a C2-C30 heterocyclic group comprising at least one heteroatom selected from the group consisting of O, N, S, Si and P, a C3-C30 aliphatic ring group, and —L′—N(Ra)(Rb), and adjacent groups may be bonded to each other to form a ring.

e, f and g are each an integer of 0 to 4, h is an integer of 0 to 3, i is an integer of 0 to 7, and when each of these is an integer of 2 or more, each of R5, each of R6, each of R7, each of R8, each of R9 are the same as or different from each other, and adjacent groups may be bonded to each other to form a ring.

Adjacent groups may be, for example, adjacent R5 groups, adjacent R6 groups, adjacent R7 groups, adjacent R8 groups, and when at least one pair of neighboring groups bonds to each other to form a ring, the ring may be selected from the group consisting of a C6-C60 aromatic ring group, a fluorene group, a C2-C60 heterocyclic group containing at least one heteroatom of O, N, S, Si and P, and a C3-C60 aliphatic ring group.

When an aromatic ring group is formed by adjacent group, the aromatic ring group may be a C6-C30, a C6-C20, a C6-C16, a C6-C14, a C6-C10 or a C6 aromatic ring group, specifically, it may be an aromatic ring such as benzene, naphthalene, phenanthrene, etc.

L′ is selected from the group consisting of a single bond, a C6-C30 arylene group, a fluorenylene group, a C2-C30 heterocyclic group containing at least one heteroatom of O, N, S, Si and P, and a C3-C30 aliphatic ring group.

Ra and Rb are each independently selected from the group consisting of a C6-C30 aryl group, a fluorenyl group, a C2-C30 heterocyclic group containing at least one heteroatom of O, N, S, Si and P, and a C3-C30 aliphatic ring group.

Formula 2 may be represented by one of Formula 2-1 to Formula 2-5.

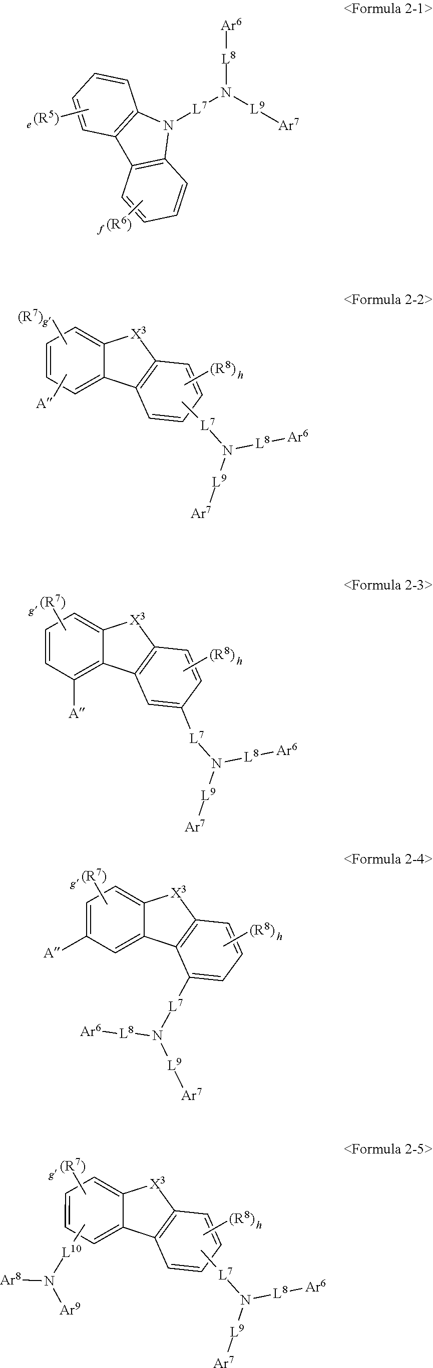

In Formula 2-1 to Formula 2-5, L7 to L9, Ar6, Ar7 are the same as defined for Formula 2.

X3 is O or S.

R5 to R8 are each independently selected from the group consisting of hydrogen, deuterium, halogen, a silane group unsubstituted or substituted with a C1-C20 alkyl group or a C6-C20 aryl group, a phosphine oxide group unsubstituted or substituted with a C1-C20 alkyl group or a C6-C20 aryl group, siloxane group, a cyano group, a nitro group, a C1-C20 alkylthio group, a C1-C20 alkoxyl group, a C6-C20 aryloxy group, a C6-C20 arylthio group, a C1-C20 alkyl group, a C2-C20 alkenyl group, a C2-C20 alkynyl group, a C6-C30 aryl group, a fluorenyl group, a C2-C30 heterocyclic group comprising at least one heteroatom selected from the group consisting of O, N, S, Si and P, a C3-C30 aliphatic ring group, and —L′—N(Ra)(Rb), and adjacent groups may be bonded to each other to form a ring.

e and f are each an integer of 0 to 4, g′ and h are each an integer of 0 to 3, and when each of these is an integer of 2 or more, each of R5, each of R6, each of R7, each of R8 are the same as or different from each other, and adjacent groups may be bonded to each other to form a ring.

Adjacent groups may be, for example, adjacent R5 groups, adjacent R6 groups, adjacent R7 groups, adjacent R8 groups, and when at least one pair of neighboring groups bonds to each other to form a ring, the ring may be selected from the group consisting of a C6-C60 aromatic ring group, a fluorene group, a C2-C60 heterocyclic group containing at least one heteroatom of O, N, S, Si and P, and a C3-C60 aliphatic ring group.

When an aromatic ring group is formed by adjacent group, the aromatic ring group may be a C6-C30, a C6-C20, a C6-C16, a C6-C14, a C6-C10 or a C6 aromatic ring group, specifically, it may be an aromatic ring such as benzene, naphthalene, phenanthrene, etc.

A″ is selected from the group consisting of a C1-C20 alkyl group, a C2-C20 alkenyl group, a C6-C30 aryl group, a fluorenyl group, a C2-C30 heterocyclic group comprising at least one heteroatom selected from the group consisting of O, N, S, Si and P, a C3-C30 aliphatic ring group, and —L′—N(Ra)(Rb).

L10 and L′ are each independently selected from the group consisting of a single bond, a C6-C30 arylene group, a fluorenylene group, a C2-C30 heterocyclic group containing at least one heteroatom of O, N, S, Si and P, and a C3-C30 aliphatic ring group.

Ar8, Ar9, Ra and Rb are each independently selected from the group consisting of a C6-C30 aryl group, a fluorenyl group, a C2-C30 heterocyclic group containing at least one heteroatom of O, N, S, Si and P, and a C3-C30 aliphatic ring group.

Specifically, the compound represented by Formula 1 may be one of the following compounds, but there is no limitation thereto.

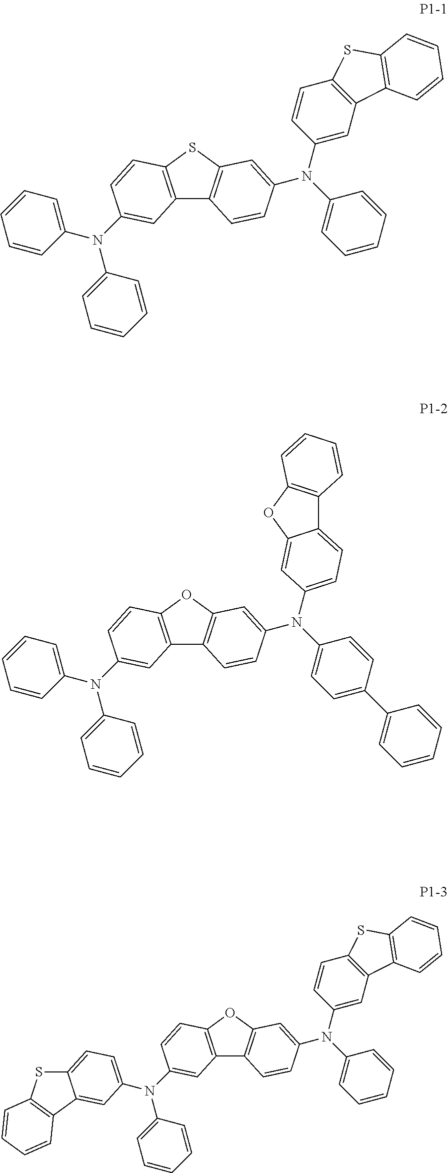 [SMILES: c1ccc(N(c2ccc3c(c2)sc2ccc(N(c4ccccc4)c4ccccc4)cc23)c2ccc3sc4ccccc4c3c2)cc1 ; c1ccc(-c2ccc(N(c3ccc4c(c3)oc3ccccc34)c3ccc4c(c3)oc3ccc(N(c5ccccc5)c5ccccc5)cc34)cc2)cc1 ; c1ccc(N(c2ccc3c(c2)oc2ccc(N(c4ccccc4)c4ccc5sc6ccccc6c5c4)cc23)c2ccc3sc4ccccc4c3c2)cc1]

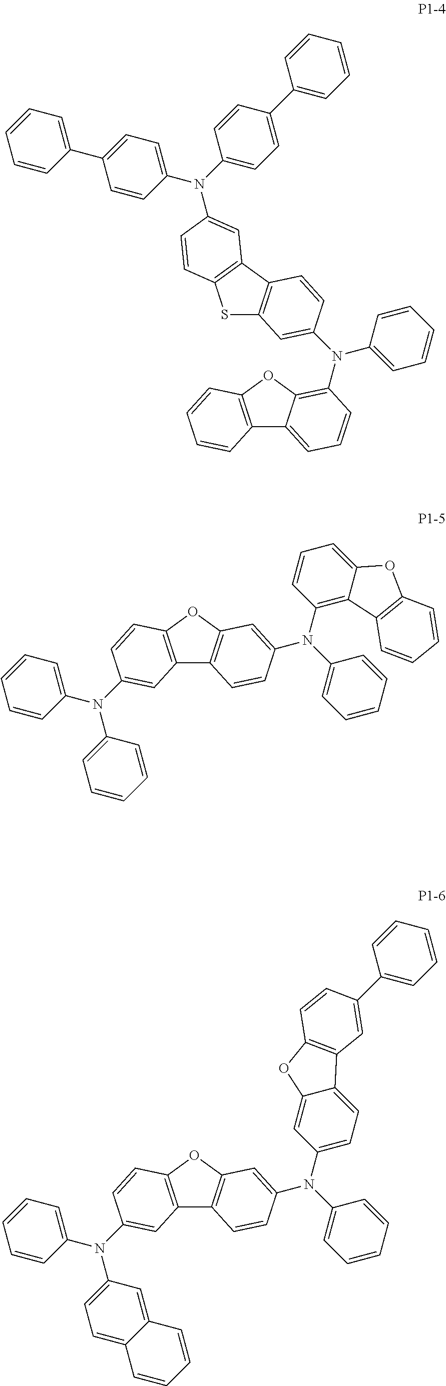 [SMILES: c1ccc(-c2ccc(N(c3ccc(-c4ccccc4)cc3)c3ccc4sc5cc(N(c6ccccc6)c6cccc7c6oc6ccccc67)ccc5c4c3)cc2)cc1 ; c1ccc(N(c2ccccc2)c2ccc3oc4cc(N(c5ccccc5)c5cccc6oc7ccccc7c56)ccc4c3c2)cc1 ; c1ccc(-c2ccc3oc4cc(N(c5ccccc5)c5ccc6c(c5)oc5ccc(N(c7ccccc7)c7ccc8ccccc8c7)cc56)ccc4c3c2)cc1]

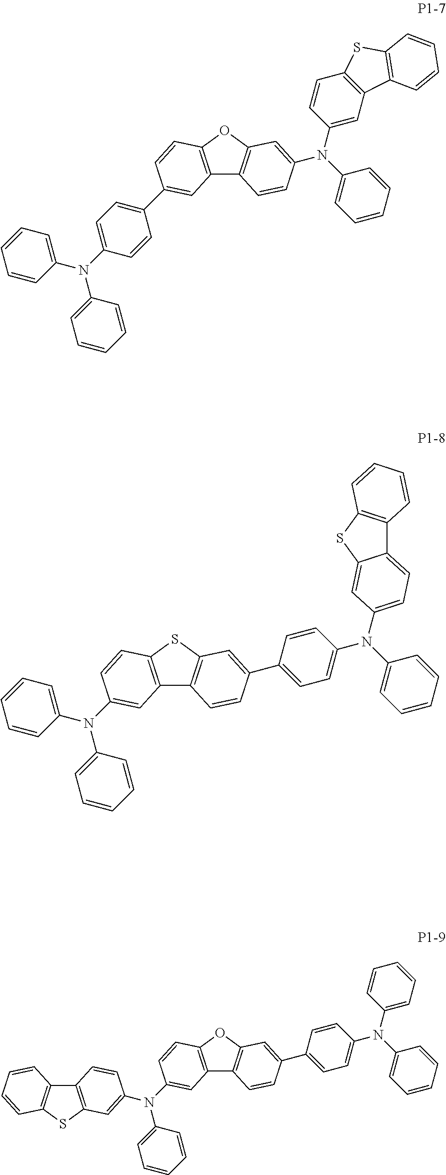 [SMILES: c1ccc(N(c2ccccc2)c2ccc(-c3ccc4oc5cc(N(c6ccccc6)c6ccc7sc8ccccc8c7c6)ccc5c4c3)cc2)cc1 ; c1ccc(N(c2ccc(-c3ccc4c(c3)sc3ccc(N(c5ccccc5)c5ccccc5)cc34)cc2)c2ccc3c(c2)sc2ccccc23)cc1 ; c1ccc(N(c2ccccc2)c2ccc(-c3ccc4c(c3)oc3ccc(N(c5ccccc5)c5ccc6c(c5)sc5ccccc56)cc34)cc2)cc1]

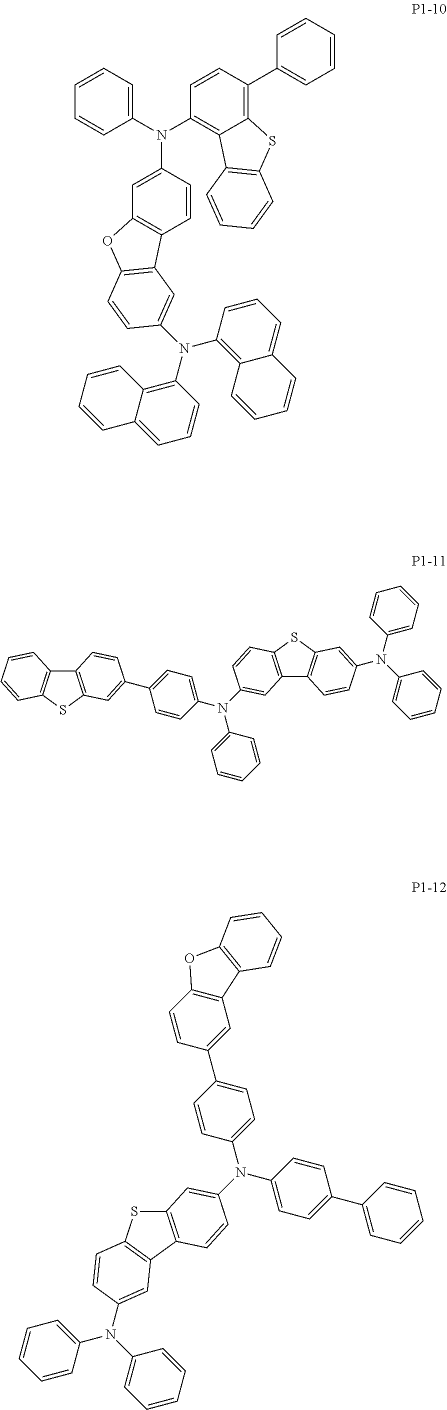 [SMILES: c1ccc(-c2ccc(N(c3ccccc3)c3ccc4c(c3)oc3ccc(N(c5cccc6ccccc56)c5cccc6ccccc56)cc34)c3c2sc2ccccc23)cc1 ; c1ccc(N(c2ccccc2)c2ccc3c(c2)sc2ccc(N(c4ccccc4)c4ccc(-c5ccc6c(c5)sc5ccccc56)cc4)cc23)cc1 ; c1ccc(-c2ccc(N(c3ccc(-c4ccc5oc6ccccc6c5c4)cc3)c3ccc4c(c3)sc3ccc(N(c5ccccc5)c5ccccc5)cc34)cc2)cc1]

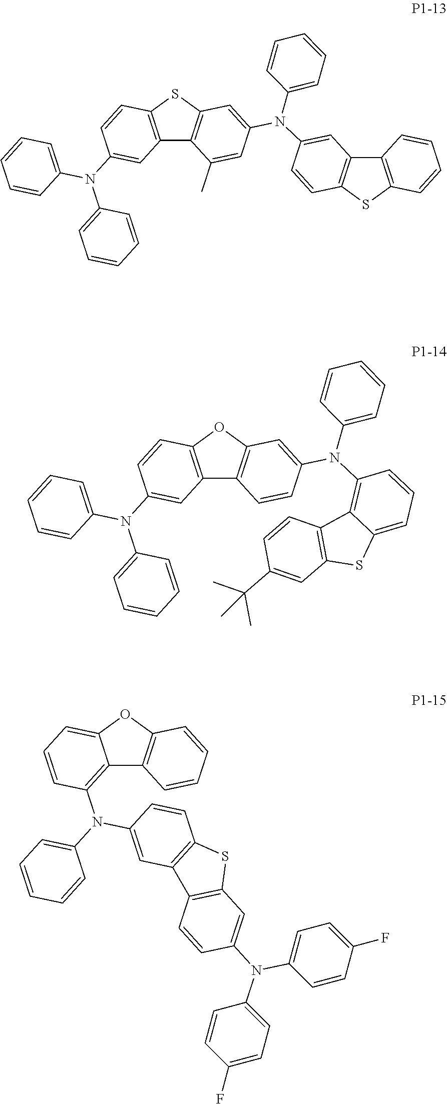 [SMILES: Cc1cc(N(c2ccccc2)c2ccc3sc4ccccc4c3c2)cc2sc3ccc(N(c4ccccc4)c4ccccc4)cc3c12 ; CC(C)(C)c1ccc2c(c1)sc1cccc(N(c3ccccc3)c3ccc4c(c3)oc3ccc(N(c5ccccc5)c5ccccc5)cc34)c12 ; Fc1ccc(N(c2ccc(F)cc2)c2ccc3c(c2)sc2ccc(N(c4ccccc4)c4cccc5oc6ccccc6c45)cc23)cc1]

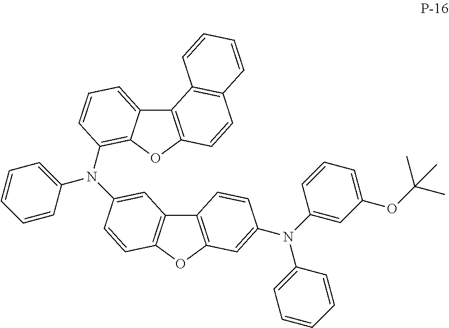 [SMILES: CC(C)(C)Oc1cccc(N(c2ccccc2)c2ccc3c(c2)oc2ccc(N(c4ccccc4)c4cccc5c4oc4ccc6ccccc6c45)cc23)c1]

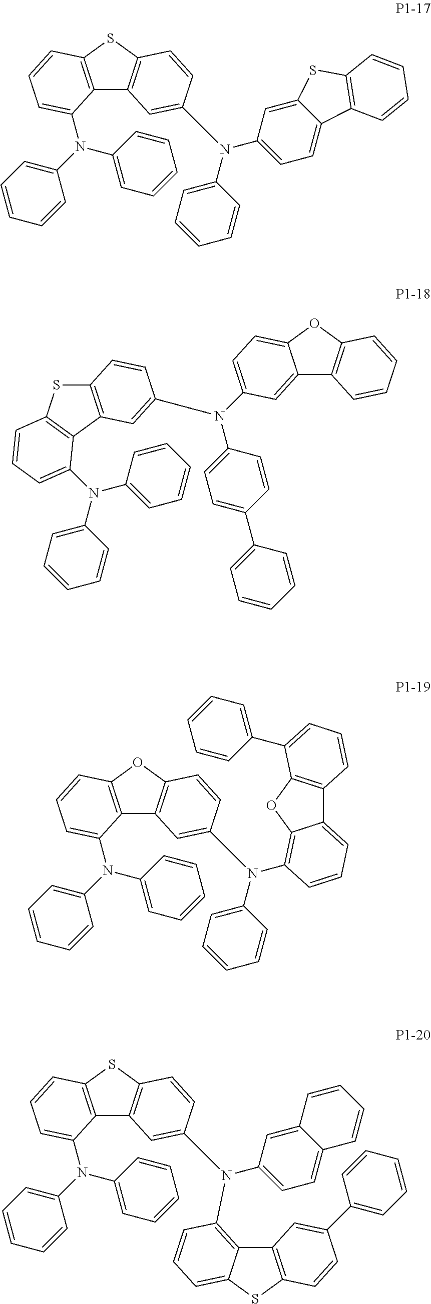 [SMILES: c1ccc(N(c2ccc3c(c2)sc2ccccc23)c2ccc3sc4cccc(N(c5ccccc5)c5ccccc5)c4c3c2)cc1 ; c1ccc(-c2ccc(N(c3ccc4oc5ccccc5c4c3)c3ccc4sc5cccc(N(c6ccccc6)c6ccccc6)c5c4c3)cc2)cc1 ; c1ccc(-c2cccc3c2oc2c(N(c4ccccc4)c4ccc5oc6cccc(N(c7ccccc7)c7ccccc7)c6c5c4)cccc23)cc1 ; c1ccc(-c2ccc3sc4cccc(N(c5ccc6ccccc6c5)c5ccc6sc7cccc(N(c8ccccc8)c8ccccc8)c7c6c5)c4c3c2)cc1]

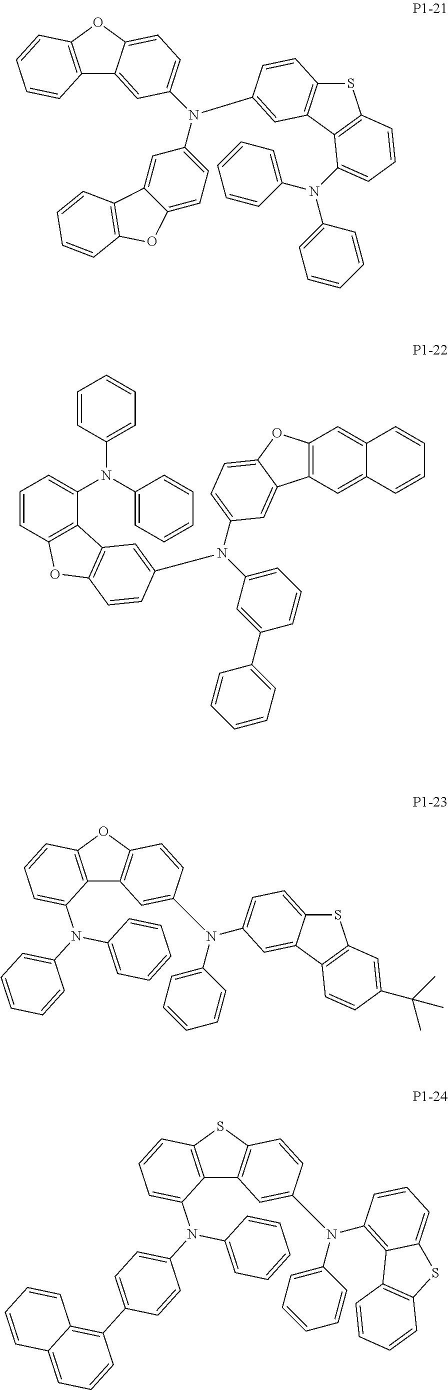 [SMILES: c1ccc(N(c2ccccc2)c2cccc3sc4ccc(N(c5ccc6oc7ccccc7c6c5)c5ccc6oc7ccccc7c6c5)cc4c23)cc1 ; c1ccc(-c2cccc(N(c3ccc4oc5cc6ccccc6cc5c4c3)c3ccc4oc5cccc(N(c6ccccc6)c6ccccc6)c5c4c3)c2)cc1 ; CC(C)(C)c1ccc2c(c1)sc1ccc(N(c3ccccc3)c3ccc4oc5cccc(N(c6ccccc6)c6ccccc6)c5c4c3)cc12 ; c1ccc(N(c2ccc3sc4cccc(N(c5ccccc5)c5ccc(-c6cccc7ccccc67)cc5)c4c3c2)c2cccc3sc4ccccc4c23)cc1]

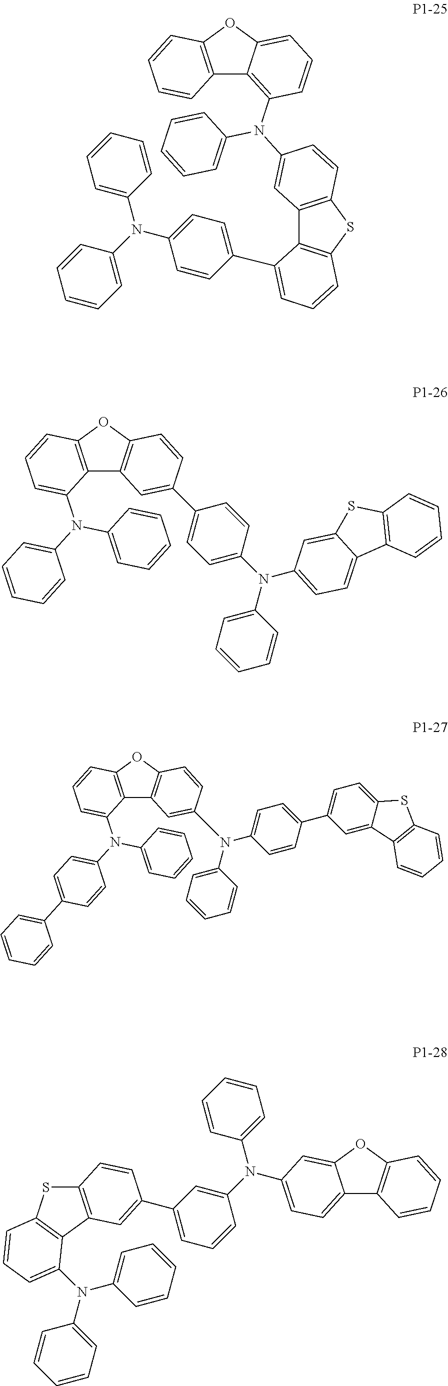 [SMILES: c1ccc(N(c2ccccc2)c2ccc(-c3cccc4sc5ccc(N(c6ccccc6)c6cccc7oc8ccccc8c67)cc5c34)cc2)cc1 ; c1ccc(N(c2ccc(-c3ccc4oc5cccc(N(c6ccccc6)c6ccccc6)c5c4c3)cc2)c2ccc3c(c2)sc2ccccc23)cc1 ; c1ccc(-c2ccc(N(c3ccccc3)c3cccc4oc5ccc(N(c6ccccc6)c6ccc(-c7ccc8sc9ccccc9c8c7)cc6)cc5c34)cc2)cc1 ; c1ccc(N(c2cccc(-c3ccc4sc5cccc(N(c6ccccc6)c6ccccc6)c5c4c3)c2)c2ccc3c(c2)oc2ccccc23)cc1]

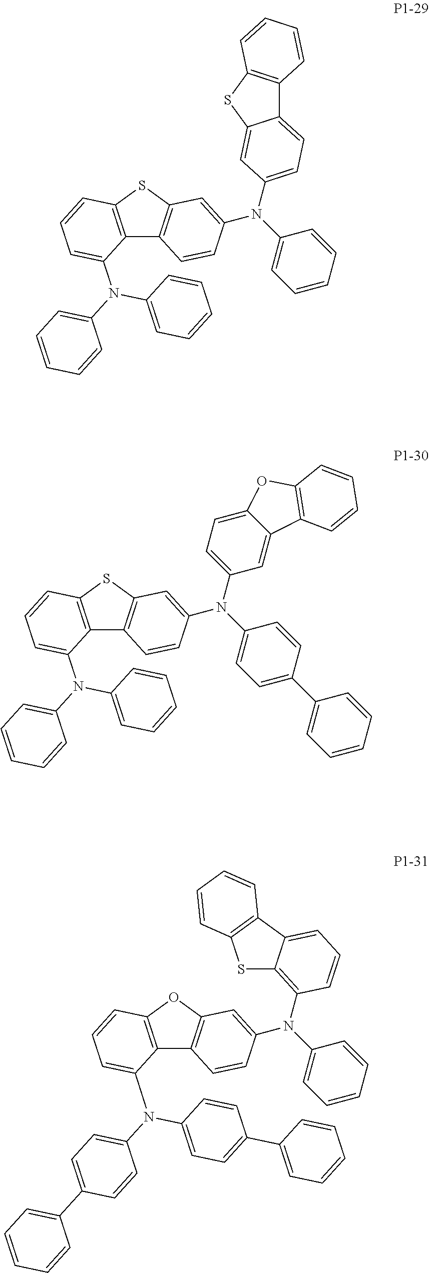 [SMILES: c1ccc(N(c2ccc3c(c2)sc2ccccc23)c2ccc3c(c2)sc2cccc(N(c4ccccc4)c4ccccc4)c23)cc1 ; c1ccc(-c2ccc(N(c3ccc4c(c3)sc3cccc(N(c5ccccc5)c5ccccc5)c34)c3ccc4oc5ccccc5c4c3)cc2)cc1 ; c1ccc(-c2ccc(N(c3ccc(-c4ccccc4)cc3)c3cccc4oc5cc(N(c6ccccc6)c6cccc7c6sc6ccccc67)ccc5c34)cc2)cc1]

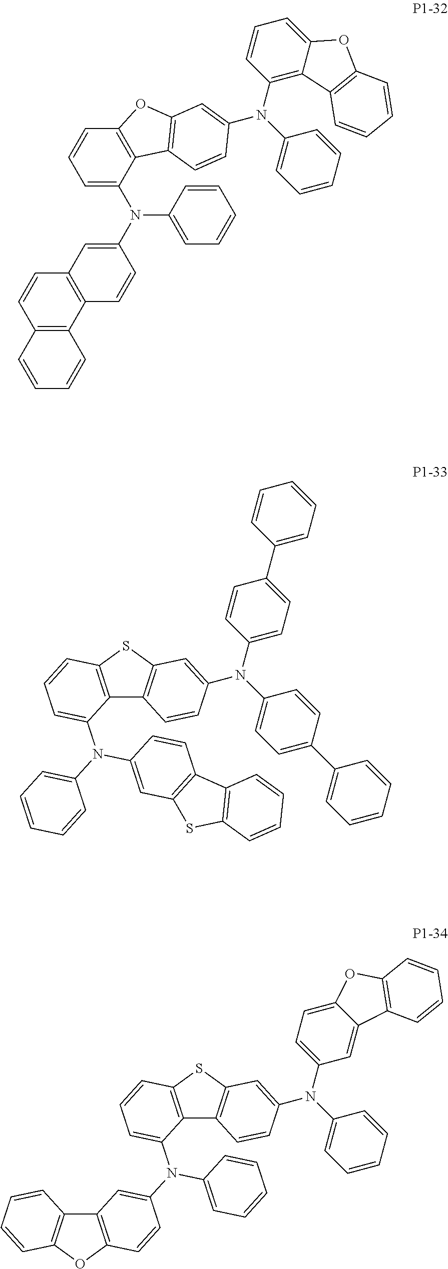 [SMILES: c1ccc(N(c2ccc3c(c2)oc2cccc(N(c4ccccc4)c4ccc5c(ccc6ccccc65)c4)c23)c2cccc3oc4ccccc4c23)cc1 ; c1ccc(-c2ccc(N(c3ccc(-c4ccccc4)cc3)c3ccc4c(c3)sc3cccc(N(c5ccccc5)c5ccc6c(c5)sc5ccccc56)c34)cc2)cc1 ; c1ccc(N(c2ccc3c(c2)sc2cccc(N(c4ccccc4)c4ccc5oc6ccccc6c5c4)c23)c2ccc3oc4ccccc4c3c2)cc1]

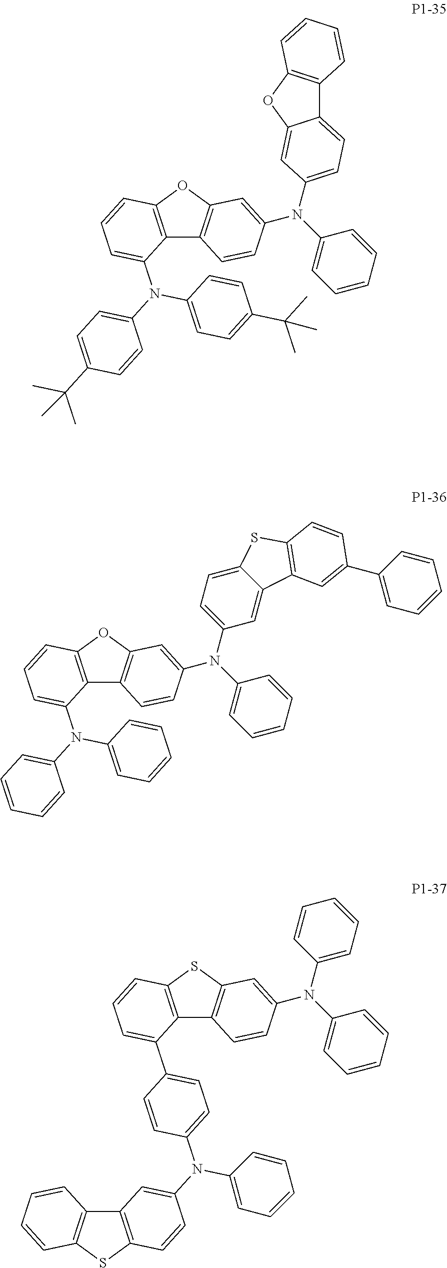 [SMILES: CC(C)(C)c1ccc(N(c2ccc(C(C)(C)C)cc2)c2cccc3oc4cc(N(c5ccccc5)c5ccc6c(c5)oc5ccccc56)ccc4c23)cc1 ; c1ccc(-c2ccc3sc4ccc(N(c5ccccc5)c5ccc6c(c5)oc5cccc(N(c7ccccc7)c7ccccc7)c56)cc4c3c2)cc1 ; c1ccc(N(c2ccccc2)c2ccc3c(c2)sc2cccc(-c4ccc(N(c5ccccc5)c5ccc6sc7ccccc7c6c5)cc4)c23)cc1]

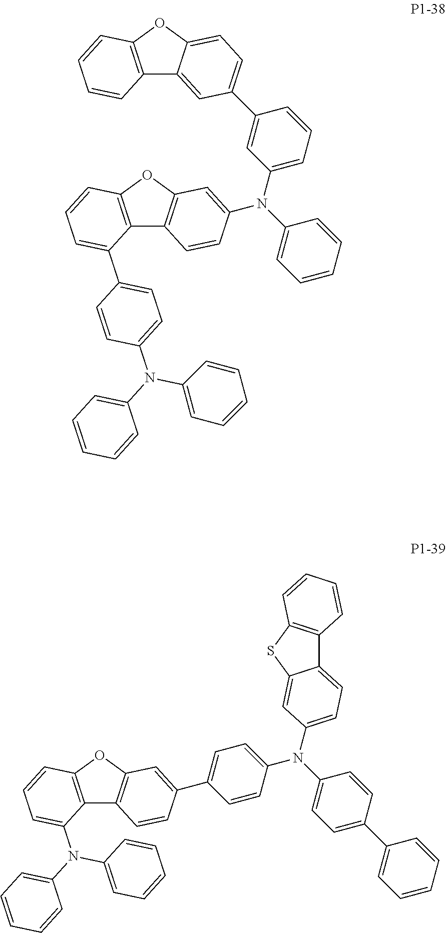 [SMILES: c1ccc(N(c2ccccc2)c2ccc(-c3cccc4oc5cc(N(c6ccccc6)c6cccc(-c7ccc8oc9ccccc9c8c7)c6)ccc5c34)cc2)cc1 ; c1ccc(-c2ccc(N(c3ccc(-c4ccc5c(c4)oc4cccc(N(c6ccccc6)c6ccccc6)c45)cc3)c3ccc4c(c3)sc3ccccc34)cc2)cc1]

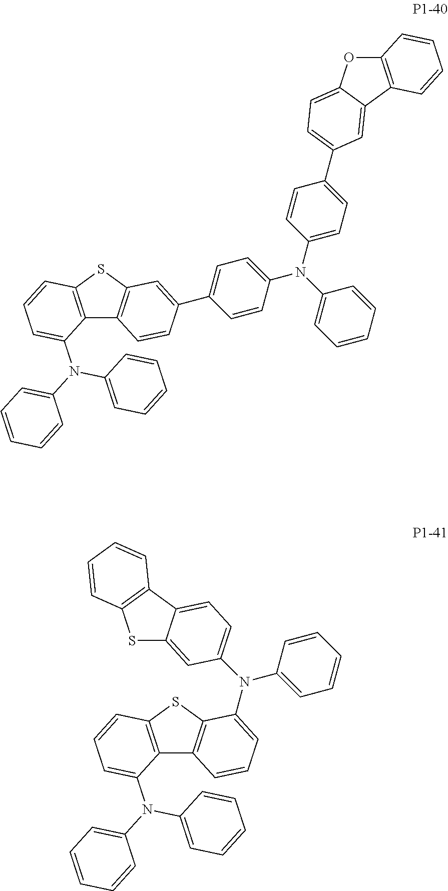 [SMILES: c1ccc(N(c2ccc(-c3ccc4c(c3)sc3cccc(N(c5ccccc5)c5ccccc5)c34)cc2)c2ccc(-c3ccc4oc5ccccc5c4c3)cc2)cc1 ; c1ccc(N(c2ccc3c(c2)sc2ccccc23)c2cccc3c2sc2cccc(N(c4ccccc4)c4ccccc4)c23)cc1]

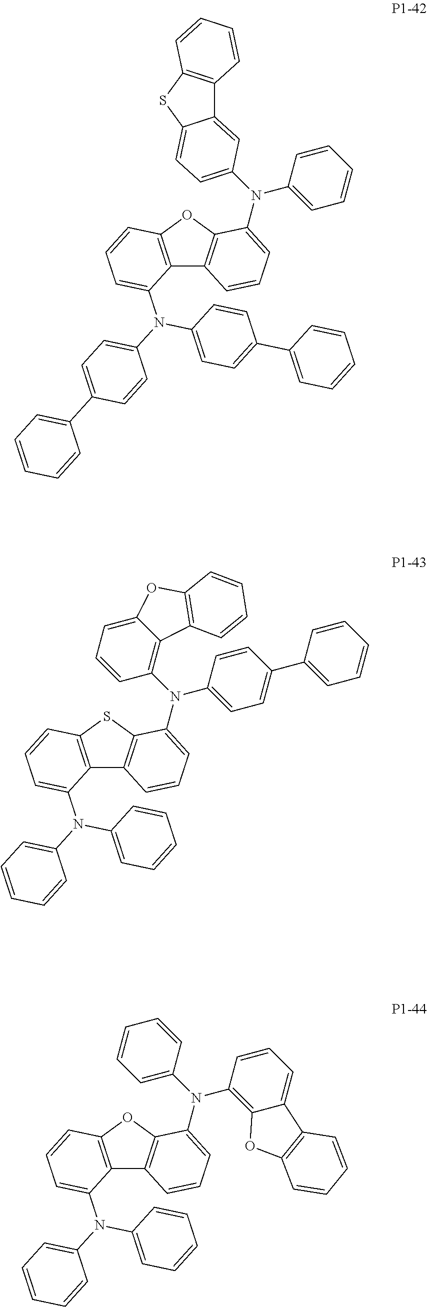 [SMILES: c1ccc(-c2ccc(N(c3ccc(-c4ccccc4)cc3)c3cccc4oc5c(N(c6ccccc6)c6ccc7sc8ccccc8c7c6)cccc5c34)cc2)cc1 ; c1ccc(-c2ccc(N(c3cccc4c3sc3cccc(N(c5ccccc5)c5ccccc5)c34)c3cccc4oc5ccccc5c34)cc2)cc1 ; c1ccc(N(c2cccc3c2oc2ccccc23)c2cccc3c2oc2cccc(N(c4ccccc4)c4ccccc4)c23)cc1]

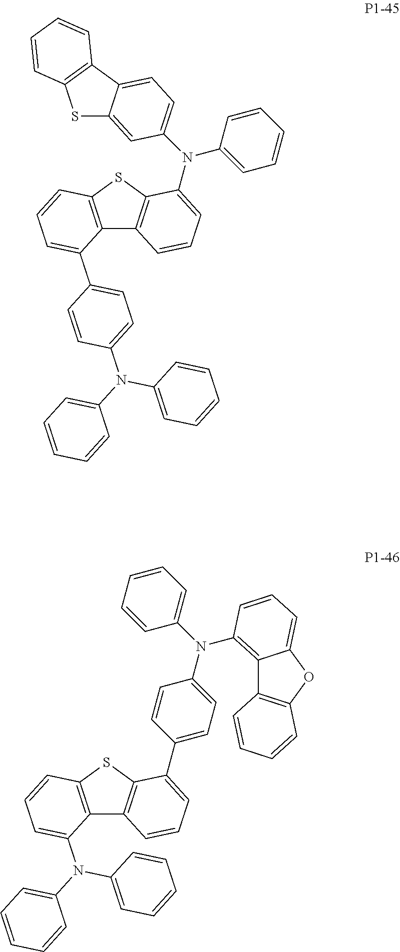 [SMILES: c1ccc(N(c2ccccc2)c2ccc(-c3cccc4sc5c(N(c6ccccc6)c6ccc7c(c6)sc6ccccc67)cccc5c34)cc2)cc1 ; c1ccc(N(c2ccc(-c3cccc4c3sc3cccc(N(c5ccccc5)c5ccccc5)c34)cc2)c2cccc3oc4ccccc4c23)cc1]

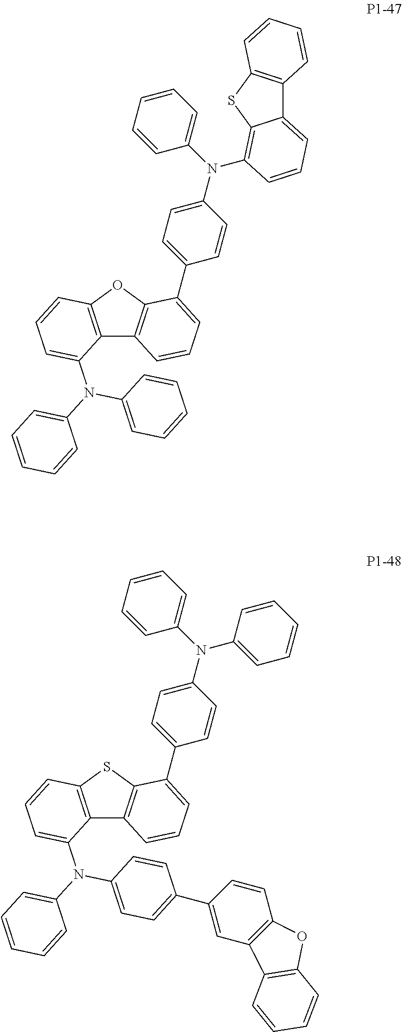 [SMILES: c1ccc(N(c2ccc(-c3cccc4c3oc3cccc(N(c5ccccc5)c5ccccc5)c34)cc2)c2cccc3c2sc2ccccc23)cc1 ; c1ccc(N(c2ccccc2)c2ccc(-c3cccc4c3sc3cccc(N(c5ccccc5)c5ccc(-c6ccc7oc8ccccc8c7c6)cc5)c34)cc2)cc1]

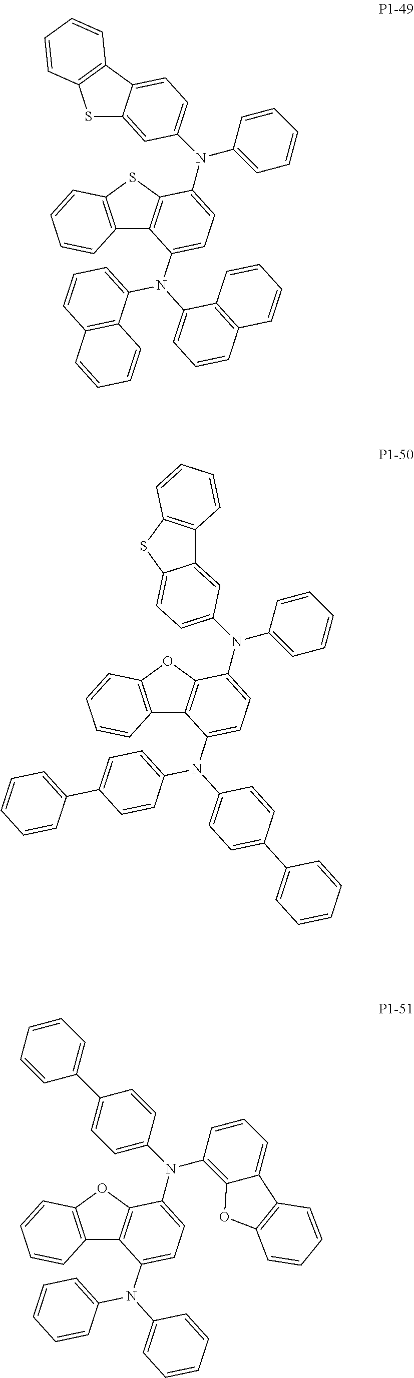 [SMILES: c1ccc(N(c2ccc3c(c2)sc2ccccc23)c2ccc(N(c3cccc4ccccc34)c3cccc4ccccc34)c3c2sc2ccccc23)cc1 ; c1ccc(-c2ccc(N(c3ccc(-c4ccccc4)cc3)c3ccc(N(c4ccccc4)c4ccc5sc6ccccc6c5c4)c4oc5ccccc5c34)cc2)cc1 ; c1ccc(-c2ccc(N(c3cccc4c3oc3ccccc34)c3ccc(N(c4ccccc4)c4ccccc4)c4c3oc3ccccc34)cc2)cc1]

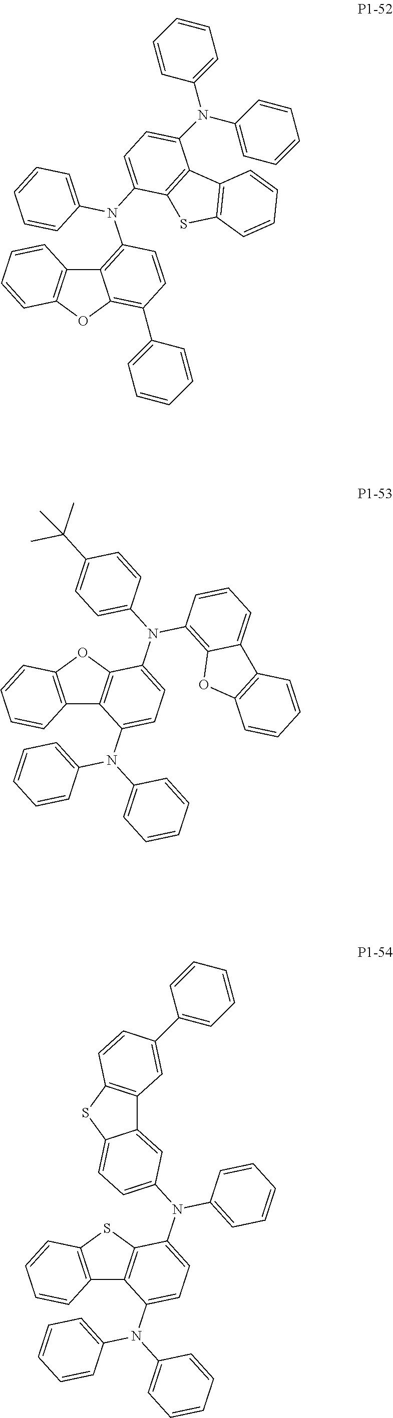 [SMILES: c1ccc(-c2ccc(N(c3ccccc3)c3ccc(N(c4ccccc4)c4ccccc4)c4c3sc3ccccc34)c3c2oc2ccccc23)cc1 ; CC(C)(C)c1ccc(N(c2cccc3c2oc2ccccc23)c2ccc(N(c3ccccc3)c3ccccc3)c3c2oc2ccccc23)cc1 ; c1ccc(-c2ccc3sc4ccc(N(c5ccccc5)c5ccc(N(c6ccccc6)c6ccccc6)c6c5sc5ccccc56)cc4c3c2)cc1]

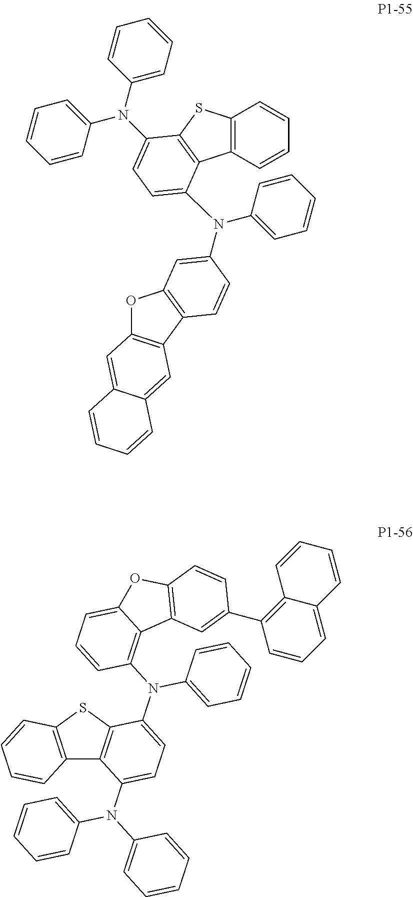 [SMILES: c1ccc(N(c2ccccc2)c2ccc(N(c3ccccc3)c3ccc4c(c3)oc3cc5ccccc5cc34)c3c2sc2ccccc23)cc1 ; c1ccc(N(c2ccc(N(c3ccccc3)c3ccccc3)c3c2sc2ccccc23)c2cccc3oc4ccc(-c5cccc6ccccc56)cc4c23)cc1]

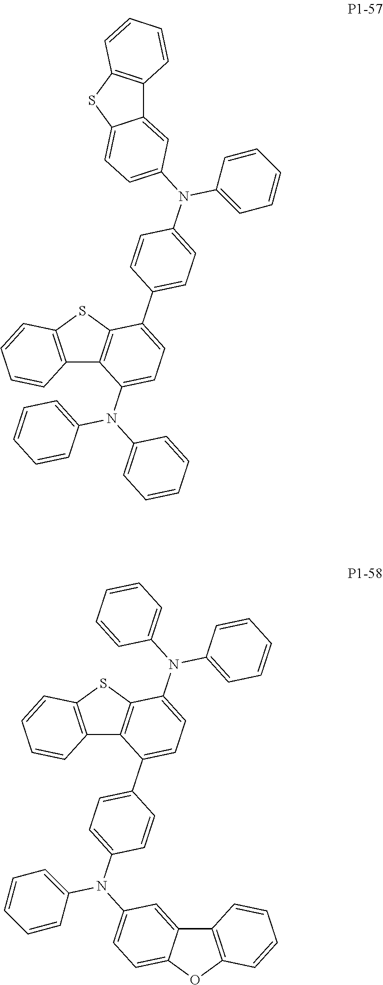 [SMILES: c1ccc(N(c2ccc(-c3ccc(N(c4ccccc4)c4ccccc4)c4c3sc3ccccc34)cc2)c2ccc3sc4ccccc4c3c2)cc1 ; c1ccc(N(c2ccc(-c3ccc(N(c4ccccc4)c4ccccc4)c4sc5ccccc5c34)cc2)c2ccc3oc4ccccc4c3c2)cc1]

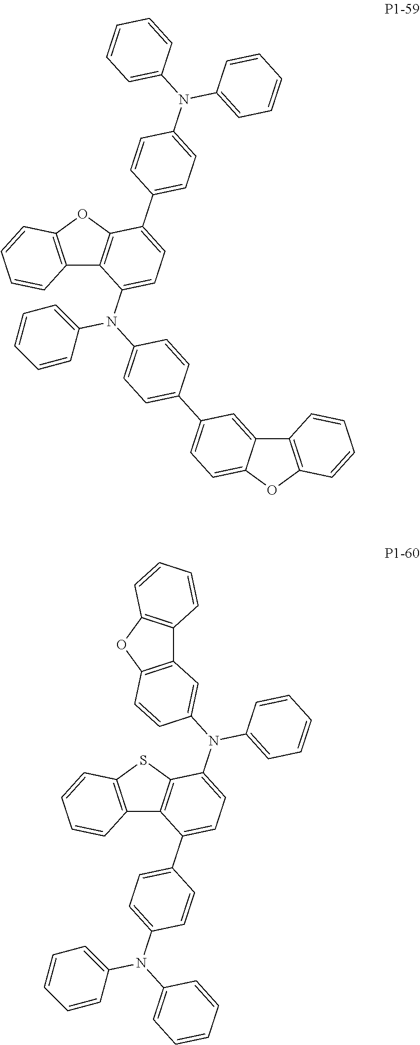 [SMILES: c1ccc(N(c2ccccc2)c2ccc(-c3ccc(N(c4ccccc4)c4ccc(-c5ccc6oc7ccccc7c6c5)cc4)c4c3oc3ccccc34)cc2)cc1 ; c1ccc(N(c2ccccc2)c2ccc(-c3ccc(N(c4ccccc4)c4ccc5oc6ccccc6c5c4)c4sc5ccccc5c34)cc2)cc1]

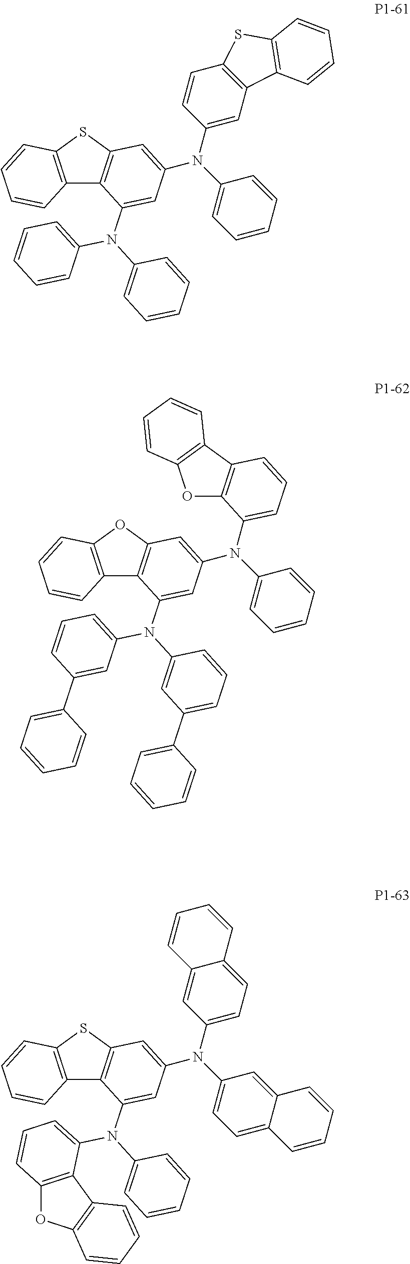 [SMILES: c1ccc(N(c2cc(N(c3ccccc3)c3ccccc3)c3c(c2)sc2ccccc23)c2ccc3sc4ccccc4c3c2)cc1 ; c1ccc(-c2cccc(N(c3cccc(-c4ccccc4)c3)c3cc(N(c4ccccc4)c4cccc5c4oc4ccccc45)cc4oc5ccccc5c34)c2)cc1 ; c1ccc(N(c2cccc3oc4ccccc4c23)c2cc(N(c3ccc4ccccc4c3)c3ccc4ccccc4c3)cc3sc4ccccc4c23)cc1]

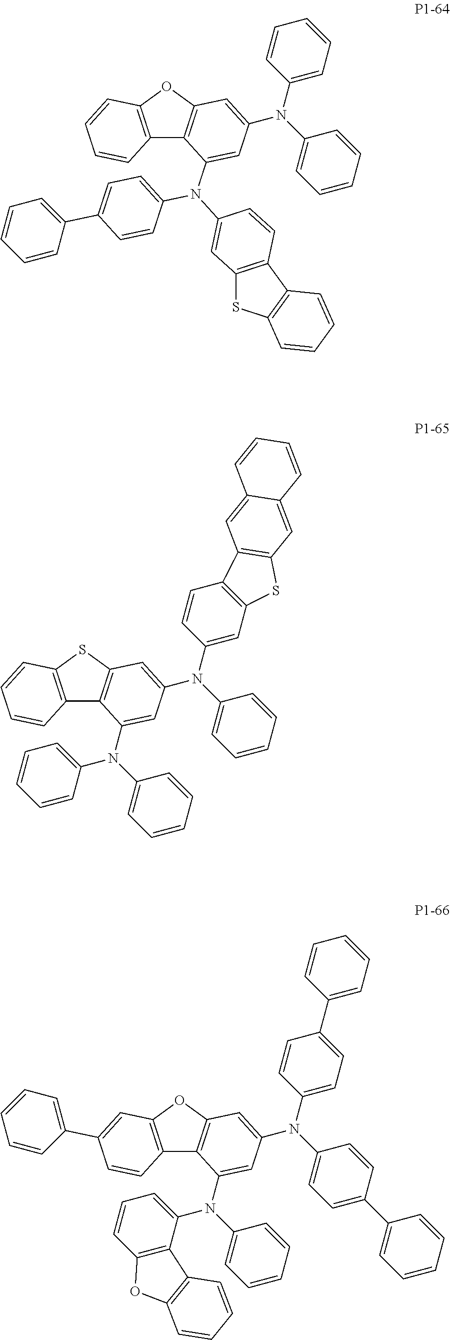 [SMILES: c1ccc(-c2ccc(N(c3ccc4c(c3)sc3ccccc34)c3cc(N(c4ccccc4)c4ccccc4)cc4oc5ccccc5c34)cc2)cc1 ; c1ccc(N(c2ccc3c(c2)sc2cc4ccccc4cc23)c2cc(N(c3ccccc3)c3ccccc3)c3c(c2)sc2ccccc23)cc1 ; c1ccc(-c2ccc(N(c3ccc(-c4ccccc4)cc3)c3cc(N(c4ccccc4)c4cccc5oc6ccccc6c45)c4c(c3)oc3cc(-c5ccccc5)ccc34)cc2)cc1]

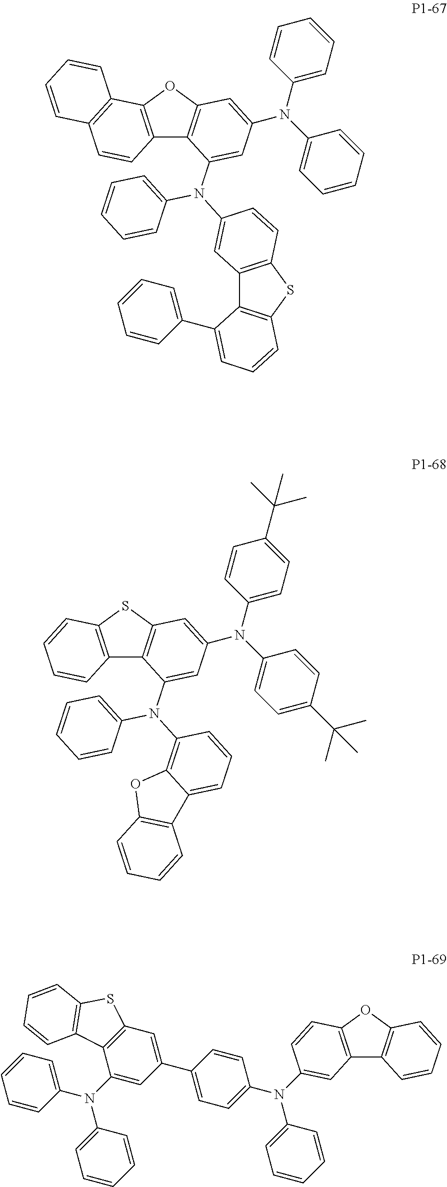 [SMILES: c1ccc(-c2cccc3sc4ccc(N(c5ccccc5)c5cc(N(c6ccccc6)c6ccccc6)cc6oc7c8ccccc8ccc7c56)cc4c23)cc1 ; CC(C)(C)c1ccc(N(c2ccc(C(C)(C)C)cc2)c2cc(N(c3ccccc3)c3cccc4c3oc3ccccc34)c3c(c2)sc2ccccc23)cc1 ; c1ccc(N(c2ccc(-c3cc(N(c4ccccc4)c4ccccc4)c4c(c3)sc3ccccc34)cc2)c2ccc3oc4ccccc4c3c2)cc1]

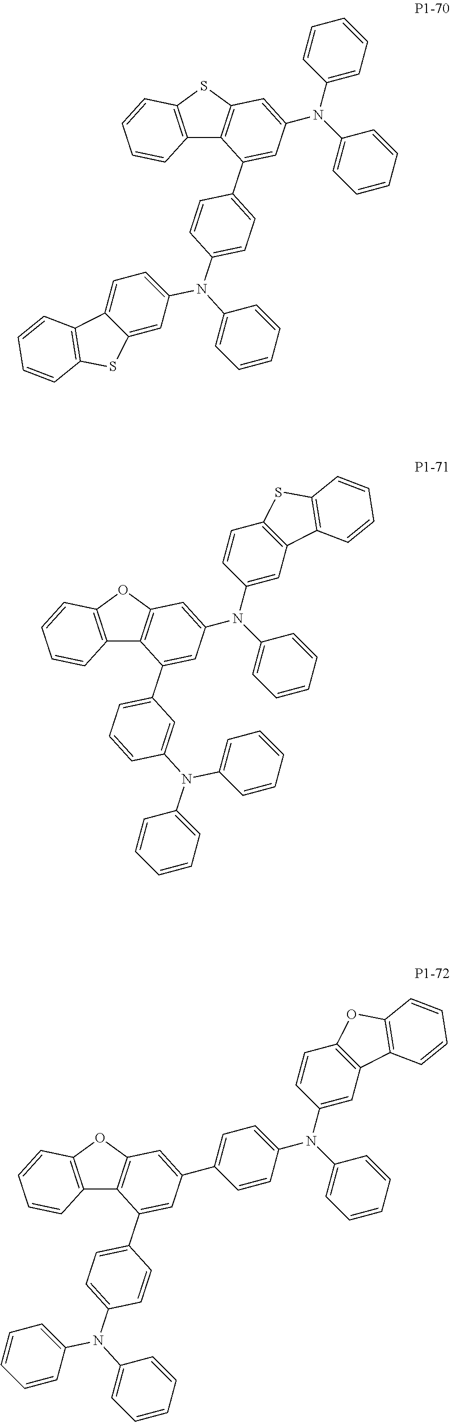 [SMILES: c1ccc(N(c2ccc(-c3cc(N(c4ccccc4)c4ccccc4)cc4sc5ccccc5c34)cc2)c2ccc3c(c2)sc2ccccc23)cc1 ; c1ccc(N(c2ccccc2)c2cccc(-c3cc(N(c4ccccc4)c4ccc5sc6ccccc6c5c4)cc4oc5ccccc5c34)c2)cc1 ; c1ccc(N(c2ccccc2)c2ccc(-c3cc(-c4ccc(N(c5ccccc5)c5ccc6oc7ccccc7c6c5)cc4)cc4oc5ccccc5c34)cc2)cc1]

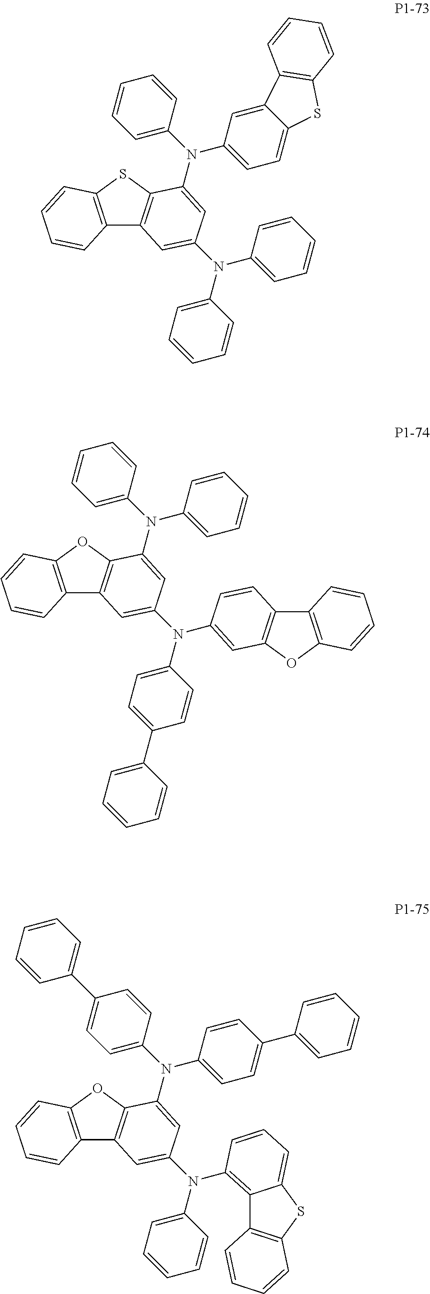 [SMILES: c1ccc(N(c2ccccc2)c2cc(N(c3ccccc3)c3ccc4sc5ccccc5c4c3)c3sc4ccccc4c3c2)cc1 ; c1ccc(-c2ccc(N(c3ccc4c(c3)oc3ccccc34)c3cc(N(c4ccccc4)c4ccccc4)c4oc5ccccc5c4c3)cc2)cc1 ; c1ccc(-c2ccc(N(c3ccc(-c4ccccc4)cc3)c3cc(N(c4ccccc4)c4cccc5sc6ccccc6c45)cc4c3oc3ccccc34)cc2)cc1]

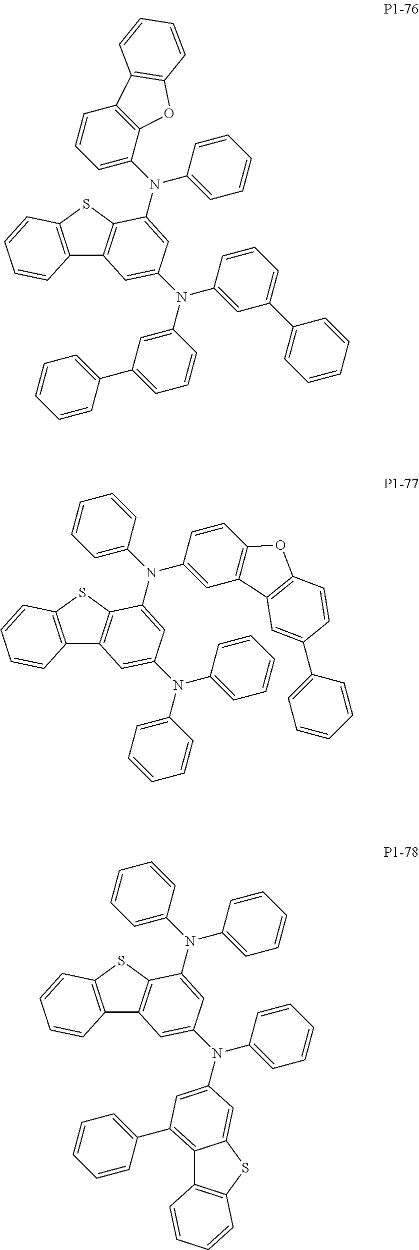 [SMILES: c1ccc(-c2cccc(N(c3cccc(-c4ccccc4)c3)c3cc(N(c4ccccc4)c4cccc5c4oc4ccccc45)c4sc5ccccc5c4c3)c2)cc1 ; c1ccc(-c2ccc3oc4ccc(N(c5ccccc5)c5cc(N(c6ccccc6)c6ccccc6)cc6c5sc5ccccc56)cc4c3c2)cc1 ; c1ccc(-c2cc(N(c3ccccc3)c3cc(N(c4ccccc4)c4ccccc4)c4sc5ccccc5c4c3)cc3sc4ccccc4c23)cc1]

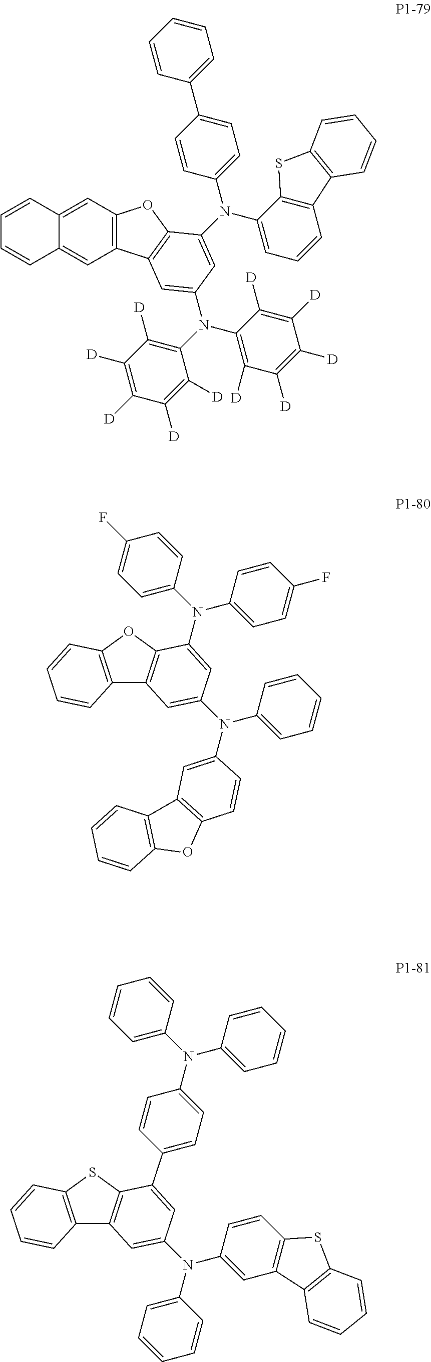 [SMILES: [2H]c1c([2H])c([2H])c(N(c2cc(N(c3ccc(-c4ccccc4)cc3)c3cccc4c3sc3ccccc34)c3oc4cc5ccccc5cc4c3c2)c2c([2H])c([2H])c([2H])c([2H])c2[2H])c([2H])c1[2H] ; Fc1ccc(N(c2ccc(F)cc2)c2cc(N(c3ccccc3)c3ccc4oc5ccccc5c4c3)cc3c2oc2ccccc23)cc1 ; c1ccc(N(c2ccccc2)c2ccc(-c3cc(N(c4ccccc4)c4ccc5sc6ccccc6c5c4)cc4c3sc3ccccc34)cc2)cc1]

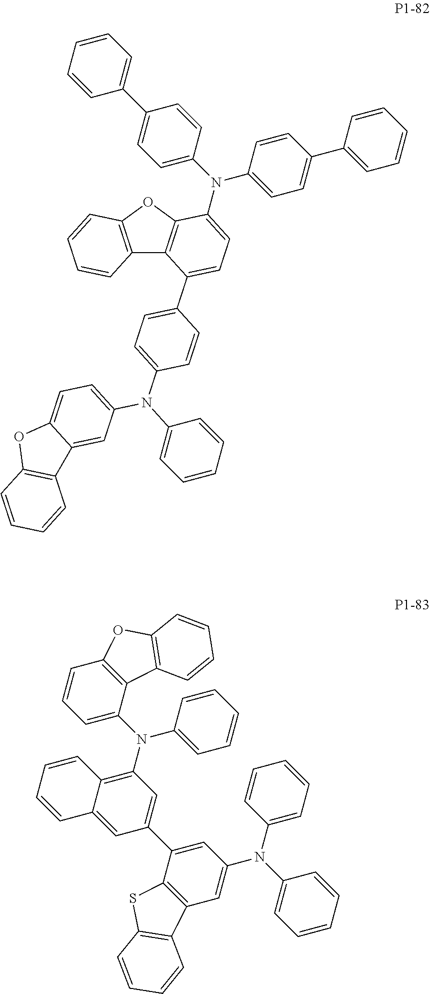 [SMILES: c1ccc(-c2ccc(N(c3ccc(-c4ccccc4)cc3)c3ccc(-c4ccc(N(c5ccccc5)c5ccc6oc7ccccc7c6c5)cc4)c4c3oc3ccccc34)cc2)cc1 ; c1ccc(N(c2ccccc2)c2cc(-c3cc(N(c4ccccc4)c4cccc5oc6ccccc6c45)c4ccccc4c3)c3sc4ccccc4c3c2)cc1]

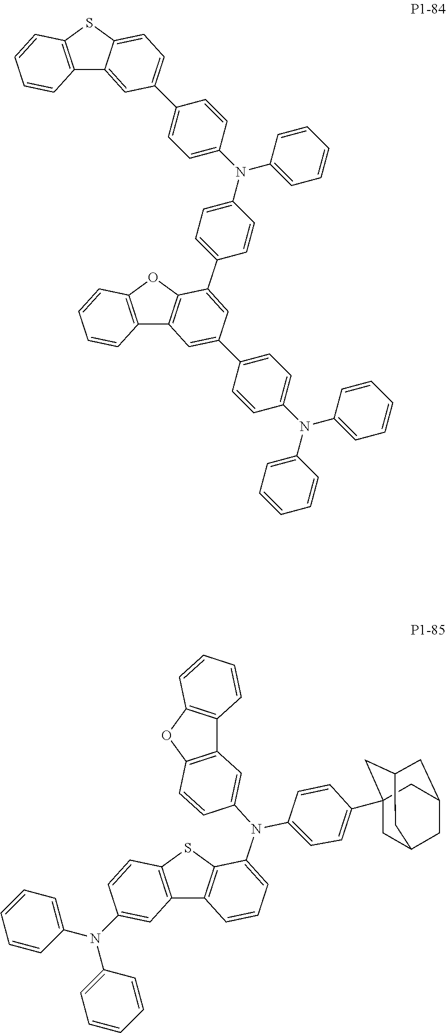 [SMILES: c1ccc(N(c2ccccc2)c2ccc(-c3cc(-c4ccc(N(c5ccccc5)c5ccc(-c6ccc7sc8ccccc8c7c6)cc5)cc4)c4oc5ccccc5c4c3)cc2)cc1 ; c1ccc(N(c2ccccc2)c2ccc3sc4c(N(c5ccc(C67CC8CC(CC(C8)C6)C7)cc5)c5ccc6oc7ccccc7c6c5)cccc4c3c2)cc1]

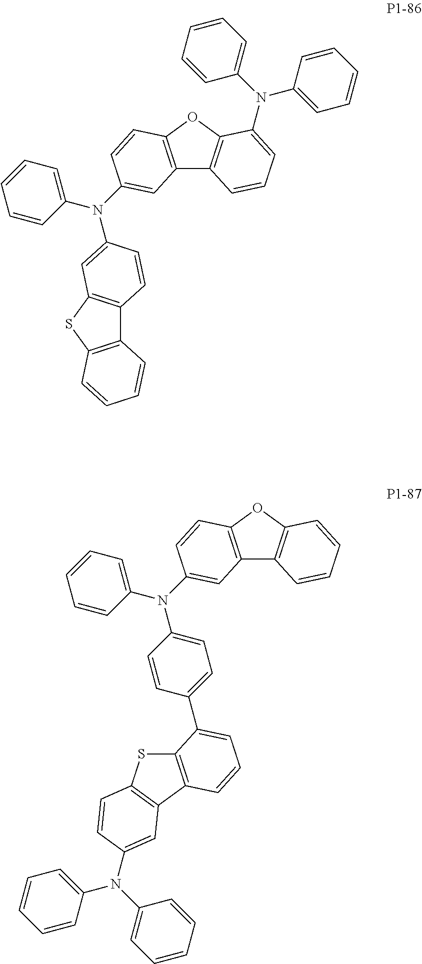 [SMILES: c1ccc(N(c2ccc3c(c2)sc2ccccc23)c2ccc3oc4c(N(c5ccccc5)c5ccccc5)cccc4c3c2)cc1 ; c1ccc(N(c2ccc(-c3cccc4c3sc3ccc(N(c5ccccc5)c5ccccc5)cc34)cc2)c2ccc3oc4ccccc4c3c2)cc1]

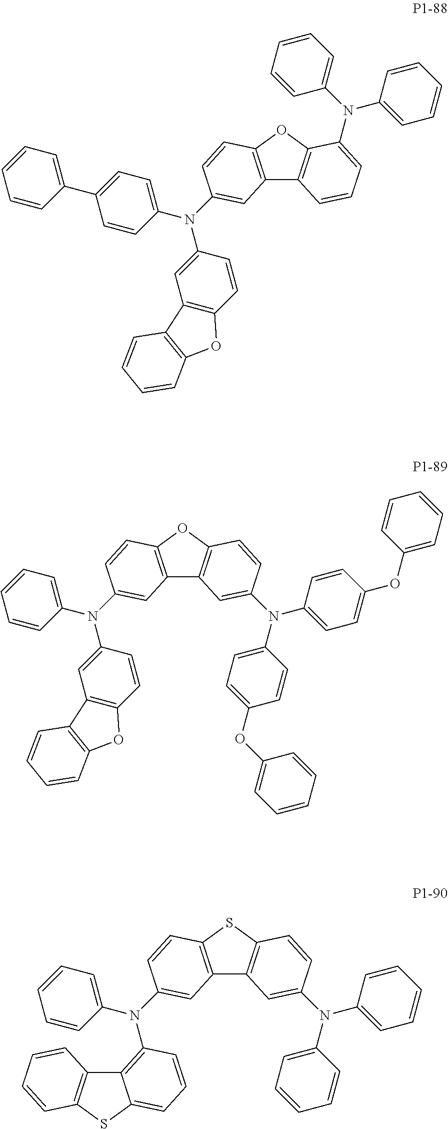 [SMILES: c1ccc(-c2ccc(N(c3ccc4oc5ccccc5c4c3)c3ccc4oc5c(N(c6ccccc6)c6ccccc6)cccc5c4c3)cc2)cc1 ; c1ccc(Oc2ccc(N(c3ccc(Oc4ccccc4)cc3)c3ccc4oc5ccc(N(c6ccccc6)c6ccc7oc8ccccc8c7c6)cc5c4c3)cc2)cc1 ; c1ccc(N(c2ccccc2)c2ccc3sc4ccc(N(c5ccccc5)c5cccc6sc7ccccc7c56)cc4c3c2)cc1]

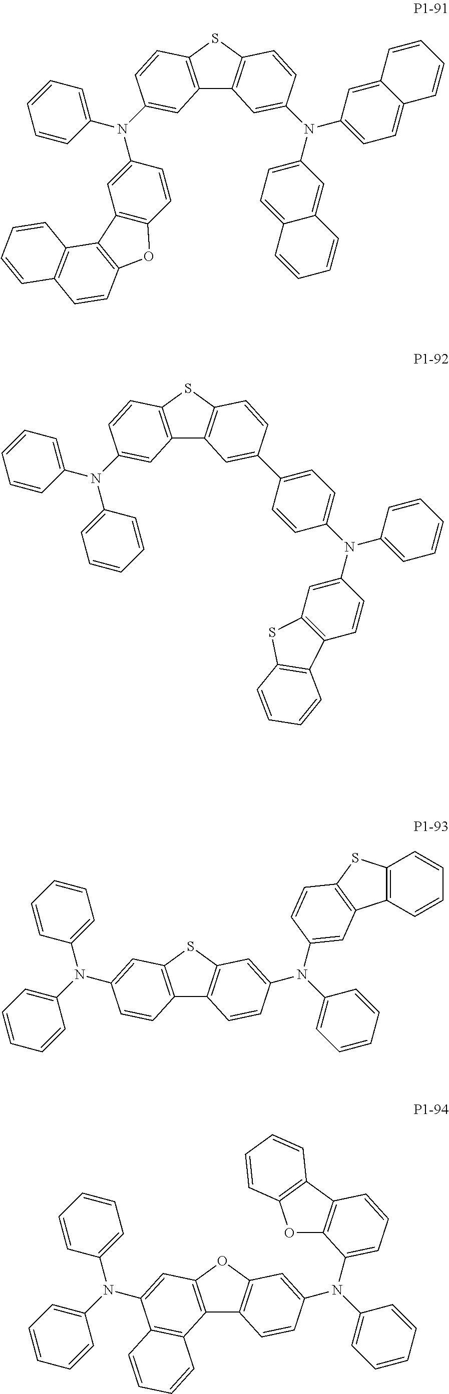 [SMILES: c1ccc(N(c2ccc3sc4ccc(N(c5ccc6ccccc6c5)c5ccc6ccccc6c5)cc4c3c2)c2ccc3oc4ccc5ccccc5c4c3c2)cc1 ; c1ccc(N(c2ccc(-c3ccc4sc5ccc(N(c6ccccc6)c6ccccc6)cc5c4c3)cc2)c2ccc3c(c2)sc2ccccc23)cc1 ; c1ccc(N(c2ccccc2)c2ccc3c(c2)sc2cc(N(c4ccccc4)c4ccc5sc6ccccc6c5c4)ccc23)cc1 ; c1ccc(N(c2ccccc2)c2cc3oc4cc(N(c5ccccc5)c5cccc6c5oc5ccccc56)ccc4c3c3ccccc23)cc1]

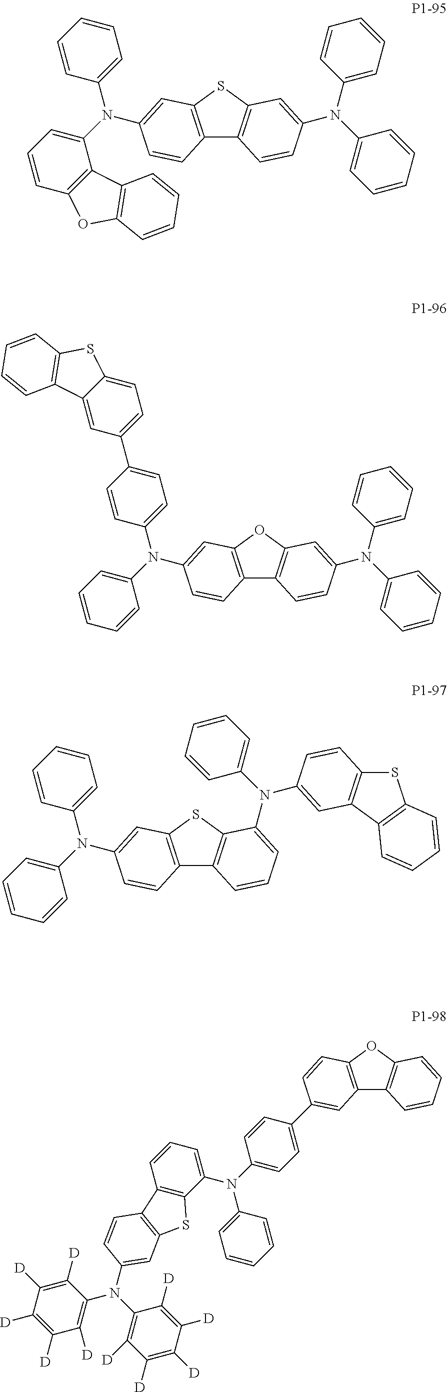 [SMILES: c1ccc(N(c2ccccc2)c2ccc3c(c2)sc2cc(N(c4ccccc4)c4cccc5oc6ccccc6c45)ccc23)cc1 ; c1ccc(N(c2ccccc2)c2ccc3c(c2)oc2cc(N(c4ccccc4)c4ccc(-c5ccc6sc7ccccc7c6c5)cc4)ccc23)cc1 ; c1ccc(N(c2ccccc2)c2ccc3c(c2)sc2c(N(c4ccccc4)c4ccc5sc6ccccc6c5c4)cccc23)cc1 ; [2H]c1c([2H])c([2H])c(N(c2ccc3c(c2)sc2c(N(c4ccccc4)c4ccc(-c5ccc6oc7ccccc7c6c5)cc4)cccc23)c2c([2H])c([2H])c([2H])c([2H])c2[2H])c([2H])c1[2H]]

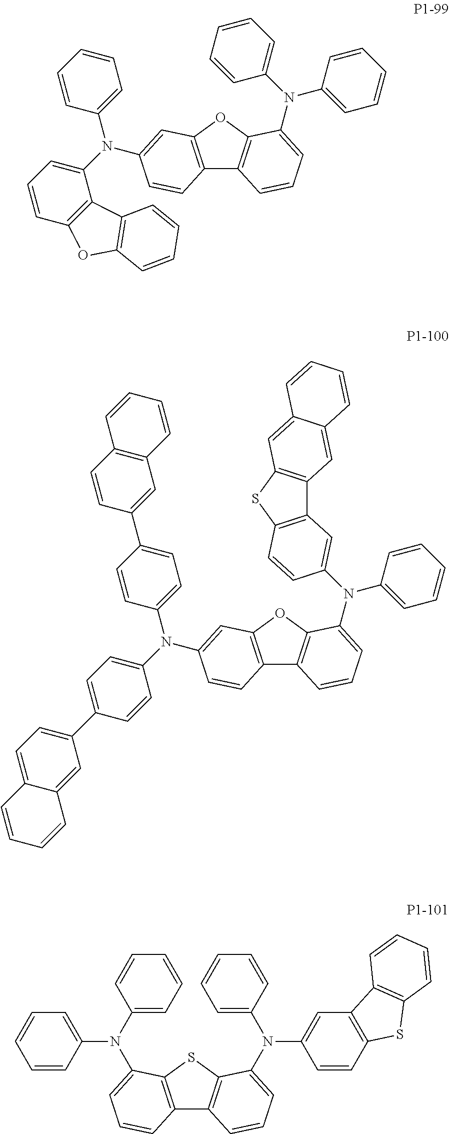 [SMILES: c1ccc(N(c2ccccc2)c2cccc3c2oc2cc(N(c4ccccc4)c4cccc5oc6ccccc6c45)ccc23)cc1 ; c1ccc(N(c2ccc3sc4cc5ccccc5cc4c3c2)c2cccc3c2oc2cc(N(c4ccc(-c5ccc6ccccc6c5)cc4)c4ccc(-c5ccc6ccccc6c5)cc4)ccc23)cc1 ; c1ccc(N(c2ccccc2)c2cccc3c2sc2c(N(c4ccccc4)c4ccc5sc6ccccc6c5c4)cccc23)cc1]

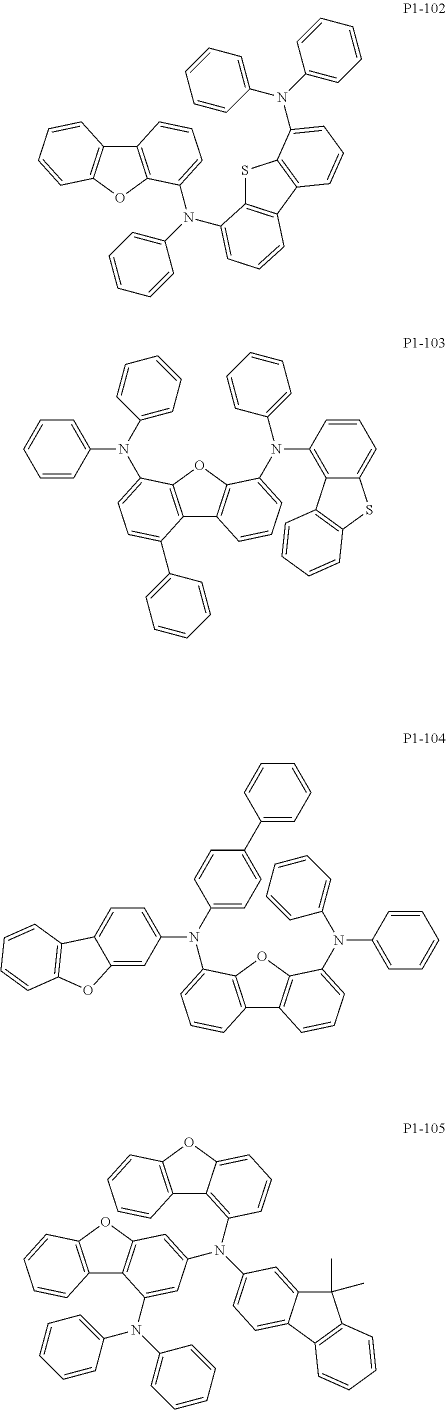

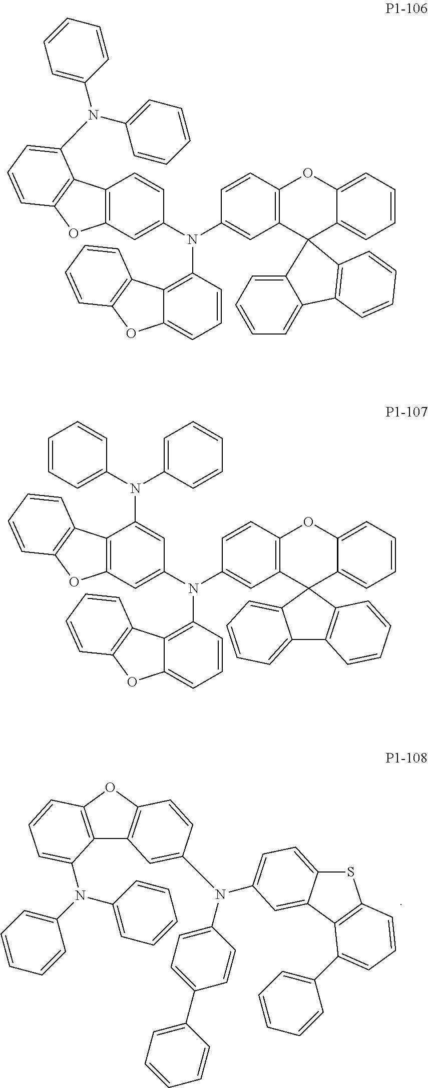 [SMILES: c1ccc(N(c2ccccc2)c2cccc3oc4cc(N(c5ccc6c(c5)C5(c7ccccc7O6)c6ccccc6-c6ccccc65)c5cccc6oc7ccccc7c56)ccc4c23)cc1 ; c1ccc(N(c2ccccc2)c2cc(N(c3ccc4c(c3)C3(c5ccccc5O4)c4ccccc4-c4ccccc43)c3cccc4oc5ccccc5c34)cc3oc4ccccc4c23)cc1 ; c1ccc(-c2ccc(N(c3ccc4oc5cccc(N(c6ccccc6)c6ccccc6)c5c4c3)c3ccc4sc5cccc(-c6ccccc6)c5c4c3)cc2)cc1]

Specifically, the compound represented by Formula 2 may be one of the following compounds, but there is no limitation thereto.

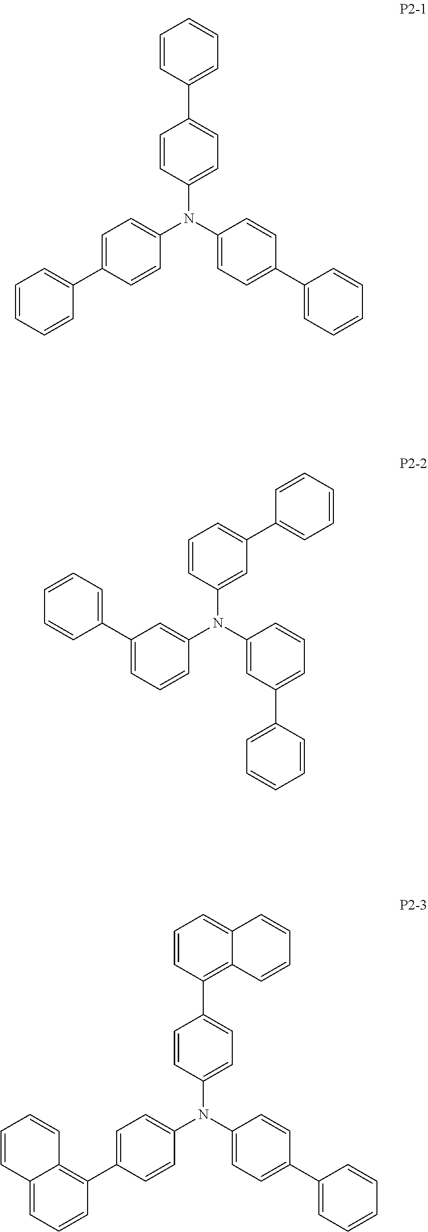 [SMILES: c1ccc(-c2ccc(N(c3ccc(-c4ccccc4)cc3)c3ccc(-c4ccccc4)cc3)cc2)cc1 ; c1ccc(-c2cccc(N(c3cccc(-c4ccccc4)c3)c3cccc(-c4ccccc4)c3)c2)cc1 ; c1ccc(-c2ccc(N(c3ccc(-c4cccc5ccccc45)cc3)c3ccc(-c4cccc5ccccc45)cc3)cc2)cc1]

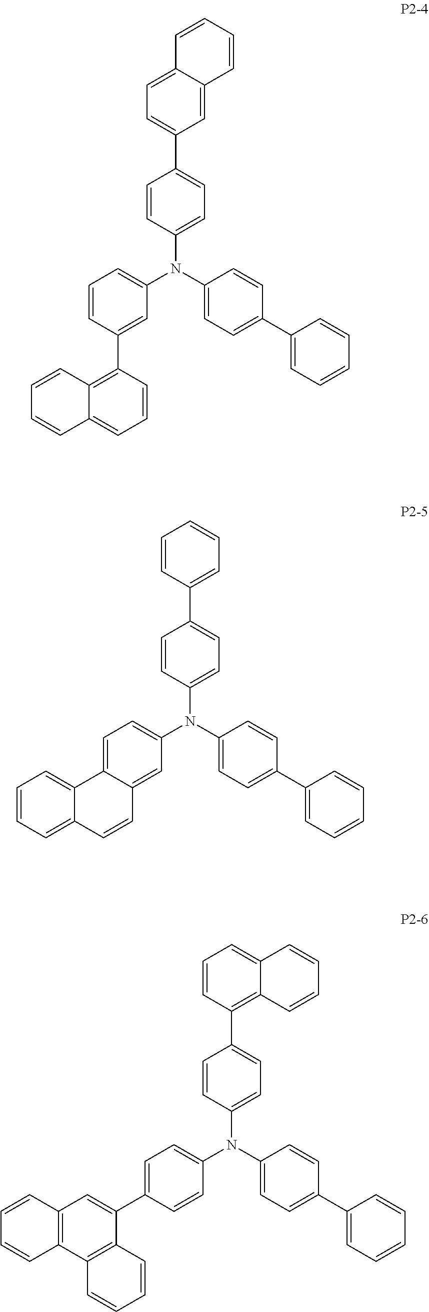 [SMILES: c1ccc(-c2ccc(N(c3ccc(-c4ccc5ccccc5c4)cc3)c3cccc(-c4cccc5ccccc45)c3)cc2)cc1 ; c1ccc(-c2ccc(N(c3ccc(-c4ccccc4)cc3)c3ccc4c(ccc5ccccc54)c3)cc2)cc1 ; c1ccc(-c2ccc(N(c3ccc(-c4cccc5ccccc45)cc3)c3ccc(-c4cc5ccccc5c5ccccc45)cc3)cc2)cc1]

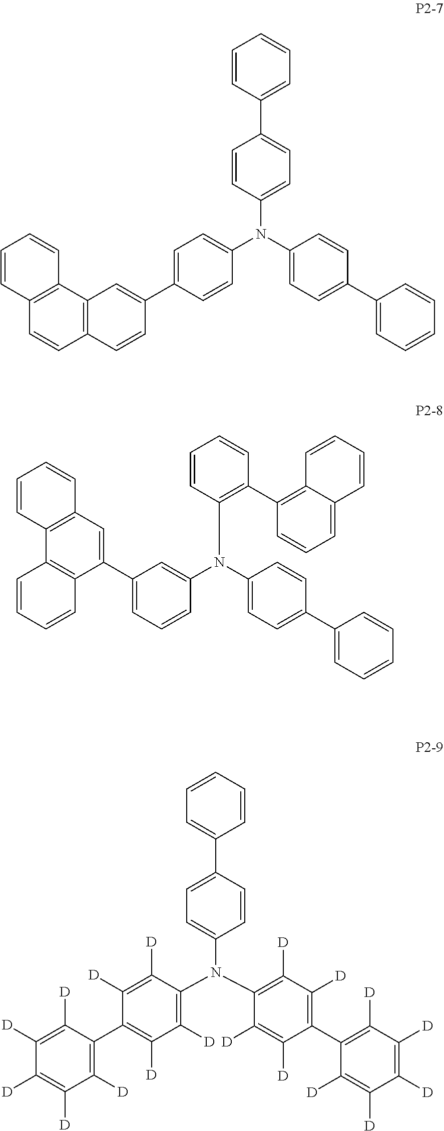 [SMILES: c1ccc(-c2ccc(N(c3ccc(-c4ccccc4)cc3)c3ccc(-c4ccc5ccc6ccccc6c5c4)cc3)cc2)cc1 ; c1ccc(-c2ccc(N(c3cccc(-c4cc5ccccc5c5ccccc45)c3)c3ccccc3-c3cccc4ccccc34)cc2)cc1 ; [2H]c1c([2H])c([2H])c(-c2c([2H])c([2H])c(N(c3ccc(-c4ccccc4)cc3)c3c([2H])c([2H])c(-c4c([2H])c([2H])c([2H])c([2H])c4[2H])c([2H])c3[2H])c([2H])c2[2H])c([2H])c1[2H]]

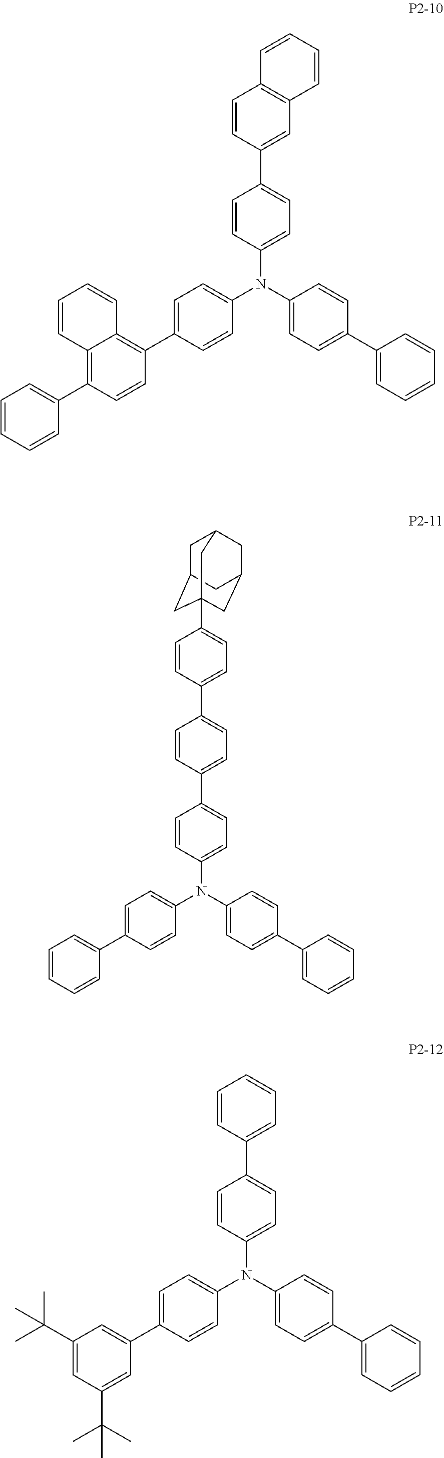 [SMILES: c1ccc(-c2ccc(N(c3ccc(-c4ccc5ccccc5c4)cc3)c3ccc(-c4ccc(-c5ccccc5)c5ccccc45)cc3)cc2)cc1 ; c1ccc(-c2ccc(N(c3ccc(-c4ccccc4)cc3)c3ccc(-c4ccc(-c5ccc(C67CC8CC(CC(C8)C6)C7)cc5)cc4)cc3)cc2)cc1 ; CC(C)(C)c1cc(-c2ccc(N(c3ccc(-c4ccccc4)cc3)c3ccc(-c4ccccc4)cc3)cc2)cc(C(C)(C)C)c1]

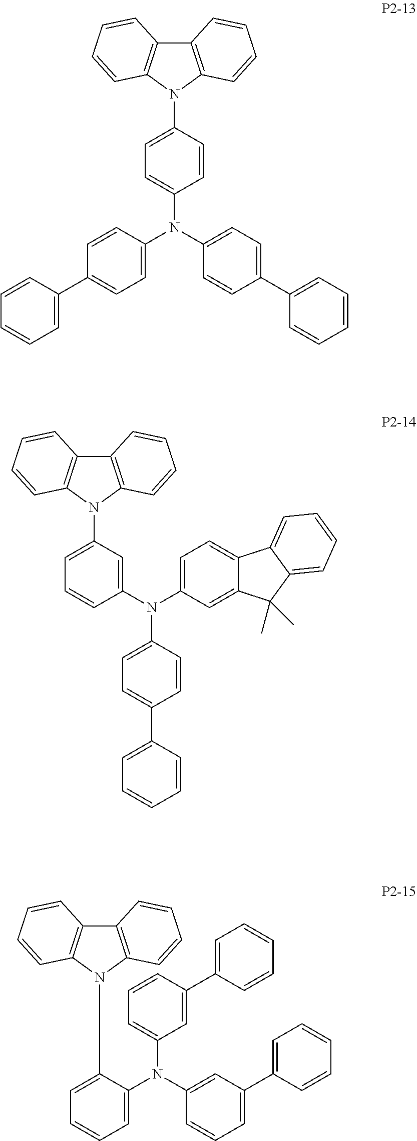 [SMILES: c1ccc(-c2ccc(N(c3ccc(-c4ccccc4)cc3)c3ccc(-n4c5ccccc5c5ccccc54)cc3)cc2)cc1 ; CC1(C)c2ccccc2-c2ccc(N(c3ccc(-c4ccccc4)cc3)c3cccc(-n4c5ccccc5c5ccccc54)c3)cc21 ; c1ccc(-c2cccc(N(c3cccc(-c4ccccc4)c3)c3ccccc3-n3c4ccccc4c4ccccc43)c2)cc1]

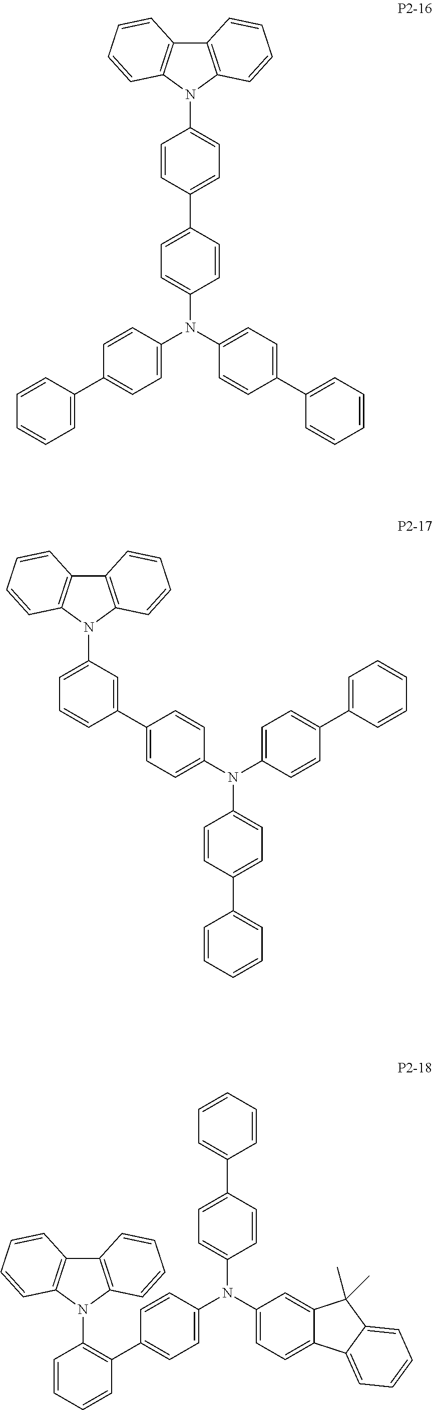 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1 ; CC1(C)c2ccccc2-c2ccc(N(c3ccc(-c4ccccc4)cc3)c3ccc(-c4ccccc4-n4c5ccccc5c5ccccc54)cc3)cc21]

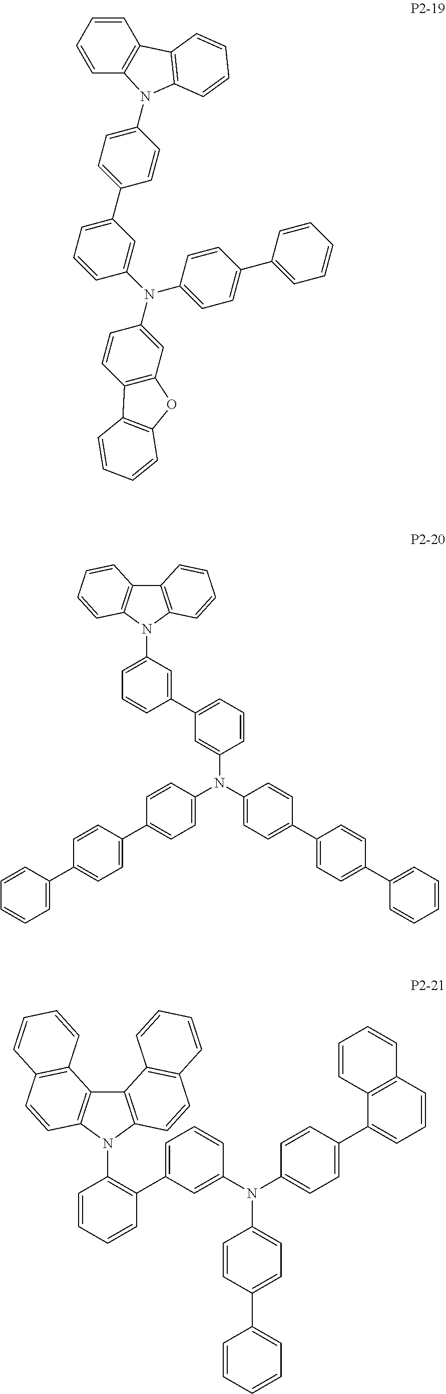 [SMILES: c1ccc(-c2ccc(N(c3cccc(-c4ccc(-n5c6ccccc6c6ccccc65)cc4)c3)c3ccc4c(c3)oc3ccccc34)cc2)cc1 ; c1ccc(-c2ccc(-c3ccc(N(c4ccc(-c5ccc(-c6ccccc6)cc5)cc4)c4cccc(-c5cccc(-n6c7ccccc7c7ccccc76)c5)c4)cc3)cc2)cc1 ; c1ccc(-c2ccc(N(c3ccc(-c4cccc5ccccc45)cc3)c3cccc(-c4ccccc4-n4c5ccc6ccccc6c5c5c6ccccc6ccc54)c3)cc2)cc1]

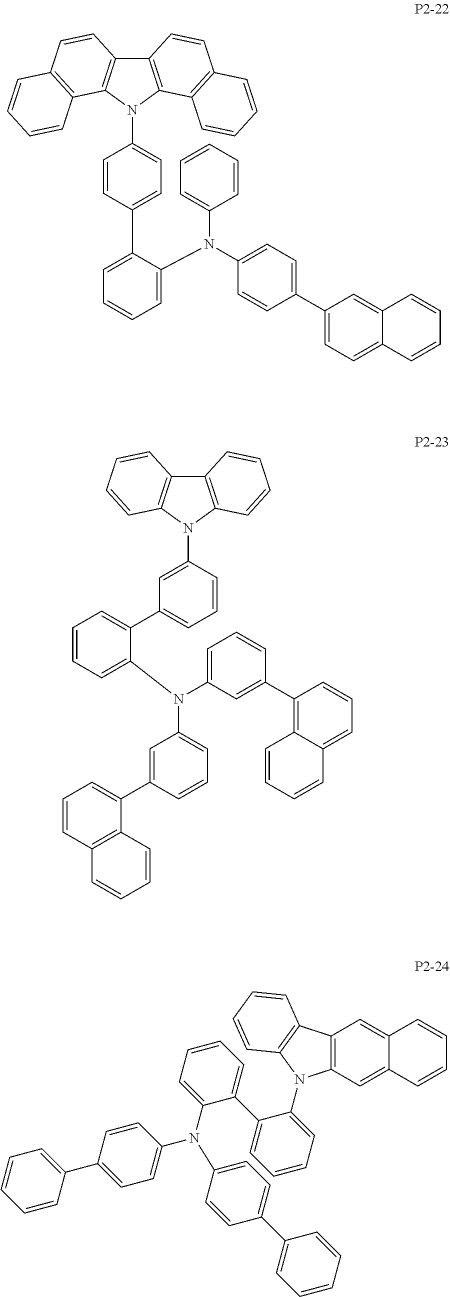 [SMILES: c1ccc(N(c2ccc(-c3ccc4ccccc4c3)cc2)c2ccccc2-c2ccc(-n3c4c5ccccc5ccc4c4ccc5ccccc5c43)cc2)cc1 ; c1cc(-c2cccc3ccccc23)cc(N(c2cccc(-c3cccc4ccccc34)c2)c2ccccc2-c2cccc(-n3c4ccccc4c4ccccc43)c2)c1 ; c1ccc(-c2ccc(N(c3ccc(-c4ccccc4)cc3)c3ccccc3-c3ccccc3-n3c4ccccc4c4cc5ccccc5cc43)cc2)cc1]

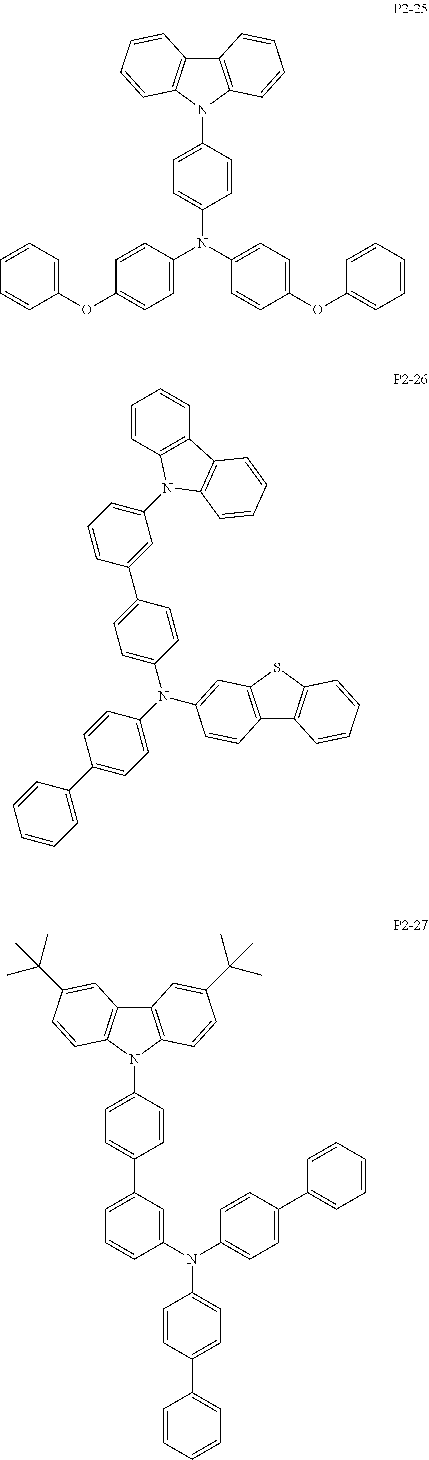 [SMILES: c1ccc(Oc2ccc(N(c3ccc(Oc4ccccc4)cc3)c3ccc(-n4c5ccccc5c5ccccc54)cc3)cc2)cc1 ; c1ccc(-c2ccc(N(c3ccc(-c4cccc(-n5c6ccccc6c6ccccc65)c4)cc3)c3ccc4c(c3)sc3ccccc34)cc2)cc1 ; CC(C)(C)c1ccc2c(c1)c1cc(C(C)(C)C)ccc1n2-c1ccc(-c2cccc(N(c3ccc(-c4ccccc4)cc3)c3ccc(-c4ccccc4)cc3)c2)cc1]

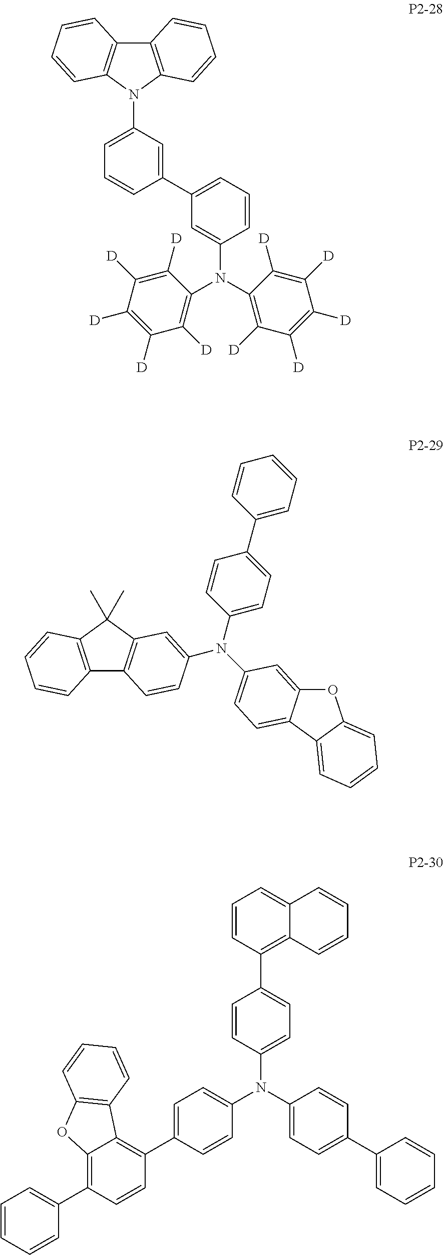 [SMILES: [2H]c1c([2H])c([2H])c(N(c2cccc(-c3cccc(-n4c5ccccc5c5ccccc54)c3)c2)c2c([2H])c([2H])c([2H])c([2H])c2[2H])c([2H])c1[2H] ; CC1(C)c2ccccc2-c2ccc(N(c3ccc(-c4ccccc4)cc3)c3ccc4c(c3)oc3ccccc34)cc21 ; c1ccc(-c2ccc(N(c3ccc(-c4cccc5ccccc45)cc3)c3ccc(-c4ccc(-c5ccccc5)c5oc6ccccc6c45)cc3)cc2)cc1]

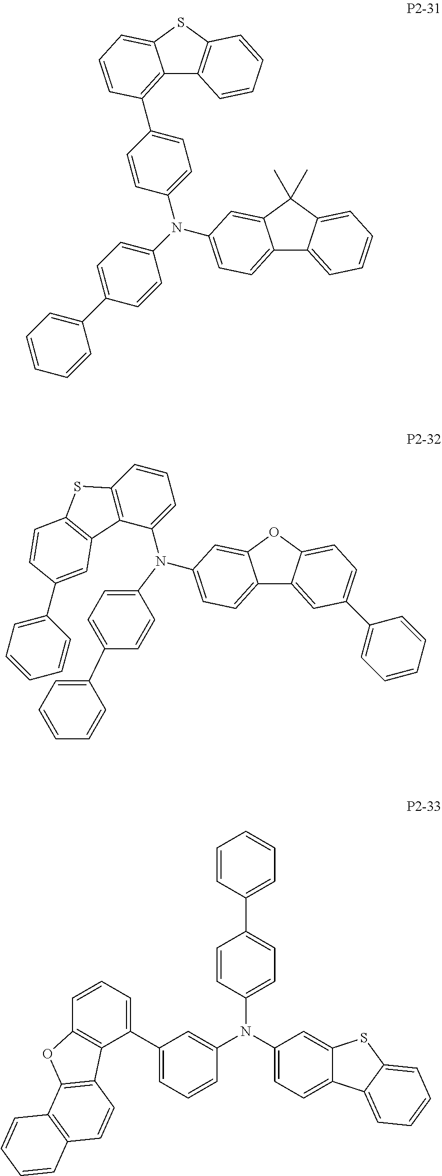 [SMILES: CC1(C)c2ccccc2-c2ccc(N(c3ccc(-c4ccccc4)cc3)c3ccc(-c4cccc5sc6ccccc6c45)cc3)cc21 ; c1ccc(-c2ccc(N(c3ccc4c(c3)oc3ccc(-c5ccccc5)cc34)c3cccc4sc5ccc(-c6ccccc6)cc5c34)cc2)cc1 ; c1ccc(-c2ccc(N(c3cccc(-c4cccc5oc6c7ccccc7ccc6c45)c3)c3ccc4c(c3)sc3ccccc34)cc2)cc1]

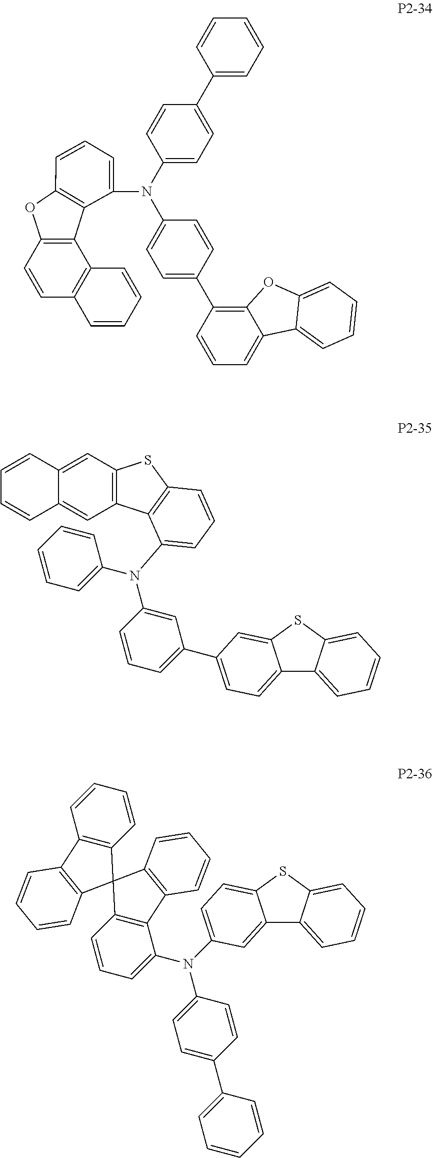 [SMILES: c1ccc(-c2ccc(N(c3ccc(-c4cccc5c4oc4ccccc45)cc3)c3cccc4oc5ccc6ccccc6c5c34)cc2)cc1 ; c1ccc(N(c2cccc(-c3ccc4c(c3)sc3ccccc34)c2)c2cccc3sc4cc5ccccc5cc4c23)cc1 ; c1ccc(-c2ccc(N(c3ccc4sc5ccccc5c4c3)c3cccc4c3-c3ccccc3C43c4ccccc4-c4ccccc43)cc2)cc1]

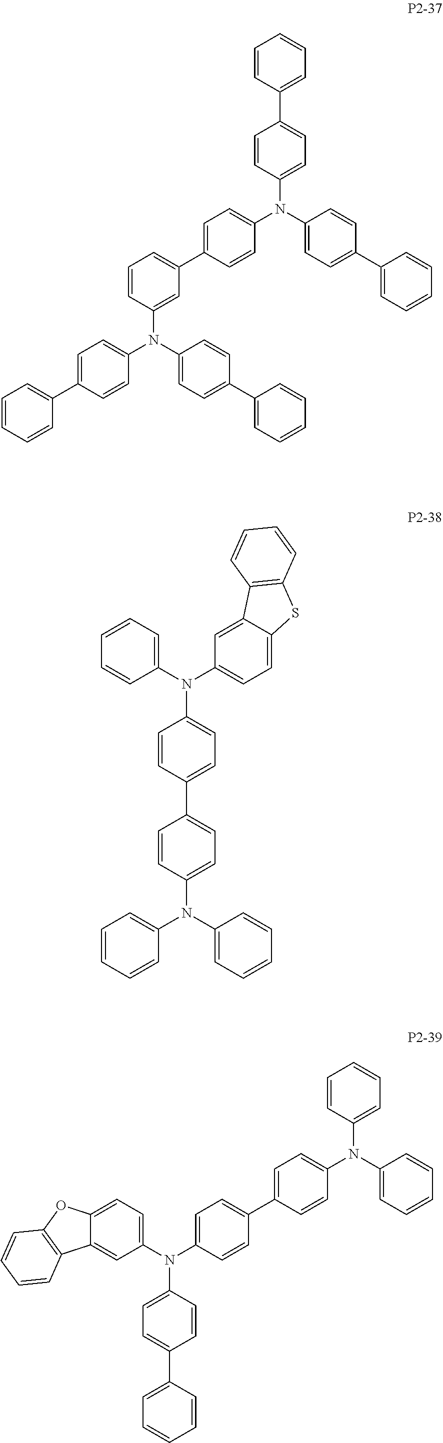 [SMILES: c1ccc(-c2ccc(N(c3ccc(-c4ccccc4)cc3)c3ccc(-c4cccc(N(c5ccc(-c6ccccc6)cc5)c5ccc(-c6ccccc6)cc5)c4)cc3)cc2)cc1 ; c1ccc(N(c2ccccc2)c2ccc(-c3ccc(N(c4ccccc4)c4ccc5sc6ccccc6c5c4)cc3)cc2)cc1 ; c1ccc(-c2ccc(N(c3ccc(-c4ccc(N(c5ccccc5)c5ccccc5)cc4)cc3)c3ccc4oc5ccccc5c4c3)cc2)cc1]

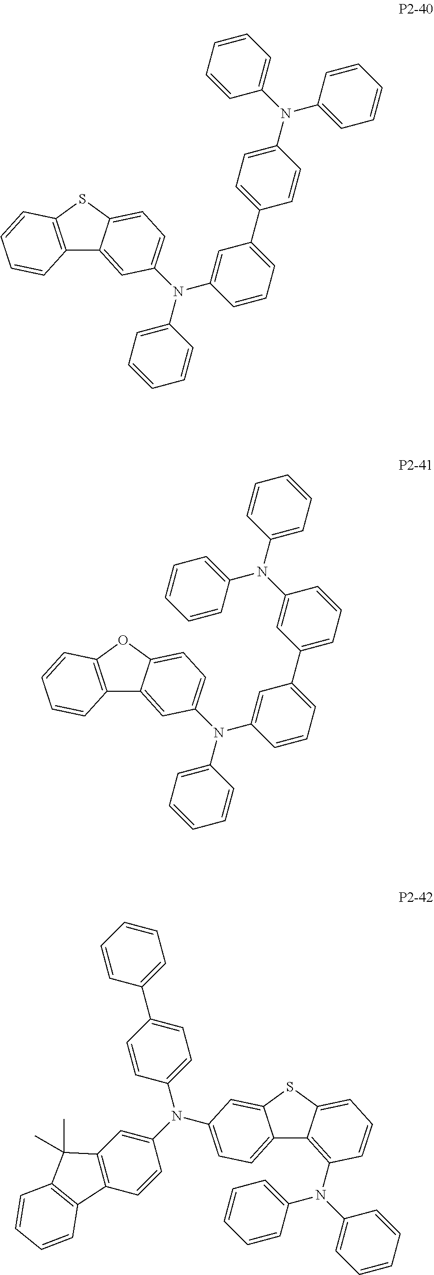 [SMILES: c1ccc(N(c2ccccc2)c2ccc(-c3cccc(N(c4ccccc4)c4ccc5sc6ccccc6c5c4)c3)cc2)cc1 ; c1ccc(N(c2ccccc2)c2cccc(-c3cccc(N(c4ccccc4)c4ccc5oc6ccccc6c5c4)c3)c2)cc1 ; CC1(C)c2ccccc2-c2ccc(N(c3ccc(-c4ccccc4)cc3)c3ccc4c(c3)sc3cccc(N(c5ccccc5)c5ccccc5)c34)cc21]

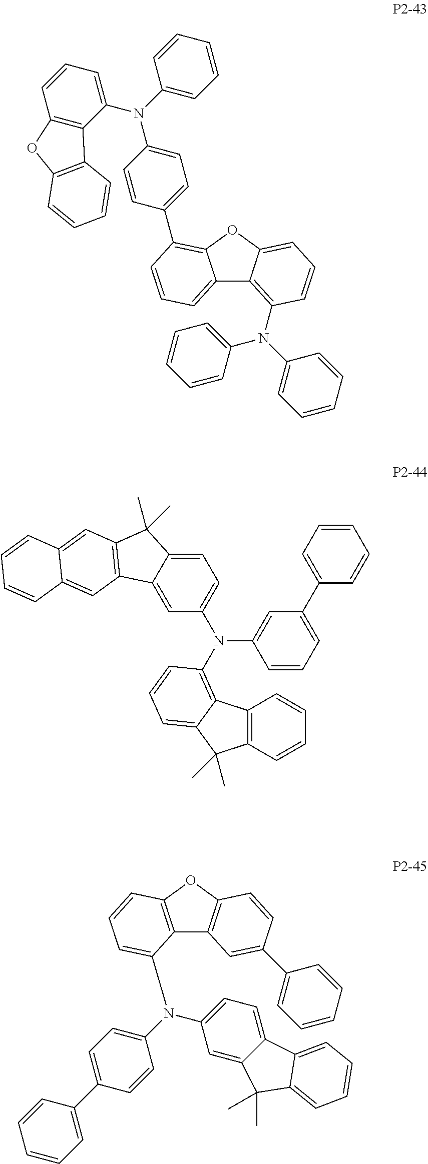 [SMILES: c1ccc(N(c2ccc(-c3cccc4c3oc3cccc(N(c5ccccc5)c5ccccc5)c34)cc2)c2cccc3oc4ccccc4c23)cc1 ; CC1(C)c2ccc(N(c3cccc(-c4ccccc4)c3)c3cccc4c3-c3ccccc3C4(C)C)cc2-c2cc3ccccc3cc21 ; CC1(C)c2ccccc2-c2ccc(N(c3ccc(-c4ccccc4)cc3)c3cccc4oc5ccc(-c6ccccc6)cc5c34)cc21]

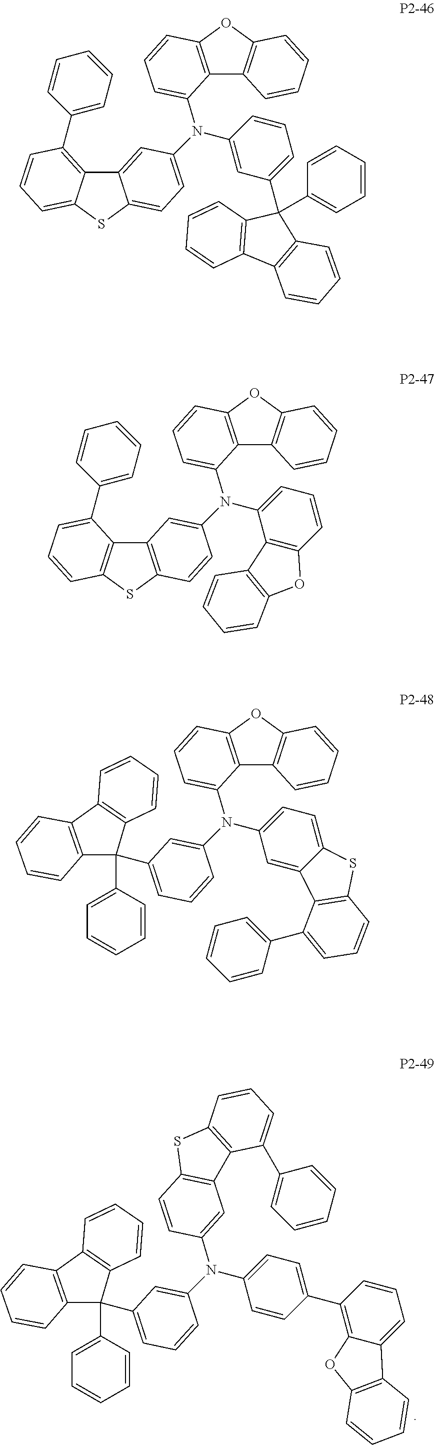 [SMILES: c1ccc(-c2cccc3sc4ccc(N(c5cccc(C6(c7ccccc7)c7ccccc7-c7ccccc76)c5)c5cccc6oc7ccccc7c56)cc4c23)cc1 ; c1ccc(-c2cccc3sc4ccc(N(c5cccc6oc7ccccc7c56)c5cccc6oc7ccccc7c56)cc4c23)cc1 ; c1ccc(-c2cccc3sc4ccc(N(c5cccc(C6(c7ccccc7)c7ccccc7-c7ccccc76)c5)c5cccc6oc7ccccc7c56)cc4c23)cc1 ; c1ccc(-c2cccc3sc4ccc(N(c5ccc(-c6cccc7c6oc6ccccc67)cc5)c5cccc(C6(c7ccccc7)c7ccccc7-c7ccccc76)c5)cc4c23)cc1]

Hereinafter, synthesis example of the compound represented by Formula 1 and 2, and preparation method of an organic electroluminescent element will be described in detail by way of examples. However, the present invention is not limited to the following examples.

### SYNTHESIS EXAMPLE

### Synthesis example of Formula 1

The compound represented by Formula 1 according to the present invention can be synthesized by reaction route of the following Reaction Scheme 1, but is not limited thereto.

<Reaction Scheme 1>(Hal1 and Hal2 are each I, Br or Cl, G1 is —L1—Ar1 or —L3—Ar3, and G2 is —L2—Ar2 or —L4—Ar4.)

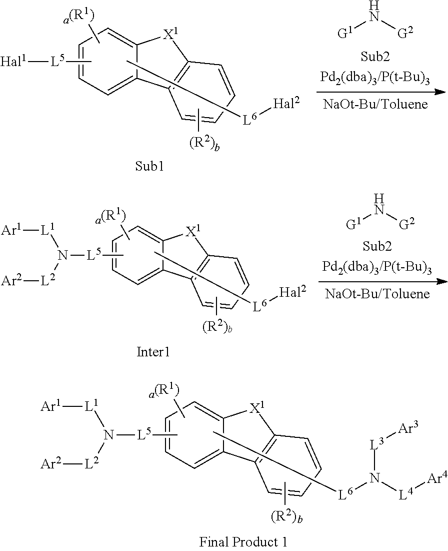

### Synthesis example of Sub1

Sub 1 of the Reaction Scheme 1 can be synthesized according to the reaction route of the following Reaction Schemes 2-1 to 2-4. Sub 1 of the Reaction Scheme 1 can be synthesized according to the following Reaction Scheme 2-1 or 2-2 when X1 is S, according to the following Reaction Scheme 2-3 or 2-4 when X1 is 0, but is not limited thereto.

### Reaction Scheme 2-1

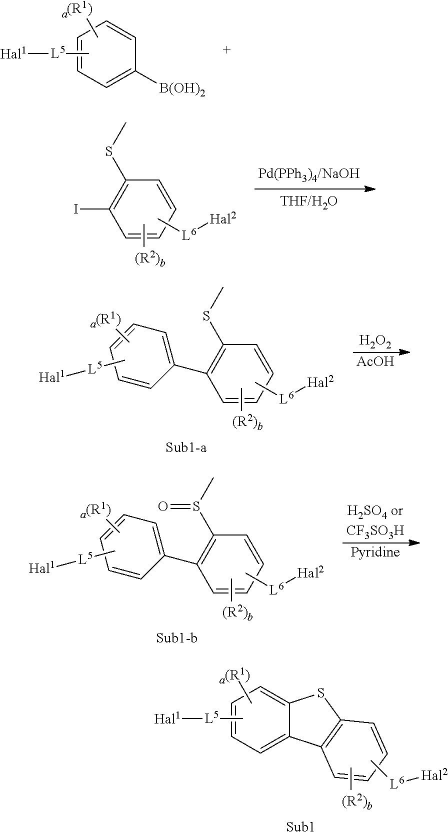

### Reaction Scheme 2-2

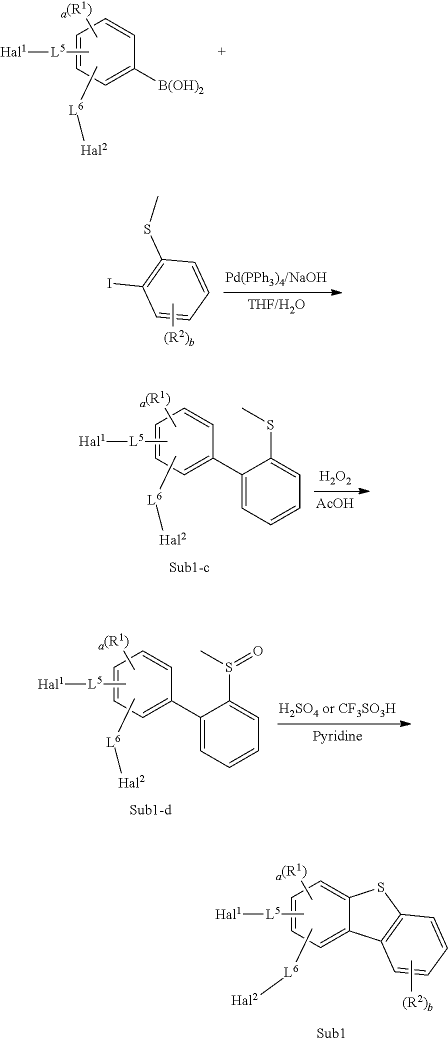

### Reaction Scheme 2-3

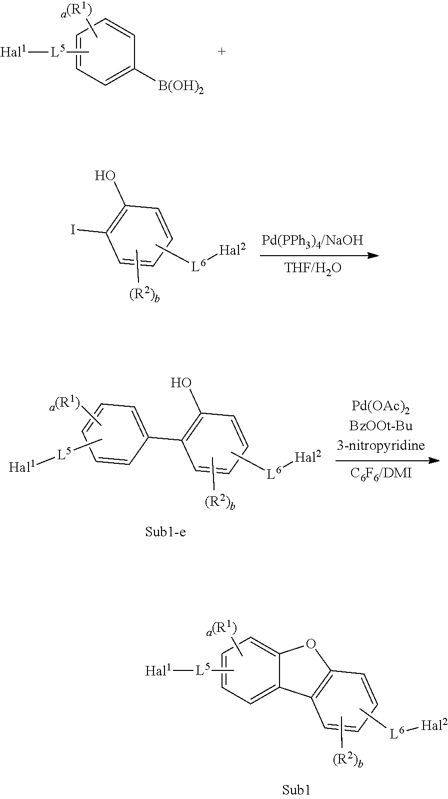

### Reaction Scheme 2-4

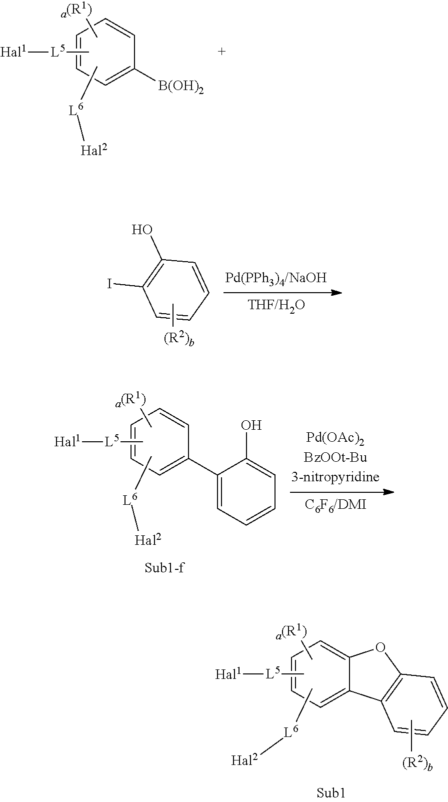

### (1). Synthesis example of Sub1-1

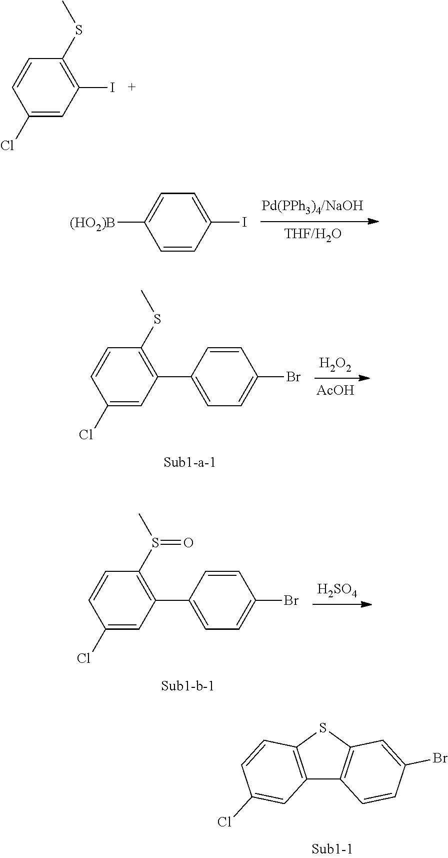

### (1) Synthesis of Sub1-a-1

After dissolving (4-chloro-2-iodophenyl)(methyl)sulfane (25.0 g, 87.9 mmol) in THE (440 mL), (4-bromophenyl)boronic acid (17.6 g, 87.9 mmol), Pd(PPh3)4 (6.09 g, 5.27 mmol), NaOH (10.5 g, 264 mmol) and H2O (220 mL) were added to the solution and the mixture was stirred at 80° C. When the reaction was completed, the reaction product was extracted with CH2Cl2 and water, and then an organic layer was dried with MgSO4 and concentrated. Then, the concentrate was separated through a silica gel column and recrystallized to obtain 23.4 g (yield: 85%) of the product.

### (2) Synthesis of Sub1-b-1

After putting Sub1-a-1 (23.4 g, 74.7 mmol) and H₂O₂ (21.3 mL), acetic acid (300 mL) into a round bottom flask, the mixture was stirred at room temperature. When the reaction was completed, acetic acid was removed, and water was added to obtain a solid. The solid was dissolved in CH2C12, and the solution was separated through a silica gel column and concentrated to obtain 22.6 g (yield: 92%) of the product.

### (3) Synthesis of Sub1-1

Sub1-b-1 (22.6 g, 68.7 mmol) was dissolved in an excess of H2SO4 and stirred at room temperature for 6 hours. When the reaction was completed, the reaction product was neutralized with aqueous NaOH solution, and the organic layer extracted with CH2Cl2 was dried with MgSO4 and concentrated. Afterwards, the concentrate was separated through a silica gel column and recrystallized to obtain 18.2 g (yield: 89%) of product.

### 2. Synthesis example of Sub1-2

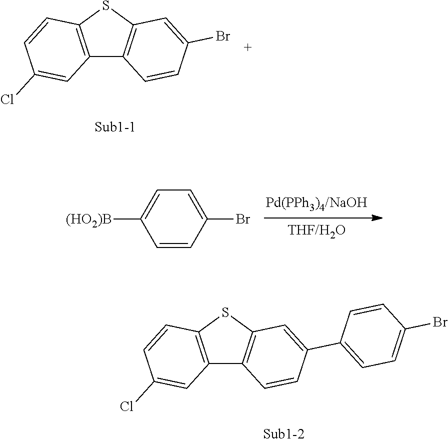

After dissolving Sub1-1 (5.0 g, 16.8 mmol) in THE (84 mL), (4-bromophenyl)boronic acid (3.4 g, 16.8 mmol), Pd(PPh3)4 (1.16 g, 1.01 mmol), NaOH (2.0 g, 50.4 mmol) and H2O (42 mL) were added to the solution and the mixture was stirred at 80° C. When the reaction was completed, the reaction product was extracted with CH2Cl2 and water, and then an organic layer was dried with MgSO4 and concentrated. Then, the concentrate was separated through a silica gel column and recrystallized to obtain 5.1 g (yield: 81%) of the product.

### 3. Synthesis example of Sub 1-5

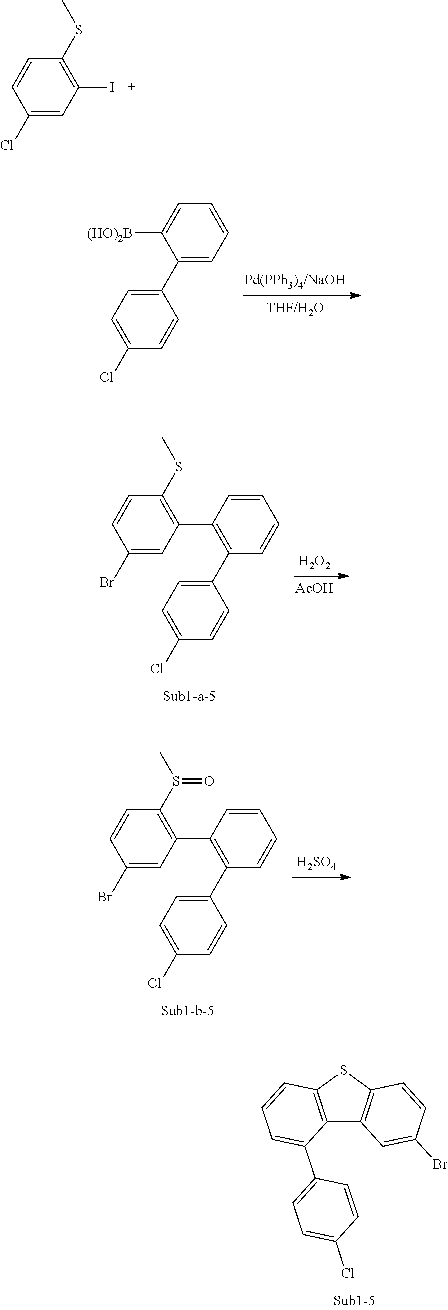

### (1) Synthesis of Sub1-a-5

After dissolving (4-bromo-2-iodophenyl)(methyl)sulfane (15.0 g, 45.6 mmol) in THE (228 mL), (4′-chloro-[1,1′-biphenyl]-2-yl)boronic acid (10.6 g, 45.6 mmol), Pd(PPh3)4 (3.16 g, 2.74 mmol), NaOH (5.47 g, 137 mmol) and H2O (114 mL) were added to the solution, and then the synthesis was carried out in the same manner as in the synthesis method of Sub1-a-1 to obtain 14.4 g (yield: 81%) of the product.

### (2) Synthesis of Sub1-b-5

Sub1-a-5 (14.4 g, 36.9 mmol), H₂O₂ (10.6 mL) and acetic acid (148 mL) were putted into a round bottom flask, and then the synthesis was carried out in the same manner as in the synthesis method of Sub1-b-1 to obtain 13.5 g (yield: 90%) of the product.

### (3) Synthesis of Sub1-5

After dissolving Sub1-b-5 (13.5 g, 33.2 mmol) in H2SO4 (40.5 mL), and then the synthesis was carried out in the same manner as in the synthesis method of Sub1-1 to obtain 10.7 g (yield: 86%) of the product.

### 4. Synthesis example of Sub 1-9

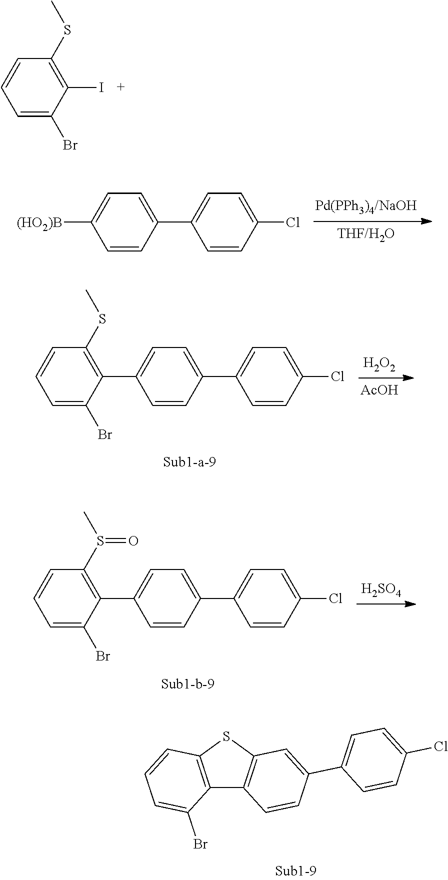

### (1) Synthesis of Sub1-a-9

After dissolving (3-bromo-2-iodophenyl)(methyl)sulfane (15.0 g, 45.6 mmol) in THE (228 mL), (4′-chloro-[1,1′-biphenyl]-4-yl)boronic acid (10.6 g, 45.6 mmol), Pd(PPh3)4 (3.16 g, 2.74 mmol), NaOH (5.47 g, 137 mmol) and H2O (114 mL) were added to the solution, and then the synthesis was carried out in the same manner as in the synthesis method of Sub1-a-1 to obtain 14.9 g (yield: 84%) of the product.

### (2) Synthesis of Sub1-b-9

Sub1-a-9 (14.9 g, 38.3 mmol), H₂O₂ (10.9 mL) and acetic acid (153 mL) were putted into a round bottom flask, and then the synthesis was carried out in the same manner as in the synthesis method of Sub1-b-1 to obtain 13.4 g (yield: 86%) of the product.

### (3) Synthesis of Sub1-9

After dissolving Sub1-b-9 (13.4 g, 32.9 mmol) in H2SO4 (40.1 mL), and then the synthesis was carried out in the same manner as in the synthesis method of Sub1-1 to obtain 11.0 g (yield: 89%) of the product.

### 5. Synthesis example of Sub 1-12

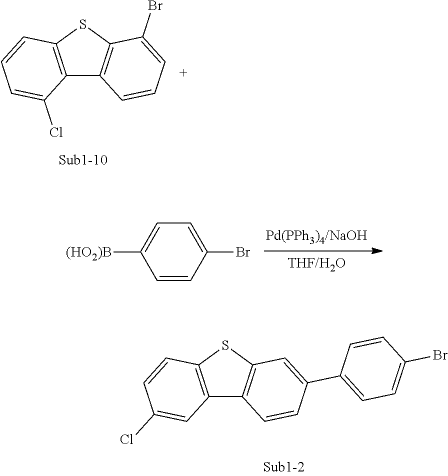

After dissolving Sub1-10 (5.0 g, 16.8 mmol) in THE (84 mL), (4-bromophenyl)boronic acid (3.4 g, 16.8 mmol), Pd(PPh3)4 (1.16 g, 1.01 mmol), NaOH (2.0 g, 50.4 mmol) and H2O (42 mL) were added to the solution, and then the synthesis was carried out in the same manner as in the synthesis method of Sub1-2 to obtain 4.5 g (yield: 72%) of the product.

### 6. Synthesis example of Sub 1-15

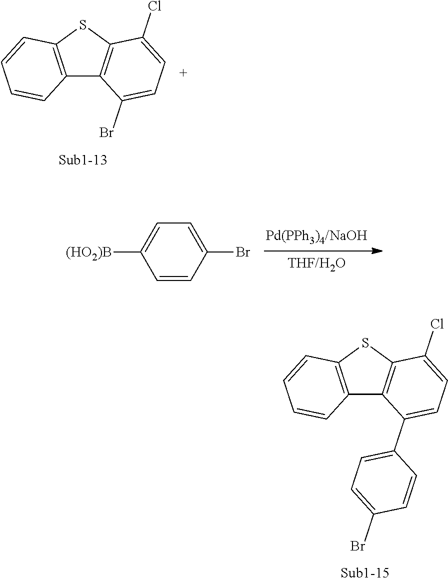

After dissolving Sub1-13 (5.0 g, 16.8 mmol) in THE (84 mL), (4-bromophenyl)boronic acid (3.4 g, 16.8 mmol), Pd(PPh3)4 (1.16 g, 1.01 mmol), NaOH (2.0 g, 50.4 mmol) and H2O (42 mL) were added to the solution, and then the synthesis was carried out in the same manner as in the synthesis method of Sub1-2 to obtain 4.3 g (yield: 68%) of the product.

### 7. Synthesis example of Sub 1-20

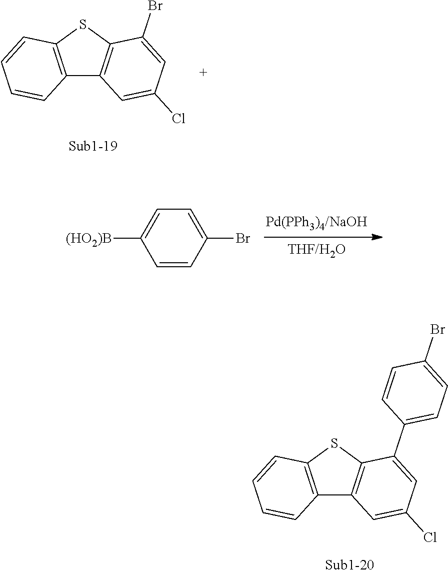

After dissolving Sub1-19 (5.0 g, 16.8 mmol) in THE (84 mL), (4-bromophenyl)boronic acid (3.4 g, 16.8 mmol), Pd(PPh3)4 (1.16 g, 1.01 mmol), NaOH (2.0 g, 50.4 mmol), H2O (42 mL) were added to the solution, and then the synthesis was carried out in the same manner as in the synthesis method of Sub1-2 to obtain 4.6 g (yield: 73%) of the product.

### 8. Synthesis example of Sub 1-31

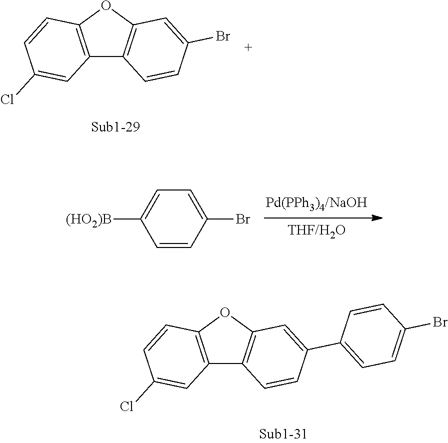

After dissolving Sub1-29 (5.0 g, 17.8 mmol) in THE (89 mL), (4-bromophenyl)boronic acid (3.6 g, 17.8 mmol), Pd(PPh3)4 (1.23 g, 1.07 mmol), NaOH (2.1 g, 53.3 mmol) and H2O (44 mL) were added to the solution, and then the synthesis was carried out in the same manner as in the synthesis method of Sub1-2 to obtain 4.8 g (yield: 76%) of the product.

### 9. Synthesis example of Sub 1-36

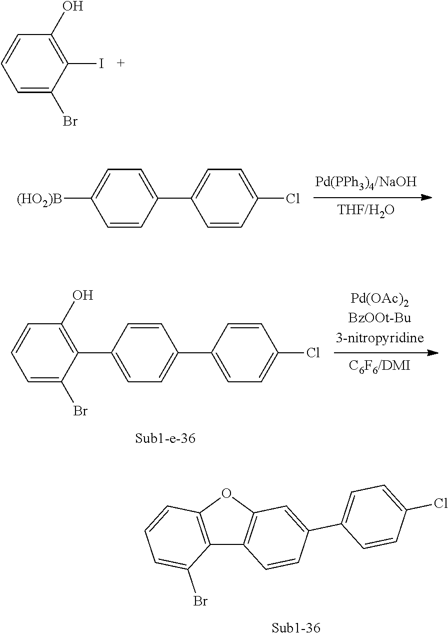

### (1) Synthesis of Sub1-e-36

After dissolving 3-bromo-2-iodophenol (15.0 g, 50.2 mmol) in THE (250 mL) chloro-[1,1′-biphenyl]-4-yl)boronic acid (11.7 g, 50.2 mmol), Pd(PPh3)4 (3.48 g, 3.01 mmol), NaOH (6.0 g, 101 mmol) and H2O (125 mL) were added to the solution, and then the synthesis was carried out in the same manner as in the synthesis method of Sub1-2 to obtain 15.2 g (yield: 84%) of the product.

### (2) Synthesis of Sub1-36

After putting Sub1-e-36 (15.2 g, 42.2 mmol), Pd(OAc)2 (0.47 g, 2.11 mmol) and 3-nitropyridine (0.26 g, 2.11 mmol) into a round bottom flask, the mixture was dissolved in C6F6 (63 mL) and DMI (42 mL), and tert-butylperoxybenzoate (16.4 g, 84.3 mmol) was added thereto. Then, the mixture was stirred at 90° C. When the reaction was completed, the reaction product was extracted with CH2C12 and water, and then an organic layer was dried with MgSO4 and concentrated. Then, the concentrate was separated through a silica gel column and recrystallized to obtain 9.8 g (yield: 65%) of the product.

### 10. Synthesis example of Sub 1-38

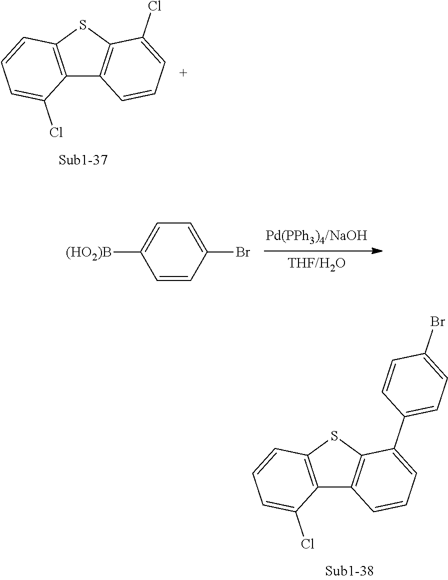

After dissolving Sub1-37 (5.0 g, 17.8 mmol) in THE (89 mL), (4-bromophenyl)boronic acid (3.6 g, 17.8 mmol), Pd(PPh3)4 (1.23 g, 1.07 mmol), NaOH (2.1 g, 53.3 mmol) and H2O (44 mL) were added to the solution, and then the synthesis was carried out in the same manner as in the synthesis method of Sub1-2 to obtain 4.5 g (yield: 71%) of the product.

Compounds belonging to Sub 1 may be, but not limited to, the following compounds, and Table 1 shows FD-MS(Field Desorption-Mass Spectrometry) values of the following compounds.

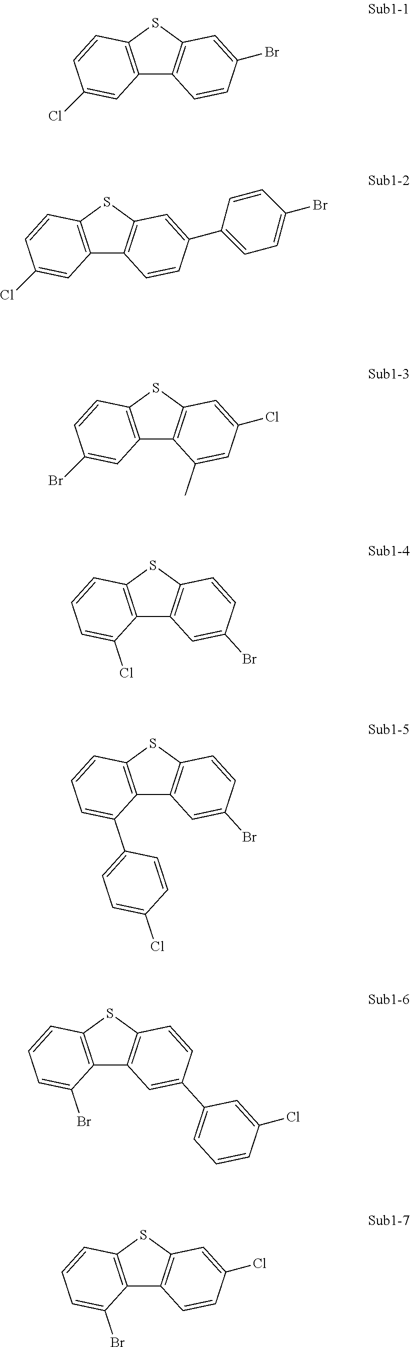

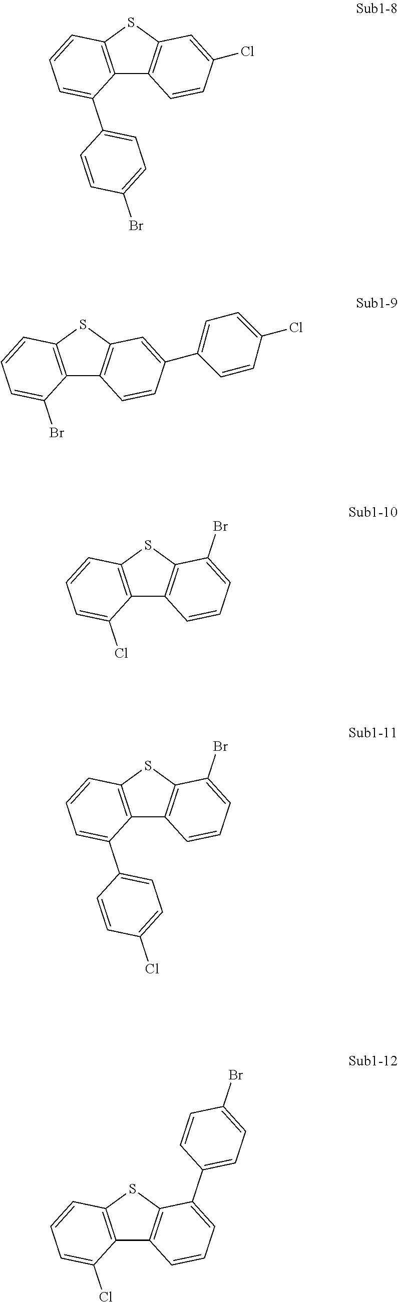 [SMILES: Clc1ccc2c(c1)sc1cccc(-c3ccc(Br)cc3)c12 ; Clc1ccc(-c2ccc3c(c2)sc2cccc(Br)c23)cc1 ; Clc1cccc2sc3c(Br)cccc3c12 ; Clc1ccc(-c2cccc3sc4c(Br)cccc4c23)cc1 ; Clc1cccc2sc3c(-c4ccc(Br)cc4)cccc3c12]

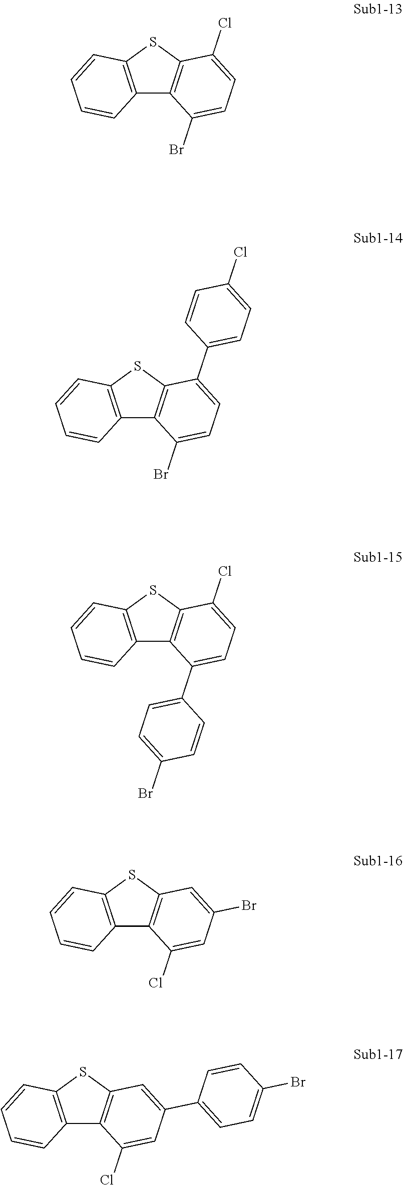 [SMILES: Clc1ccc(Br)c2c1sc1ccccc12 ; Clc1ccc(-c2ccc(Br)c3c2sc2ccccc23)cc1 ; Clc1ccc(-c2ccc(Br)cc2)c2c1sc1ccccc12 ; Clc1cc(Br)cc2sc3ccccc3c12 ; Clc1cc(-c2ccc(Br)cc2)cc2sc3ccccc3c12]

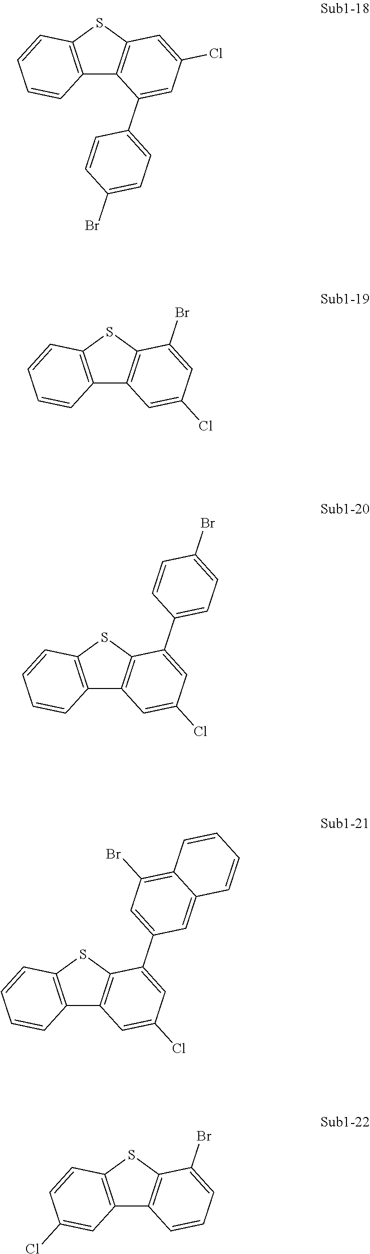 [SMILES: Clc1cc(-c2ccc(Br)cc2)c2c(c1)sc1ccccc12 ; Clc1cc(Br)c2sc3ccccc3c2c1 ; Clc1cc(-c2ccc(Br)cc2)c2sc3ccccc3c2c1 ; Clc1cc(-c2cc(Br)c3ccccc3c2)c2sc3ccccc3c2c1 ; Clc1ccc2sc3c(Br)cccc3c2c1]

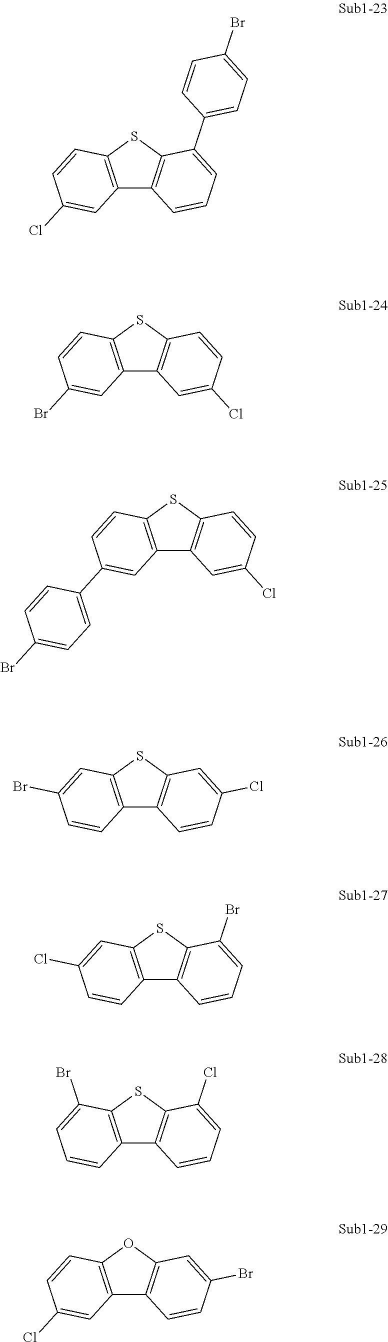

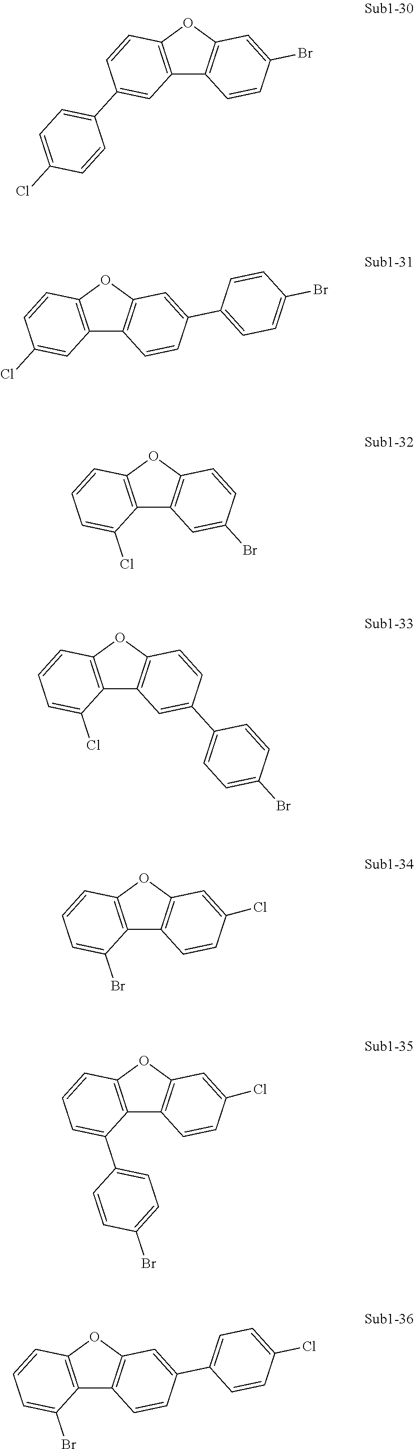

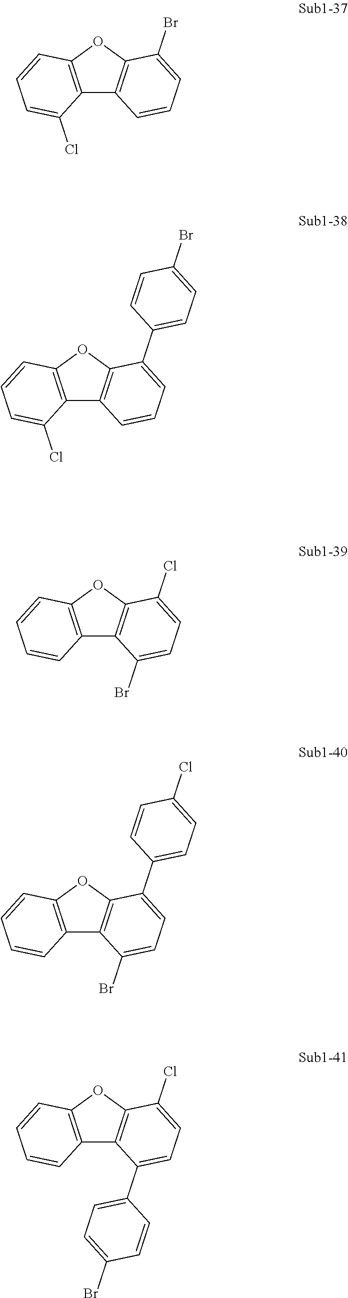 [SMILES: Clc1cccc2oc3c(Br)cccc3c12 ; Clc1cccc2oc3c(-c4ccc(Br)cc4)cccc3c12 ; Clc1ccc(Br)c2c1oc1ccccc12 ; Clc1ccc(-c2ccc(Br)c3c2oc2ccccc23)cc1 ; Clc1ccc(-c2ccc(Br)cc2)c2c1oc1ccccc12]

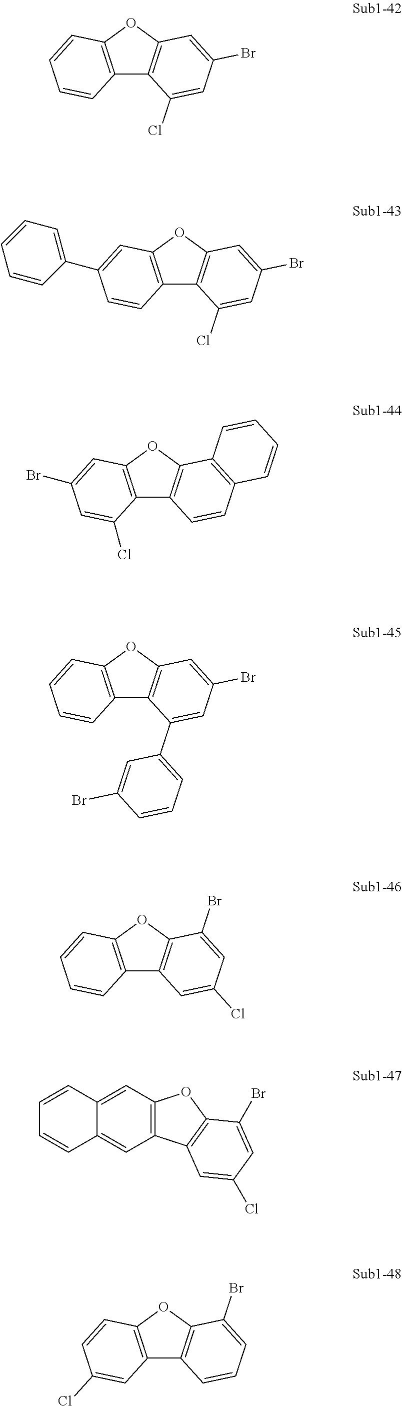

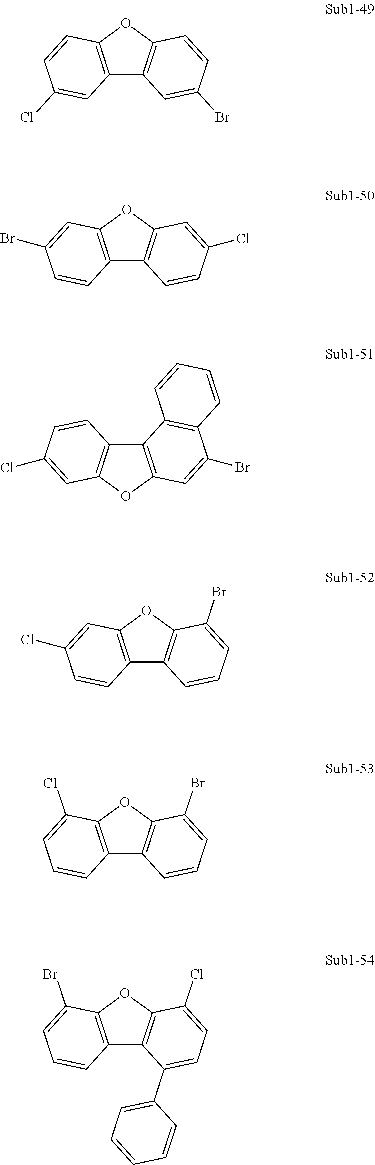 [SMILES: Clc1ccc2oc3ccc(Br)cc3c2c1 ; Clc1ccc2c(c1)oc1cc(Br)ccc12 ; Clc1ccc2c(c1)oc1cc(Br)c3ccccc3c12 ; Clc1ccc2c(c1)oc1c(Br)cccc12 ; Clc1cccc2c1oc1c(Br)cccc12 ; Clc1ccc(-c2ccccc2)c2c1oc1c(Br)cccc12]

TABLE 1

| Compound | FD-MS | Compound | FD-MS |
|---|---|---|---|
| Sub1-1 | m/z = 295.91(C₁₂H₆BrClS = 297.59) | Sub1-2 | m/z = 371.94(C₁₈H₁₀BrClS = 373.69) |
| Sub1-3 | m/z = 309.92(C₁₃H₈BrClS = 311.62) | Sub1-4 | m/z = 295.91(C₁₂H₆BrClS = 297.59) |
| Sub1-5 | m/z = 371.94(C₁₈H₁₀BrClS = 373.69) | Sub1-6 | m/z = 371.94(C₁₈H₁₀BrClS = 373.69) |
| Sub1-7 | m/z = 295.91(C₁₂H₆BrClS = 297.59) | Sub1-8 | m/z = 371.94(C₁₈H₁₀BrClS = 373.69) |
| Sub1-9 | m/z = 371.94(C₁₈H₁₀BrClS = 373.69) | Sub1-10 | m/z = 295.91(C₁₂H₆BrClS = 297.59) |
| Sub1-11 | m/z = 371.94(C₁₈H₁₀BrClS = 373.69) | Sub1-12 | m/z = 371.94(C₁₈H₁₀BrClS = 373.69) |
| Sub1-13 | m/z = 295.91(C₁₂H₆BrClS = 297.59) | Sub1-14 | m/z = 371.94(C₁₈H₁₀BrClS = 373.69) |
| Sub1-15 | m/z = 371.94(C₁₈H₁₀BrClS = 373.69) | Sub1-16 | m/z = 295.91(C₁₂H₆BrClS = 297.59) |
| Sub1-17 | m/z = 371.94(C₁₈H₁₀BrClS = 373.69) | Sub1-18 | m/z = 371.94(C₁₈H₁₀BrClS = 373.69) |
| Sub1-19 | m/z = 295.91(C₁₂H₆BrClS = 297.59) | Sub1-20 | m/z = 371.94(C₁₈H₁₀BrClS = 373.69) |
| Sub1-21 | m/z = 421.95(C₂₂H₁₂BrClS = 423.75) | Sub1-22 | m/z = 295.91(C₁₂H₆BrClS = 297.59) |
| Sub1-23 | m/z = 371.94(C₁₈H₁₀BrClS = 373.69) | Sub1-24 | m/z = 295.91(C₁₂H₆BrClS = 297.59) |
| Sub1-25 | m/z = 371.94(C₁₈H₁₀BrClS = 373.69) | Sub1-26 | m/z = 295.91(C₁₂H₆BrClS = 297.59) |
| Sub1-27 | m/z = 295.91(C₁₂H₆BrClS = 297.59) | Sub1-28 | m/z = 295.91(C₁₂H₆BrClS = 297.59) |
| Sub1-29 | m/z = 279.93(C₁₂H₆BrClO = 281.53) | Sub1-30 | m/z = 355.96(C₁₈H₁₀BrClO = 357.63) |
| Sub1-31 | m/z = 355.96(C₁₈H₁₀BrClO = 357.63) | Sub1-32 | m/z = 279.93(C₁₂H₆BrClO = 281.53) |
| Sub1-33 | m/z = 355.96(C₁₈H₁₀BrClO = 357.63) | Sub1-34 | m/z = 279.93(C₁₂H₆BrClO = 281.53) |
| Sub1-35 | m/z = 355.96(C₁₈H₁₀BrClO = 357.63) | Sub1-36 | m/z = 355.96(C₁₈H₁₀BrClO = 357.63) |
| Sub1-37 | m/z = 279.93(C₁₂H₆BrClO = 281.53) | Sub1-38 | m/z = 355.96(C₁₈H₁₀BrClO = 357.63) |
| Sub1-39 | m/z = 279.93(C₁₂H₆BrClO = 281.53) | Sub1-40 | m/z = 355.96(C₁₈H₁₀BrClO = 357.63) |
| Sub1-41 | m/z = 355.96(C₁₈H₁₀BrClO = 357.63) | Sub1-42 | m/z = 279.93(C₁₂H₆BrClO = 281.53) |
| Sub1-43 | m/z = 355.96(C₁₈H₁₀BrClO = 357.63) | Sub1-44 | m/z = 329.94(C₁₆H₈BrClO = 331.59) |
| Sub1-45 | m/z = 355.96(C₁₈H₁₀BrClO = 357.63) | Sub1-46 | m/z = 279.93(C₁₂H₆BrClO = 281.53) |
| Sub1-47 | m/z = 329.94(C₁₆H₈BrClO = 331.59) | Sub1-48 | m/z = 279.93(C₁₂H₆BrClO = 281.53) |
| Sub1-49 | m/z = 279.93(C₁₂H₆BrClO = 281.53) | Sub1-50 | m/z = 279.93(C₁₂H₆BrClO = 281.53) |
| Sub1-51 | m/z = 329.94(C₁₆H₈BrClO = 331.59) | Sub1-52 | m/z = 279.93(C₁₂H₆BrClO = 281.53) |
| Sub1-53 | m/z = 279.93(C₁₂H₆BrClO = 281.53) | Sub1-54 | m/z = 355.96(C₁₈H₁₀BrClO = 357.63) |

### Synthesis example of Sub 2

Sub 2 of Reaction Scheme 1 may be synthesized by the reaction route of Reaction Scheme 3 below (disclosed in Korean Patent No. 10-1251451 of the applicant of the present invention(registration notice dated Apr. 5, 2013)), but is not limited thereto.

### <Reaction Scheme 3>(Hal3 is I, Br or Cl)

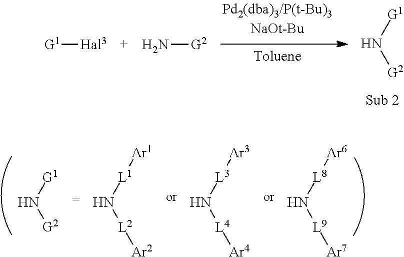

Compounds belonging to Sub 2 may be, but not limited to, the following compounds, and Table 2 shows FD-MS(Field Desorption-Mass Spectrometry) values of the following compounds.

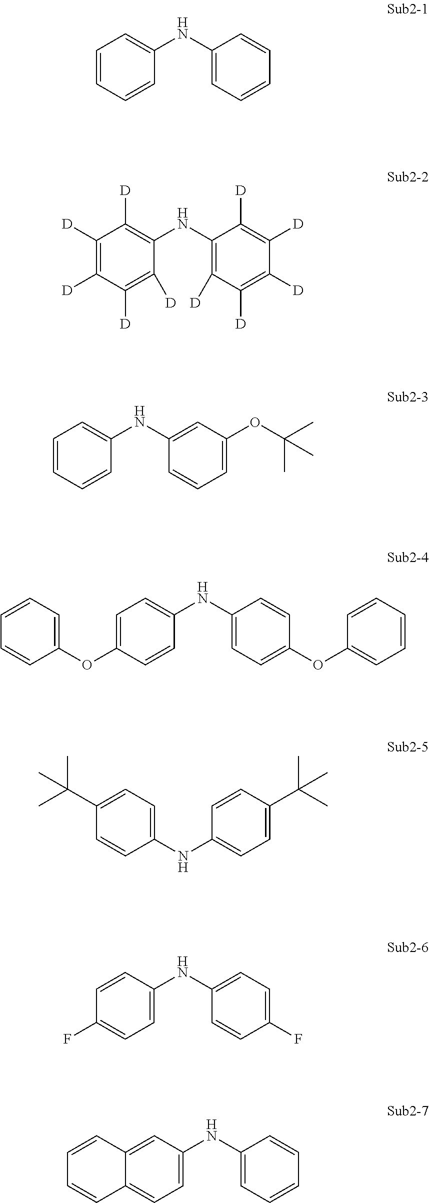

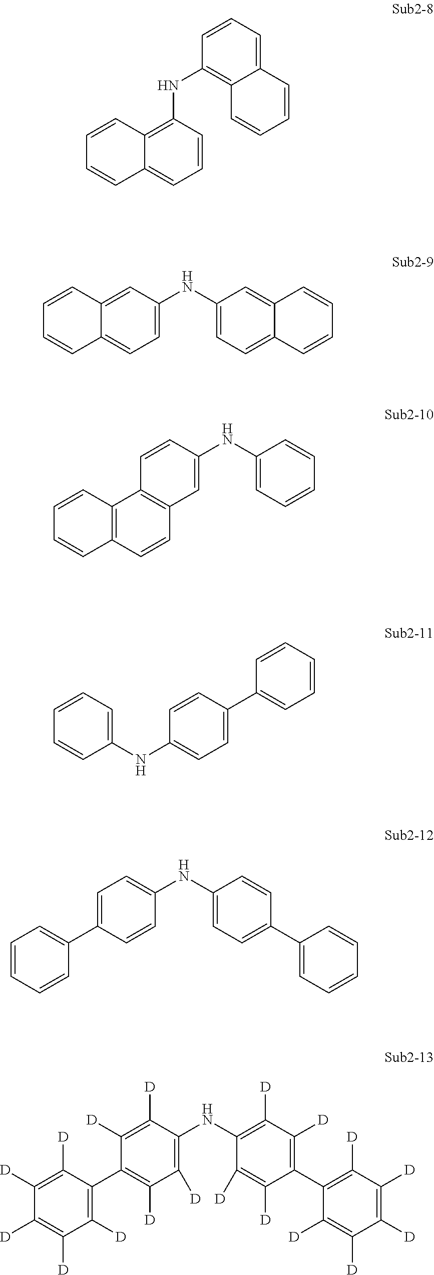 [SMILES: c1ccc2c(Nc3cccc4ccccc34)cccc2c1 ; c1ccc2cc(Nc3ccc4ccccc4c3)ccc2c1 ; c1ccc(Nc2ccc3c(ccc4ccccc43)c2)cc1 ; c1ccc(Nc2ccc(-c3ccccc3)cc2)cc1 ; c1ccc(-c2ccc(Nc3ccc(-c4ccccc4)cc3)cc2)cc1 ; [2H]c1c([2H])c([2H])c(-c2c([2H])c([2H])c(Nc3c([2H])c([2H])c(-c4c([2H])c([2H])c([2H])c([2H])c4[2H])c([2H])c3[2H])c([2H])c2[2H])c([2H])c1[2H]]

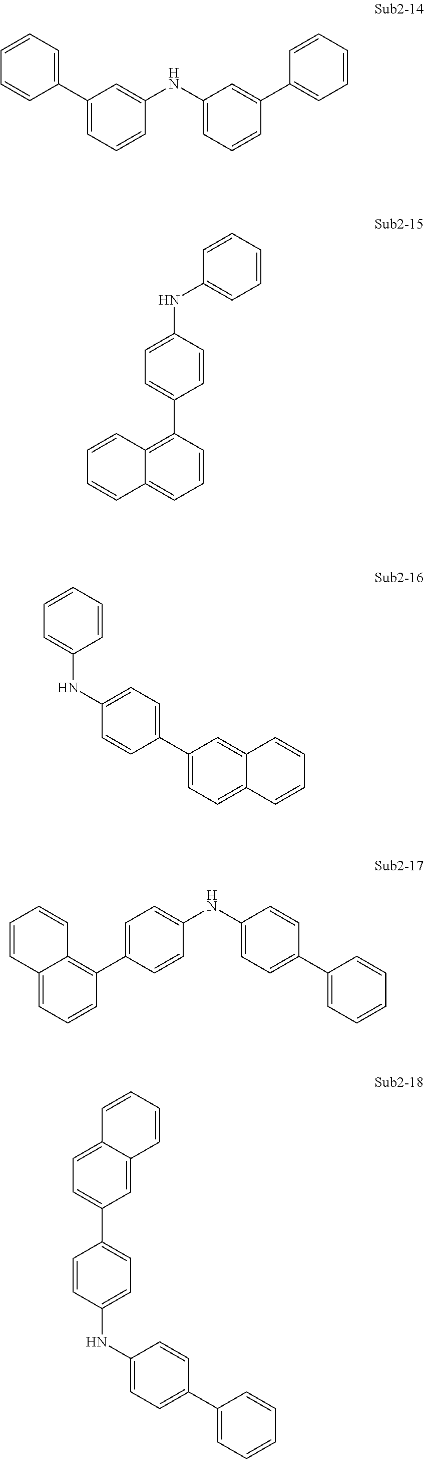 [SMILES: c1ccc(-c2cccc(Nc3cccc(-c4ccccc4)c3)c2)cc1 ; c1ccc(Nc2ccc(-c3cccc4ccccc34)cc2)cc1 ; c1ccc(Nc2ccc(-c3ccc4ccccc4c3)cc2)cc1 ; c1ccc(-c2ccc(Nc3ccc(-c4cccc5ccccc45)cc3)cc2)cc1 ; c1ccc(-c2ccc(Nc3ccc(-c4ccc5ccccc5c4)cc3)cc2)cc1]

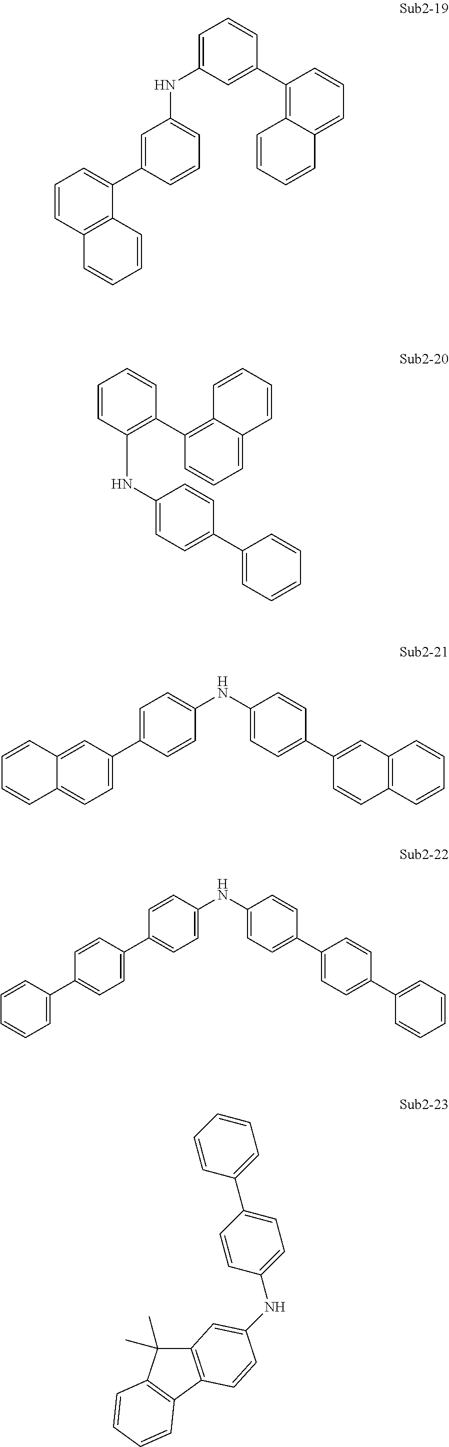 [SMILES: c1cc(Nc2cccc(-c3cccc4ccccc34)c2)cc(-c2cccc3ccccc23)c1 ; c1ccc(-c2ccc(Nc3ccccc3-c3cccc4ccccc34)cc2)cc1 ; c1ccc2cc(-c3ccc(Nc4ccc(-c5ccc6ccccc6c5)cc4)cc3)ccc2c1 ; c1ccc(-c2ccc(-c3ccc(Nc4ccc(-c5ccc(-c6ccccc6)cc5)cc4)cc3)cc2)cc1 ; CC1(C)c2ccccc2-c2ccc(Nc3ccc(-c4ccccc4)cc3)cc21]

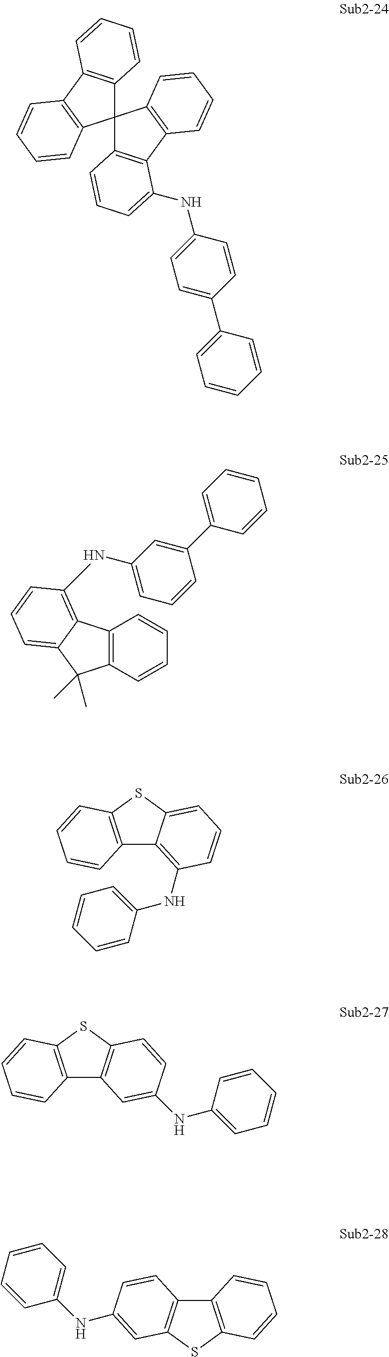 [SMILES: c1ccc(-c2ccc(Nc3cccc4c3-c3ccccc3C43c4ccccc4-c4ccccc43)cc2)cc1 ; CC1(C)c2ccccc2-c2c(Nc3cccc(-c4ccccc4)c3)cccc21 ; c1ccc(Nc2cccc3sc4ccccc4c23)cc1 ; c1ccc(Nc2ccc3sc4ccccc4c3c2)cc1 ; c1ccc(Nc2ccc3c(c2)sc2ccccc23)cc1]

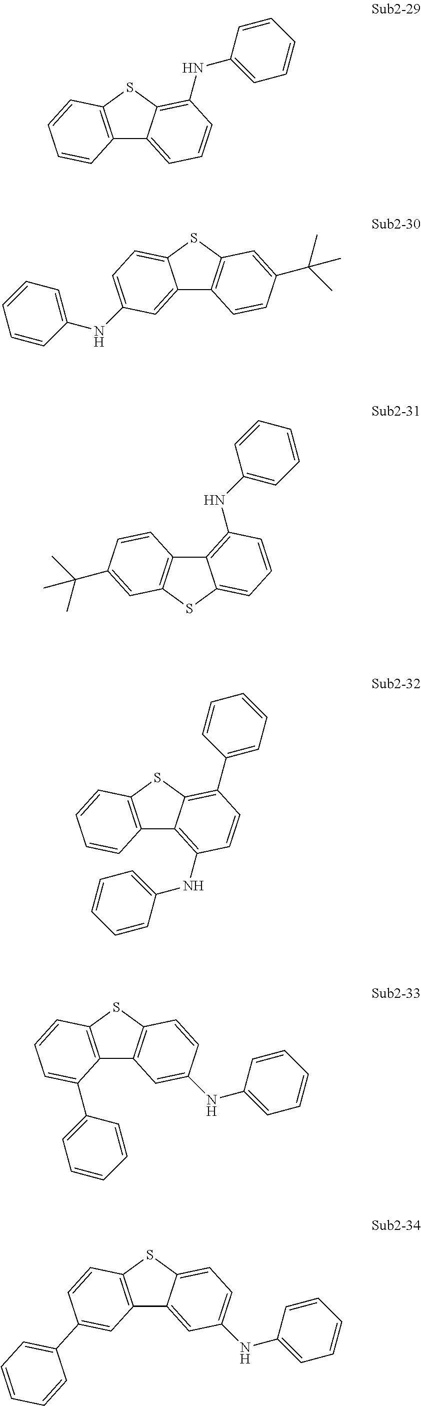

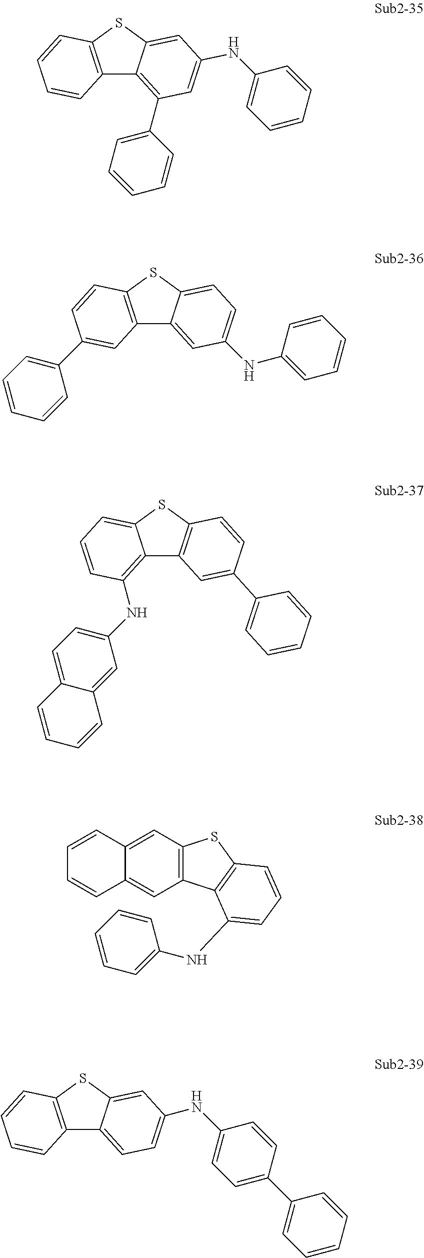 [SMILES: c1ccc(Nc2cc(-c3ccccc3)c3c(c2)sc2ccccc23)cc1 ; c1ccc(Nc2ccc3sc4ccc(-c5ccccc5)cc4c3c2)cc1 ; c1ccc(-c2ccc3sc4cccc(Nc5ccc6ccccc6c5)c4c3c2)cc1 ; c1ccc(Nc2cccc3sc4cc5ccccc5cc4c23)cc1 ; c1ccc(-c2ccc(Nc3ccc4c(c3)sc3ccccc34)cc2)cc1]

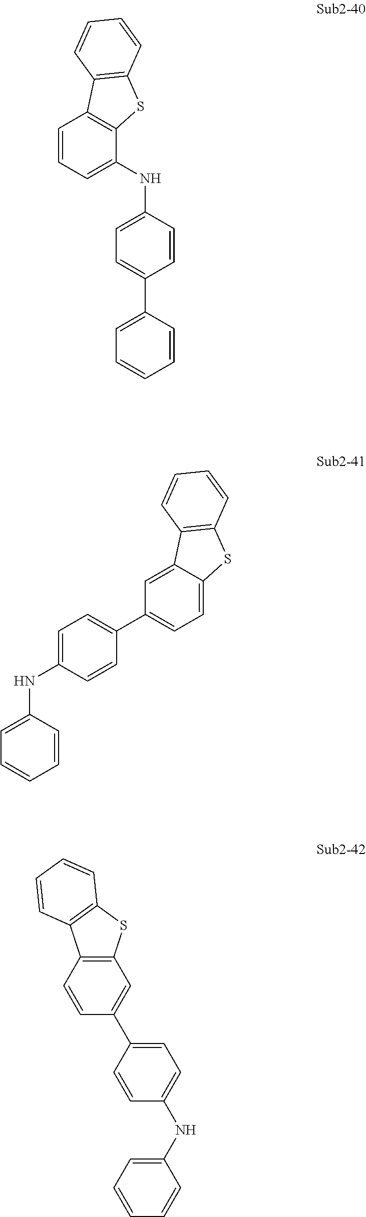 [SMILES: c1ccc(-c2ccc(Nc3cccc4c3sc3ccccc34)cc2)cc1 ; c1ccc(Nc2ccc(-c3ccc4sc5ccccc5c4c3)cc2)cc1 ; c1ccc(Nc2ccc(-c3ccc4c(c3)sc3ccccc34)cc2)cc1]

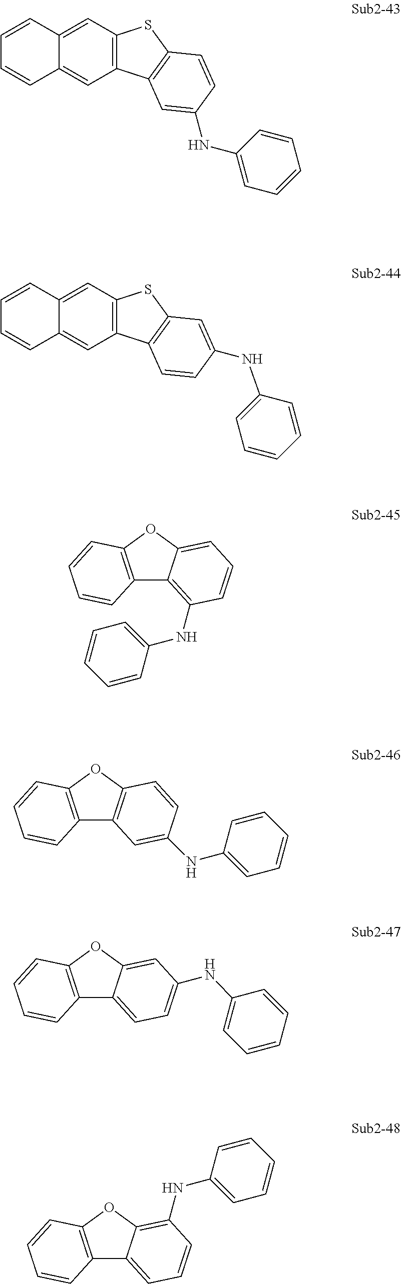 [SMILES: c1ccc(Nc2ccc3sc4cc5ccccc5cc4c3c2)cc1 ; c1ccc(Nc2ccc3c(c2)sc2cc4ccccc4cc23)cc1 ; c1ccc(Nc2cccc3oc4ccccc4c23)cc1 ; c1ccc(Nc2ccc3oc4ccccc4c3c2)cc1 ; c1ccc(Nc2ccc3c(c2)oc2ccccc23)cc1 ; c1ccc(Nc2cccc3c2oc2ccccc23)cc1]

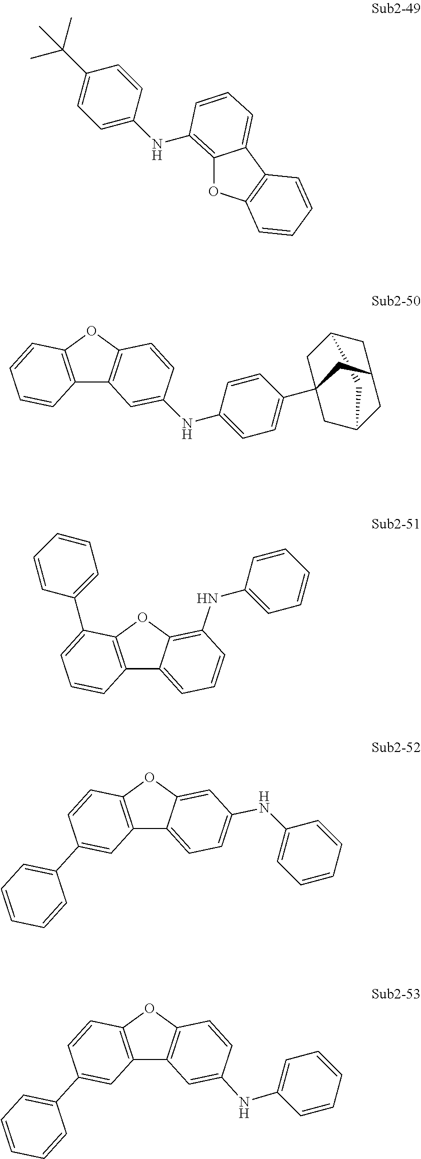 [SMILES: CC(C)(C)c1ccc(Nc2cccc3c2oc2ccccc23)cc1 ; c1ccc2c(c1)oc1ccc(Nc3ccc([C@]45C[C@H]6C[C@H](C[C@H](C6)C4)C5)cc3)cc12 ; c1ccc(Nc2cccc3c2oc2c(-c4ccccc4)cccc23)cc1 ; c1ccc(Nc2ccc3c(c2)oc2ccc(-c4ccccc4)cc23)cc1 ; c1ccc(Nc2ccc3oc4ccc(-c5ccccc5)cc4c3c2)cc1]

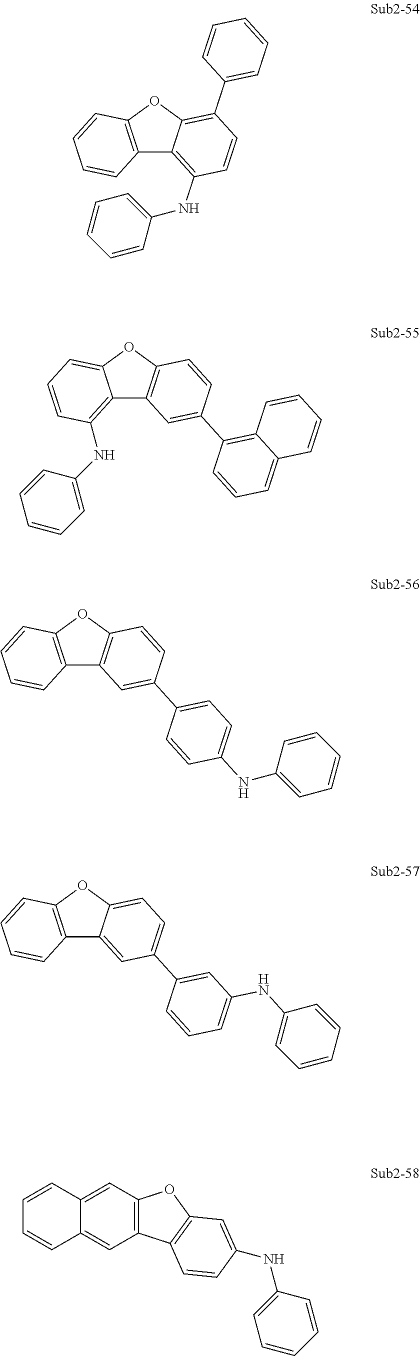 [SMILES: c1ccc(Nc2ccc(-c3ccccc3)c3oc4ccccc4c23)cc1 ; c1ccc(Nc2cccc3oc4ccc(-c5cccc6ccccc56)cc4c23)cc1 ; c1ccc(Nc2ccc(-c3ccc4oc5ccccc5c4c3)cc2)cc1 ; c1ccc(Nc2cccc(-c3ccc4oc5ccccc5c4c3)c2)cc1 ; c1ccc(Nc2ccc3c(c2)oc2cc4ccccc4cc23)cc1]

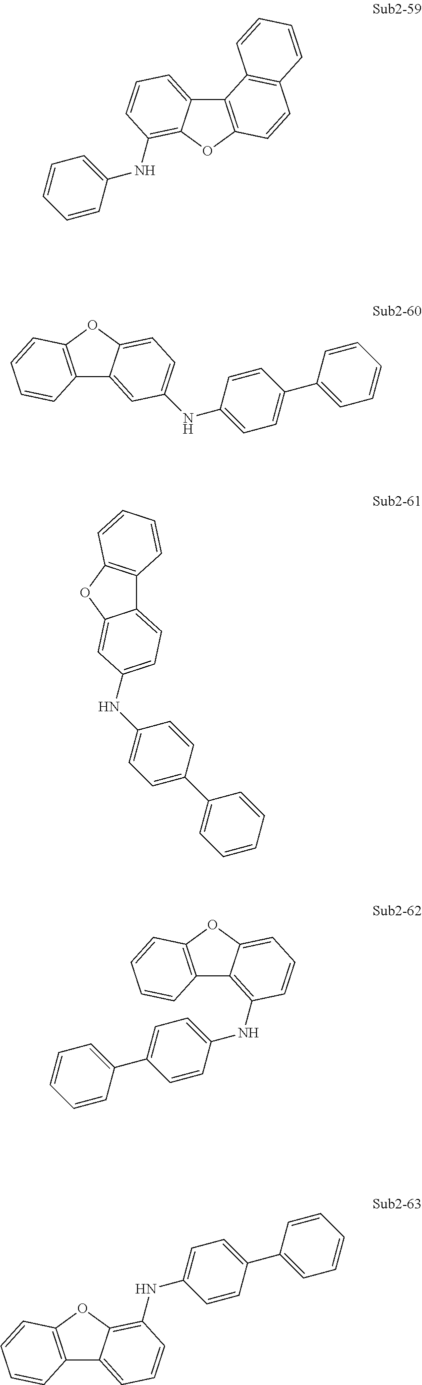 [SMILES: c1ccc(Nc2cccc3c2oc2ccc4ccccc4c23)cc1 ; c1ccc(-c2ccc(Nc3ccc4oc5ccccc5c4c3)cc2)cc1 ; c1ccc(-c2ccc(Nc3ccc4c(c3)oc3ccccc34)cc2)cc1 ; c1ccc(-c2ccc(Nc3cccc4oc5ccccc5c34)cc2)cc1 ; c1ccc(-c2ccc(Nc3cccc4c3oc3ccccc34)cc2)cc1]

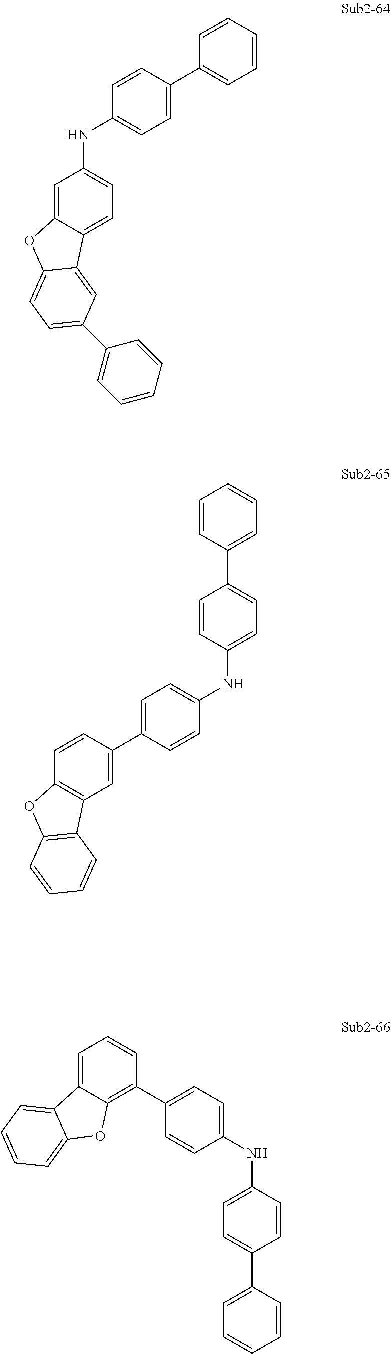 [SMILES: c1ccc(-c2ccc(Nc3ccc4c(c3)oc3ccc(-c5ccccc5)cc34)cc2)cc1 ; c1ccc(-c2ccc(Nc3ccc(-c4ccc5oc6ccccc6c5c4)cc3)cc2)cc1 ; c1ccc(-c2ccc(Nc3ccc(-c4cccc5c4oc4ccccc45)cc3)cc2)cc1]

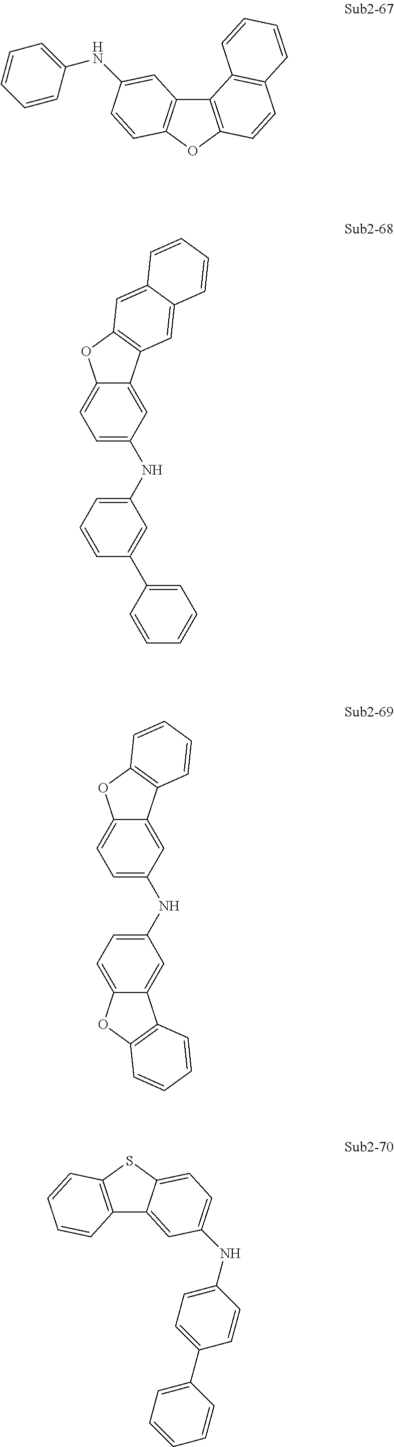 [SMILES: c1ccc(Nc2ccc3oc4ccc5ccccc5c4c3c2)cc1 ; c1ccc(-c2cccc(Nc3ccc4oc5cc6ccccc6cc5c4c3)c2)cc1 ; c1ccc2c(c1)oc1ccc(Nc3ccc4oc5ccccc5c4c3)cc12 ; c1ccc(-c2ccc(Nc3ccc4sc5ccccc5c4c3)cc2)cc1]

TABLE 2

| Compound | FD-MS | Compound | FD-MS |
|---|---|---|---|
| Sub2-1 | m/z = 169.09(C₁₂H₁₁N = 169.23) | Sub2-2 | m/z = 179.15(C₁₂HD₁₀N = 179.29) |
| Sub2-3 | m/z = 241.15(C₁₆H₁₉NO = 241.33) | Sub2-4 | m/z = 353.14(C₂₄H₁₉NO₂ = 353.42) |
| Sub2-5 | m/z = 281.21(C₂₀H₂₇N = 281.44) | Sub2-6 | m/z = 205.07(C₁₂H₉F₂N = 205.21) |
| Sub2-7 | m/z = 219.1(C₁₆H₁₃N = 219.29) | Sub2-8 | m/z = 269.12(C₂₀H₁₅N = 269.35) |
| Sub2-9 | m/z = 269.12(C₂₀H₁₅N = 269.35) | Sub2-10 | m/z = 269.12(C₂₀H₁₅N = 269.35) |
| Sub2-11 | m/z = 245.12(C₁₈H₁₅N = 245.33) | Sub2-12 | m/z = 321.15(C₂₄H₁₉N = 321.42) |
| Sub2-13 | m/z = 339.26(C₂₄HD₁₈N = 339.53) | Sub2-14 | m/z = 321.15(C₂₄H₁₉N = 321.42) |
| Sub2-15 | m/z = 295.14(C₂₂H₁₇N = 295.39) | Sub2-16 | m/z = 295.14(C₂₂H₁₇N = 295.39) |
| Sub2-17 | m/z = 371.17(C₂₈H₂₁N = 371.48) | Sub2-18 | m/z = 371.17(C₂₈H₂₁N = 371.48) |
| Sub2-19 | m/z = 421.18(C₃₂H₂₃N = 421.54) | Sub2-20 | m/z = 371.17(C₂₈H₂₁N = 371.48) |
| Sub2-21 | m/z = 421.18(C₃₂H₂₃N = 421.54) | Sub2-22 | m/z = 473.21(C₃₆H₂₇N = 473.62) |
| Sub2-23 | m/z = 361.18(C₂₇H₂₃N = 361.49) | Sub2-24 | m/z = 483.2(C₃₇H₂₅N = 483.61) |
| Sub2-25 | m/z = 361.18(C₂₇H₂₃N = 361.49) | Sub2-26 | m/z = 275.08(C₁₈H₁₃NS = 275.37) |
| Sub2-27 | m/z = 275.08(C₁₈H₁₃NS = 275.37) | Sub2-28 | m/z = 275.08(C₁₈H₁₃NS = 275.37) |
| Sub2-29 | m/z = 275.08(C₁₈H₁₃NS = 275.37) | Sub2-30 | m/z = 331.14(C₂₂H₂₁NS = 331.48) |
| Sub2-31 | m/z = 331.14(C₂₂H₂₁NS = 331.48) | Sub2-32 | m/z = 351.11(C₂₄H₁₇NS = 351.47) |
| Sub2-33 | m/z = 351.11(C₂₄H₁₇NS = 351.47) | Sub2-34 | m/z = 351.11(C₂₄H₁₇NS = 351.47) |
| Sub2-35 | m/z = 351.11(C₂₄H₁₇NS = 351.47) | Sub2-36 | m/z = 351.11(C₂₄H₁₇NS = 351.47) |
| Sub2-37 | m/z = 401.12(C₂₈H₁₉NS = 401.53) | Sub2-38 | m/z = 325.09(C₂₂H₁₅NS = 325.43) |
| Sub2-39 | m/z = 351.11(C₂₄H₁₇NS = 351.47) | Sub2-40 | m/z = 351.11(C₂₄H₁₇NS = 351.47) |
| Sub2-41 | m/z = 351.11(C₂₄H₁₇NS = 351.47) | Sub2-42 | m/z = 351.11(C₂₄H₁₇NS = 351.47) |
| Sub2-43 | m/z = 325.09(C₂₂H₁₅NS = 325.43) | Sub2-44 | m/z = 325.09(C₂₂H₁₅NS = 325.43) |
| Sub2-45 | m/z = 259.1(C₁₈H₁₃NO = 259.31) | Sub2-46 | m/z = 259.1(C₁₈H₁₃NO = 259.31) |
| Sub2-47 | m/z = 259.1(C₁₈H₁₃NO = 259.31) | Sub2-48 | m/z = 259.1(C₁₈H₁₃NO = 259.31) |
| Sub2-49 | m/z = 315.16(C₂₂H₂₁NO = 315.42) | Sub2-50 | m/z = 393.21(C₂₈H₂₇NO = 393.53) |
| Sub2-51 | m/z = 335.13(C₂₄H₁₇NO = 335.41) | Sub2-52 | m/z = 335.13(C₂₄H₁₇NO = 335.41) |
| Sub2-53 | m/z = 335.13(C₂₄H₁₇NO = 335.41) | Sub2-54 | m/z = 335.13(C₂₄H₁₇NO = 335.41) |
| Sub2-55 | m/z = 385.15(C₂₈H₁₉NO = 385.47) | Sub2-56 | m/z = 335.13(C₂₄H₁₇NO = 335.41) |
| Sub2-57 | m/z = 335.13(C₂₄H₁₇NO = 335.41) | Sub2-58 | m/z = 309.12(C₂₂H₁₅NO = 309.37) |
| Sub2-59 | m/z = 309.12(C₂₂H₁₅NO = 309.37) | Sub2-60 | m/z = 335.13(C₂₄H₁₇NO = 335.41) |
| Sub2-61 | m/z = 335.13(C₂₄H₁₇NO = 335.41) | Sub2-62 | m/z = 335.13(C₂₄H₁₇NO = 335.41) |
| Sub2-63 | m/z = 335.13(C₂₄H₁₇NO = 335.41) | Sub2-64 | m/z = 411.16(C₃₀H₂₁NO = 411.5) |
| Sub2-65 | m/z = 411.16(C₃₀H₂₁NO = 411.5) | Sub2-66 | m/z = 411.16(C₃₀H₂₁NO = 411.5) |
| Sub2-67 | m/z = 309.12(C₂₂H₁₅NO = 309.37) | Sub2-68 | m/z = 385.15(C₂₈H₁₉NO = 385.47) |
| Sub2-69 | m/z = 349.11(C₂₄H₁₅NO₂ = 349.39) | Sub2-70 | m/z = 351.11(C₂₄H₁₇NS = 351.47) |

### Synthesis example of Final compound

### 1. Synthesis example of P1-1

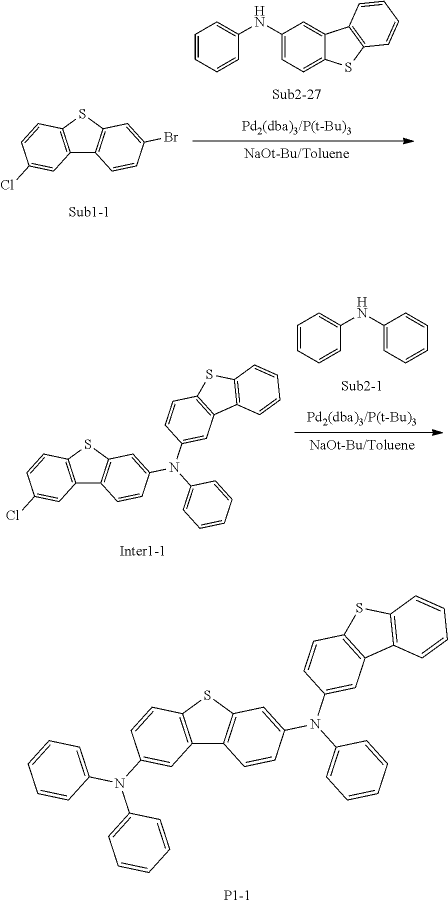

### [342](1) Synthesis of Inter1-1

Sub1-1 (5.0 g, 16.8 mmol), Sub2-27 (4.6 g, 16.8 mmol), Pd2(dba)3 (0.46 g, 0.50 mmol), P(t-Bu)3 (0.20 g, 1.01 mmol), NaOt-Bu (3.2 g, 33.6 mmol) and toluene (84 mL) were put into a round bottom flask, and the reaction was carried out at 60° C. When the reaction was completed, the reaction product was extracted with CH2Cl2 and water, and then an organic layer was dried with MgSO4 and concentrated. Then, the concentrate was separated through a silica gel column and recrystallized to obtain 6.0 g (yield: 72%) of the product.

### (2) Synthesis of P1-1

Inter1-1 (6.0 g, 12.1 mmol), Sub2-1 (2.0 g, 12.1 mmol), Pd2(dba)3 (0.33 g, 0.36 mmol), P(t-Bu)3 (0.15 g, 0.73 mmol), NaOt-Bu (2.3 g, 24.2 mmol) and toluene (60 mL) were put into a round bottom flask, and the reaction was carried out at 80° C. When the reaction was completed, the reaction product was extracted with CH2Cl2 and water, and then an organic layer was dried with MgSO4 and concentrated. Then, the concentrate was separated through a silica gel column and recrystallized to obtain 5.8 g (yield: 77%) of the product.

### 2. Synthesis example of P1-8

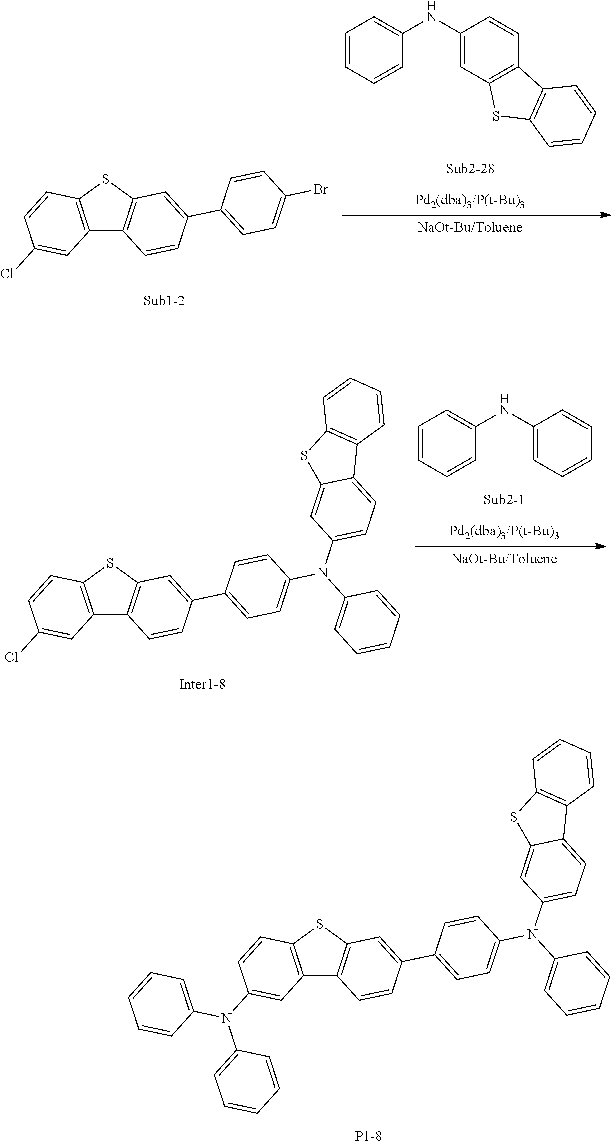

### (1) Synthesis of Inter1-8

Sub1-2 (5.0 g, 13.4 mmol), Sub2-28 (3.7 g, 13.4 mmol), Pd2(dba)3 (0.37 g, 0.40 mmol), P(t-Bu)3 (0.16 g, 0.80 mmol), NaOt-Bu (2.6 g, 26.8 mmol), Toluene (67 mL) were putted into a round bottom flask, and then the synthesis was carried out in the same manner as in the synthesis method of Inter1-1 to obtain 5.5 g (yield: 73%) of the product.

### (2) Synthesis of P1-8

Inter1-8 (5.5 g, 9.8 mmol), Sub2-1 (1.7 g, 9.8 mmol), Pd2(dba)3 (0.27 g, 0.29 mmol), P(t-Bu)3 (0.12 g, 0.59 mmol), NaOt-Bu (1.9 g, 19.5 mmol) and toluene (49 mL) were putted into a round bottom flask, and then the synthesis was carried out in the same manner as in the synthesis method of P1-1 to obtain 5.4 g (yield: 79%) of the product.

### 3. Synthesis example of P1-25

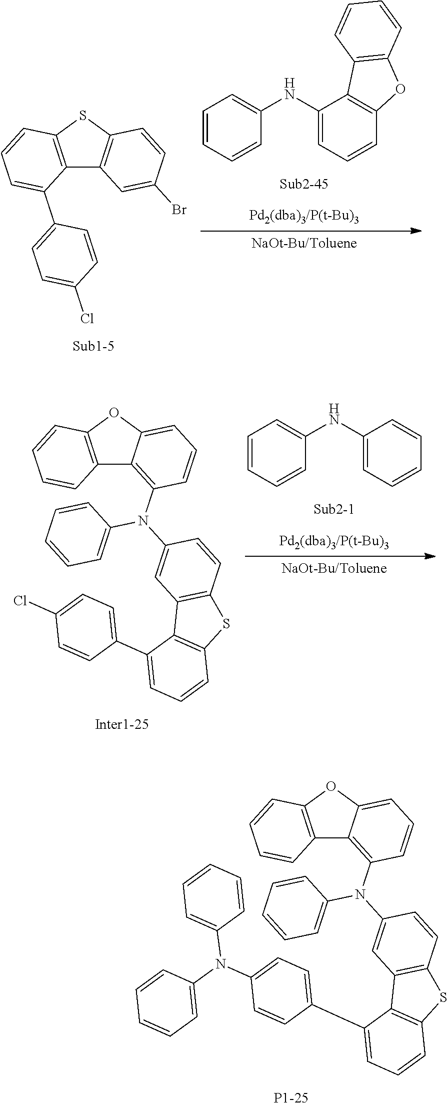

### (1) Synthesis of Inter1-25

Sub1-5 (5.0 g, 13.4 mmol), Sub2-45 (3.5 g, 13.4 mmol), Pd2(dba)3 (0.37 g, 0.40 mmol), P(t-Bu)3 (0.16 g, 0.80 mmol), NaOt-Bu (2.6 g, 26.8 mmol) and toluene (67 mL) were putted into a round bottom flask, and then the synthesis was carried out in the same manner as in the synthesis method of Inter1-1 to obtain 4.6 g (yield: 62%) of the product.

### (2) Synthesis of P1-25

Inter1-25 (4.6 g, 8.3 mmol), Sub2-1 (1.4 g, 8.3 mmol), Pd2(dba)3 (0.23 g, 0.25 mmol), P(t-Bu)3 (0.10 g, 0.50 mmol), NaOt-Bu (1.6 g, 16.6 mmol) and toluene (41 mL) were putted into a round bottom flask, and then the synthesis was carried out in the same manner as in the synthesis method of Inter1-1 to obtain 4.0 g (yield: 71%) of the product.

### 4. Synthesis example of P1-40

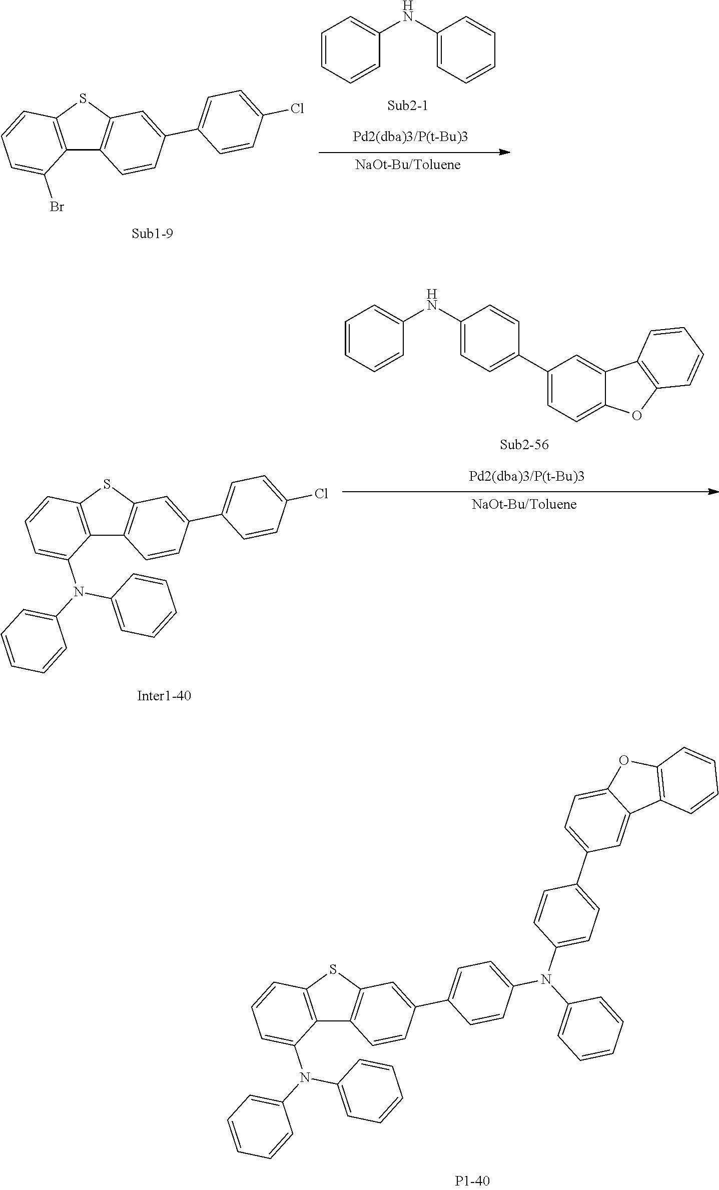 [SMILES: c1ccc(Nc2ccccc2)cc1 ; Clc1ccc(-c2ccc3c(c2)sc2cccc(Br)c23)cc1 ; c1ccc(Nc2ccc(-c3ccc4oc5ccccc5c4c3)cc2)cc1 ; Clc1ccc(-c2ccc3c(c2)sc2cccc(N(c4ccccc4)c4ccccc4)c23)cc1 ; c1ccc(N(c2ccc(-c3ccc4c(c3)sc3cccc(N(c5ccccc5)c5ccccc5)c34)cc2)c2ccc(-c3ccc4oc5ccccc5c4c3)cc2)cc1]

### (1) Synthesis of Inter1-40

Sub1-9 (5.0 g, 13.4 mmol), Sub2-1 (2.3 g, 13.4 mmol), Pd2(dba)3 (0.37 g, 0.40 mmol), P(t-Bu)3 (0.16 g, 0.80 mmol), NaOt-Bu (2.6 g, 26.8 mmol) and toluene (67 mL) were putted into a round bottom flask, and then the synthesis was carried out in the same manner as in the synthesis method of Inter1-1 to obtain 4.4 g (yield: 71%) of the product.

### (2) Synthesis of P1-40

Inter1-40 (4.4 g, 9.5 mmol), Sub2-56 (3.2 g, 9.5 mmol), Pd2(dba)3 (0.26 g, 0.28 mmol), P(t-Bu)3 (0.12 g, 0.57 mmol), NaOt-Bu (1.8 g, 19.0 mmol) and toluene (47 mL) were putted into a round bottom flask, and then the synthesis was carried out in the same manner as in the synthesis method of P1-1 to obtain 5.6 g (yield: 78%) of the product.

### 5. Synthesis example of P1-47

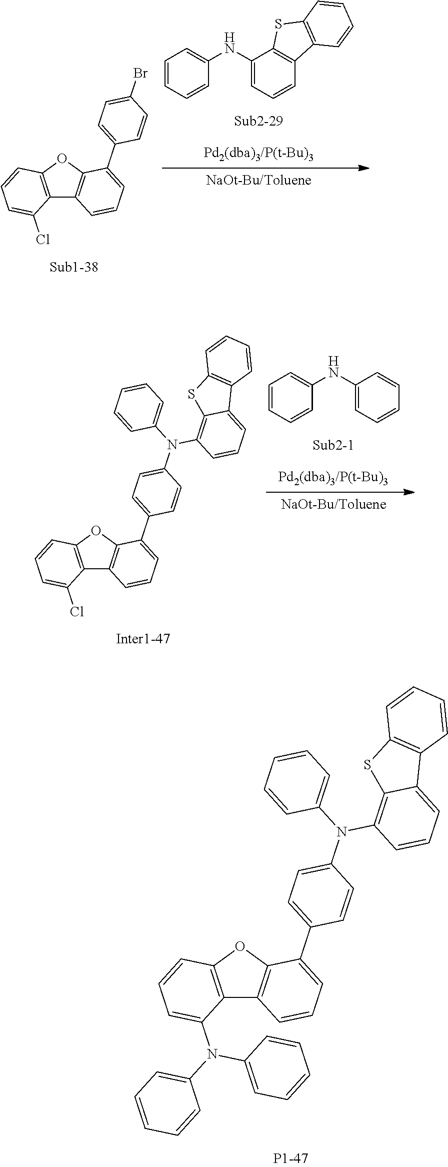

### (1) Synthesis of Inter1-47

Sub1-38 (5.0 g, 14.0 mmol), Sub2-29 (3.8 g, 14.0 mmol), Pd2(dba)3 (0.38 g, 0.42 mmol), P(t-Bu)3 (0.17 g, 0.84 mmol), NaOt-Bu (2.7 g, 28.0 mmol) and toluene (70 mL) were putted into a round bottom flask, and then the synthesis was carried out in the same manner as in the synthesis method of Inter1-1 to obtain 5.8 g (yield: 75%) of the product.

### (2) Synthesis of P1-47

Inter1-47 (5.8 g, 10.5 mmol), Sub2-1 (1.8 g, 10.5 mmol), Pd2(dba)3 (0.29 g, 0.31 mmol), P(t-Bu)3 (0.13 g, 0.63 mmol), NaOt-Bu (2.0 g, 21.0 mmol) and toluene (52 mL) were putted into a round bottom flask, and then the synthesis was carried out in the same manner as in the synthesis method of P1-1 to obtain 5.2 g (yield: 72%) of the product.

### 6. Synthesis example of P1-58

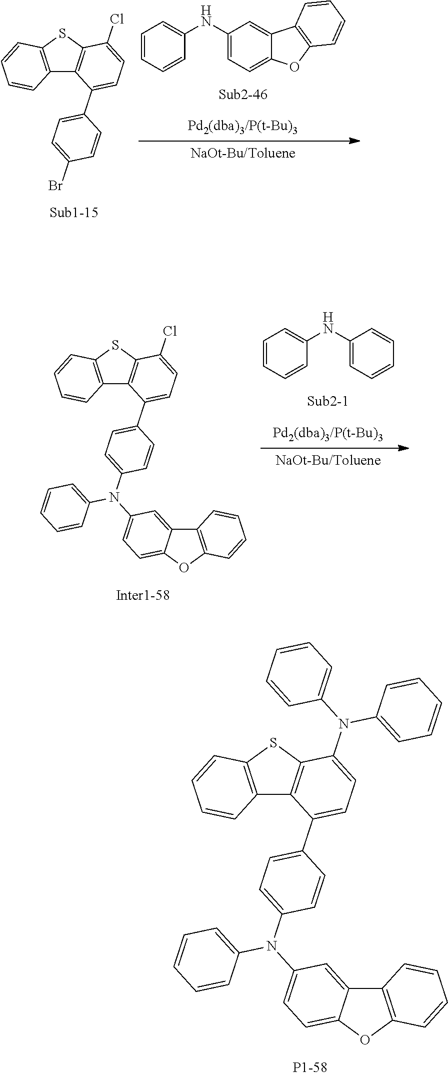

### (1) Synthesis of Inter1-58

Sub1-15 (5.0 g, 13.4 mmol), Sub2-46 (3.5 g, 13.4 mmol), Pd2(dba)3 (0.37 g, 0.40 mmol), P(t-Bu)3 (0.16 g, 0.80 mmol), NaOt-Bu (2.6 g, 26.8 mmol) and toluene (67 mL) were putted into a round bottom flask, and then the synthesis was carried out in the same manner as in the synthesis method of Inter1-1 to obtain 5.7 g (yield: 77%) of the product.

### (2) Synthesis of P1-58

Inter1-58 (5.7 g, 10.3 mmol), Sub2-1 (1.7 g, 10.3 mmol), Pd2(dba)3 (0.28 g, 0.31 mmol), P(t-Bu)3 (0.13 g, 0.62 mmol), NaOt-Bu (2.0 g, 20.6 mmol) and toluene (52 mL) were putted into a round bottom flask, and then the synthesis was carried out in the same manner as in the synthesis method of P1-1 to obtain 4.9 g (yield: 69%) of the product.

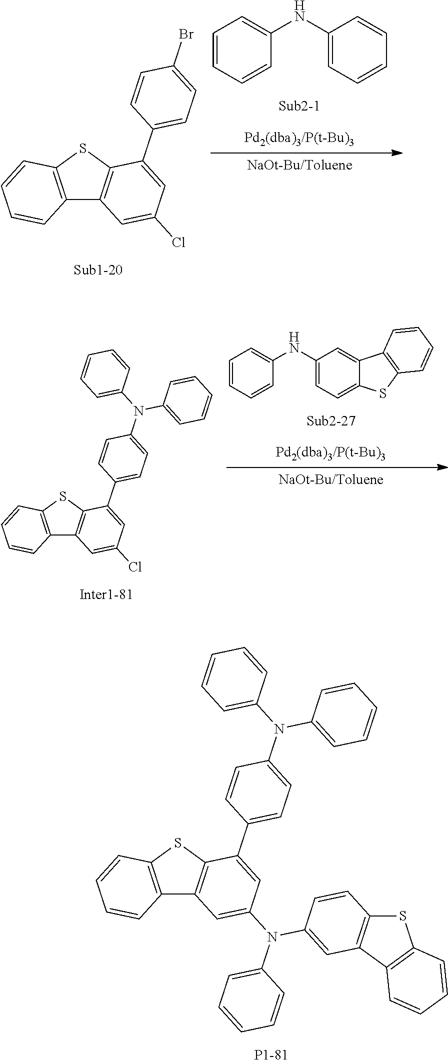

### (1) Synthesis of Inter1-81

Sub1-20 (5.0 g, 13.4 mmol), Sub2-1 (2.3 g, 13.4 mmol), Pd2(dba)3 (0.37 g, 0.40 mmol), P(t-Bu)3 (0.16 g, 0.80 mmol), NaOt-Bu (2.6 g, 26.8 mmol) and toluene (67 mL) were putted into a round bottom flask, and then the synthesis was carried out in the same manner as in the synthesis method of Inter1-1 to obtain 4.8 g (yield: 78%) of the product.

### (2) Synthesis of P1-81

Inter1-81 (4.8 g, 10.4 mmol), Sub2-27 (2.9 g, 10.4 mmol), Pd2(dba)3 (0.29 g, 0.31 mmol), P(t-Bu)3 (0.13 g, 0.63 mmol), NaOt-Bu (2.0 g, 20.9 mmol) and toluene (52 mL) were putted into a round bottom flask, and then the synthesis was carried out in the same manner as in the synthesis method of P1-1 to obtain 5.3 g (yield: 73%) of the product.

### 8. Synthesis example of P1-90

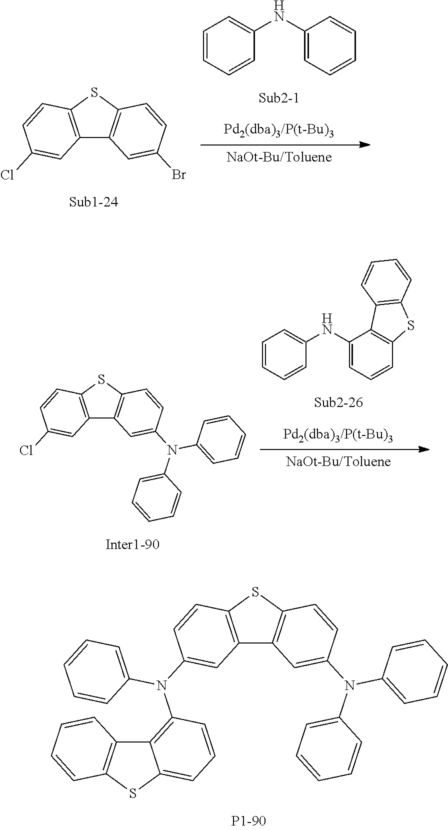 [SMILES: c1ccc(Nc2ccccc2)cc1 ; Clc1ccc2sc3ccc(Br)cc3c2c1 ; Clc1ccc2sc3ccc(N(c4ccccc4)c4ccccc4)cc3c2c1 ; c1ccc(Nc2cccc3sc4ccccc4c23)cc1 ; c1ccc(N(c2ccccc2)c2ccc3sc4ccc(N(c5ccccc5)c5cccc6sc7ccccc7c56)cc4c3c2)cc1]

### (1) Synthesis of Inter1-90

Sub1-24 (5.0 g, 16.8 mmol), Sub2-1 (2.8 g, 16.8 mmol), Pd2(dba)3 (0.46 g, 0.50 mmol), P(t-Bu)3 (0.20 g, 1.01 mmol), NaOt-Bu (3.2 g, 33.6 mmol) and toluene (84 mL) were putted into a round bottom flask, and then the synthesis was carried out in the same manner as in the synthesis method of Inter1-1 to obtain 4.8 g (yield: 74%) of the product.

### (2) Synthesis of P1-90

Inter1-90 (4.8 g, 12.4 mmol), Sub2-26 (3.4 g, 12.4 mmol), Pd2(dba)3 (0.34 g, 0.37 mmol), P(t-Bu)3 (0.15 g, 0.75 mmol), NaOt-Bu (2.4 g, 24.9 mmol) and toluene (62 mL) were putted into a round bottom flask, and then the synthesis was carried out in the same manner as in the synthesis method of P1-1 to obtain 5.6 g (yield: 72%) of the product.

FD-MS values of the compounds P1-1 to P1-108 of the present invention synthesized by the above synthesis method are shown in Table 3 below.

TABLE 3

| Compound | FD-MS | Compound | FD-MS |
|---|---|---|---|
| P1-1 | m/z = 624.17(C₄₂H₂₈N₂S₂ = 624.82) | P1-2 | m/z = 668.25(C₄₈H₃₂N₂O₂ = 668.8) |
| P1-3 | m/z = 714.18(C₄₈H₃₀N₂OS₂ = 714.9) | P1-4 | m/z = 760.25(C₅₄H₃₆N₂OS = 760.96) |
| P1-5 | m/z = 592.22(C₄₂H₂₈N₂O₂ = 592.7) | P1-6 | m/z = 718.26(C₅₂H₃₄N₂O₂ = 718.86) |
| P1-7 | m/z = 684.22(C₄₈H₃₂N₂OS = 684.86) | P1-8 | m/z = 700.2(C₄₈H₃₂N₂S₂ = 700.92) |
| P1-9 | m/z = 684.22(C₄₈H₃₂N₂OS = 684.86) | P1-10 | m/z = 784.25(C₅₆H₃₆N₂OS = 784.98) |
| P1-11 | m/z = 700.2(C₄₈H₃₂N₂S₂ = 700.92) | P1-12 | m/z = 760.25(C₅₄H₃₆N₂OS = 760.96) |
| P1-13 | m/z = 638.19(C₄₃H₃₀N₂S₂ = 638.85) | P1-14 | m/z = 664.25(C₄₆H₃₆N₂OS = 664.87) |
| P1-15 | m/z = 644.17(C₄₂H₂₆F₂N₂OS = 644.74) | P1-16 | m/z = 714.29(C₅₀H₃₈N₂O₃ = 714.87) |
| P1-17 | m/z = 624.17(C₄₂H₂₈N₂S₂ = 624.82) | P1-18 | m/z = 684.22(C₄₈H₃₂N₂OS = 684.86) |
| P1-19 | m/z = 668.25(C₄₈H₃₂N₂O₂ = 668.8) | P1-20 | m/z = 750.22(C₅₂H₃₄N₂S₂ = 750.98) |
| P1-21 | m/z = 698.2(C₄₈H₃₀N₂O₂S = 698.84) | P1-22 | m/z = 718.26(C₅₂H₃₄N₂O₂ = 718.86) |
| P1-23 | m/z = 664.25(C₄₆H₃₆N₂OS = 664.87) | P1-24 | m/z = 750.22(C₅₂H₃₄N₂S₂ = 750.98) |
| P1-25 | m/z = 684.22(C₄₈H₃₂N₂OS = 684.86) | P1-26 | m/z = 684.22(C₄₈H₃₂N₂OS = 684.86) |
| P1-27 | m/z = 760.25(C₅₄H₃₆N₂OS = 760.96) | P1-28 | m/z = 684.22(C₄₈H₃₂N₂OS = 684.86) |
| P1-29 | m/z = 624.17(C₄₂H₂₈N₂S₂ = 624.82) | P1-30 | m/z = 684.22(C₄₈H₃₂N₂OS = 684.86) |
| P1-31 | m/z = 760.25(C₅₄H₃₆N₂OS = 760.96) | P1-32 | m/z = 692.25(C₅₀H₃₂N₂O₂ = 692.82) |
| P1-33 | m/z = 776.23(C₅₄H₃₆N₂S₂ = 777.02) | P1-34 | m/z = 698.2(C₄₈H₃₀N₂O₂S = 698.84) |
| P1-35 | m/z = 704.34(C₅₀H₄₄N₂O₂ = 704.91) | P1-36 | m/z = 684.22(C₄₈H₃₂N₂OS = 684.86) |
| P1-37 | m/z = 700.2(C₄₈H₃₂N₂S₂ = 700.92) | P1-38 | m/z = 744.28(C₅₄H₃₆N₂O₂ = 744.89) |
| P1-39 | m/z = 760.25(C₅₄H₃₆N₂OS = 760.96) | P1-40 | m/z = 760.25(C₅₄H₃₆N₂OS = 760.96) |
| P1-41 | m/z = 624.17(C₄₂H₂₈N₂S₂ = 624.82) | P1-42 | m/z = 760.25(C₅₄H₃₆N₂OS = 760.96) |
| P1-43 | m/z = 684.22(C₄₈H₃₂N₂OS = 684.86) | P1-44 | m/z = 592.22(C₄₂H₂₈N₂O₂ = 592.7) |
| P1-45 | m/z = 700.2(C₄₈H₃₂N₂S₂ = 700.92) | P1-46 | m/z = 684.22(C₄₈H₃₂N₂OS = 684.86) |
| P1-47 | m/z = 684.22(C₄₈H₃₂N₂OS = 684.86) | P1-48 | m/z = 760.25(C₅₄H₃₆N₂OS = 760.96) |
| P1-49 | m/z = 724.2(C₅₀H₃₂N₂S₂ = 724.94) | P1-50 | m/z = 760.25(C₅₄H₃₆N₂OS = 760.96) |
| P1-51 | m/z = 668.25(C₄₈H₃₂N₂O₂ = 668.8) | P1-52 | m/z = 684.22(C₄₈H₃₂N₂OS = 684.86) |
| P1-53 | m/z = 648.28(C₄₆H₃₆N₂O₂ = 648.81) | P1-54 | m/z = 700.2(C₄₈H₃₂N₂S₂ = 700.92) |
| P1-55 | m/z = 658.21(C₄₆H₃₀N₂OS = 658.82) | P1-56 | m/z = 734.24(C₅₂H₃₄N₂OS = 734.92) |
| P1-57 | m/z = 700.2(C₄₈H₃₂N₂S₂ = 700.92) | P1-58 | m/z = 684.22(C₄₈H₃₂N₂OS = 684.86) |
| P1-59 | m/z = 744.28(C₅₄H₃₆N₂O₂ = 744.89) | P1-60 | m/z = 684.22(C₄₈H₃₂N₂OS = 684.86) |
| P1-61 | m/z = 624.17(C₄₂H₂₈N₂S₂ = 624.82) | P1-62 | m/z = 744.28(C₅₄H₃₆N₂O₂ = 744.89) |
| P1-63 | m/z = 708.22(C₅₀H₃₂N₂OS = 708.88) | P1-64 | m/z = 684.22(C₄₈H₃₂N₂OS = 684.86) |
| P1-65 | m/z = 674.19(C₄₆H₃₀N₂S₂ = 674.88) | P1-66 | m/z = 820.31(C₆₀H₄₀N₂O₂ = 820.99) |
| P1-67 | m/z = 734.24(C₅₂H₃₄N₂OS = 734.92) | P1-68 | m/z = 720.32(C₅₀H₄₄N₂OS = 720.98) |
| P1-69 | m/z = 684.22(C₄₈H₃₂N₂OS = 684.86) | P1-70 | m/z = 700.2(C₄₈H₃₂N₂S₂ = 700.92) |
| P1-71 | m/z = 684.22(C₄₈H₃₂N₂OS = 684.86) | P1-72 | m/z = 744.28(C₅₄H₃₆N₂O₂ = 744.89) |
| P1-73 | m/z = 624.17(C₄₂H₂₈N₂S₂ = 624.82) | P1-74 | m/z = 668.25(C₄₈H₃₂N₂O₂ = 668.8) |
| P1-75 | m/z = 760.25(C₅₄H₃₆N₂OS = 760.96) | P1-76 | m/z = 760.25(C₅₄H₃₆N₂OS = 760.96) |
| P1-77 | m/z = 684.22(C₄₈H₃₂N₂OS = 684.86) | P1-78 | m/z = 700.2(C₄₈H₃₂N₂S₂ = 700.92) |
| P1-79 | m/z = 744.3(C₅₂H₂₄D₁₀N₂OS = 744.98) | P1-80 | m/z = 628.2(C₄₂H₂₆F₂N₂O₂ = 628.68) |
| P1-81 | m/z = 700.2(C₄₈H₃₂N₂S₂ = 700.92) | P1-82 | m/z = 820.31(C₆₀H₄₀N₂O₂ = 820.99) |
| P1-83 | m/z = 734.24(C₅₂H₃₄N₂OS = 734.92) | P1-84 | m/z = 836.29(C₆₀H₄₀N₂OS = 837.05) |
| P1-85 | m/z = 742.3(C₅₂H₄₂N₂OS = 742.98) | P1-86 | m/z = 608.19(C₄₂H₂₈N₂OS = 608.76) |
| P1-87 | m/z = 684.22(C₄₈H₃₂N₂OS = 684.86) | P1-88 | m/z = 668.25(C₄₈H₃₂N₂O₂ = 668.8) |
| P1-89 | m/z = 776.27(C₅₄H₃₆N₂O₄ = 776.89) | P1-90 | m/z = 624.17(C₄₂H₂₈N₂S₂ = 624.82) |
| P1-91 | m/z = 758.24(C₅₄H₃₄N₂OS = 758.94) | P1-92 | m/z = 700.2(C₄₈H₃₂N₂S₂ = 700.92) |
| P1-93 | m/z = 624.17(C₄₂H₂₈N₂S₂-624.82) | P1-94 | m/z = 642.23(C₄₆H₃₀N₂O₂ = 642.76) |
| P1-95 | m/z = 608.19(C₄₂H₂₈N₂OS = 608.76) | P1-96 | m/z = 684.22(C₄₈H₃₂N₂OS = 684.86) |
| P1-97 | m/z = 624.17(C₄₂H₂₈N₂S₂ = 624.82) | P1-98 | m/z = 694.29(C₄₈H₂₂D₁₀N₂OS = 694.92) |
| P1-99 | m/z = 592.22(C₄₂H₂₈N₂O₂ = 592.7) | P1-100 | m/z = 910.3(C₆₆H₄₂N₂OS = 911.14) |
| P1-101 | m/z = 624.17(C₄₂H₂₈N₂S₂ = 624.82) | P1-102 | m/z = 608.19(C₄₂H₂₈N₂OS = 608.76) |
| P1-103 | m/z = 684.22(C₄₈H₃₂N₂OS = 684.86) | P1-104 | m/z = 668.25(C₄₈H₃₂N₂O₂ = 668.8) |
| P1-105 | m/z = 708.28(C₅₁H₃₆N₂O₂ = 708.86) | P1-106 | m/z = 846.29(C₆₁H₃₈N₂O₃ = 846.99) |
| P1-107 | m/z = 846.29(C₆₁H₃₈N₂O₃ = 846.99) | P1-108 | m/z = 760.25(C₅₄H₃₆N₂OS = 760.96) |

### Synthesis example of 2

### Synthesis example of Formula 2

The compound represented by Formula 2 according to the present invention can be synthesized by reaction route of the following Reaction Scheme 4, but is not limited thereto.

<Reaction Scheme 4>(Hal4 is I, Br or CI, G1 is —L8—Ar6, and G2 is —L9—Ar7.)

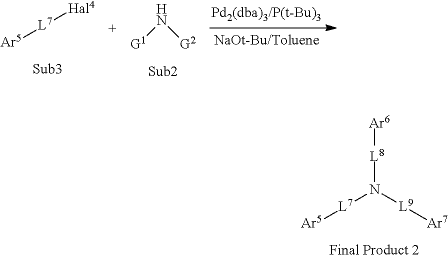

### Example compound of Sub3

Compounds belonging to Sub 3 may be, but not limited to, the following compounds, and Table 4 shows FD-MS(Field Desorption-Mass Spectrometry) values of the following compounds.

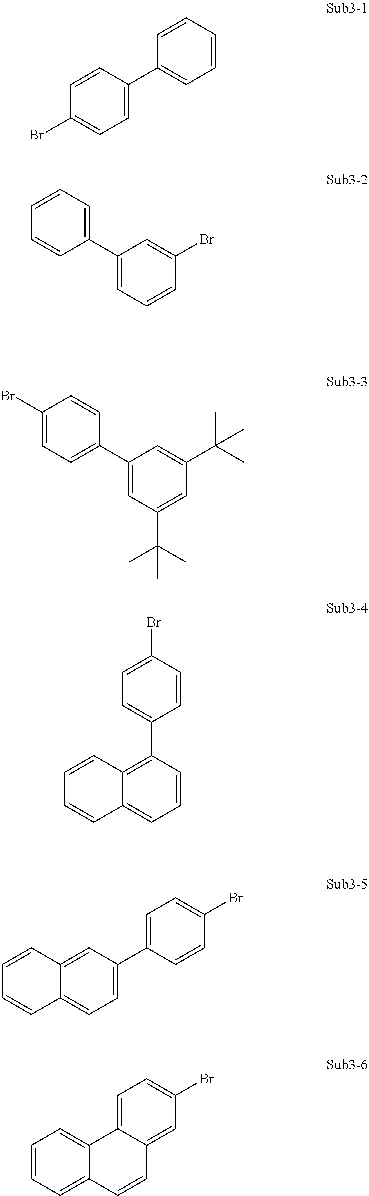

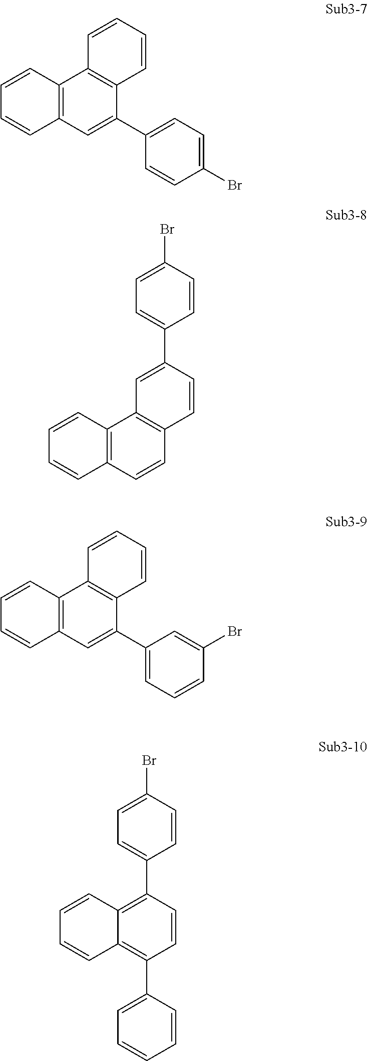

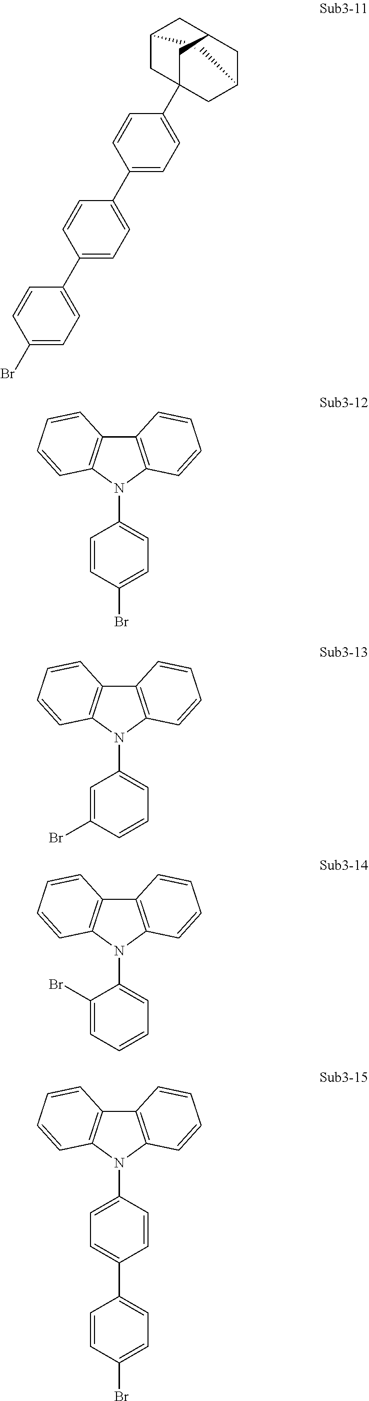

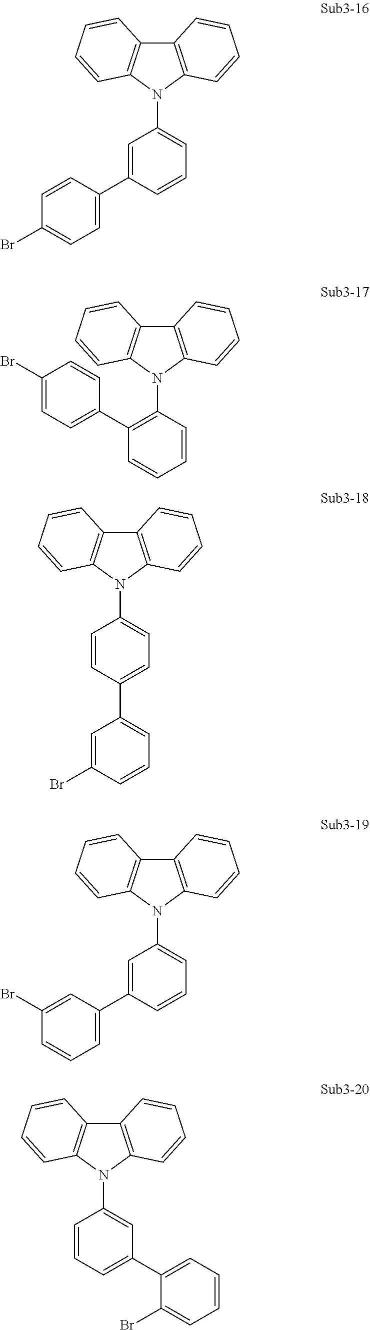

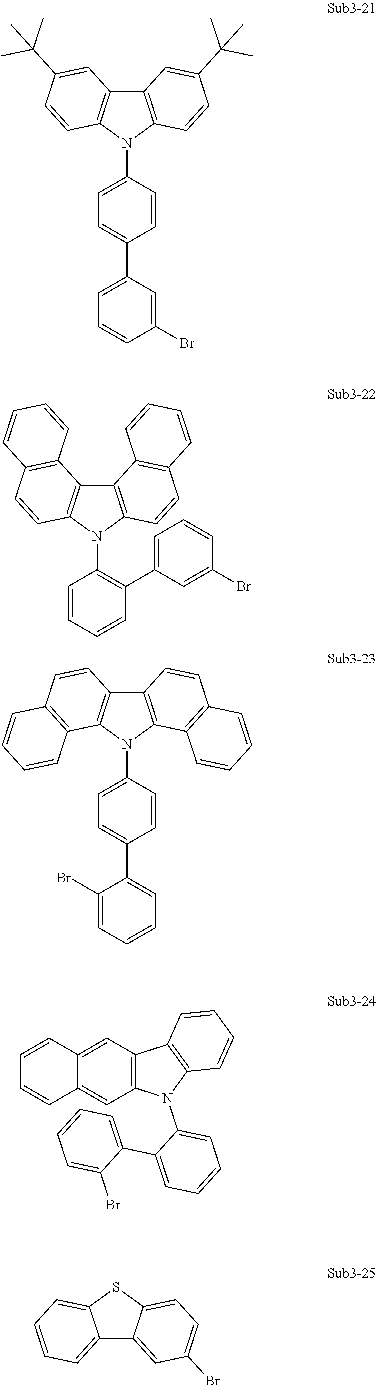

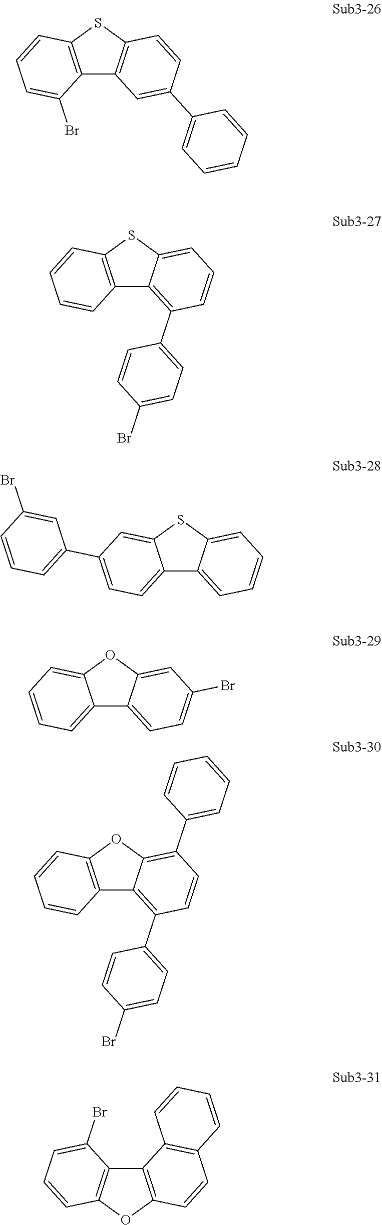

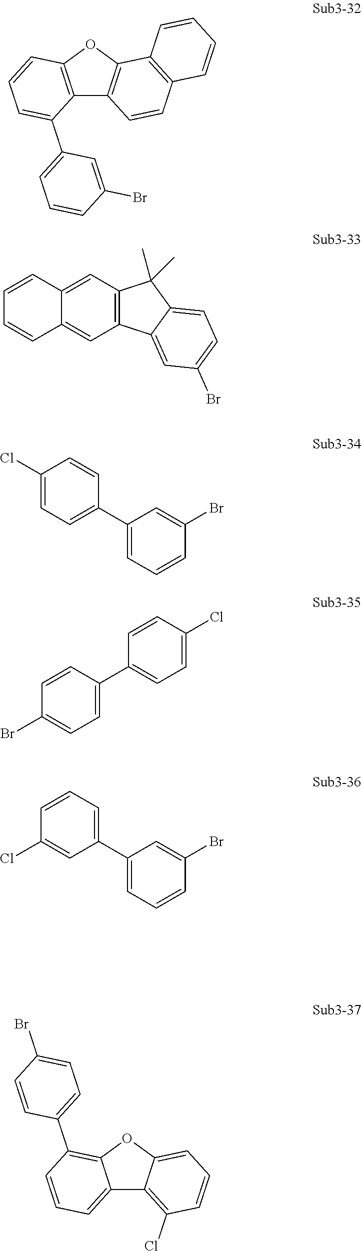

TABLE 4

| Compound | FD-MS | Compound | FD-MS |
|---|---|---|---|
| Sub3-1 | m/z = 231.99(C₁₂H₉Br = 233.11) | Sub3-2 | m/z = 231.99(C₁₂H₉Br = 233.11) |
| Sub3-3 | m/z = 344.11(C₂₀H₂₅Br = 345.32) | Sub3-4 | m/z = 282(C₁₆H₁₁Br = 283.17) |
| Sub3-5 | m/z = 282(C₁₆H₁₁Br = 283.17) | Sub3-6 | m/z = 255.99(C₁₄H₉Br = 257.13) |
| Sub3-7 | m/z = 332.02(C₂₀H₁₃Br = 333.23) | Sub3-8 | m/z = 332.02(C₂₀H₁₃Br = 333.23) |
| Sub3-9 | m/z = 332.02(C₂₀H₁₃Br = 333.23) | Sub3-10 | m/z = 358.04(C₂₂H₁₅Br = 359.27) |
| Sub3-11 | m/z = 442.13(C₂₈H₂₇Br = 443.43) | Sub3-12 | m/z = 321.02(C₁₈H₁₂BrN = 322.21) |
| Sub3-13 | m/z = 321.02(C₁₈H₁₂BrN = 322.21) | Sub3-14 | m/z = 321.02(C₁₈H₁₂BrN = 322.21) |
| Sub3-15 | m/z = 397.05(C₂₄H₁₆BrN = 398.3) | Sub3-16 | m/z = 397.05(C₂₄H₁₆BrN = 398.3) |
| Sub3-17 | m/z = 397.05(C₂₄H₁₆BrN = 398.3) | Sub3-18 | m/z = 397.05(C₂₄H₁₆BrN = 398.3) |
| Sub3-19 | m/z = 397.05(C₂₄H₁₆BrN = 398.3) | Sub3-20 | m/z = 397.05(C₂₄H₁₆BrN = 398.3) |
| Sub3-21 | m/z = 509.17(C₃₂H₃₂BrN = 510.52) | Sub3-22 | m/z = 497.08(C₃₂H₂₀BrN = 498.42) |
| Sub3-23 | m/z = 497.08(C₃₂H₂₀BrN = 498.42) | Sub3-24 | m/z = 447.06(C₂₈H₁₈BrN = 448.36) |
| Sub3-25 | m/z = 261.95(C₁₂H₇BrS = 263.15) | Sub3-26 | m/z = 337.98(C₁₈H₁₁BrS = 339.25) |
| Sub3-27 | m/z = 337.98(C₁₈H₁₁BrS = 339.25) | Sub3-28 | m/z = 337.98(C₁₈H₁₁BrS = 339.25) |
| Sub3-29 | m/z = 245.97(C₁₂H₇BrO = 247.09) | Sub3-30 | m/z = 398.03(C₂₄H₁₅BrO = 399.29) |
| Sub3-31 | m/z = 295.98(C₁₆H₉BrO = 297.15) | Sub3-32 | m/z = 372.01(C₂₂H₁₃BrO = 373.25) |
| Sub3-33 | m/z = 322.04(C₁₉H₁₅Br = 323.23) | Sub3-34 | m/z = 265.95(C₁₂H₈BrCl = 267.55) |
| Sub3-35 | m/z = 265.95(C₁₂H₈BrCl = 267.55) | Sub3-36 | m/z = 265.95(C₁₂H₈BrCl = 267.55) |
| Sub3-37 | m/z = 355.95(C₁₈H₁₀BrClO = 357.63) | | |

### Synthesis example of Final compound

### 1. Synthesis example of P2-1

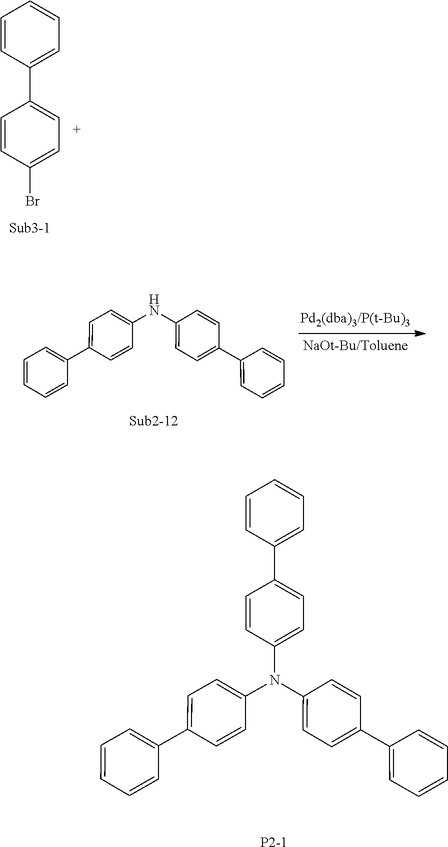 [SMILES: Brc1ccc(-c2ccccc2)cc1 ; c1ccc(-c2ccc(Nc3ccc(-c4ccccc4)cc3)cc2)cc1 ; c1ccc(-c2ccc(N(c3ccc(-c4ccccc4)cc3)c3ccc(-c4ccccc4)cc3)cc2)cc1 ; "P2-1"]

Sub3-1 (5.0 g, 21.6 mmol), Sub2-12 (5.0 g, 21.6 mmol), Pd2(dba)3 (0.59 g, 0.65 mmol), P(t-Bu)3 (0.26 g, 1.29 mmol), NaOt-Bu (4.1 g, 43.1 mmol) and toluene (108 mL) were put into a round bottom flask, and the reaction was carried out at 80° C. When the reaction was completed, the reaction product was extracted with CH2Cl2 and water, and then an organic layer was dried with MgSO4 and concentrated. Then, the concentrate was separated through a silica gel column and recrystallized to obtain 8.1 g (yield: 79%) of the product.

### 2. Synthesis example of P2-6

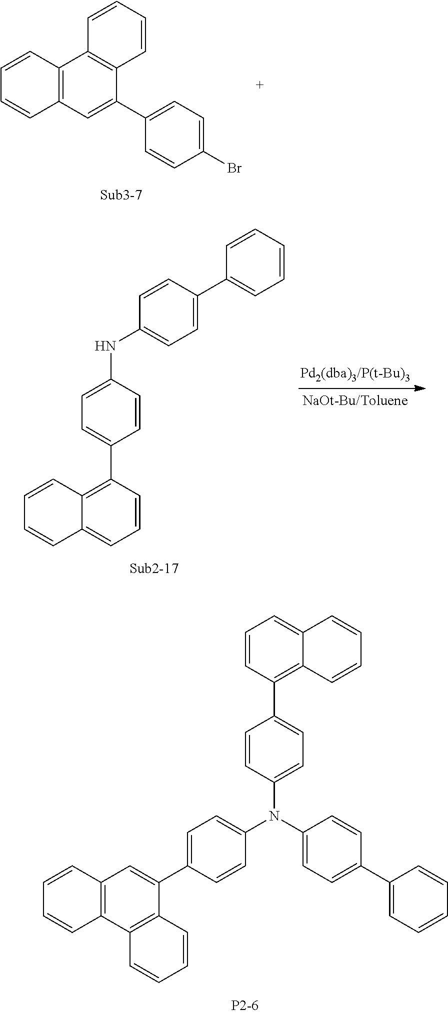 [SMILES: Brc1ccc(-c2cc3ccccc3c3ccccc23)cc1 ; c1ccc(-c2ccc(Nc3ccc(-c4cccc5ccccc45)cc3)cc2)cc1 ; c1ccc(-c2ccc(N(c3ccc(-c4cccc5ccccc45)cc3)c3ccc(-c4cc5ccccc5c5ccccc45)cc3)cc2)cc1]

Sub3-7 (5.0 g, 15.0 mmol), Sub2-17 (5.6 g, 15.0 mmol), Pd2(dba)3 (0.41 g, 0.45 mmol), P(t-Bu)3 (0.18 g, 0.90 mmol), NaOt-Bu (2.9 g, 30.0 mmol) and toluene (75 mL) were putted into a round bottom flask, and then the synthesis was carried out in the same manner as in the synthesis method of P2-1 to obtain 7.2 g (yield: 77%) of the product.

### 3. Synthesis example of P2-17

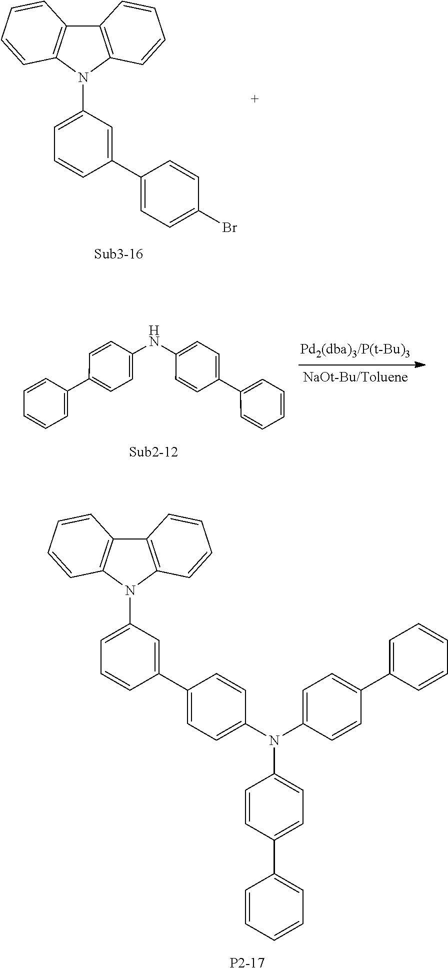 [SMILES: Brc1ccc(-c2cccc(-n3c4ccccc4c4ccccc43)c2)cc1 ; c1ccc(-c2ccc(Nc3ccc(-c4ccccc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

Sub3-16 (5.0 g, 12.6 mmol), Sub2-12 (4.0 g, 12.6 mmol), Pd2(dba)3 (0.34 g, 0.38 mmol), P(t-Bu)3 (0.15 g, 0.75 mmol), NaOt-Bu (2.4 g, 25.1 mmol) and toluene (63 mL) were putted into a round bottom flask, and then the synthesis was carried out in the same manner as in the synthesis method of P2-1 to obtain 6.3 g (yield: 78%) of the product.

### 4. Synthesis example of P2-29

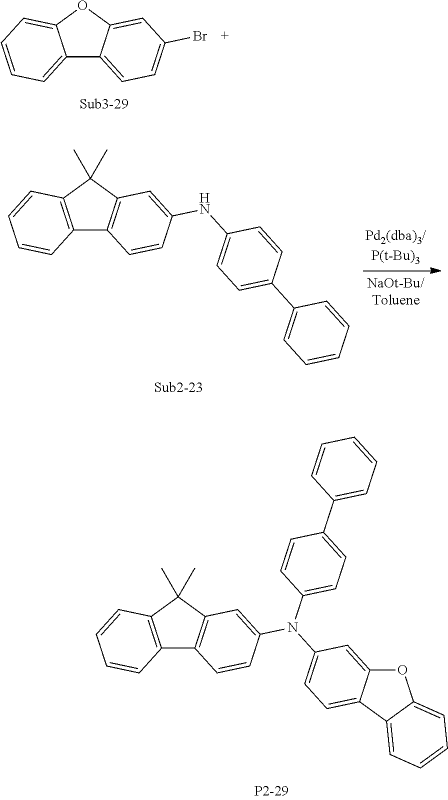 [SMILES: Brc1ccc2c(c1)oc1ccccc12 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3ccc4c(c3)oc3ccccc34)cc21]

Sub3-29 (5.0 g, 20.2 mmol), Sub2-23 (7.3 g, 20.2 mmol), Pd2(dba)3 (0.56 g, 0.61 mmol), P(t-Bu)3 (0.25 g, 1.21 mmol), NaOt-Bu (3.9 g, 40.5 mmol) and toluene (100 mL) were putted into a round bottom flask, and then the synthesis was carried out in the same manner as in the synthesis method of P2-1 to obtain 7.7 g (yield: 72%) of the product.

### 5. Synthesis example of P2-40

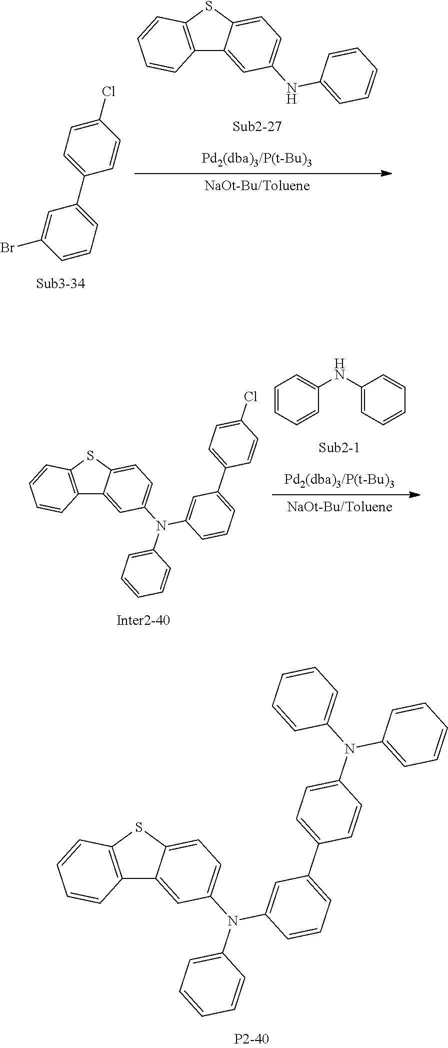

### (1) Synthesis of Inter2-40

Sub3-34 (5.0 g, 13.6 mmol), Sub2-27 (3.7 g, 13.6 mmol), Pd2(dba)3 (0.37 g, 0.41 mmol), P(t-Bu)3 (0.17 g, 0.82 mmol), NaOt-Bu (2.6 g, 27.2 mmol) and toluene (68 mL) were put into a round bottom flask, and the reaction was carried out at 60° C. When the reaction was completed, the reaction product was extracted with CH2Cl2 and water, and then an organic layer was dried with MgSO4 and concentrated. Then, the concentrate was separated through a silica gel column and recrystallized to obtain 4.9 g (yield: 78%) of the product.

### (2) Synthesis of P2-40

Inter2-40 (4.9 g, 10.6 mmol), Sub2-1 (1.8 g, 10.6 mmol), Pd2(dba)3 (0.29 g, 0.32 mmol), P(t-Bu)3 (0.13 g, 0.64 mmol), NaOt-Bu (2.0 g, 21.2 mmol) and toluene (53 mL) were put into a round bottom flask, and the reaction was carried out at 80° C. When the reaction was completed, the reaction product was extracted with CH2C12 and water, and then an organic layer was dried with MgSO4 and concentrated. Then, the concentrate was separated through a silica gel column and recrystallized to obtain 4.8 g (yield: 76%) of the product.

### 6. Synthesis example of P2-43

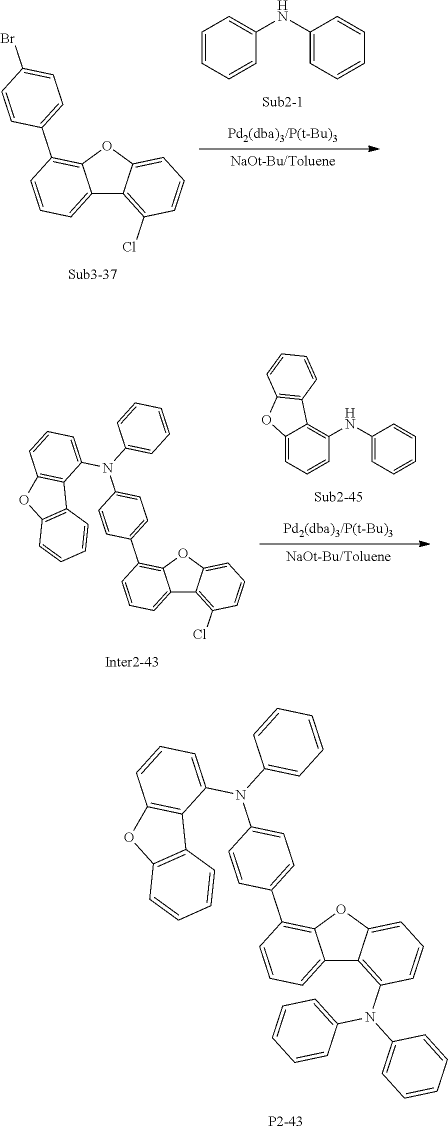 [SMILES: Clc1cccc2oc3c(-c4ccc(Br)cc4)cccc3c12 ; c1ccc(Nc2ccccc2)cc1 ; Clc1cccc2oc3c(-c4ccc(N(c5ccccc5)c5cccc6oc7ccccc7c56)cc4)cccc3c12 ; c1ccc(Nc2cccc3oc4ccccc4c23)cc1 ; c1ccc(N(c2ccc(-c3cccc4c3oc3cccc(N(c5ccccc5)c5ccccc5)c34)cc2)c2cccc3oc4ccccc4c23)cc1]

### (1) Synthesis of Inter2-43

Sub3-37 (5.0 g, 14.0 mmol), Sub2-1 (2.4 g, 14.0 mmol), Pd2(dba)3 (0.38 g, 0.42 mmol), P(t-Bu)3 (0.17 g, 0.84 mmol), NaOt-Bu (2.7 g, 28.0 mmol) and toluene (70 mL) were putted into a round bottom flask, and then the synthesis was carried out in the same manner as in the synthesis method of Inter2-40 to obtain 5.9 g (yield: 79%) of the product.

### (2) Synthesis of P2-43

Inter2-43 (5.9 g, 11.0 mmol), Sub2-45 (2.9 g, 11.0 mmol), Pd2(dba)3 (0.13 g, 0.66 mmol), P(t-Bu)3 (0.13 g, 0.66 mmol), NaOt-Bu (2.1 g, 22.1 mmol) and toluene (55 mL) were putted into a round bottom flask, and then the synthesis was carried out in the same manner as in the synthesis method of P2-40 to obtain 5.2 g (yield: 71%) of the product.

### 7. Synthesis example of P2-44

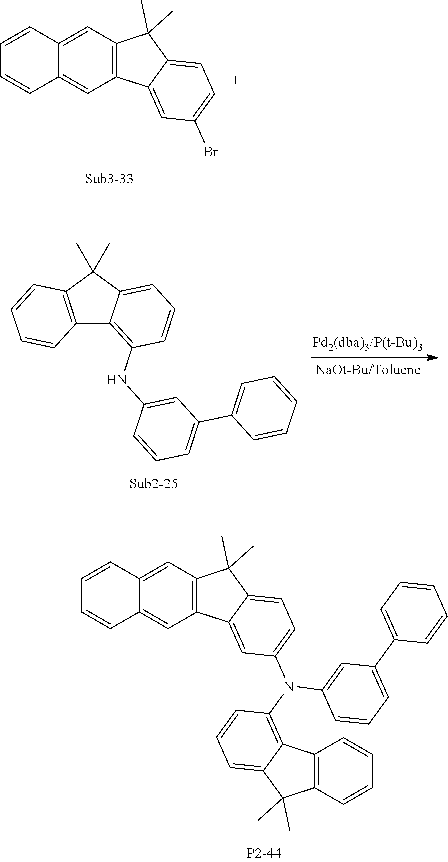 [SMILES: CC1(C)c2ccc(Br)cc2-c2cc3ccccc3cc21 ; CC1(C)c2ccccc2-c2c(Nc3cccc(-c4ccccc4)c3)cccc21 ; CC1(C)c2ccc(N(c3cccc(-c4ccccc4)c3)c3cccc4c3-c3ccccc3C4(C)C)cc2-c2cc3ccccc3cc21]

Sub3-33 (5.0 g, 15.5 mmol), Sub2-25 (5.6 g, 15.5 mmol), Pd2(dba)3 (0.42 g, 0.46 mmol), P(t-Bu)3 (0.19 g, 0.93 mmol), NaOt-Bu (3.0 g, 30.9 mmol) and toluene (77 mL) were putted into a round bottom flask, and then the synthesis was carried out in the same manner as in the synthesis method of P2-1 to obtain 6.7 g (yield: 72%) of the product.

FD-MS values of the compounds P2-1 to P2-49 of the present invention synthesized by the above synthesis method are shown in Table 5 below.

TABLE 5

| Compound | FD-MS | Compound | FD-MS |
|---|---|---|---|
| P2-1 | m/z = 473.21(C₃₆H₂₇N = 473.62) | P2-2 | m/z = 473.21(C₃₆H₂₇N = 473.62) |
| P2-3 | m/z = 573.25(C₄₄H₃₁N = 573.74) | P2-4 | m/z = 573.25(C₄₄H₃₁N = 573.74) |
| P2-5 | m/z = 497.21(C₃₈H₂₇N = 497.64) | P2-6 | m/z = 623.26(C₄₈H₃₃N = 623.8) |
| P2-7 | m/z = 573.25(C₄₄H₃₁N = 573.74) | P2-8 | m/z = 623.26(C₄₈H₃₃N = 623.8) |
| P2-9 | m/z = 491.33(C₃₆H₉D₁₈N = 491.73) | P2-10 | m/z = 649.28(C₅₀H₃₅N = 649.84) |
| P2-11 | m/z = 683.36(C₅₂H₄₅N = 683.94) | P2-12 | m/z = 585.34(C₄₄H₄₃N = 585.84) |
| P2-13 | m/z = 562.24(C₄₂H₃₀N₂ = 562.72) | P2-14 | m/z = 602.27(C₄₅H₃₄N₂ = 602.78) |
| P2-15 | m/z = 562.24(C₄₂H₃₀N₂ = 562.72) | P2-16 | m/z = 638.27(C₄₈H₃₄N₂ = 638.81) |
| P2-17 | m/z = 638.27(C₄₈H₃₄N₂ = 638.81) | P2-18 | m/z = 678.3(C₅₁H₃₈N₂ = 678.88) |
| P2-19 | m/z = 652.25(C₄₈H₃₂N₂O = 652.8) | P2-20 | m/z = 790.33(C₆₀H₄₂N₂ = 791.01) |
| P2-21 | m/z = 788.32(C₆₀H₄₀N₂ = 788.99) | P2-22 | m/z = 712.29(C₅₄H₃₆N₂ = 712.9) |
| P2-23 | m/z = 738.3(C₅₆H₃₈N₂ = 738.93) | P2-24 | m/z = 688.29(C₅₂H₃₆N₂ = 688.87) |
| P2-25 | m/z = 594.23(C₄₂H₃₀N₂O₂ = 594.71) | P2-26 | m/z = 668.23(C₄₈H₃₂N₂S = 668.86) |
| P2-27 | m/z = 750.4(C₅₆H₅₀N₂ = 751.03) | P2-28 | m/z = 496.27(C₃₆H₁₆D₁₀N₂ = 496.68) |
| P2-29 | m/z = 527.22(C₃₉H₂₉NO = 527.67) | P2-30 | m/z = 689.27(C₅₂H₃₅NO = 689.86) |
| P2-31 | m/z = 619.23(C₄₅H₃₃NS = 619.83) | P2-32 | m/z = 669.21(C₄₈H₃₁NOS = 669.84) |
| P2-33 | m/z = 643.2(C₄₆H₂₉NOS = 643.8) | P2-34 | m/z = 627.22(C₄₆H₂₉NO₂ = 627.74) |
| P2-35 | m/z = 583.14(C₄₀H₂₅NS₂ = 583.77) | P2-36 | m/z = 665.22(C₄₉H₃₁NS = 665.85) |
| P2-37 | m/z = 792.35(C₆₀H₄₄N₂ = 793.03) | P2-38 | m/z = 594.21(C₄₂H₃₀N₂S = 594.78) |
| P2-39 | m/z = 654.27(C₄₈H₃₄N₂O = 654.81) | P2-40 | m/z = 594.21(C₄₂H₃₀N₂S = 594.78) |
| P2-41 | m/z = 578.24(C₄₂H₃₀N₂O = 578.72) | P2-42 | m/z = 710.28(C₅₁H₃₈N₂S = 710.94) |
| P2-43 | m/z = 668.25(C₄₈H₃₂N₂O₂ = 668.8) | P2-44 | m/z = 603.29(C₄₆H₃₇N = 603.81) |
| P2-45 | m/z = 603.26(C₄₅H₃₃NO = 603.77) | P2-46 | m/z = 757.24(C₅₅H₃₅NOS = 757.95) |
| P2-47 | m/z = 607.16(C₄₂H₂₅NO₂S = 607.73) | P2-48 | m/z = 833.28(C₆₁H₃₉NOS = 834.05) |
| P2-49 | m/z = 833.28(C₆₁H₃₉NOS = 834.05) | | |

Fabrication and Evaluation of Organic Electric Element

[Test Example 1] Red organic electroluminescent element (emission-auxiliary layer)

After vacuum-depositing 4,4′,4″-tris[2-naphthyl(phenyl)amino]triphenylamine (hereinafter abbreviated as “2-TNATA”) on an ITO layer (anode) formed on a glass substrate to form a hole injection layer of 70 nm thickness, a hole transport layer of 70 nm thickness was formed by vacuum-depositing N,N′-bis(1-naphthalenyl)-N,N′-bis-phenyl-(1,1′-biphenyl)-4,4′-diamine (hereinafter abbreviated as “NPB”) on the hole injection layer.

Compound P1-1 of the present invention was vacuum deposited to a thickness of 70 nm on the hole transport layer to form a first light-emitting auxiliary layer, and then compound P2-3 of the present invention was vacuum deposited to a thickness of 5 nm on the first light-emitting auxiliary layer to form a second light-emitting auxiliary layer.

Next, 4,4′-N,N′-dicarbazole-biphenyl (hereinafter abbreviated as “CBP”) as a host material and bis-(1-phenyl isoquinolyl)iridium(III)acetylacetonate (hereinafter abbreviated as “(piq)21r(acac)”) as a dopant material in a weight ratio of 95:5 were deposited on the second light-emitting auxiliary layer to form a light-emitting layer of 40 nm thickness.

Next, (1,1′-bisphenyl-4-olato)bis(2-methyl-8-quinolinolato)aluminum (hereinafter abbreviated as “BAlq”) was vacuum-deposited to form a hole blocking layer of 5 nm thickness on the light-emitting layer, and bis(10-hydroxybenzo[h]quinolinato)beryllium (hereinafter abbreviated as “BeBq2”) was vacuum-deposited to form a an electron transport layer of 30 nm thickness on the hole blocking layer.

Thereafter, LiF was deposited to form an electron injection layer of 0.2 nm thickness on the electron transport layer, and then Al was deposited to form a cathode of 150 nm thickness on the electron injection layer.

### [Test Example 2] to [Test Example 60]

The organic electroluminescent elements were fabricated in the same manner as described in Example 1 except that the compounds of the present invention described in the following Table 6 were used as materials of a first light-emitting auxiliary layer and a second light-emitting auxiliary layer.

### [Comparative Example 1] to [Comparative Example 17]

The organic electroluminescent elements were fabricated in the same manner as described in Example 1 except that a single light-emitting auxiliary layer was formed using a single material listed in Table 6 below.

### Comparative Example 18

The organic electroluminescent elements were fabricated in the same manner as described in Example 1 except that the following comparative compound A was used as material of a first light-emitting auxiliary layer, and the compound P1-1 of the present invention was used as material of a second light-emitting auxiliary layer as shown in Table 6 below.

### Comp. CompdA

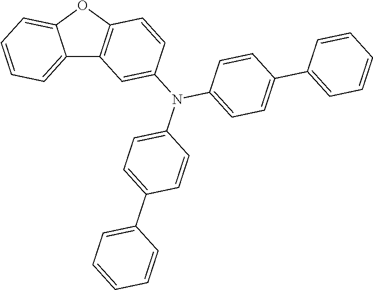 [SMILES: c1ccc(-c2ccc(N(c3ccc(-c4ccccc4)cc3)c3ccc4oc5ccccc5c4c3)cc2)cc1]

A forward bias DC voltage was applied to the electroluminescent elements manufactured in Test Examples 1 to 60 and Comparative Examples 1 to 18, and electroluminescence (EL) characteristics were measured with Photo Research's PR-650 and lifetime(T95) was measured with a lifetime measuring device manufactured by Mc Science company at 2500 cd/m2 standard luminance. The measurement results are shown in Table 6 below.

TABLE 6

| | | | | Current | | | |
|---|---|---|---|---|---|---|---|
| | | | Voltage | Density | Brightness | Efficiency | Lifetime |
| | EAL 1 | EAL 2 | (V) | (mA/cm²) | (cd/m²) | (cd/A) | T(95) |
| comp. Ex(1) | Com.(P1-1) | | 5.3 | 14.0 | 2500.0 | 17.8 | 91.3 |
| comp. Ex(2) | Com.(P1-8) | | 5.4 | 13.0 | 2500.0 | 19.2 | 102.2 |
| comp. Ex(3) | Com.(P1-18) | | 5.5 | 14.1 | 2500.0 | 17.7 | 90.8 |
| comp. Ex(4) | Com.(P1-40) | | 5.5 | 12.6 | 2500.0 | 19.8 | 94.6 |
| comp. Ex(5) | Com.(P1-46) | | 5.3 | 12.8 | 2500.0 | 19.6 | 90.3 |
| comp. Ex(6) | Com.(P1-57) | | 5.4 | 14.5 | 2500.0 | 17.2 | 88.4 |
| comp. Ex(7) | Com.(P1-69) | | 5.4 | 14.4 | 2500.0 | 17.4 | 89.7 |
| comp. Ex(8) | Com.(P1-73) | | 5.4 | 14.7 | 2500.0 | 17.0 | 90.5 |
| comp. Ex(9) | Com.(P1-86) | | 5.4 | 14.9 | 2500.0 | 16.8 | 87.3 |
| comp. Ex(10) | Com.(P1-92) | | 5.3 | 15.1 | 2500.0 | 16.6 | 83.4 |
| comp. Ex(11) | Com.(P1-93) | | 5.5 | 15.4 | 2500.0 | 16.2 | 81.6 |
| comp. Ex(12) | Com.(P1-104) | | 5.5 | 15.7 | 2500.0 | 15.9 | 78.2 |
| comp. Ex(13) | Com.(P2-3) | | 5.6 | 13.4 | 2500.0 | 18.6 | 93.2 |
| comp. Ex(14) | Com.(P2-17) | | 5.5 | 12.7 | 2500.0 | 19.7 | 103.3 |
| comp. Ex(15) | Com.(P2-29) | | 5.5 | 14.2 | 2500.0 | 17.6 | 86.3 |
| comp. Ex(16) | Com.(P2-43) | | 5.4 | 12.4 | 2500.0 | 20.2 | 101.4 |
| comp. Ex(17) | Com.(P2-44) | | 5.6 | 14.9 | 2500.0 | 16.8 | 83.2 |
| comp. Ex(18) | Comp. compd A | Com.(P1-1) | 5.3 | 12.2 | 2500.0 | 20.5 | 104.5 |
| Test Ex.(1) | Com.(P1-1) | Com.(P2-3) | 4.8 | 9.2 | 2500.0 | 27.2 | 122.0 |
| Test Ex.(2) | | Com.(P2-17) | 4.8 | 8.7 | 2500.0 | 28.8 | 134.1 |
| Test Ex.(3) | | Com.(P2-29) | 4.9 | 10.2 | 2500.0 | 24.6 | 118.5 |
| Test Ex.(4) | | Com.(P2-43) | 4.8 | 8.5 | 2500.0 | 29.4 | 128.9 |
| Test Ex.(5) | | Com.(P2-44) | 4.8 | 9.7 | 2500.0 | 25.9 | 116.2 |
| Test Ex.(6) | Com.(P1-8) | Com.(P2-3) | 4.9 | 8.9 | 2500.0 | 28.1 | 125.2 |
| Test Ex.(7) | | Com.(P2-17) | 4.9 | 8.3 | 2500.0 | 30.0 | 136.4 |
| Test Ex.(8) | | Com.(P2-29) | 4.9 | 9.8 | 2500.0 | 25.6 | 121.2 |
| Test Ex.(9) | | Com.(P2-43) | 4.9 | 8.2 | 2500.0 | 30.6 | 131.3 |
| Test Ex.(10) | | Com.(P2-44) | 4.9 | 9.3 | 2500.0 | 26.9 | 119.3 |
| Test Ex.(11) | Com.(P1-18) | Com.(P2-3) | 4.9 | 9.3 | 2500.0 | 26.9 | 121.9 |
| Test Ex.(12) | | Com.(P2-17) | 4.9 | 8.7 | 2500.0 | 28.6 | 133.6 |
| Test Ex.(13) | Com.(P1-18) | Com.(P2-29) | 5.0 | 10.2 | 2500.0 | 24.5 | 118.6 |
| Test Ex.(14) | | Com.(P2-43) | 4.9 | 8.5 | 2500.0 | 29.3 | 127.9 |
| Test Ex.(15) | | Com.(P2-44) | 4.9 | 9.7 | 2500.0 | 25.7 | 116.3 |
| Test Ex.(16) | Com.(P1-40) | Com.(P2-3) | 4.9 | 8.9 | 2500.0 | 28.2 | 123.4 |
| Test Ex.(17) | | Com.(P2-17) | 4.9 | 8.3 | 2500.0 | 30.2 | 136.0 |
| Test Ex.(18) | | Com.(P2-29) | 4.9 | 9.7 | 2500.0 | 25.7 | 120.3 |
| Test Ex.(19) | | Com.(P2-43) | 4.9 | 8.1 | 2500.0 | 31.0 | 129.9 |
| Test Ex.(20) | | Com.(P2-44) | 4.9 | 9.3 | 2500.0 | 27.0 | 118.2 |
| Test Ex.(21) | Com.(P1-46) | Com.(P2-3) | 5.0 | 9.1 | 2500.0 | 27.5 | 122.7 |
| Test Ex.(22) | | Com.(P2-17) | 5.0 | 8.5 | 2500.0 | 29.4 | 134.7 |
| Test Ex.(23) | | Com.(P2-29) | 5.0 | 10.0 | 2500.0 | 25.1 | 119.7 |
| Test Ex.(24) | | Com.(P2-43) | 5.0 | 8.2 | 2500.0 | 30.3 | 128.7 |
| Test Ex.(25) | | Com.(P2-44) | 5.0 | 9.5 | 2500.0 | 26.3 | 117.2 |
| Test Ex.(26) | Com.(P1-57) | Com.(P2-3) | 4.9 | 9.7 | 2500.0 | 25.8 | 120.5 |
| Test Ex.(27) | | Com.(P2-17) | 4.9 | 9.0 | 2500.0 | 27.7 | 133.0 |
| Test Ex.(28) | | Com.(P2-29) | 5.0 | 10.6 | 2500.0 | 23.5 | 117.7 |
| Test Ex.(29) | | Com.(P2-43) | 4.9 | 8.9 | 2500.0 | 28.2 | 126.6 |
| Test Ex.(30) | | Com.(P2-44) | 4.9 | 10.1 | 2500.0 | 24.7 | 114.7 |
| Test Ex.(31) | Com.(P1-69) | Com.(P2-3) | 4.9 | 9.5 | 2500.0 | 26.3 | 121.2 |
| Test Ex.(32) | | Com.(P2-17) | 4.9 | 8.9 | 2500.0 | 28.1 | 133.0 |
| Test Ex.(33) | | Com.(P2-29) | 5.0 | 10.5 | 2500.0 | 23.9 | 118.6 |
| Test Ex.(34) | | Com.(P2-43) | 4.9 | 8.7 | 2500.0 | 28.7 | 127.4 |
| Test Ex.(35) | | Com.(P2-44) | 4.9 | 9.9 | 2500.0 | 25.2 | 116.0 |
| Test Ex.(36) | Com.(P1-73) | Com.(P2-3) | 4.9 | 9.5 | 2500.0 | 26.3 | 121.4 |
| Test Ex.(37) | | Com.(P2-17) | 4.9 | 9.0 | 2500.0 | 27.7 | 133.3 |
| Test Ex.(38) | | Com.(P2-29) | 5.0 | 10.5 | 2500.0 | 23.8 | 118.8 |
| Test Ex.(39) | | Com.(P2-43) | 4.9 | 8.8 | 2500.0 | 28.4 | 127.6 |
| Test Ex.(40) | | Com.(P2-44) | 4.9 | 10.0 | 2500.0 | 25.1 | 116.5 |
| Test Ex.(41) | Com.(P1-86) | Com.(P2-3) | 5.0 | 9.7 | 2500.0 | 25.7 | 120.1 |
| Test Ex.(42) | | Com.(P2-17) | 5.0 | 9.2 | 2500.0 | 27.3 | 131.2 |
| Test Ex.(43) | Com.(P1-86) | Com.(P2-29) | 5.0 | 10.8 | 2500.0 | 23.2 | 117.4 |
| Test Ex.(44) | | Com.(P2-43) | 5.0 | 8.9 | 2500.0 | 28.2 | 126.3 |
| Test Ex.(45) | | Com.(P2-44) | 5.0 | 10.2 | 2500.0 | 24.5 | 114.5 |
| Test Ex.(46) | Com.(P1-92) | Com.(P2-3) | 4.8 | 9.9 | 2500.0 | 25.3 | 120.1 |
| Test Ex.(47) | | Com.(P2-17) | 4.8 | 9.2 | 2500.0 | 27.2 | 130.6 |
| Test Ex.(48) | | Com.(P2-29) | 4.9 | 10.9 | 2500.0 | 23.0 | 115.9 |
| Test Ex.(49) | | Com.(P2-43) | 4.8 | 9.0 | 2500.0 | 27.8 | 125.2 |
| Test Ex.(50) | | Com.(P2-44) | 4.8 | 10.3 | 2500.0 | 24.2 | 114.1 |
| Test Ex.(51) | Com.(P1-93) | Com.(P2-3) | 5.1 | 10.1 | 2500.0 | 24.8 | 119.1 |
| Test Ex.(52) | | Com.(P2-17) | 5.1 | 9.5 | 2500.0 | 26.4 | 130.0 |
| Test Ex.(53) | | Com.(P2-29) | 5.1 | 11.0 | 2500.0 | 22.7 | 115.6 |
| Test Ex.(54) | | Com.(P2-43) | 5.1 | 9.2 | 2500.0 | 27.2 | 124.4 |
| Test Ex.(55) | | Com.(P2-44) | 5.1 | 10.5 | 2500.0 | 23.8 | 113.2 |
| Test Ex.(56) | Com.(P1-104) | Com.(P2-3) | 5.1 | 10.1 | 2500.0 | 24.7 | 118.1 |
| Test Ex.(57) | | Com.(P2-17) | 5.1 | 9.6 | 2500.0 | 26.1 | 129.0 |
| Test Ex.(58) | | Com.(P2-29) | 5.2 | 11.2 | 2500.0 | 22.3 | 115.6 |
| Test Ex.(59) | | Com.(P2-43) | 5.1 | 9.3 | 2500.0 | 27.0 | 124.5 |
| Test Ex.(60) | | Com.(P2-44) | 5.1 | 10.6 | 2500.0 | 23.6 | 112.0 |

From Table 6, it can be seen that in case of Comparative example 18 and Test examples of the present invention in which a plurality of light-emitting auxiliary layers were formed, rather than Comparative Example 1 to Comparative Example 17 in which the light-emitting auxiliary layer was formed as a single layer using a single material, the organic electric element characteristics are improved. In particular, according to embodiments of the present invention, the driving voltage of the organic electric element can be significantly lowered, and the luminous efficiency and lifespan can be significantly improved.

A light-emitting auxiliary layer must well receive holes from the hole transport layer, must well transmit holes to the host, and must well block electrons from passing from the host. However, it is not easy to select a material that satisfies all of these required properties when forming a single light-emitting auxiliary layer with one material since the properties (hole mobility, energy level, etc.) of the compounds forming each layer are different.

When forming a plurality of light-emitting auxiliary layers with the compound of the present invention, it is easy to improve the overall element performance since the above required characteristics can be more easily satisfied.

In Comparative Example 18, two light-emitting auxiliary layers were formed using different materials, but the characteristics of element were significantly superior according to the example of the present invention.

There is a difference in that Comparative compound A has a structure in which dibenzothiophene is substituted with a diarylamine group, whereas the compound of the present invention has a structure in which two amine groups are bonded to dibenzothiophene or dibenzofuran, and one of the amine groups is further substituted with dibenzothiophene or dibenzofuran. It appears that when a compound with an additional amine group as in the present invention is used as material for a first light-emitting auxiliary layer, the stability for holes and packing density are increased, thereby improving the driving voltage, and the refractive index and thermal stability are increased since dibenzothiophene or dibenzofuran is further substituted, thereby improving performance of the element. Therefore, it appears that the driving voltage of the element varies depending on the material forming a first light-emitting auxiliary layer, and the efficiency and lifespan of the element vary depending on the material forming a second light-emitting auxiliary layer.

In order to confirm these characteristics, the hole mobility according to HOD (Hole Only Device) was measured for the compounds in Table 7. Table 7 shows the hole mobility of HOD (Hole Only Device) in an organic electric element that manufactured by depositing in the following order: ITO layer (anode)/HAT-CN 5 nm/comparative compound A or compound of the present invention 300 nm/HAT-CN 1 nm/Al (cathode) 100 nm.

TABLE 7

| | hole mobility |
|---|---|
| Compound | (cm/V · S) |
| Comp. compd A | 4.2 × 10⁻⁵ |
| P1-1 | 1.2 × 10⁻³ |
| P1-8 | 9.4 × 10⁻⁴ |
| P1-18 | 7.8 × 10⁻⁴ |
| P1-40 | 5.5 × 10⁻⁴ |
| P1-46 | 1.6 × 10⁻⁴ |
| P1-57 | 3.2 × 10⁻⁴ |
| P1-69 | 4.2 × 10⁻⁴ |
| P1-73 | 3.9 × 10⁻⁴ |
| P1-86 | 3.0 × 10⁻⁴ |
| P1-92 | 1.3 × 10⁻³ |
| P1-93 | 6.1 × 10⁻⁵ |
| P1-104 | 3.0 × 10⁻⁵ |

Looking at Table 7 above, it can be seen that the hole mobility of the compound of the present invention is faster than that of comparative compound A.

Referring to Table 6 above, it can be seen that the driving voltage is lower when the compound of the present invention is used as material for a first light-emitting auxiliary layer, comparing to when comparative compound A is used(Comparative Example 18). Therefore, it can be seen that the driving voltage can be lowered by forming a first light-emitting auxiliary layer with a material with high hole mobility.

However, the efficiency and lifespan of the element cannot be improved simply by using a material with high hole mobility, and the characteristics of the compound, such as the difference in energy level from the light-emitting layer, affect the overall performance of the device.

Therefore, the present invention manufactured an element introducing a second light-emitting auxiliary layer in order to compensate for this problem, and DFT method (B3LYP/6-31g(D)) of the Gaussian program was used to confirm the energy level characteristics of a second light-emitting auxiliary layer. HOMO, LUMO and T1 values are shown in Table 8 below.

TABLE 8

| Compound | P2-3 | P2-17 | P2-29 | P2-43 | P2-44 |
|---|---|---|---|---|---|
| G. HOMO | −5.001 | −5.018 | −4.832 | −5.004 | −4.978 |
| G. LUMO | −1.106 | −0.871 | −1.064 | −1.087 | −1.378 |
| G. T1 | 2.570 | 2.726 | 2.648 | 2.778 | 2.511 |

Referring to Table 6 and Table 8, it can be seen that the HOMO value of the material of a second light-emitting auxiliary layer affects the efficiency of an element, the LUMO value affects the lifespan of an element, and the T1 value affects the efficiency and lifespan.

It appears that when a compound with a low HOMO value is used as the material for a second light-emitting auxiliary layer, the hole injection from the second light-emitting auxiliary layer to the host can be smoothly performed, thereby improving the efficiency of an element, when a compound with a high LUMO value is used, it can effectively block electrons coming from the host, thereby improving the lifespan of an element, and when a compound with a high T1 value is used, it can effectively block triplet electrons coming from the dopant, thereby improving both efficiency and lifespan.

### [Test Example 61] to [Test Example 75] Green organic electroluminescent element (emission-auxiliary layer)

The organic electroluminescent elements were fabricated in the same manner as described in Example 1 except that the compounds in Table 9 below were used as the first and second light-emitting auxiliary layer materials, and the first light-emitting auxiliary layer was formed to a thickness of 30 nm, the second light-emitting auxiliary layer was formed to a thickness of 5 nm, and tris(2-phenylpyridine)-iridium (hereinafter referred to as Ir(ppy)3) was used as dopant.

### [Comparative Example 19] to [Comparative Example 26]

The organic electroluminescent elements were fabricated in the same manner as described in Example 61 except that a single light-emitting auxiliary layer was formed using a single material listed in Table 9 below.

### Comparative Example 27

The organic electroluminescent elements were fabricated in the same manner as described in Example 61 except that the following comparative compound A was used as material of a first light-emitting auxiliary layer, and the compound P1-1 of the present invention was used as material of a second light-emitting auxiliary layer as shown in Table 9 below.

A forward bias DC voltage was applied to the electroluminescent elements manufactured in Test Examples 61 to 75 and Comparative Examples 19 to 27, and electroluminescence (EL) characteristics were measured with Photo Research's PR-650 and lifetime(T95) was measured with a lifetime measuring device manufactured by Mc Science company at 5000 cd/m2 standard luminance. The measurement results are shown in Table 9 below.

TABLE 9

| | | | | Current | | | |
|---|---|---|---|---|---|---|---|
| | | | Voltage | Density | Brightness | Efficiency | Lifetime |
| | EAL 1 | EAL 2 | (V) | (mA/cm²) | (cd/m²) | (cd/A) | T(95) |
| comp. Ex(19) | Com.(P1-105) | | 5.4 | 22.3 | 5000.0 | 22.4 | 93.2 |
| comp. Ex(20) | Com.(P1-107) | | 5.4 | 21.0 | 5000.0 | 23.8 | 94.3 |
| comp. Ex(21) | Com.(P1-108) | | 5.3 | 22.5 | 5000.0 | 22.2 | 92.4 |
| comp. Ex(22) | Com.(P2-29) | | 5.5 | 23.7 | 5000.0 | 21.1 | 91.2 |
| comp. Ex(23) | Com.(P2-45) | | 5.5 | 21.4 | 5000.0 | 23.4 | 97.3 |
| comp. Ex(24) | Com.(P2-47) | | 5.5 | 20.3 | 5000.0 | 24.6 | 98.9 |
| comp. Ex(25) | Com.(P2-48) | | 5.4 | 19.4 | 5000.0 | 25.8 | 98.5 |
| comp. Ex(26) | Com.(P2-49) | | 5.4 | 19.7 | 5000.0 | 25.4 | 97.6 |
| comp. Ex(27) | Comp. compd A | Com.(P1-1) | 5.2 | 14.2 | 5000.0 | 35.2 | 115.6 |
| Test Ex.(61) | Com.(P1-105) | Com.(P2-29) | 5.1 | 10.7 | 5000.0 | 46.7 | 136.9 |
| Test Ex.(62) | | Com.(P2-45) | 5.1 | 9.6 | 5000.0 | 52.3 | 152.5 |
| Test Ex.(63) | | Com.(P2-47) | 5.1 | 9.2 | 5000.0 | 54.6 | 163.7 |
| Test Ex.(64) | | Com.(P2-48) | 5.1 | 9.0 | 5000.0 | 55.4 | 158.5 |
| Test Ex.(65) | | Com.(P2-49) | 5.1 | 9.4 | 5000.0 | 53.0 | 144.2 |
| Test Ex.(66) | Com.(P1-107) | Com.(P2-29) | 5.0 | 10.6 | 5000.0 | 47.1 | 141.0 |
| Test Ex.(67) | | Com.(P2-45) | 5.0 | 9.4 | 5000.0 | 53.4 | 158.0 |
| Test Ex.(68) | | Com.(P2-47) | 4.9 | 9.0 | 5000.0 | 55.8 | 169.7 |
| Test Ex.(69) | | Com.(P2-48) | 5.0 | 8.9 | 5000.0 | 56.4 | 164.0 |
| Test Ex.(70) | | Com.(P2-49) | 5.0 | 9.2 | 5000.0 | 54.3 | 148.7 |
| Test Ex.(71) | Com.(P1-108) | Com.(P2-29) | 4.8 | 11.0 | 5000.0 | 45.3 | 131.6 |
| Test Ex.(72) | | Com.(P2-45) | 4.8 | 9.7 | 5000.0 | 51.5 | 146.0 |
| Test Ex.(73) | | Com.(P2-47) | 4.7 | 9.3 | 5000.0 | 53.7 | 157.5 |
| Test Ex.(74) | | Com.(P2-48) | 4.8 | 9.2 | 5000.0 | 54.3 | 152.2 |
| Test Ex.(75) | | Com.(P2-49) | 4.8 | 9.5 | 5000.0 | 52.5 | 138.1 |

From Table 9, it can be seen that the characteristics of an element are improved when a plurality of light-emitting auxiliary layers are formed compared to the case where a light-emitting auxiliary layer is formed as a single layer using a single material (Comparative Example 19 to Comparative Example 26).

As explained in the red organic electric element discussed above, it appears that the characteristics of an element are improved when a plurality of light-emitting auxiliary layers are formed since a first light-emitting auxiliary layer affects the driving voltage of an element, and a second light-emitting auxiliary layer affects the efficiency and lifespan of an element.

To confirm this, as in Table 10, the hole mobility of Comparative Compound A and the compound of the present invention was measured, and the hole mobility measurement was conducted under the conditions shown in Table 7. The measurement results are shown in Table 10 below.

TABLE 10

| | hole mobility |
|---|---|
| Compound | (cm/V · S) |
| Comp. compd A | 4.2 × 10⁻⁵ |
| P1-105 | 5.4 × 10⁻⁴ |
| P1-107 | 7.9 × 10⁻⁴ |
| P1-108 | 1.2 × 10⁻³ |

Looking at Tables 9 and 10, as described in the previous red organic electroluminescent device, it can be seen that when a compound with high hole mobility is used as material for a first light-emitting auxiliary layer, the driving voltage of an element is reduced. That is, when comparing Comparative Compound A and the compound of the present invention, it can be seen that the hole mobility of the compound of the present invention is noticeably higher than that of comparative compound A, and it can be confirmed that the driving voltage of an element is significantly reduced when the compound of the present invention is used as a first light-emitting auxiliary layer material.

In addition, the DFT method (B3LYP/6-31g(D)) of the Gaussian program was used to confirm the energy level characteristics of a second light-emitting auxiliary layer, and the measured data are shown in Table 11 below.

TABLE 11

| Compound | P2-29 | P2-45 | P2-47 | P2-48 | P2-49 |
|---|---|---|---|---|---|
| G. T1 | 2.648 | 2.711 | 2.818 | 2.830 | 2.717 |

Looking at Table 9 and Table 11, it appears that triplet electrons may be prevented from transferring from the dopant when T1 of a second light-emitting auxiliary layer is high, which can affect efficiency and lifespan. In particular, it can be seen that compounds with a high T1 of 2.7 or more show high efficiency and long lifespan since the T1 of the green dopant is formed to be high. In particular, it can be seen that compounds with a high T1 of 2.7 or more show high efficiency and long lifespan since the T1 of the green dopant is formed to be high

In conclusion, it appears that a first light-emitting auxiliary layer performs the role of hole transport, and a second light-emitting auxiliary layer performs the role of injecting holes into the dopant or host and blocking electrons from the host. It can be seen that when a plurality of light-emitting auxiliary layers are formed as in the present invention, appropriate interactions can occur in each layer and maximizing the synergy effect between compounds, as a result, the characteristics of the element are greatly improved compared to when a single light-emitting auxiliary layer is formed.

Although the exemplary embodiments of the present invention have been described for illustrative purposes, those skilled in the art to which the present invention pertains will be capable of various modifications without departing from the essential characteristics of the present invention. Accordingly, the embodiments disclosed in this specification are for illustrative purposes rather than limiting the present invention, and the scope of the present invention is not limited by these embodiments. The scope of the present invention shall be construed on the basis of the accompanying claims, and it shall be construed that all of the technical arts included within the scope equivalent to the claims belong to the present invention.

1: An organic electric element comprising:
a first electrodes;
a second electrode; and
an organic material layer formed between the first electrode and the second electrode,
wherein the organic material layer comprises a light-emitting layer, a hole transport layer between the first electrode and the light-emitting layer, and a plurality of light-emitting auxiliary layers between the hole transport layer and the light-emitting layer, and
the plurality of light-emitting auxiliary layers comprise a first light-emitting auxiliary layer adjacent to the hole transport layer and a second light-emitting auxiliary layer adjacent to the light-emitting layer,
the first light-emitting auxiliary layer comprises a compound represented by the following Formula 1, and the second light-emitting auxiliary layer comprises a compound represented by the following Formula 2: 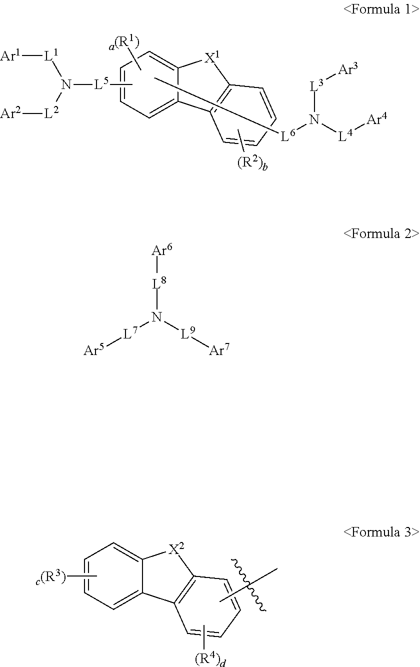
wherein:
Ar¹ to Ar⁷ are each independently selected from the group consisting of a C6-C6o aryl group, a fluorenyl group, a C₂-C₆₀ heterocyclic group containing at least one heteroatom of O, N, S, Si and P, and a C₃-C₆₀ aliphatic ring group, at least one of Ar¹ to Ar⁴ is Formula 3, and Formula 3 is bonded to one of L¹ to L⁴ of Formula 1,
X¹ and X² are each independently O or S,
L¹ to L⁹ are each independently selected from the group consisting of a single bond, a C₆-C₆₀ arylene group, a fluorenylene group, a C₂-C₆₀ heterocyclic group containing at least one heteroatom of O, N, S, Si and P, and a C₃-C₆₀ aliphatic ring group,
R¹ to R⁴ are each independently selected from the group consisting of hydrogen, deuterium, halogen, a cyano group, a nitro group, a C₆-C₆₀ aryl group, a fluorenyl group, a C₂-C₆₀ heterocyclic group containing at least one heteroatom of O, N, S, Si and P, a C₃-C₆₀ aliphatic ring group, a C₁-C₂₀ alkyl group, a C₂-C₂₀ alkenyl group, a C₂-C₂₀ alkynyl group, a C₁-C₂₀ alkoxyl group, and a C₆-C₂₀ aryloxy group, and adjacent groups may be bonded to each other to form a ring,
a and d are each an integer of 0 to 3, b and c are each an integer of 0 to 4, and when each of these is an integer of 2 or more, each of R¹, each of R², each of R³, each of R⁴ are the same as or different from each other,
the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by adjacent groups may be each optionally substituted with one or more substituents selected from the group consisting of deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and —L′—N(Rₐ)(R_{b}),
L′ is selected from the group consisting of a single bond, a C₆-C₃₀ arylene group, a fluorenylene group, a C₂-C₃₀ heterocyclic group containing at least one heteroatom of O, N, S, Si and P, and a C₃-C₃₀ aliphatic ring group, and
Rₐ and R_{b} are each independently selected from the group consisting of a C₆-C₃₀ aryl group, a fluorenyl group, a C₂-C₃₀ heterocyclic group containing at least one heteroatom of O, N, S, Si and P, and a C₃-C₃₀ aliphatic ring group.

2: The organic electric element of claim 1, wherein Formula 1 is represented by Formula 1-1 or Formula 1-2: 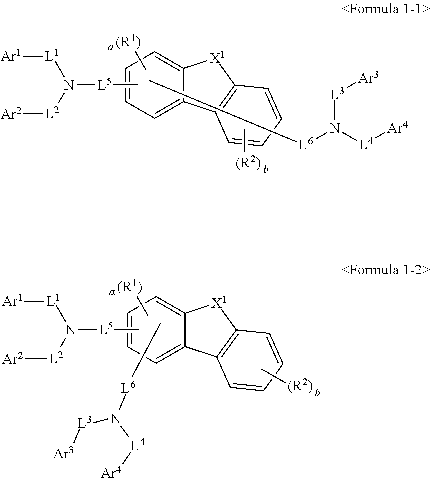
wherein X¹, R¹, R², a, b, L¹ to L⁶, Ar¹ to Ar⁴ are the same as defined in claim 1.

3: The organic electric element of claim 1, wherein Formula 1 is represented by one of Formula 1-3 to Formula 1-9: 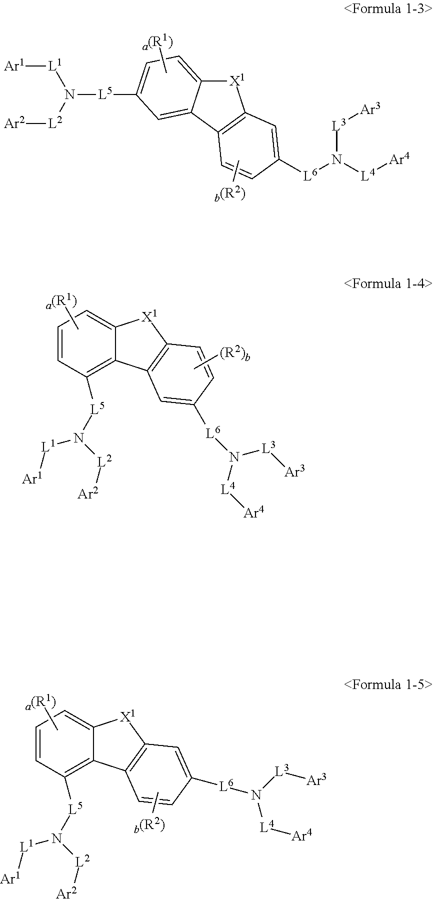 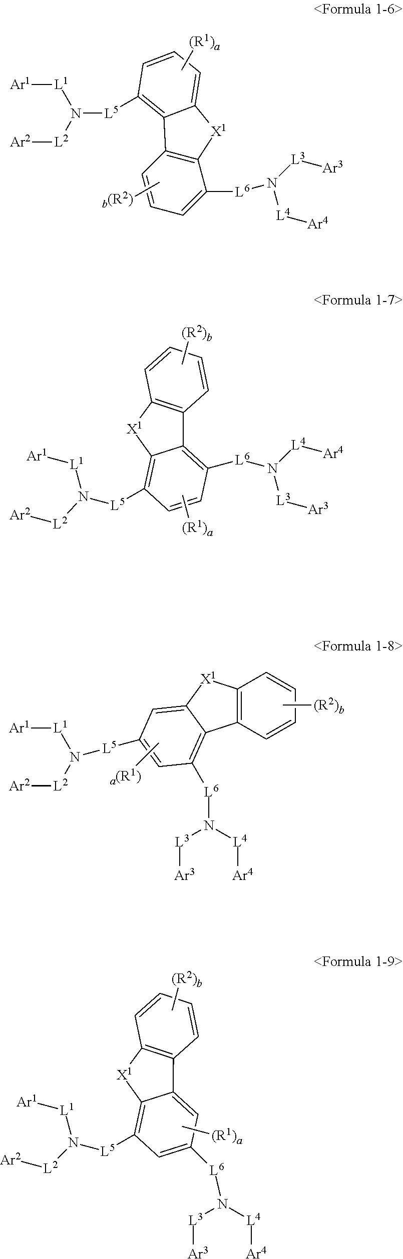
wherein X¹, R¹, R², a, b, L¹ to L⁶, Ar¹ to Ar⁴ are the same as defined in claim 1.

4: The organic electric element of claim 1, wherein Formula 3 is represented by one of Formula 3-1 to Formula 3-4: 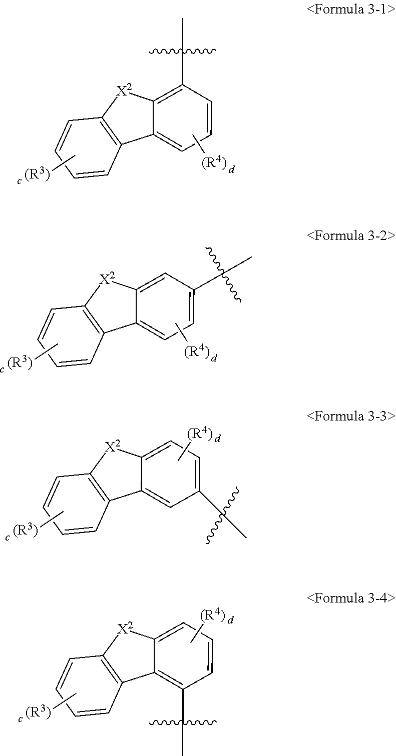
wherein X², R³, R⁴, c, d are the same as defined in claim 1.

5: The organic electric element of claim 1, wherein Ar⁵ in Formula 2 is one of Formula b to Formula d: 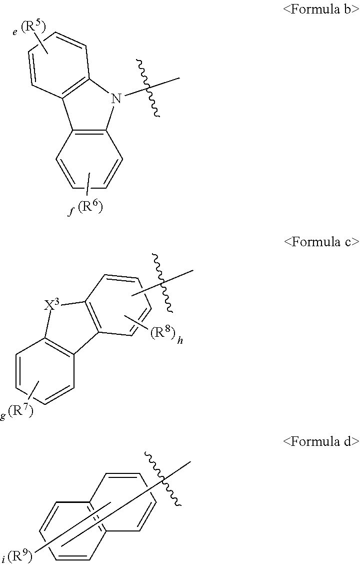
wherein:
X³ is O or S,
R⁵ to R⁹ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and —L′—N(Rₐ)(R_{b}), and adjacent groups may be bonded to each other to form a ring,
e, f and g are each an integer of 0 to 4, h is an integer of 0 to 3, i is an integer of 0 to 7, and when each of these is an integer of 2 or more, each of R⁵, each of R⁶, each of R⁷, each of R′, each of R⁹ are the same as or different from each other, and
L′, Rₐ and R_{b} are the same as defined in claim 1.

6: The organic electric element of claim 1, wherein Formula 2 is represented by Formula 2-1: 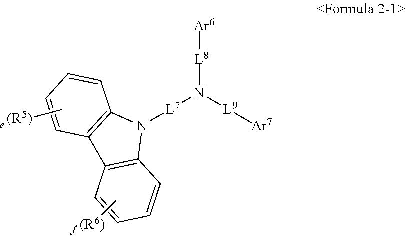
wherein, L⁷ to L⁹, Ar⁶, Ar⁷ are the same as defined in claim 1,
R⁵ and R⁶ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and —L′—N(Rₐ)(R_{b}), and adjacent groups may be bonded to each other to form a ring,
e, f and g are each an integer of 0 to 4, and when each of these is an integer of 2 or more, each of R⁵, each of R⁶ are the same as or different from each other, and
L′, Rₐ and R_{b} are the same as defined in claim 1.

7: The organic electric element of claim 1, wherein at least one of the L¹ to L⁹ is one of the following Formula L-1 to Formula L-12 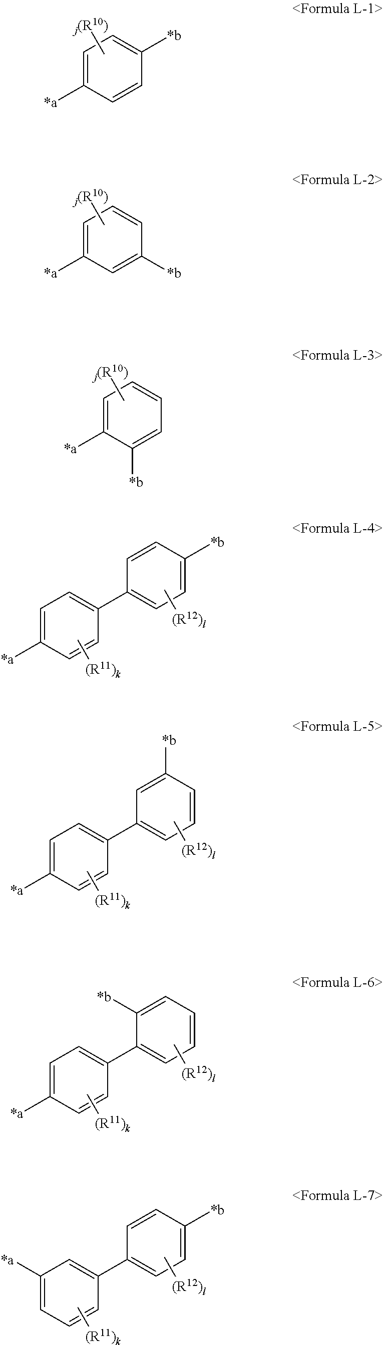 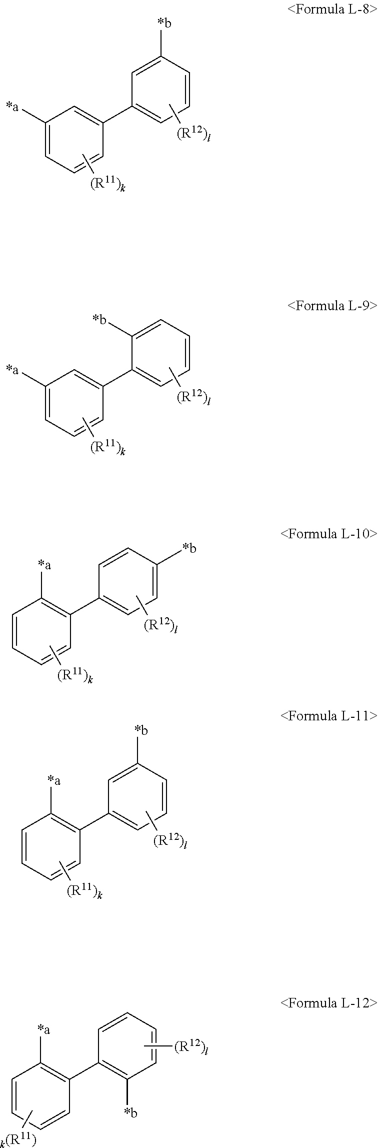
wherein:
R¹⁰ to R¹² are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₂₀ aryloxy group, a C₆-C₂₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and —L′—N(Rₐ)(R_{b}), and adjacent groups may be bonded to each other to form a ring,
j, k and l are each an integer of 0 to 4, and when each of these is an integer of 2 or more, each of R¹⁰, each of R¹¹, each of R¹² are the same as or different from each other,
a represents the position bonded to the nitrogen of the amine group,
b represents the position bonded to Ar¹ to Ar⁷ when at least one of L¹ to L⁴, L⁷ to L⁹ is one of the above Formulas, it represents the position bonded to the benzene ring to which R¹ is bonded when L⁵ is one of the above Formulas, and it represents the position bonded to the benzene ring to which R² is bonded when L⁶ is one of the above Formulas, and
L′, Rₐ and R_{b} are the same as defined in claim 1.

8: The organic electric element of claim 1, wherein the compound represented by Formula 1 is one of the following compounds:

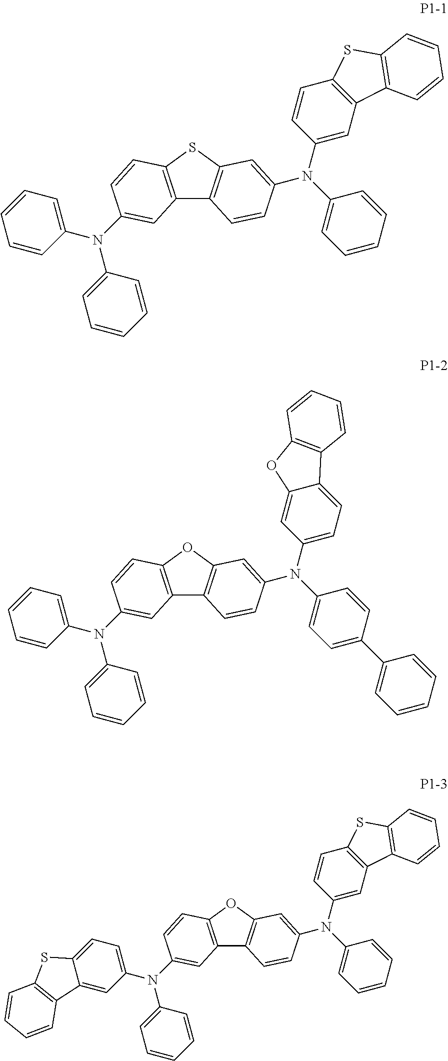 [SMILES: c1ccc(N(c2ccc3c(c2)sc2ccc(N(c4ccccc4)c4ccccc4)cc23)c2ccc3sc4ccccc4c3c2)cc1 ; c1ccc(-c2ccc(N(c3ccc4c(c3)oc3ccccc34)c3ccc4c(c3)oc3ccc(N(c5ccccc5)c5ccccc5)cc34)cc2)cc1 ; c1ccc(N(c2ccc3c(c2)oc2ccc(N(c4ccccc4)c4ccc5sc6ccccc6c5c4)cc23)c2ccc3sc4ccccc4c3c2)cc1]

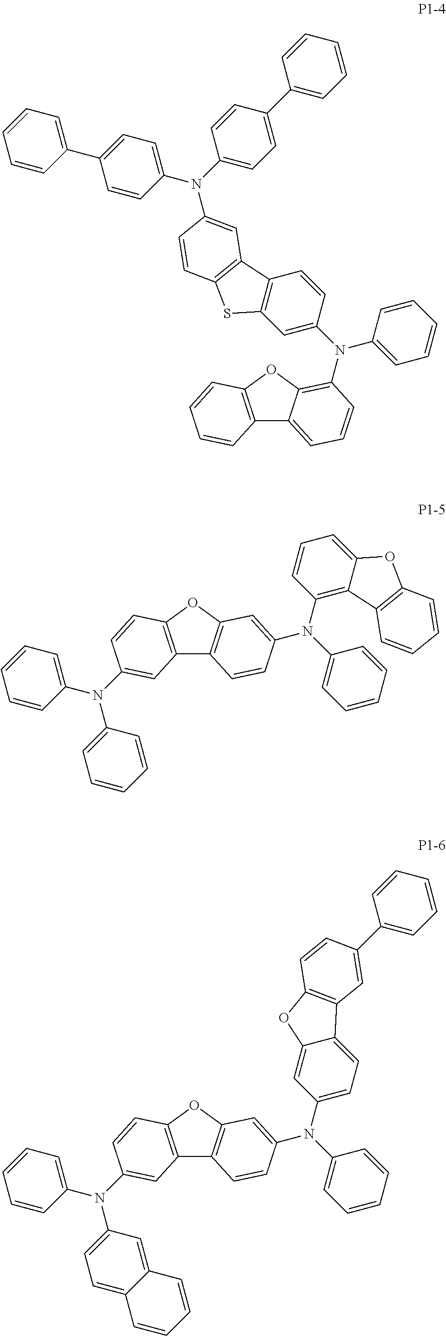 [SMILES: c1ccc(-c2ccc(N(c3ccc(-c4ccccc4)cc3)c3ccc4sc5cc(N(c6ccccc6)c6cccc7c6oc6ccccc67)ccc5c4c3)cc2)cc1 ; c1ccc(N(c2ccccc2)c2ccc3oc4cc(N(c5ccccc5)c5cccc6oc7ccccc7c56)ccc4c3c2)cc1 ; c1ccc(-c2ccc3oc4cc(N(c5ccccc5)c5ccc6c(c5)oc5ccc(N(c7ccccc7)c7ccc8ccccc8c7)cc56)ccc4c3c2)cc1]

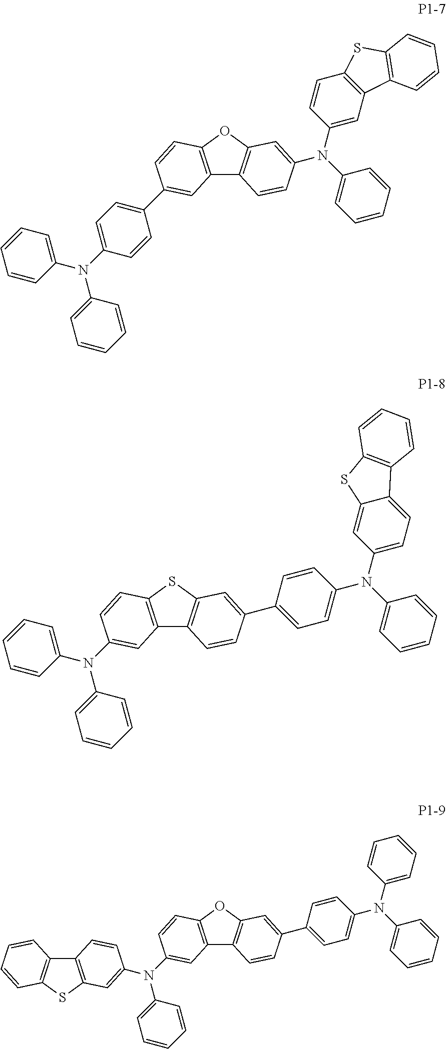 [SMILES: c1ccc(N(c2ccccc2)c2ccc(-c3ccc4oc5cc(N(c6ccccc6)c6ccc7sc8ccccc8c7c6)ccc5c4c3)cc2)cc1 ; c1ccc(N(c2ccc(-c3ccc4c(c3)sc3ccc(N(c5ccccc5)c5ccccc5)cc34)cc2)c2ccc3c(c2)sc2ccccc23)cc1 ; c1ccc(N(c2ccccc2)c2ccc(-c3ccc4c(c3)oc3ccc(N(c5ccccc5)c5ccc6c(c5)sc5ccccc56)cc34)cc2)cc1]

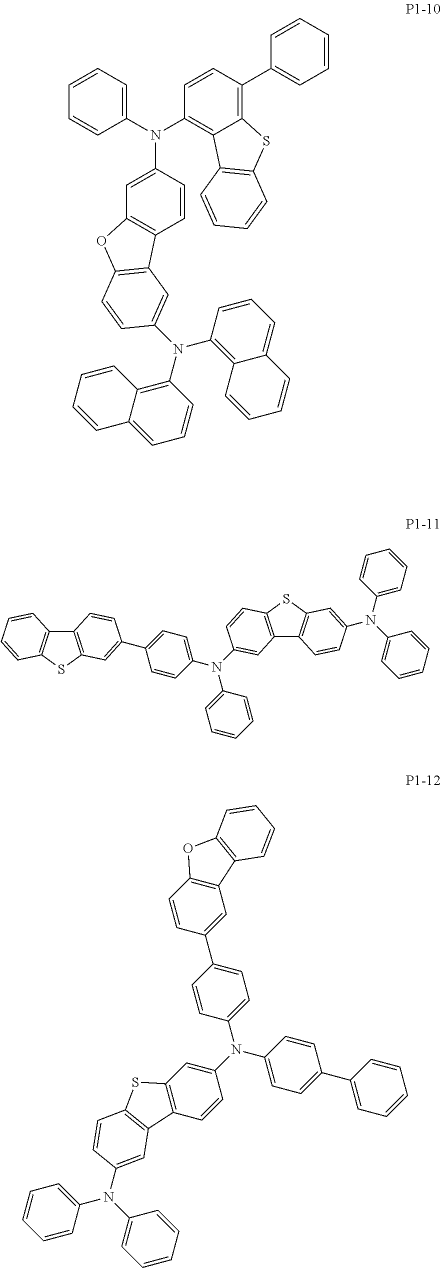 [SMILES: c1ccc(-c2ccc(N(c3ccccc3)c3ccc4c(c3)oc3ccc(N(c5cccc6ccccc56)c5cccc6ccccc56)cc34)c3c2sc2ccccc23)cc1 ; c1ccc(N(c2ccccc2)c2ccc3c(c2)sc2ccc(N(c4ccccc4)c4ccc(-c5ccc6c(c5)sc5ccccc56)cc4)cc23)cc1 ; c1ccc(-c2ccc(N(c3ccc(-c4ccc5oc6ccccc6c5c4)cc3)c3ccc4c(c3)sc3ccc(N(c5ccccc5)c5ccccc5)cc34)cc2)cc1]

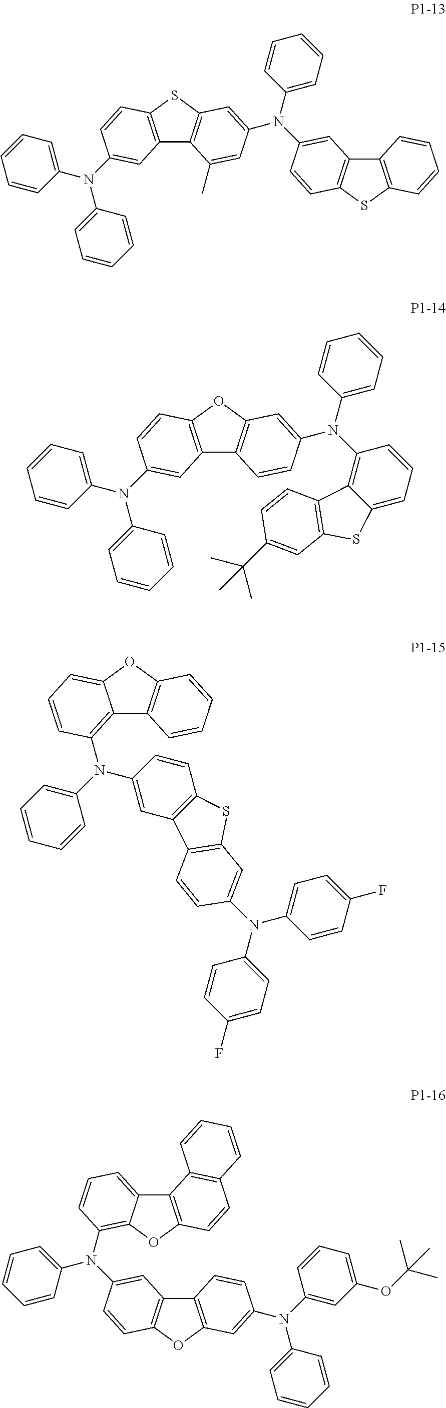 [SMILES: Cc1cc(N(c2ccccc2)c2ccc3sc4ccccc4c3c2)cc2sc3ccc(N(c4ccccc4)c4ccccc4)cc3c12 ; CC(C)(C)c1ccc2c(c1)sc1cccc(N(c3ccccc3)c3ccc4c(c3)oc3ccc(N(c5ccccc5)c5ccccc5)cc34)c12 ; Fc1ccc(N(c2ccc(F)cc2)c2ccc3c(c2)sc2ccc(N(c4ccccc4)c4cccc5oc6ccccc6c45)cc23)cc1 ; CC(C)(C)Oc1cccc(N(c2ccccc2)c2ccc3c(c2)oc2ccc(N(c4ccccc4)c4cccc5c4oc4ccc6ccccc6c45)cc23)c1]

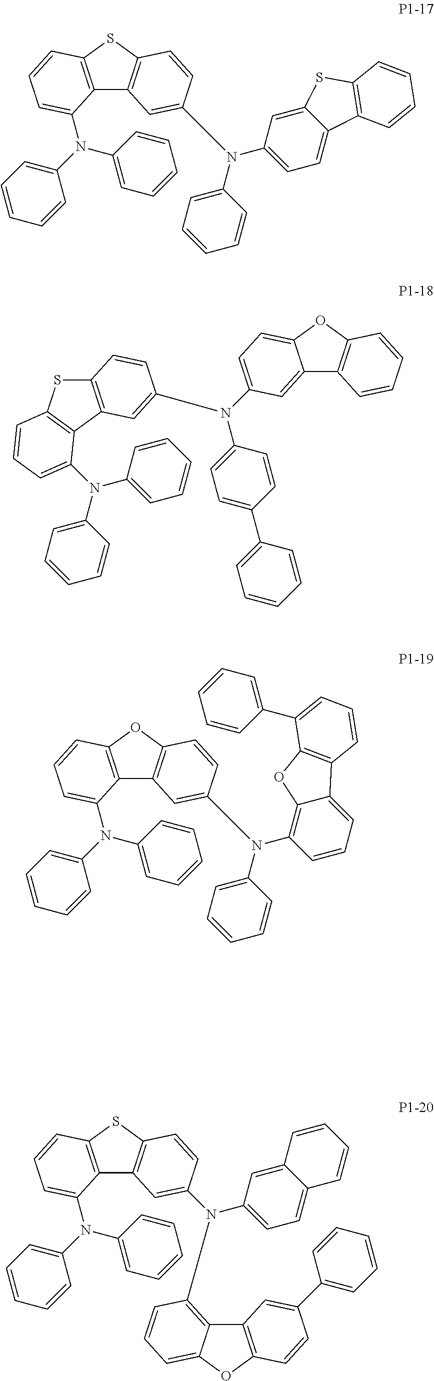 [SMILES: c1ccc(N(c2ccc3c(c2)sc2ccccc23)c2ccc3sc4cccc(N(c5ccccc5)c5ccccc5)c4c3c2)cc1 ; c1ccc(-c2ccc(N(c3ccc4oc5ccccc5c4c3)c3ccc4sc5cccc(N(c6ccccc6)c6ccccc6)c5c4c3)cc2)cc1 ; c1ccc(-c2cccc3c2oc2c(N(c4ccccc4)c4ccc5oc6cccc(N(c7ccccc7)c7ccccc7)c6c5c4)cccc23)cc1 ; c1ccc(-c2ccc3oc4cccc(N(c5ccc6ccccc6c5)c5ccc6sc7cccc(N(c8ccccc8)c8ccccc8)c7c6c5)c4c3c2)cc1]

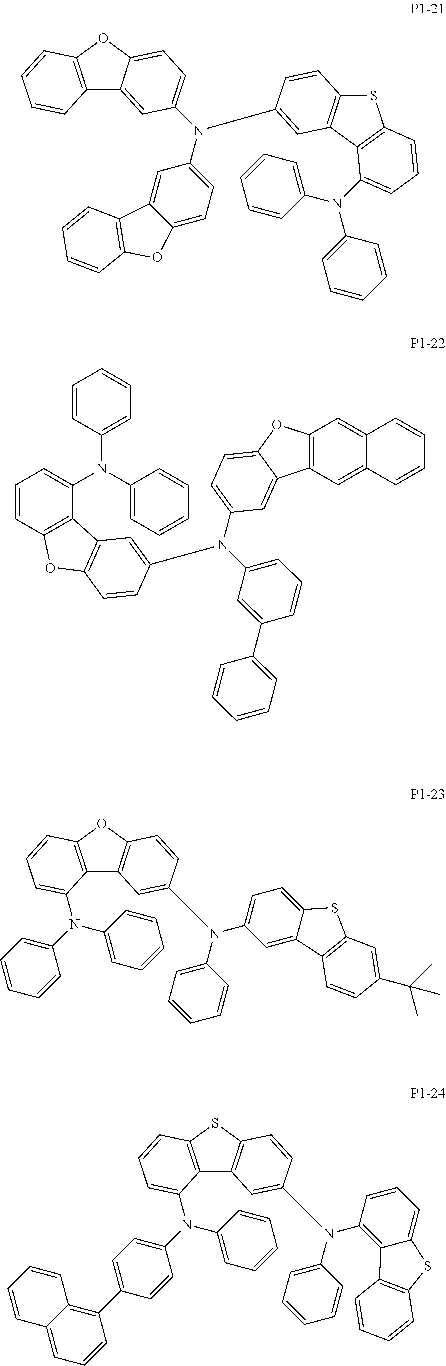 [SMILES: c1ccc(N(c2ccccc2)c2cccc3sc4ccc(N(c5ccc6oc7ccccc7c6c5)c5ccc6oc7ccccc7c6c5)cc4c23)cc1 ; c1ccc(-c2cccc(N(c3ccc4oc5cc6ccccc6cc5c4c3)c3ccc4oc5cccc(N(c6ccccc6)c6ccccc6)c5c4c3)c2)cc1 ; CC(C)(C)c1ccc2c(c1)sc1ccc(N(c3ccccc3)c3ccc4oc5cccc(N(c6ccccc6)c6ccccc6)c5c4c3)cc12 ; c1ccc(N(c2ccc3sc4cccc(N(c5ccccc5)c5ccc(-c6cccc7ccccc67)cc5)c4c3c2)c2cccc3sc4ccccc4c23)cc1]

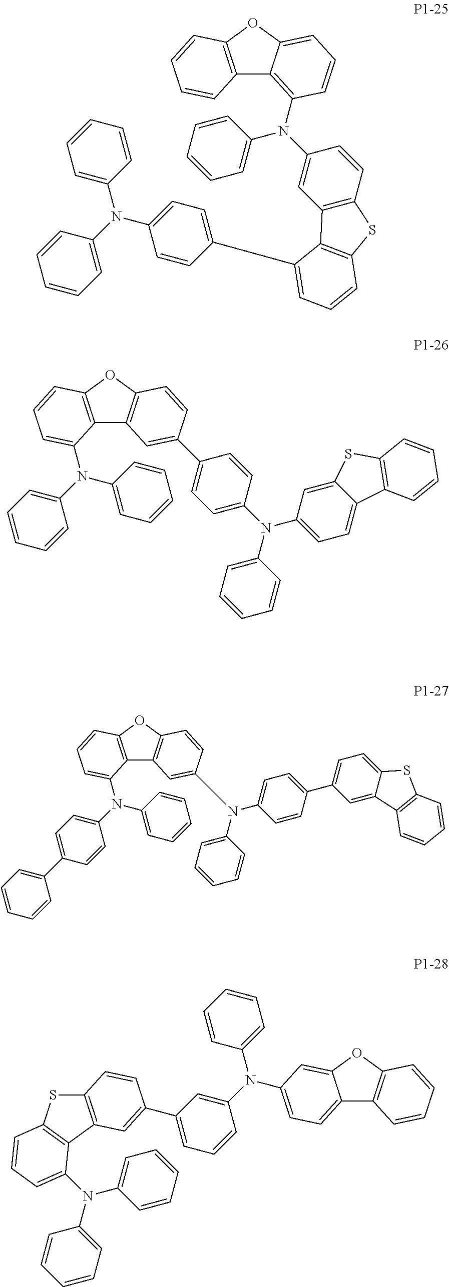 [SMILES: c1ccc(N(c2ccccc2)c2ccc(-c3cccc4sc5ccc(N(c6ccccc6)c6cccc7oc8ccccc8c67)cc5c34)cc2)cc1 ; c1ccc(N(c2ccc(-c3ccc4oc5cccc(N(c6ccccc6)c6ccccc6)c5c4c3)cc2)c2ccc3c(c2)sc2ccccc23)cc1 ; c1ccc(-c2ccc(N(c3ccccc3)c3cccc4oc5ccc(N(c6ccccc6)c6ccc(-c7ccc8sc9ccccc9c8c7)cc6)cc5c34)cc2)cc1 ; c1ccc(N(c2cccc(-c3ccc4sc5cccc(N(c6ccccc6)c6ccccc6)c5c4c3)c2)c2ccc3c(c2)oc2ccccc23)cc1]

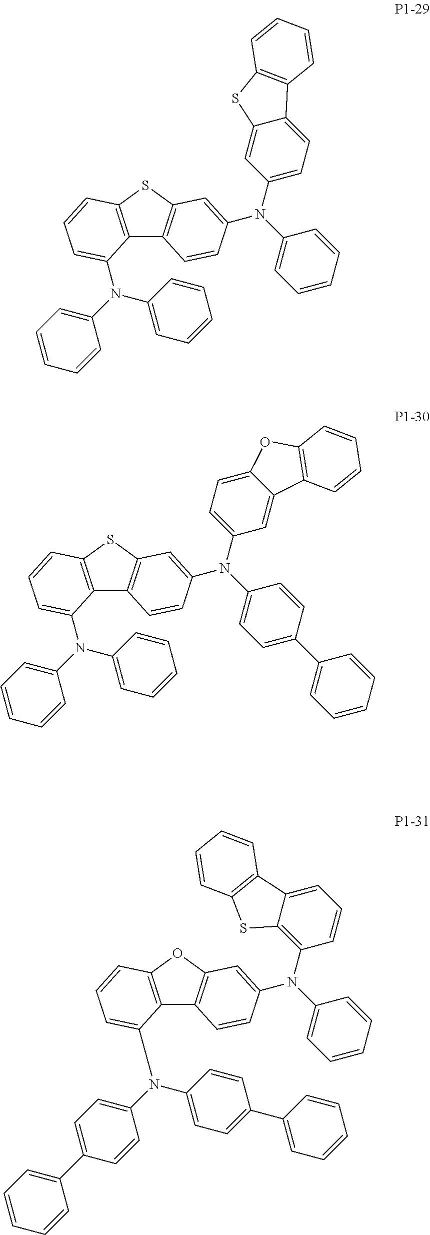 [SMILES: c1ccc(N(c2ccc3c(c2)sc2ccccc23)c2ccc3c(c2)sc2cccc(N(c4ccccc4)c4ccccc4)c23)cc1 ; c1ccc(-c2ccc(N(c3ccc4c(c3)sc3cccc(N(c5ccccc5)c5ccccc5)c34)c3ccc4oc5ccccc5c4c3)cc2)cc1 ; c1ccc(-c2ccc(N(c3ccc(-c4ccccc4)cc3)c3cccc4oc5cc(N(c6ccccc6)c6cccc7c6sc6ccccc67)ccc5c34)cc2)cc1]

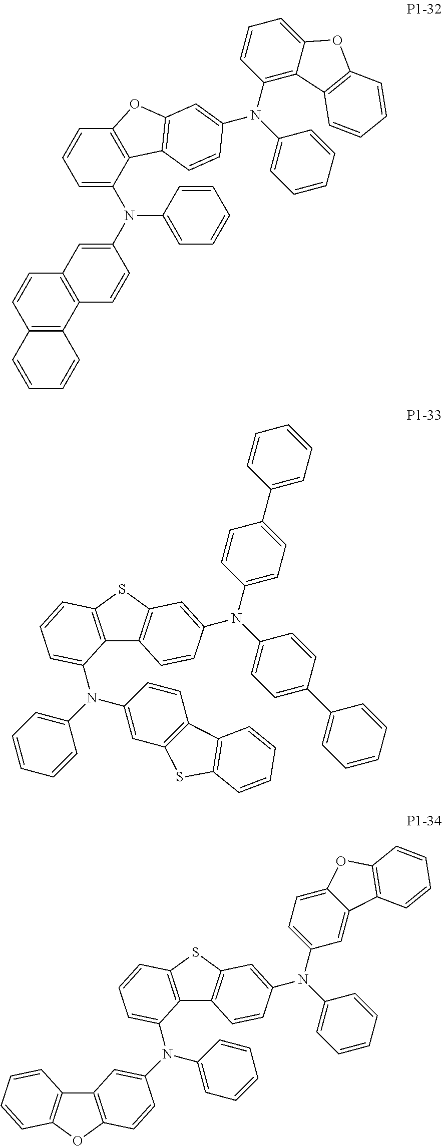 [SMILES: c1ccc(N(c2ccc3c(c2)oc2cccc(N(c4ccccc4)c4ccc5c(ccc6ccccc65)c4)c23)c2cccc3oc4ccccc4c23)cc1 ; c1ccc(-c2ccc(N(c3ccc(-c4ccccc4)cc3)c3ccc4c(c3)sc3cccc(N(c5ccccc5)c5ccc6c(c5)sc5ccccc56)c34)cc2)cc1 ; c1ccc(N(c2ccc3c(c2)sc2cccc(N(c4ccccc4)c4ccc5oc6ccccc6c5c4)c23)c2ccc3oc4ccccc4c3c2)cc1]

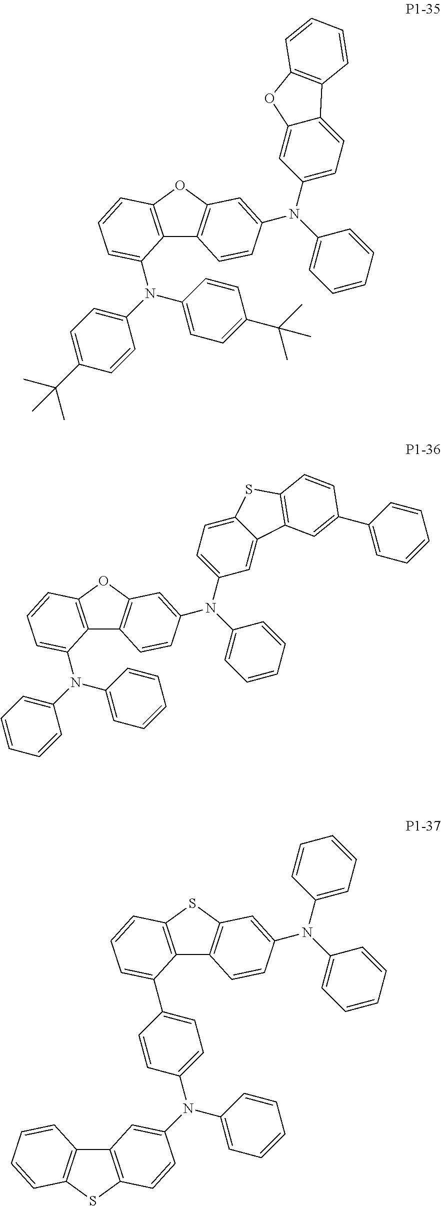 [SMILES: CC(C)(C)c1ccc(N(c2ccc(C(C)(C)C)cc2)c2cccc3oc4cc(N(c5ccccc5)c5ccc6c(c5)oc5ccccc56)ccc4c23)cc1 ; c1ccc(-c2ccc3sc4ccc(N(c5ccccc5)c5ccc6c(c5)oc5cccc(N(c7ccccc7)c7ccccc7)c56)cc4c3c2)cc1 ; c1ccc(N(c2ccccc2)c2ccc3c(c2)sc2cccc(-c4ccc(N(c5ccccc5)c5ccc6sc7ccccc7c6c5)cc4)c23)cc1]

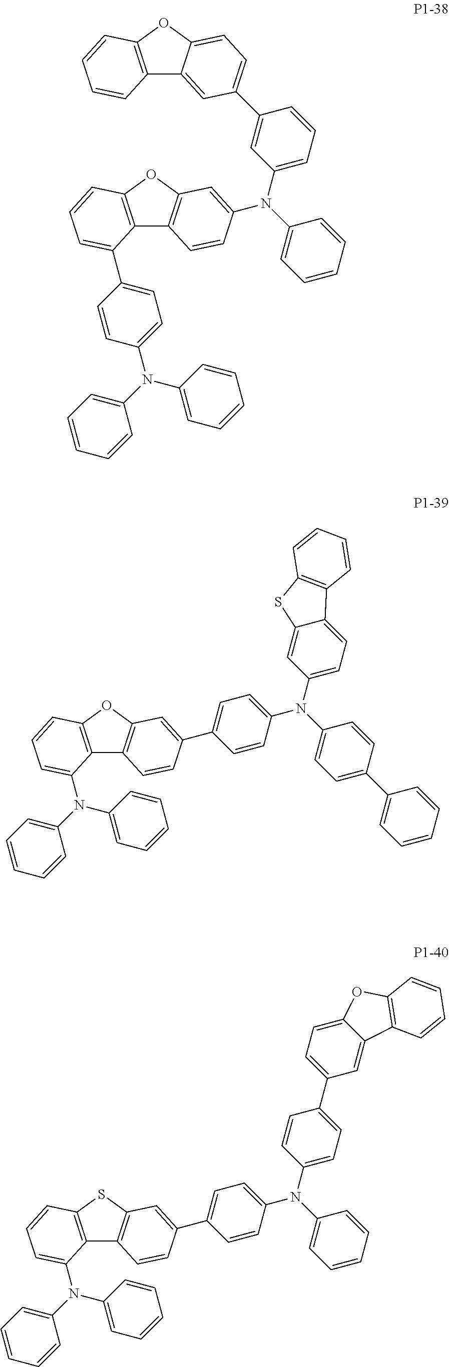 [SMILES: c1ccc(N(c2ccccc2)c2ccc(-c3cccc4oc5cc(N(c6ccccc6)c6cccc(-c7ccc8oc9ccccc9c8c7)c6)ccc5c34)cc2)cc1 ; c1ccc(-c2ccc(N(c3ccc(-c4ccc5c(c4)oc4cccc(N(c6ccccc6)c6ccccc6)c45)cc3)c3ccc4c(c3)sc3ccccc34)cc2)cc1 ; c1ccc(N(c2ccc(-c3ccc4c(c3)sc3cccc(N(c5ccccc5)c5ccccc5)c34)cc2)c2ccc(-c3ccc4oc5ccccc5c4c3)cc2)cc1]

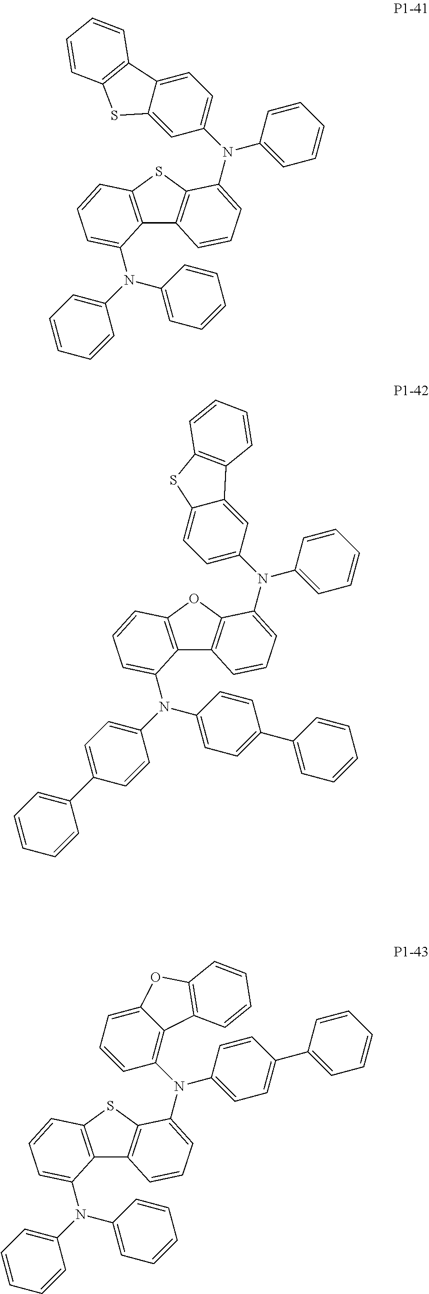 [SMILES: c1ccc(N(c2ccc3c(c2)sc2ccccc23)c2cccc3c2sc2cccc(N(c4ccccc4)c4ccccc4)c23)cc1 ; c1ccc(-c2ccc(N(c3ccc(-c4ccccc4)cc3)c3cccc4oc5c(N(c6ccccc6)c6ccc7sc8ccccc8c7c6)cccc5c34)cc2)cc1 ; c1ccc(-c2ccc(N(c3cccc4c3sc3cccc(N(c5ccccc5)c5ccccc5)c34)c3cccc4oc5ccccc5c34)cc2)cc1]

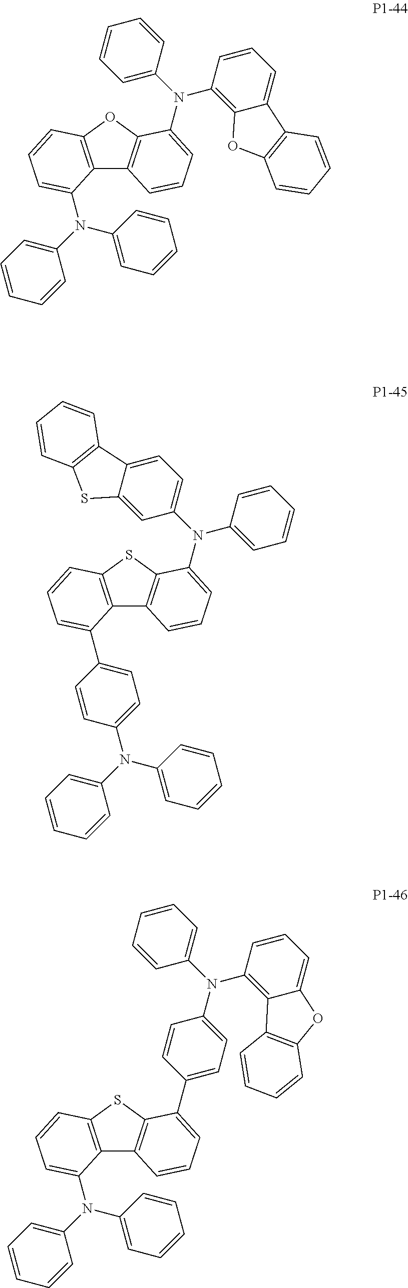 [SMILES: c1ccc(N(c2cccc3c2oc2ccccc23)c2cccc3c2oc2cccc(N(c4ccccc4)c4ccccc4)c23)cc1 ; c1ccc(N(c2ccccc2)c2ccc(-c3cccc4sc5c(N(c6ccccc6)c6ccc7c(c6)sc6ccccc67)cccc5c34)cc2)cc1 ; c1ccc(N(c2ccc(-c3cccc4c3sc3cccc(N(c5ccccc5)c5ccccc5)c34)cc2)c2cccc3oc4ccccc4c23)cc1]

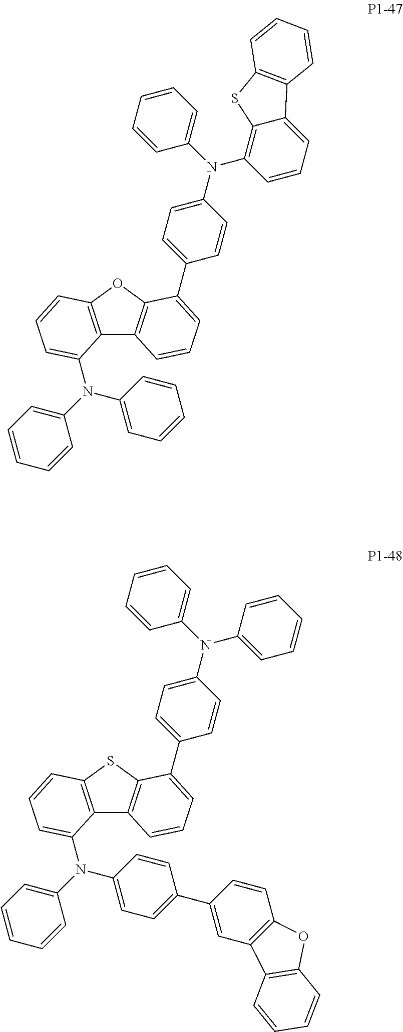 [SMILES: c1ccc(N(c2ccc(-c3cccc4c3oc3cccc(N(c5ccccc5)c5ccccc5)c34)cc2)c2cccc3c2sc2ccccc23)cc1 ; c1ccc(N(c2ccccc2)c2ccc(-c3cccc4c3sc3cccc(N(c5ccccc5)c5ccc(-c6ccc7oc8ccccc8c7c6)cc5)c34)cc2)cc1]

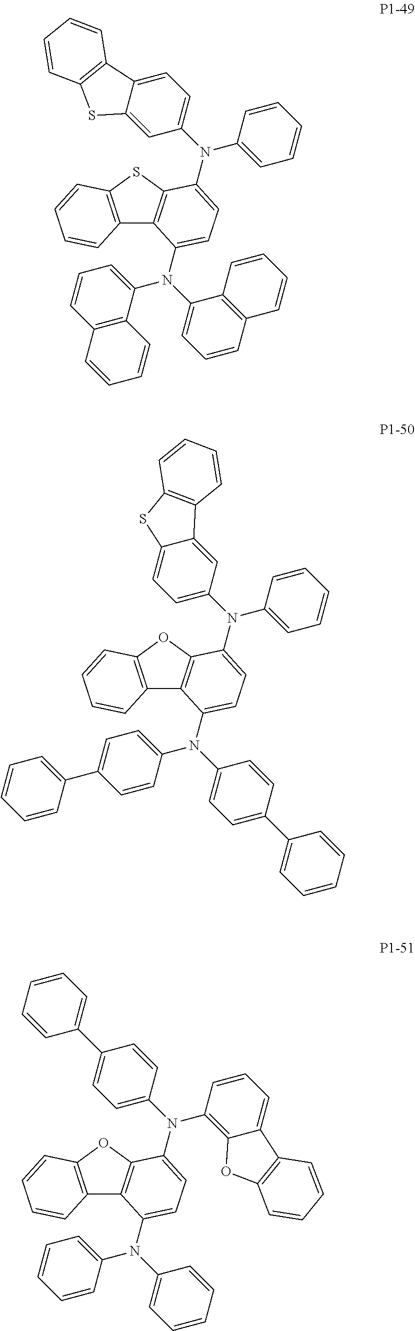 [SMILES: c1ccc(N(c2ccc3c(c2)sc2ccccc23)c2ccc(N(c3cccc4ccccc34)c3cccc4ccccc34)c3c2sc2ccccc23)cc1 ; c1ccc(-c2ccc(N(c3ccc(-c4ccccc4)cc3)c3ccc(N(c4ccccc4)c4ccc5sc6ccccc6c5c4)c4oc5ccccc5c34)cc2)cc1 ; c1ccc(-c2ccc(N(c3cccc4c3oc3ccccc34)c3ccc(N(c4ccccc4)c4ccccc4)c4c3oc3ccccc34)cc2)cc1]

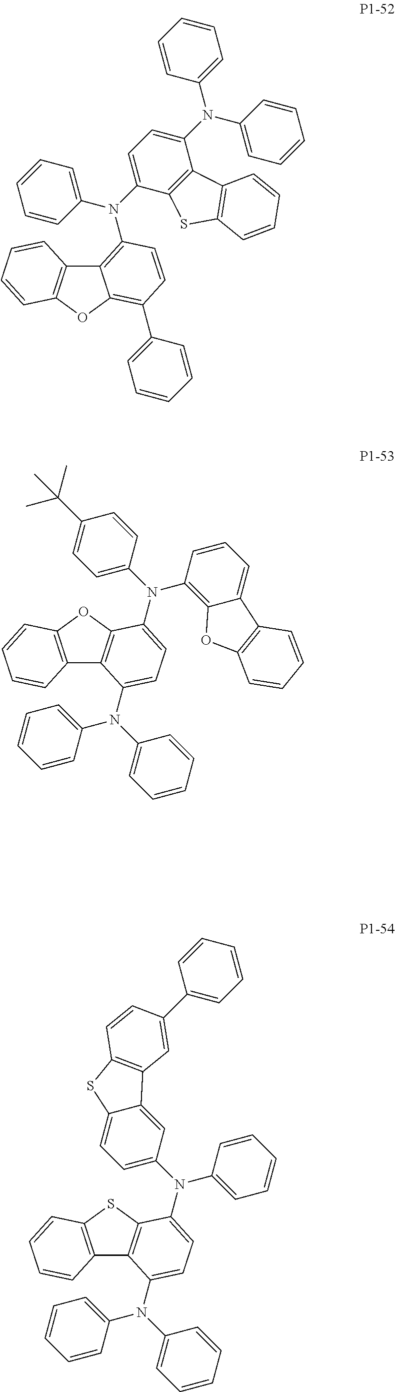 [SMILES: c1ccc(-c2ccc(N(c3ccccc3)c3ccc(N(c4ccccc4)c4ccccc4)c4c3sc3ccccc34)c3c2oc2ccccc23)cc1 ; CC(C)(C)c1ccc(N(c2cccc3c2oc2ccccc23)c2ccc(N(c3ccccc3)c3ccccc3)c3c2oc2ccccc23)cc1 ; c1ccc(-c2ccc3sc4ccc(N(c5ccccc5)c5ccc(N(c6ccccc6)c6ccccc6)c6c5sc5ccccc56)cc4c3c2)cc1]

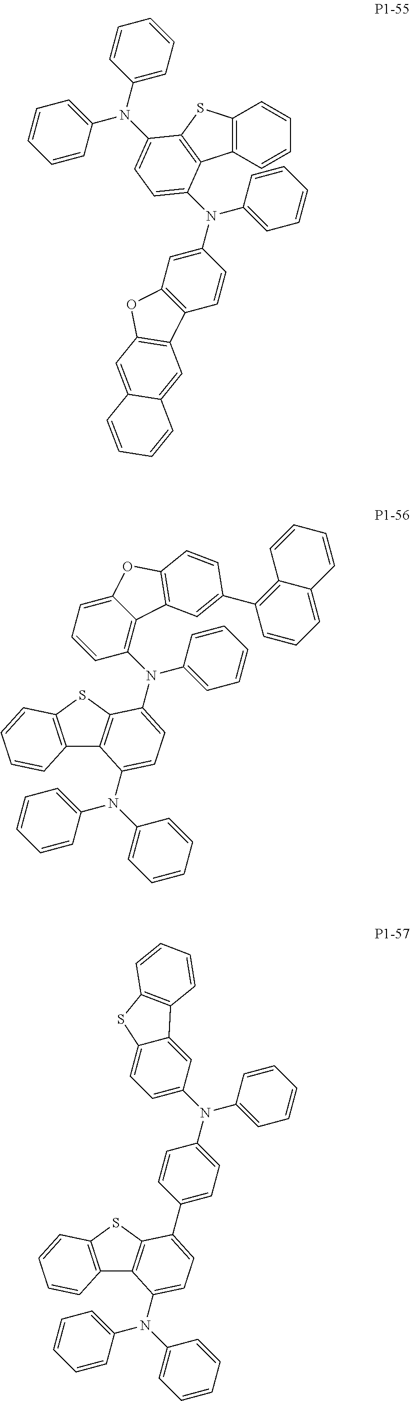 [SMILES: c1ccc(N(c2ccccc2)c2ccc(N(c3ccccc3)c3ccc4c(c3)oc3cc5ccccc5cc34)c3c2sc2ccccc23)cc1 ; c1ccc(N(c2ccc(N(c3ccccc3)c3ccccc3)c3c2sc2ccccc23)c2cccc3oc4ccc(-c5cccc6ccccc56)cc4c23)cc1 ; c1ccc(N(c2ccc(-c3ccc(N(c4ccccc4)c4ccccc4)c4c3sc3ccccc34)cc2)c2ccc3sc4ccccc4c3c2)cc1]

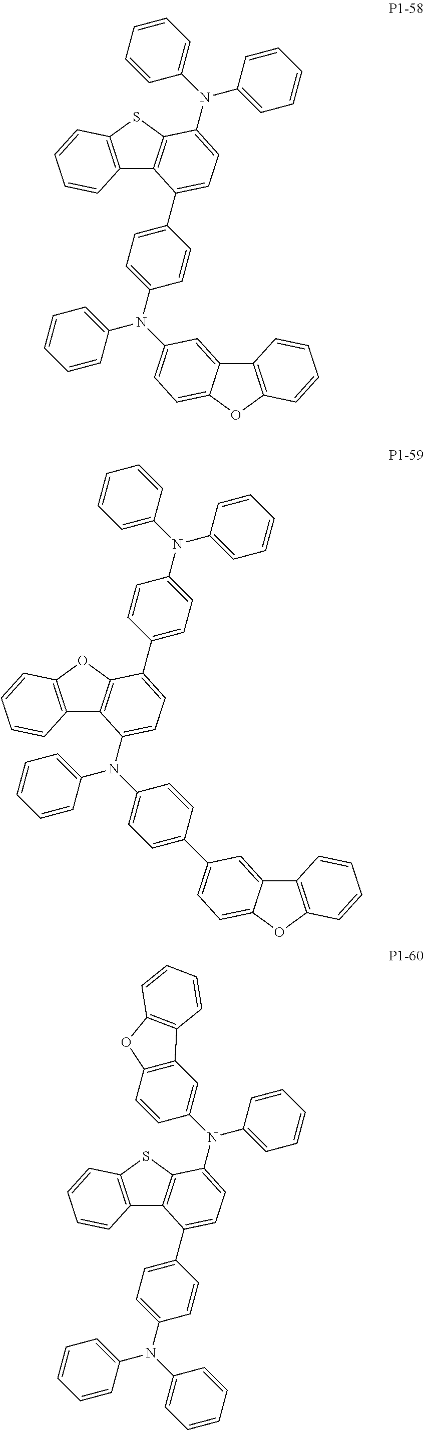 [SMILES: c1ccc(N(c2ccc(-c3ccc(N(c4ccccc4)c4ccccc4)c4sc5ccccc5c34)cc2)c2ccc3oc4ccccc4c3c2)cc1 ; c1ccc(N(c2ccccc2)c2ccc(-c3ccc(N(c4ccccc4)c4ccc(-c5ccc6oc7ccccc7c6c5)cc4)c4c3oc3ccccc34)cc2)cc1 ; c1ccc(N(c2ccccc2)c2ccc(-c3ccc(N(c4ccccc4)c4ccc5oc6ccccc6c5c4)c4sc5ccccc5c34)cc2)cc1]

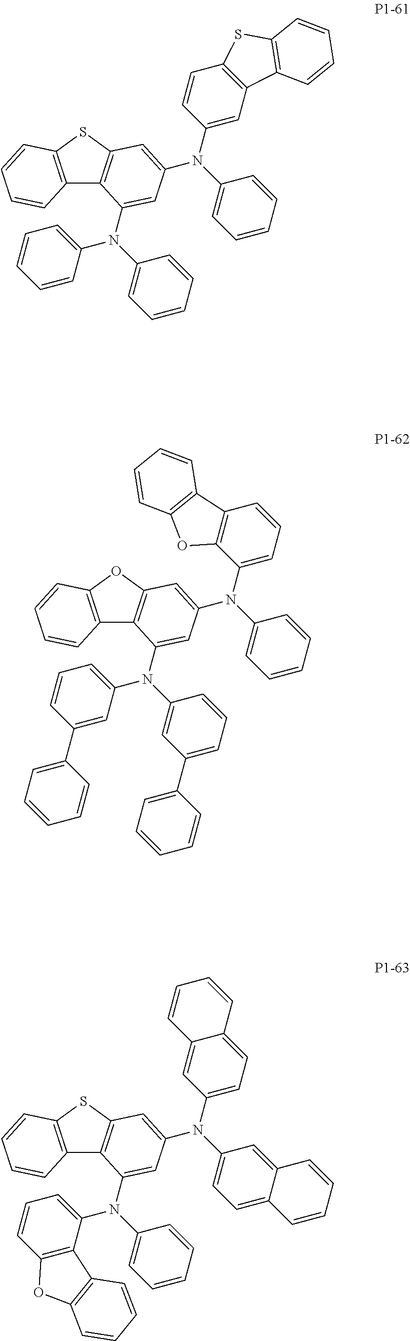 [SMILES: c1ccc(N(c2cc(N(c3ccccc3)c3ccccc3)c3c(c2)sc2ccccc23)c2ccc3sc4ccccc4c3c2)cc1 ; c1ccc(-c2cccc(N(c3cccc(-c4ccccc4)c3)c3cc(N(c4ccccc4)c4cccc5c4oc4ccccc45)cc4oc5ccccc5c34)c2)cc1 ; c1ccc(N(c2cccc3oc4ccccc4c23)c2cc(N(c3ccc4ccccc4c3)c3ccc4ccccc4c3)cc3sc4ccccc4c23)cc1]

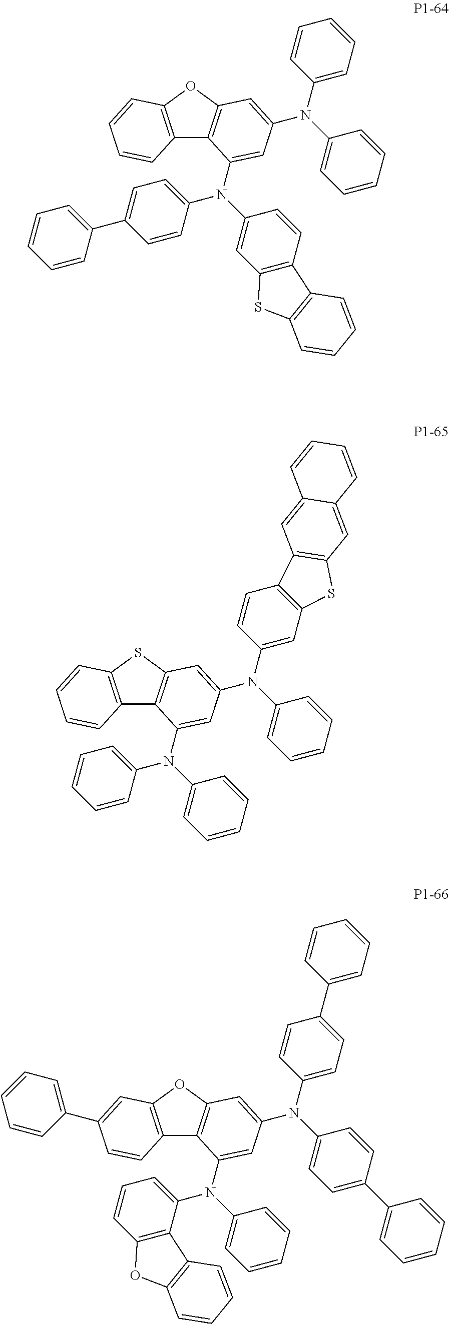 [SMILES: c1ccc(-c2ccc(N(c3ccc4c(c3)sc3ccccc34)c3cc(N(c4ccccc4)c4ccccc4)cc4oc5ccccc5c34)cc2)cc1 ; c1ccc(N(c2ccc3c(c2)sc2cc4ccccc4cc23)c2cc(N(c3ccccc3)c3ccccc3)c3c(c2)sc2ccccc23)cc1 ; c1ccc(-c2ccc(N(c3ccc(-c4ccccc4)cc3)c3cc(N(c4ccccc4)c4cccc5oc6ccccc6c45)c4c(c3)oc3cc(-c5ccccc5)ccc34)cc2)cc1]

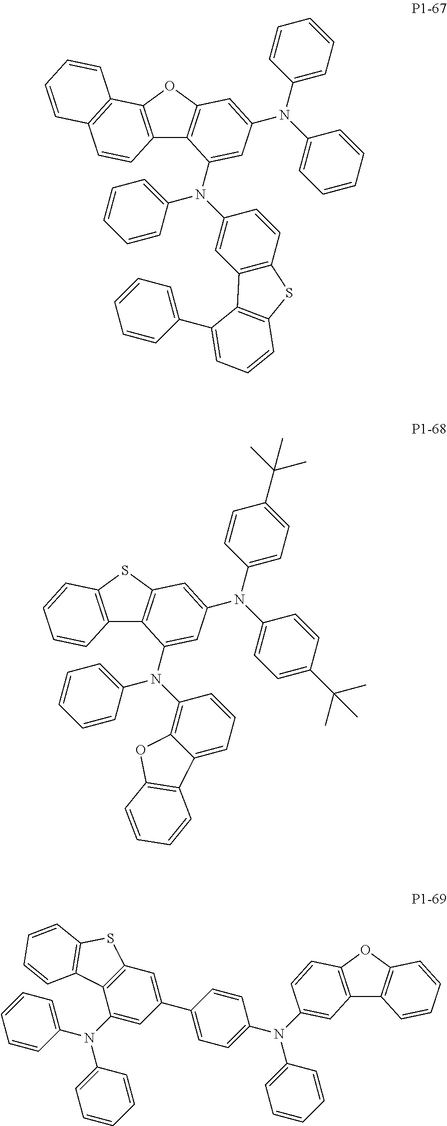 [SMILES: c1ccc(-c2cccc3sc4ccc(N(c5ccccc5)c5cc(N(c6ccccc6)c6ccccc6)cc6oc7c8ccccc8ccc7c56)cc4c23)cc1 ; CC(C)(C)c1ccc(N(c2ccc(C(C)(C)C)cc2)c2cc(N(c3ccccc3)c3cccc4c3oc3ccccc34)c3c(c2)sc2ccccc23)cc1 ; c1ccc(N(c2ccc(-c3cc(N(c4ccccc4)c4ccccc4)c4c(c3)sc3ccccc34)cc2)c2ccc3oc4ccccc4c3c2)cc1]

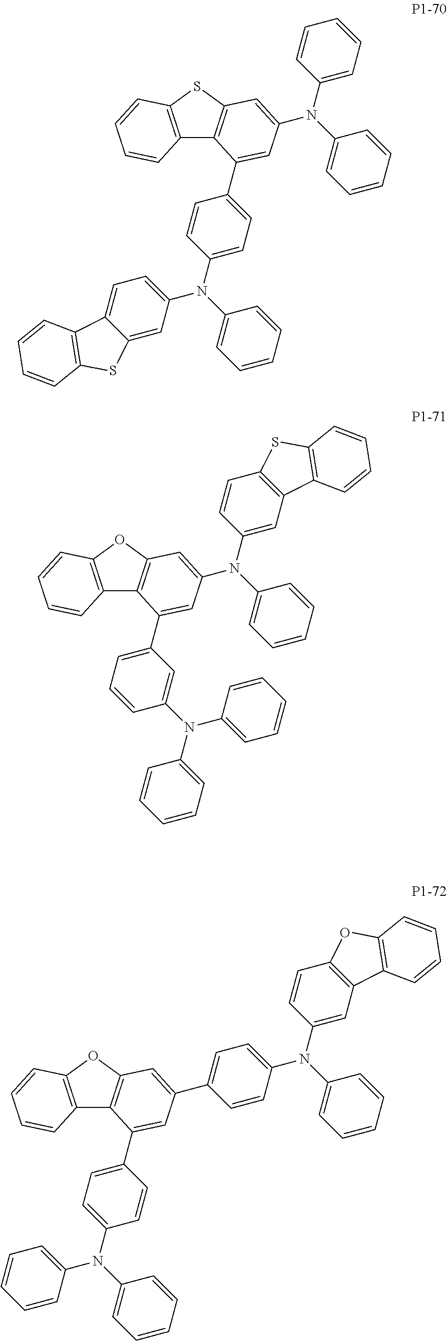 [SMILES: c1ccc(N(c2ccc(-c3cc(N(c4ccccc4)c4ccccc4)cc4sc5ccccc5c34)cc2)c2ccc3c(c2)sc2ccccc23)cc1 ; c1ccc(N(c2ccccc2)c2cccc(-c3cc(N(c4ccccc4)c4ccc5sc6ccccc6c5c4)cc4oc5ccccc5c34)c2)cc1 ; c1ccc(N(c2ccccc2)c2ccc(-c3cc(-c4ccc(N(c5ccccc5)c5ccc6oc7ccccc7c6c5)cc4)cc4oc5ccccc5c34)cc2)cc1]

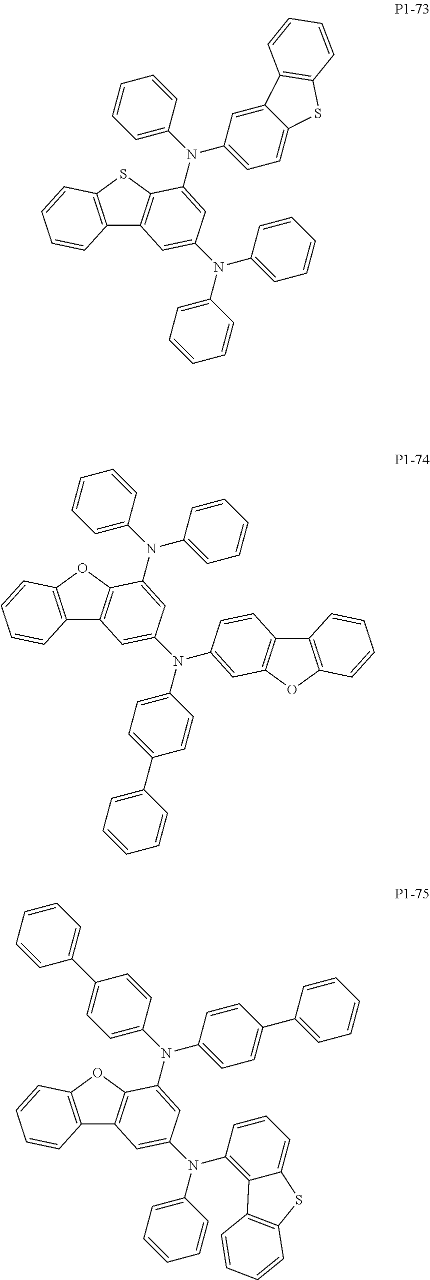 [SMILES: c1ccc(N(c2ccccc2)c2cc(N(c3ccccc3)c3ccc4sc5ccccc5c4c3)c3sc4ccccc4c3c2)cc1 ; c1ccc(-c2ccc(N(c3ccc4c(c3)oc3ccccc34)c3cc(N(c4ccccc4)c4ccccc4)c4oc5ccccc5c4c3)cc2)cc1 ; c1ccc(-c2ccc(N(c3ccc(-c4ccccc4)cc3)c3cc(N(c4ccccc4)c4cccc5sc6ccccc6c45)cc4c3oc3ccccc34)cc2)cc1]

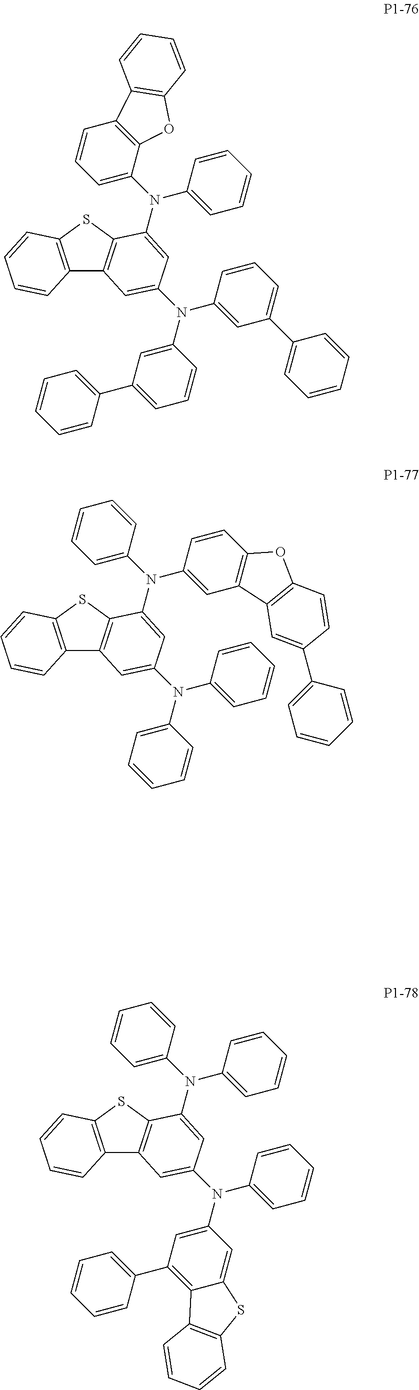 [SMILES: c1ccc(-c2cccc(N(c3cccc(-c4ccccc4)c3)c3cc(N(c4ccccc4)c4cccc5c4oc4ccccc45)c4sc5ccccc5c4c3)c2)cc1 ; c1ccc(-c2ccc3oc4ccc(N(c5ccccc5)c5cc(N(c6ccccc6)c6ccccc6)cc6c5sc5ccccc56)cc4c3c2)cc1 ; c1ccc(-c2cc(N(c3ccccc3)c3cc(N(c4ccccc4)c4ccccc4)c4sc5ccccc5c4c3)cc3sc4ccccc4c23)cc1]

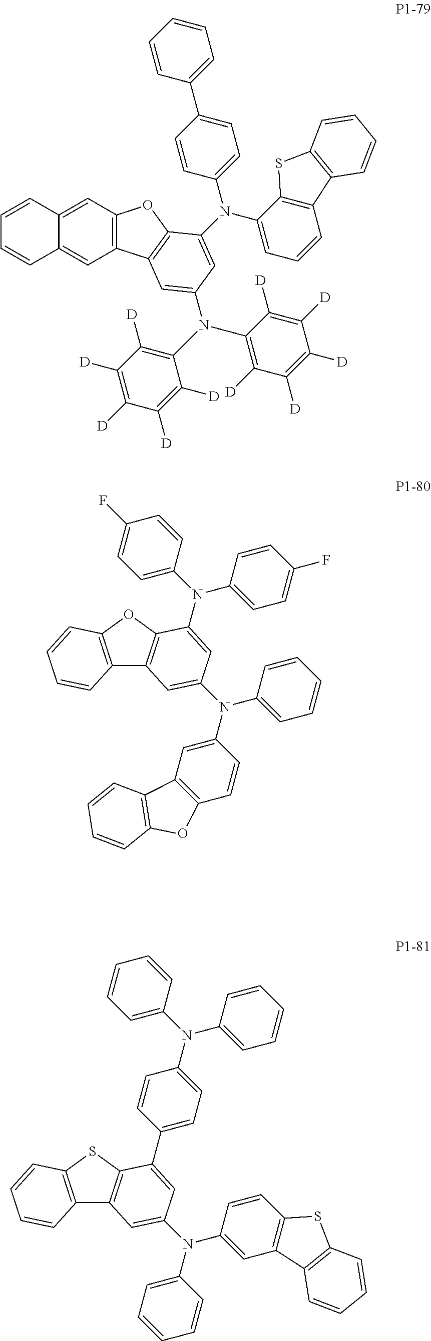 [SMILES: [2H]c1c([2H])c([2H])c(N(c2cc(N(c3ccc(-c4ccccc4)cc3)c3cccc4c3sc3ccccc34)c3oc4cc5ccccc5cc4c3c2)c2c([2H])c([2H])c([2H])c([2H])c2[2H])c([2H])c1[2H] ; Fc1ccc(N(c2ccc(F)cc2)c2cc(N(c3ccccc3)c3ccc4oc5ccccc5c4c3)cc3c2oc2ccccc23)cc1 ; c1ccc(N(c2ccccc2)c2ccc(-c3cc(N(c4ccccc4)c4ccc5sc6ccccc6c5c4)cc4c3sc3ccccc34)cc2)cc1]

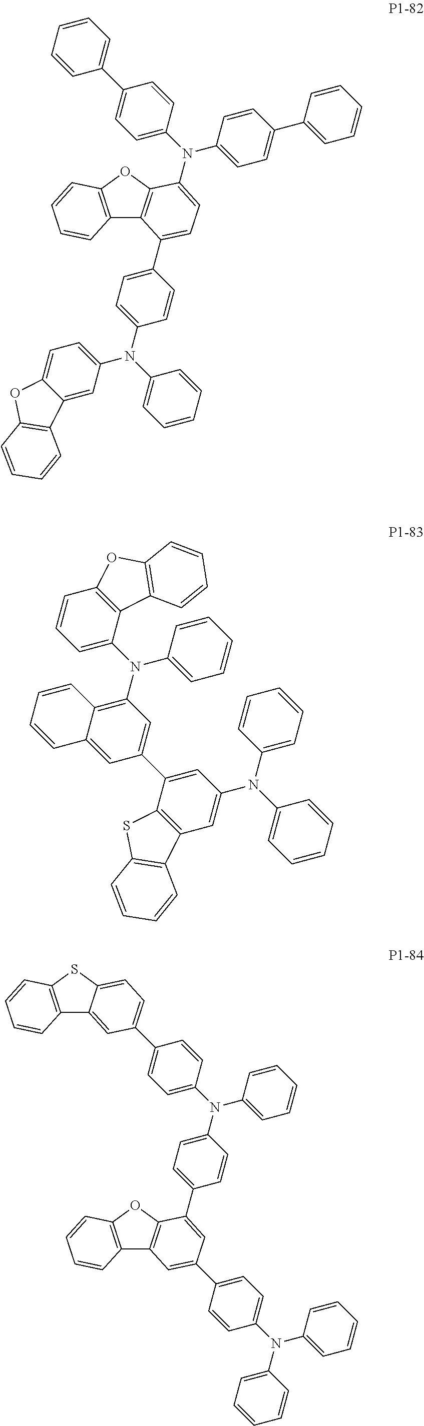 [SMILES: c1ccc(-c2ccc(N(c3ccc(-c4ccccc4)cc3)c3ccc(-c4ccc(N(c5ccccc5)c5ccc6oc7ccccc7c6c5)cc4)c4c3oc3ccccc34)cc2)cc1 ; c1ccc(N(c2ccccc2)c2cc(-c3cc(N(c4ccccc4)c4cccc5oc6ccccc6c45)c4ccccc4c3)c3sc4ccccc4c3c2)cc1 ; c1ccc(N(c2ccccc2)c2ccc(-c3cc(-c4ccc(N(c5ccccc5)c5ccc(-c6ccc7sc8ccccc8c7c6)cc5)cc4)c4oc5ccccc5c4c3)cc2)cc1]

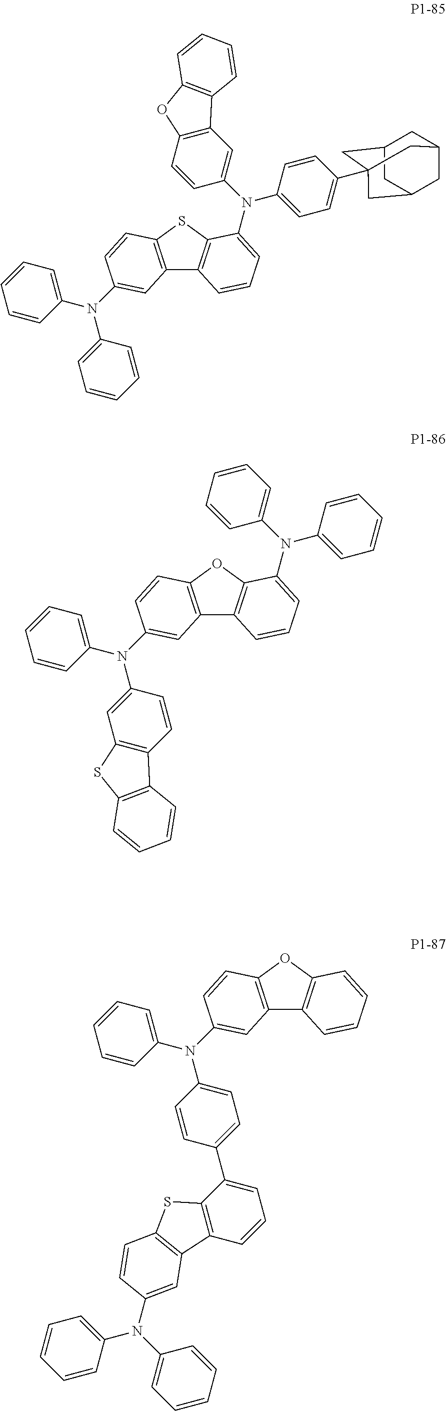 [SMILES: c1ccc(N(c2ccccc2)c2ccc3sc4c(N(c5ccc(C67CC8CC(CC(C8)C6)C7)cc5)c5ccc6oc7ccccc7c6c5)cccc4c3c2)cc1 ; c1ccc(N(c2ccc3c(c2)sc2ccccc23)c2ccc3oc4c(N(c5ccccc5)c5ccccc5)cccc4c3c2)cc1 ; c1ccc(N(c2ccc(-c3cccc4c3sc3ccc(N(c5ccccc5)c5ccccc5)cc34)cc2)c2ccc3oc4ccccc4c3c2)cc1]

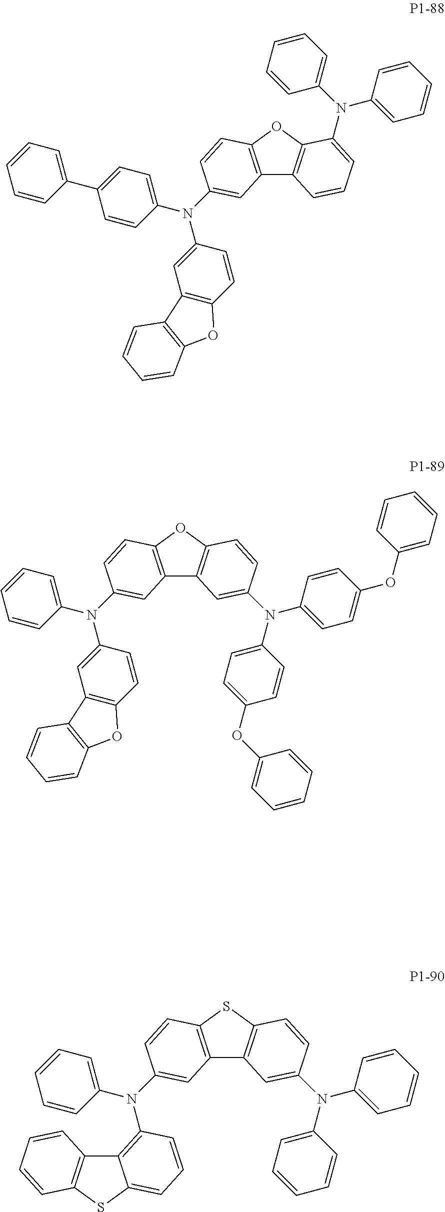 [SMILES: c1ccc(-c2ccc(N(c3ccc4oc5ccccc5c4c3)c3ccc4oc5c(N(c6ccccc6)c6ccccc6)cccc5c4c3)cc2)cc1 ; c1ccc(Oc2ccc(N(c3ccc(Oc4ccccc4)cc3)c3ccc4oc5ccc(N(c6ccccc6)c6ccc7oc8ccccc8c7c6)cc5c4c3)cc2)cc1 ; c1ccc(N(c2ccccc2)c2ccc3sc4ccc(N(c5ccccc5)c5cccc6sc7ccccc7c56)cc4c3c2)cc1]

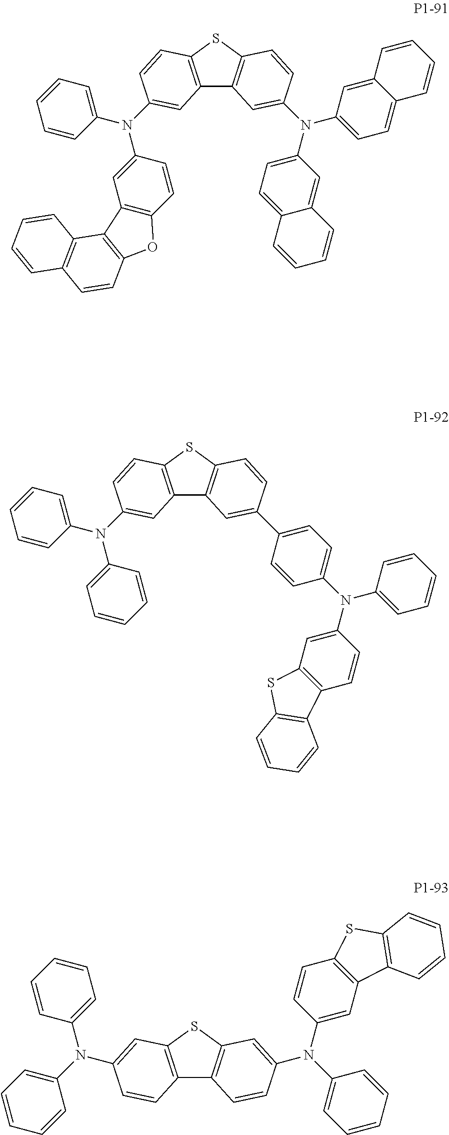 [SMILES: c1ccc(N(c2ccc3sc4ccc(N(c5ccc6ccccc6c5)c5ccc6ccccc6c5)cc4c3c2)c2ccc3oc4ccc5ccccc5c4c3c2)cc1 ; c1ccc(N(c2ccc(-c3ccc4sc5ccc(N(c6ccccc6)c6ccccc6)cc5c4c3)cc2)c2ccc3c(c2)sc2ccccc23)cc1 ; c1ccc(N(c2ccccc2)c2ccc3c(c2)sc2cc(N(c4ccccc4)c4ccc5sc6ccccc6c5c4)ccc23)cc1]

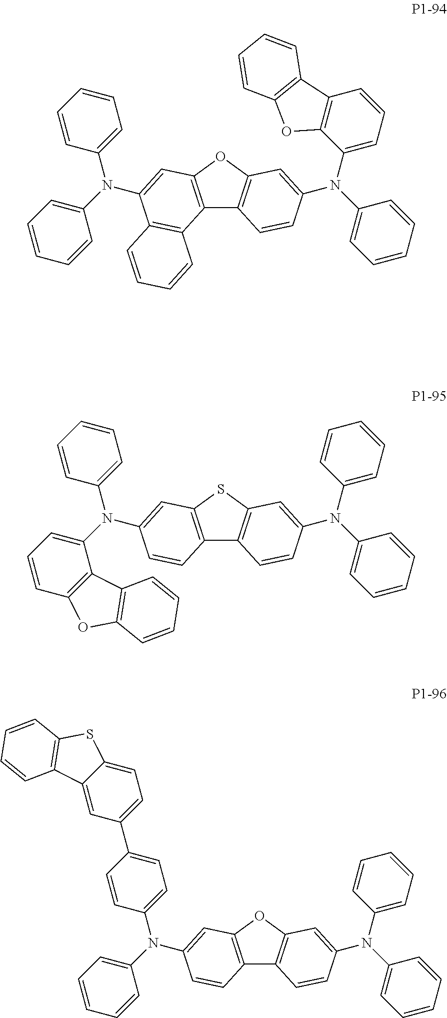 [SMILES: c1ccc(N(c2ccccc2)c2cc3oc4cc(N(c5ccccc5)c5cccc6c5oc5ccccc56)ccc4c3c3ccccc23)cc1 ; c1ccc(N(c2ccccc2)c2ccc3c(c2)sc2cc(N(c4ccccc4)c4cccc5oc6ccccc6c45)ccc23)cc1 ; c1ccc(N(c2ccccc2)c2ccc3c(c2)oc2cc(N(c4ccccc4)c4ccc(-c5ccc6sc7ccccc7c6c5)cc4)ccc23)cc1]

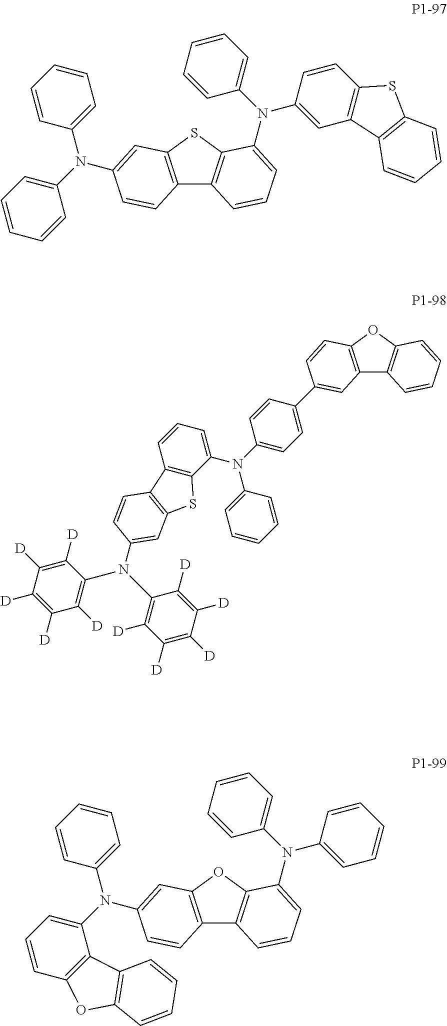 [SMILES: c1ccc(N(c2ccccc2)c2ccc3c(c2)sc2c(N(c4ccccc4)c4ccc5sc6ccccc6c5c4)cccc23)cc1 ; [2H]c1c([2H])c([2H])c(N(c2ccc3c(c2)sc2c(N(c4ccccc4)c4ccc(-c5ccc6oc7ccccc7c6c5)cc4)cccc23)c2c([2H])c([2H])c([2H])c([2H])c2[2H])c([2H])c1[2H] ; c1ccc(N(c2ccccc2)c2cccc3c2oc2cc(N(c4ccccc4)c4cccc5oc6ccccc6c45)ccc23)cc1]

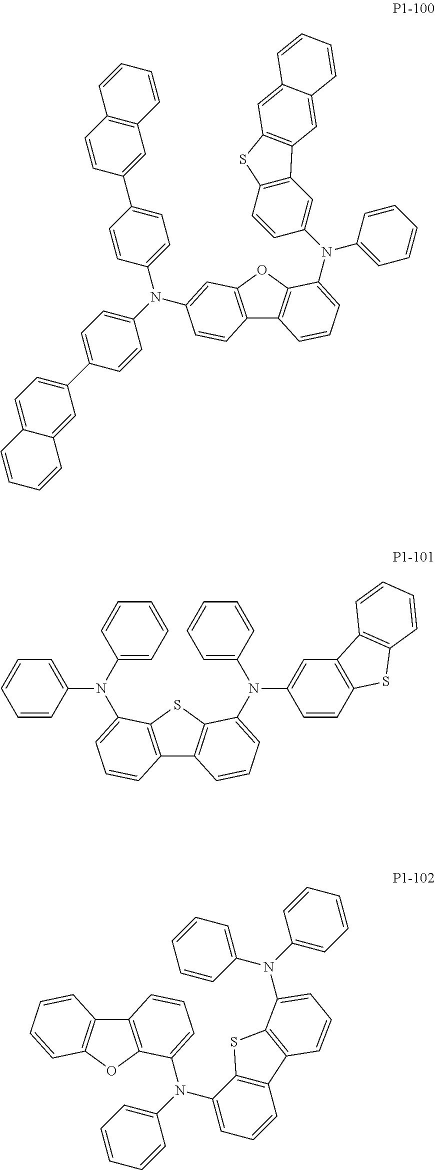 [SMILES: c1ccc(N(c2ccc3sc4cc5ccccc5cc4c3c2)c2cccc3c2oc2cc(N(c4ccc(-c5ccc6ccccc6c5)cc4)c4ccc(-c5ccc6ccccc6c5)cc4)ccc23)cc1 ; c1ccc(N(c2ccccc2)c2cccc3c2sc2c(N(c4ccccc4)c4ccc5sc6ccccc6c5c4)cccc23)cc1 ; c1ccc(N(c2ccccc2)c2cccc3c2sc2c(N(c4ccccc4)c4cccc5c4oc4ccccc45)cccc23)cc1]

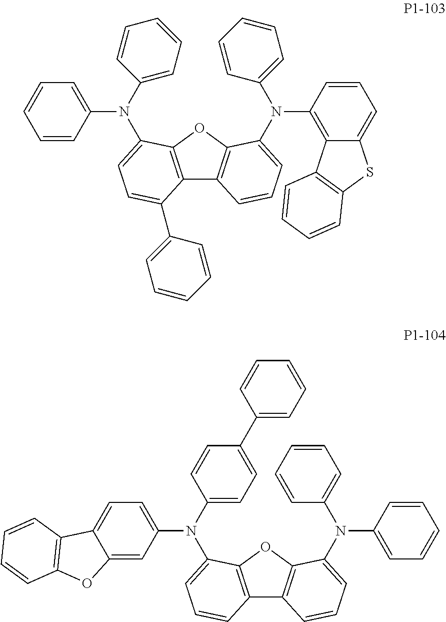 [SMILES: c1ccc(-c2ccc(N(c3ccccc3)c3ccccc3)c3oc4c(N(c5ccccc5)c5cccc6sc7ccccc7c56)cccc4c23)cc1 ; c1ccc(-c2ccc(N(c3ccc4c(c3)oc3ccccc34)c3cccc4c3oc3c(N(c5ccccc5)c5ccccc5)cccc34)cc2)cc1]

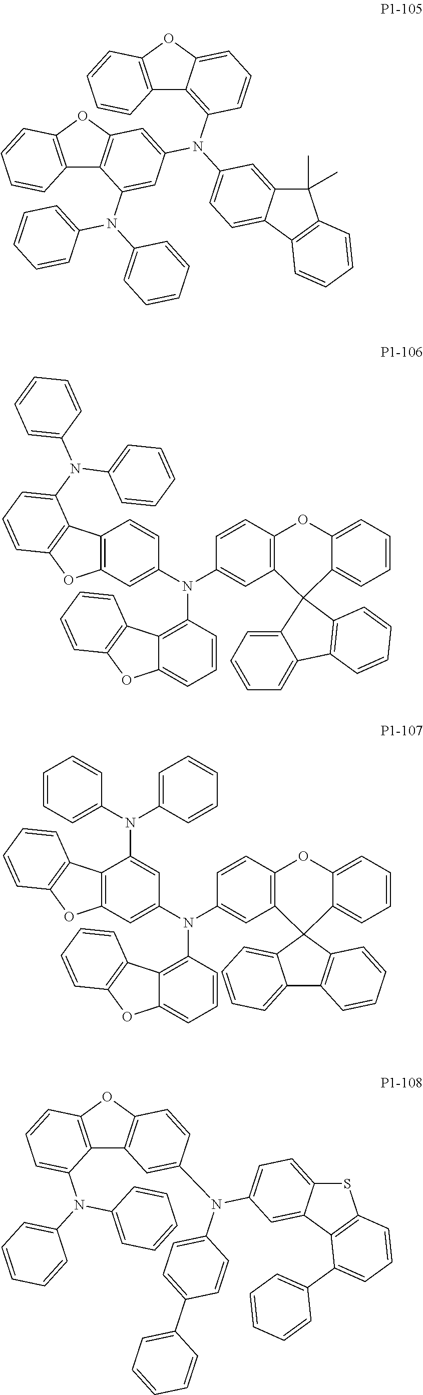 [SMILES: CC1(C)c2ccccc2-c2ccc(N(c3cc(N(c4ccccc4)c4ccccc4)c4c(c3)oc3ccccc34)c3cccc4oc5ccccc5c34)cc21 ; c1ccc(N(c2ccccc2)c2cccc3oc4cc(N(c5ccc6c(c5)C5(c7ccccc7O6)c6ccccc6-c6ccccc65)c5cccc6oc7ccccc7c56)ccc4c23)cc1 ; c1ccc(N(c2ccccc2)c2cc(N(c3ccc4c(c3)C3(c5ccccc5O4)c4ccccc4-c4ccccc43)c3cccc4oc5ccccc5c34)cc3oc4ccccc4c23)cc1 ; c1ccc(-c2ccc(N(c3ccc4oc5cccc(N(c6ccccc6)c6ccccc6)c5c4c3)c3ccc4sc5cccc(-c6ccccc6)c5c4c3)cc2)cc1]

9: The organic electric element of claim 1, wherein the compound represented by Formula 2 is one of the following compounds:

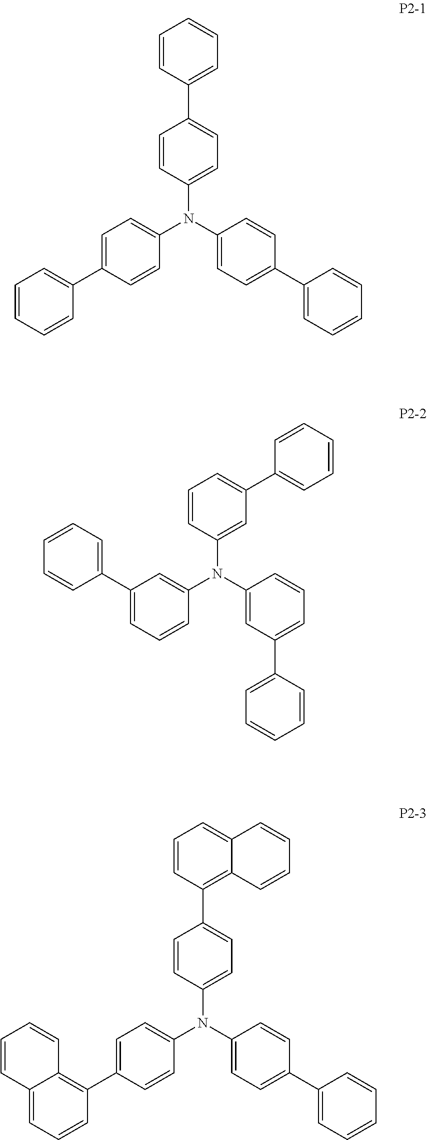 [SMILES: c1ccc(-c2ccc(N(c3ccc(-c4ccccc4)cc3)c3ccc(-c4ccccc4)cc3)cc2)cc1 ; c1ccc(-c2cccc(N(c3cccc(-c4ccccc4)c3)c3cccc(-c4ccccc4)c3)c2)cc1 ; c1ccc(-c2ccc(N(c3ccc(-c4cccc5ccccc45)cc3)c3ccc(-c4cccc5ccccc45)cc3)cc2)cc1]

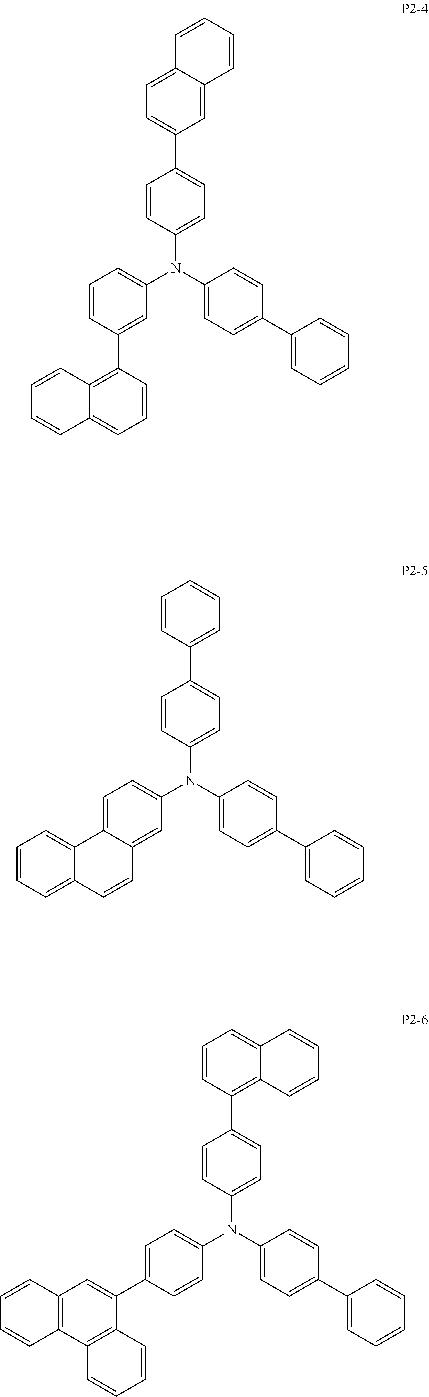 [SMILES: c1ccc(-c2ccc(N(c3ccc(-c4ccc5ccccc5c4)cc3)c3cccc(-c4cccc5ccccc45)c3)cc2)cc1 ; c1ccc(-c2ccc(N(c3ccc(-c4ccccc4)cc3)c3ccc4c(ccc5ccccc54)c3)cc2)cc1 ; c1ccc(-c2ccc(N(c3ccc(-c4cccc5ccccc45)cc3)c3ccc(-c4cc5ccccc5c5ccccc45)cc3)cc2)cc1]

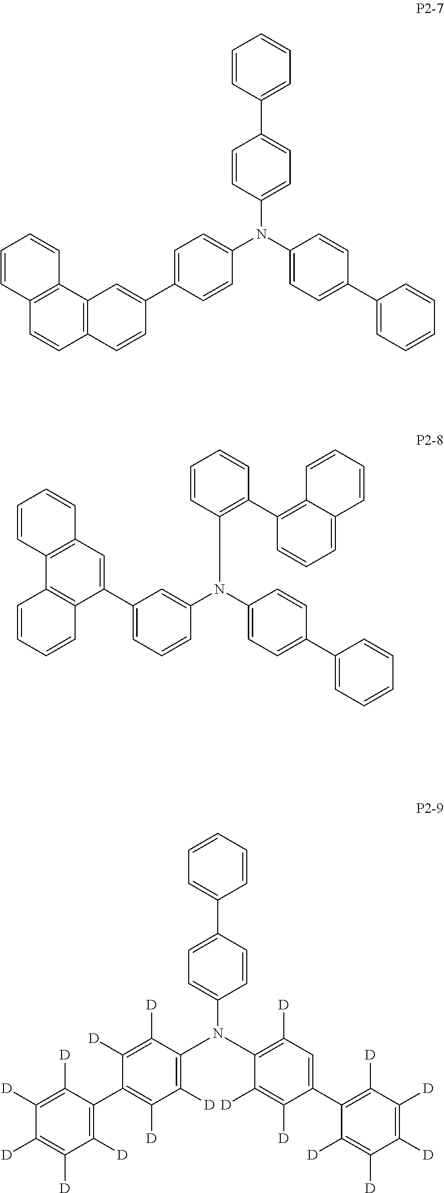 [SMILES: c1ccc(-c2ccc(N(c3ccc(-c4ccccc4)cc3)c3ccc(-c4ccc5ccc6ccccc6c5c4)cc3)cc2)cc1 ; c1ccc(-c2ccc(N(c3cccc(-c4cc5ccccc5c5ccccc45)c3)c3ccccc3-c3cccc4ccccc34)cc2)cc1 ; [2H]c1cc(-c2c([2H])c([2H])c([2H])c([2H])c2[2H])c([2H])c([2H])c1N(c1ccc(-c2ccccc2)cc1)c1c([2H])c([2H])c(-c2c([2H])c([2H])c([2H])c([2H])c2[2H])c([2H])c1[2H]]

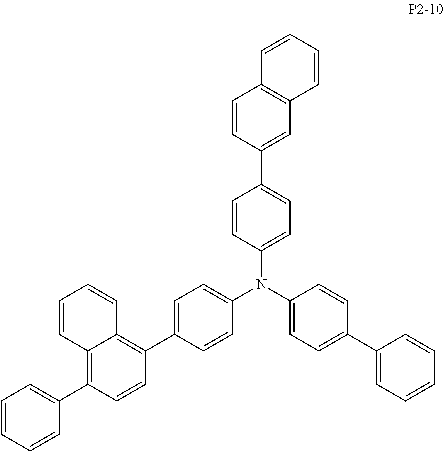 [SMILES: c1ccc(-c2ccc(N(c3ccc(-c4ccc5ccccc5c4)cc3)c3ccc(-c4ccc(-c5ccccc5)c5ccccc45)cc3)cc2)cc1]

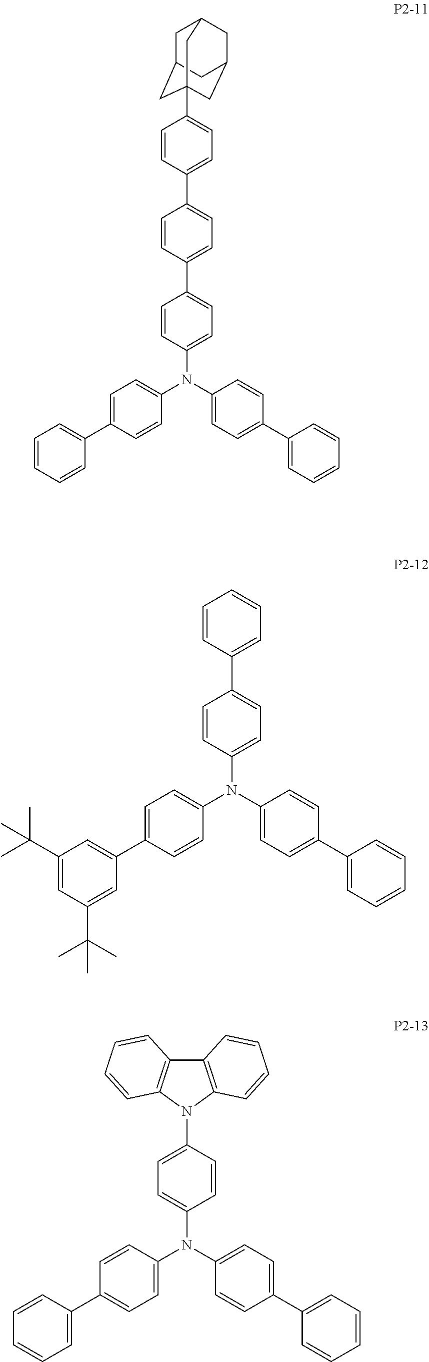 [SMILES: c1ccc(-c2ccc(N(c3ccc(-c4ccccc4)cc3)c3ccc(-c4ccc(-c5ccc(C67CC8CC(CC(C8)C6)C7)cc5)cc4)cc3)cc2)cc1 ; CC(C)(C)c1cc(-c2ccc(N(c3ccc(-c4ccccc4)cc3)c3ccc(-c4ccccc4)cc3)cc2)cc(C(C)(C)C)c1 ; c1ccc(-c2ccc(N(c3ccc(-c4ccccc4)cc3)c3ccc(-n4c5ccccc5c5ccccc54)cc3)cc2)cc1]

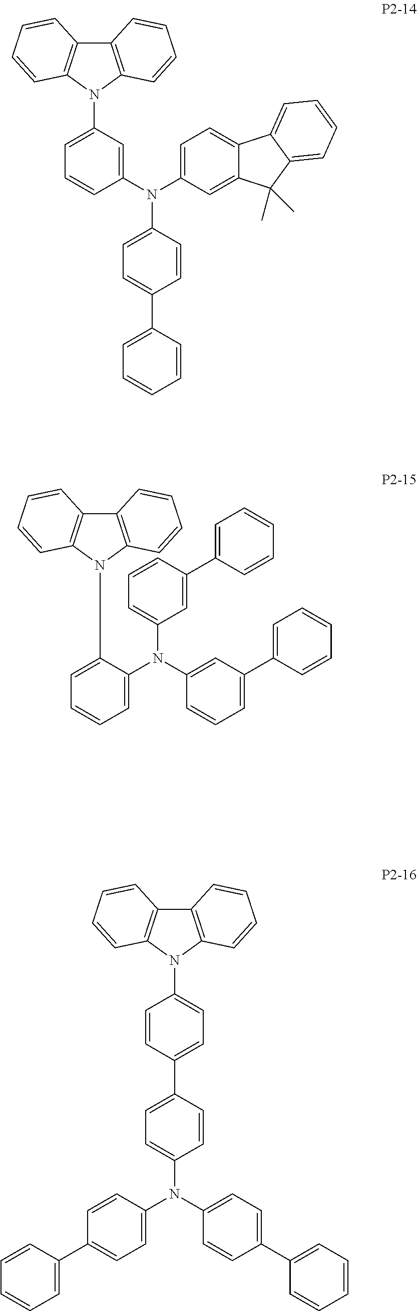 [SMILES: CC1(C)c2ccccc2-c2ccc(N(c3ccc(-c4ccccc4)cc3)c3cccc(-n4c5ccccc5c5ccccc54)c3)cc21 ; c1ccc(-c2cccc(N(c3cccc(-c4ccccc4)c3)c3ccccc3-n3c4ccccc4c4ccccc43)c2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

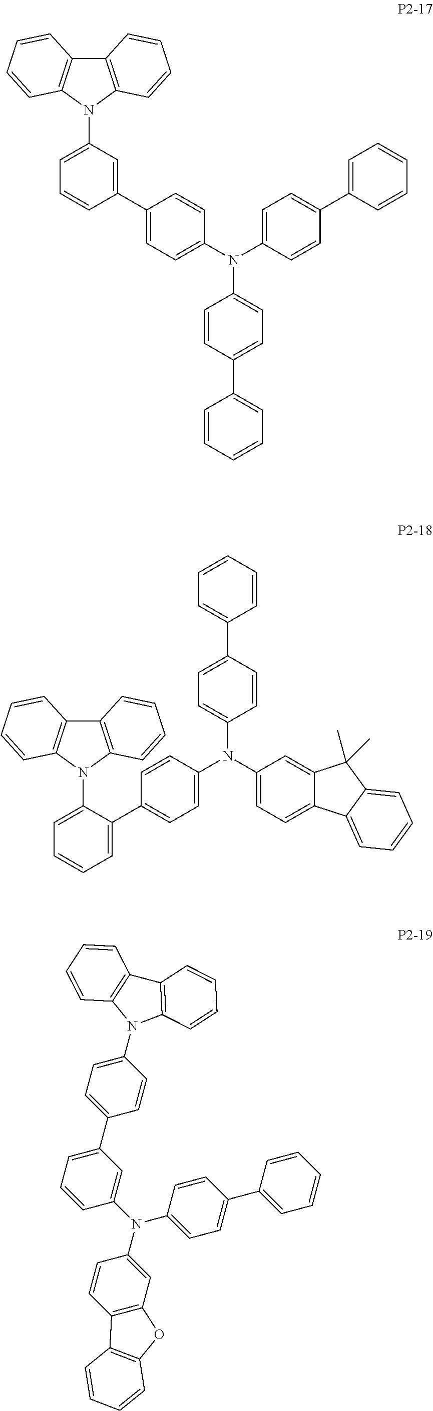 [SMILES: c1ccc(-c2ccc(N(c3ccc(-c4ccccc4)cc3)c3ccc(-c4cccc(-n5c6ccccc6c6ccccc65)c4)cc3)cc2)cc1 ; CC1(C)c2ccccc2-c2ccc(N(c3ccc(-c4ccccc4)cc3)c3ccc(-c4ccccc4-n4c5ccccc5c5ccccc54)cc3)cc21 ; c1ccc(-c2ccc(N(c3cccc(-c4ccc(-n5c6ccccc6c6ccccc65)cc4)c3)c3ccc4c(c3)oc3ccccc34)cc2)cc1]

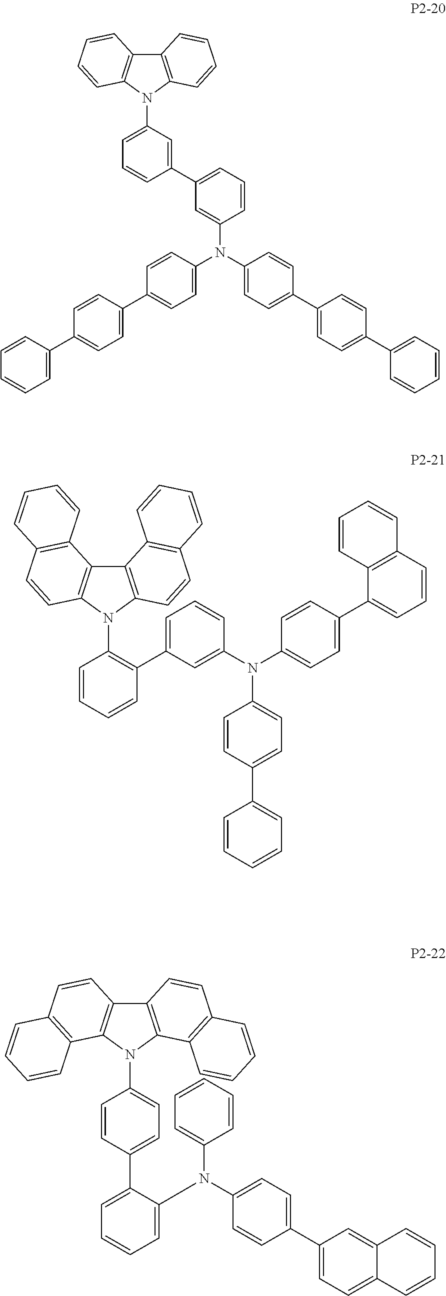 [SMILES: c1ccc(-c2ccc(-c3ccc(N(c4ccc(-c5ccc(-c6ccccc6)cc5)cc4)c4cccc(-c5cccc(-n6c7ccccc7c7ccccc76)c5)c4)cc3)cc2)cc1 ; c1ccc(-c2ccc(N(c3ccc(-c4cccc5ccccc45)cc3)c3cccc(-c4ccccc4-n4c5ccc6ccccc6c5c5c6ccccc6ccc54)c3)cc2)cc1 ; c1ccc(N(c2ccc(-c3ccc4ccccc4c3)cc2)c2ccccc2-c2ccc(-n3c4c5ccccc5ccc4c4ccc5ccccc5c43)cc2)cc1]

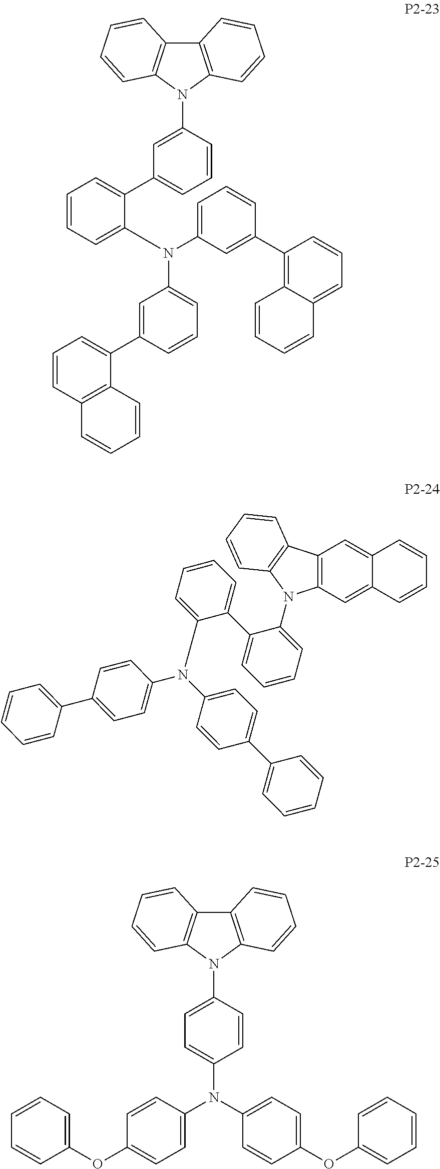 [SMILES: c1cc(-c2cccc3ccccc23)cc(N(c2cccc(-c3cccc4ccccc34)c2)c2ccccc2-c2cccc(-n3c4ccccc4c4ccccc43)c2)c1 ; c1ccc(-c2ccc(N(c3ccc(-c4ccccc4)cc3)c3ccccc3-c3ccccc3-n3c4ccccc4c4cc5ccccc5cc43)cc2)cc1 ; c1ccc(Oc2ccc(N(c3ccc(Oc4ccccc4)cc3)c3ccc(-n4c5ccccc5c5ccccc54)cc3)cc2)cc1]

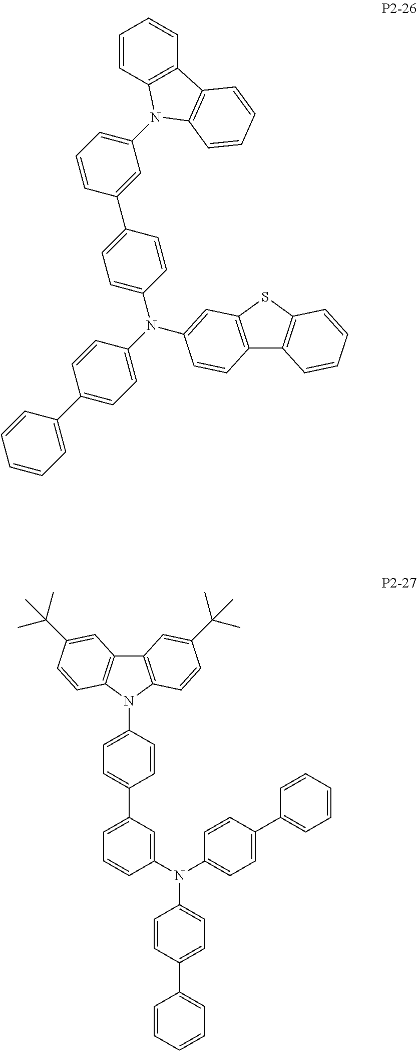 [SMILES: c1ccc(-c2ccc(N(c3ccc(-c4cccc(-n5c6ccccc6c6ccccc65)c4)cc3)c3ccc4c(c3)sc3ccccc34)cc2)cc1 ; CC(C)(C)c1ccc2c(c1)c1cc(C(C)(C)C)ccc1n2-c1ccc(-c2cccc(N(c3ccc(-c4ccccc4)cc3)c3ccc(-c4ccccc4)cc3)c2)cc1]

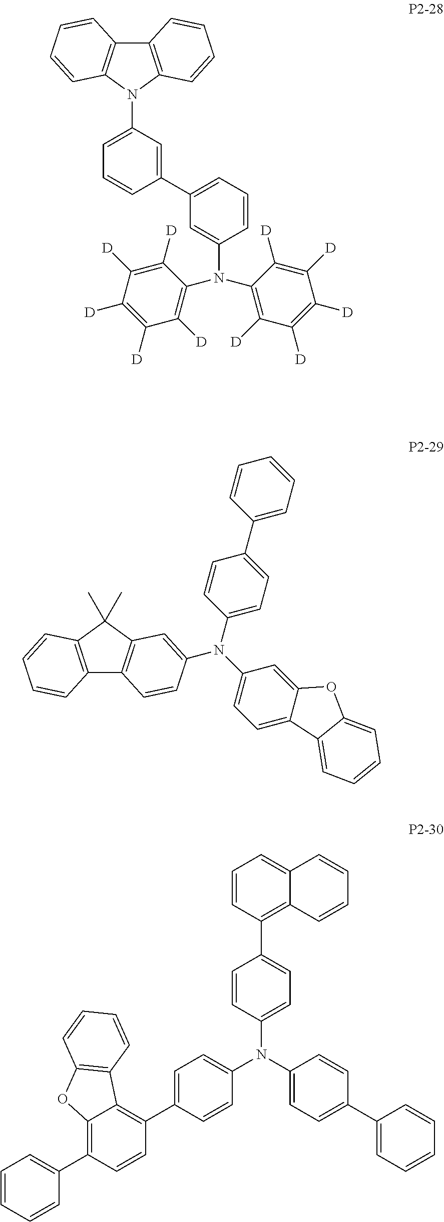 [SMILES: [2H]c1c([2H])c([2H])c(N(c2cccc(-c3cccc(-n4c5ccccc5c5ccccc54)c3)c2)c2c([2H])c([2H])c([2H])c([2H])c2[2H])c([2H])c1[2H] ; CC1(C)c2ccccc2-c2ccc(N(c3ccc(-c4ccccc4)cc3)c3ccc4c(c3)oc3ccccc34)cc21 ; c1ccc(-c2ccc(N(c3ccc(-c4cccc5ccccc45)cc3)c3ccc(-c4ccc(-c5ccccc5)c5oc6ccccc6c45)cc3)cc2)cc1]

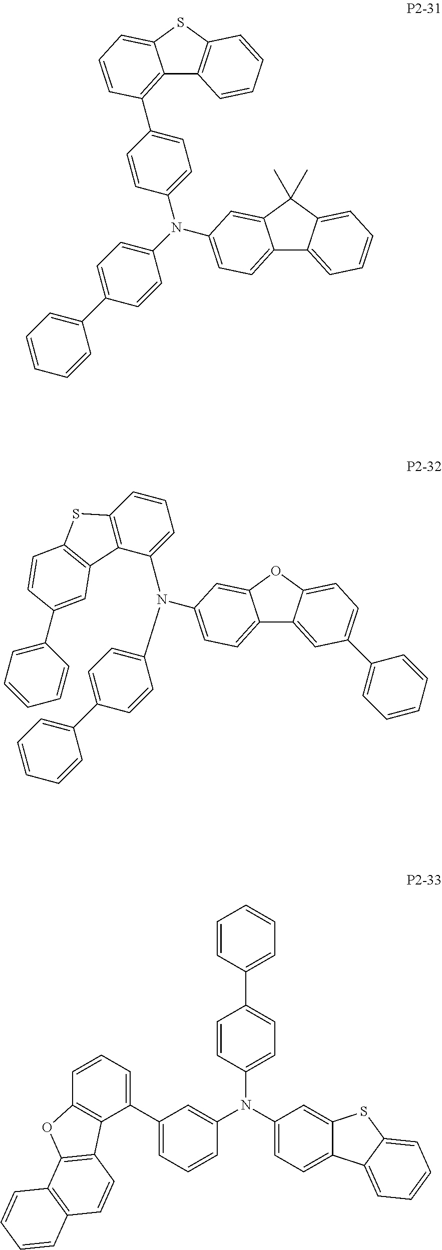 [SMILES: CC1(C)c2ccccc2-c2ccc(N(c3ccc(-c4ccccc4)cc3)c3ccc(-c4cccc5sc6ccccc6c45)cc3)cc21 ; c1ccc(-c2ccc(N(c3ccc4c(c3)oc3ccc(-c5ccccc5)cc34)c3cccc4sc5ccc(-c6ccccc6)cc5c34)cc2)cc1 ; c1ccc(-c2ccc(N(c3cccc(-c4cccc5oc6c7ccccc7ccc6c45)c3)c3ccc4c(c3)sc3ccccc34)cc2)cc1]

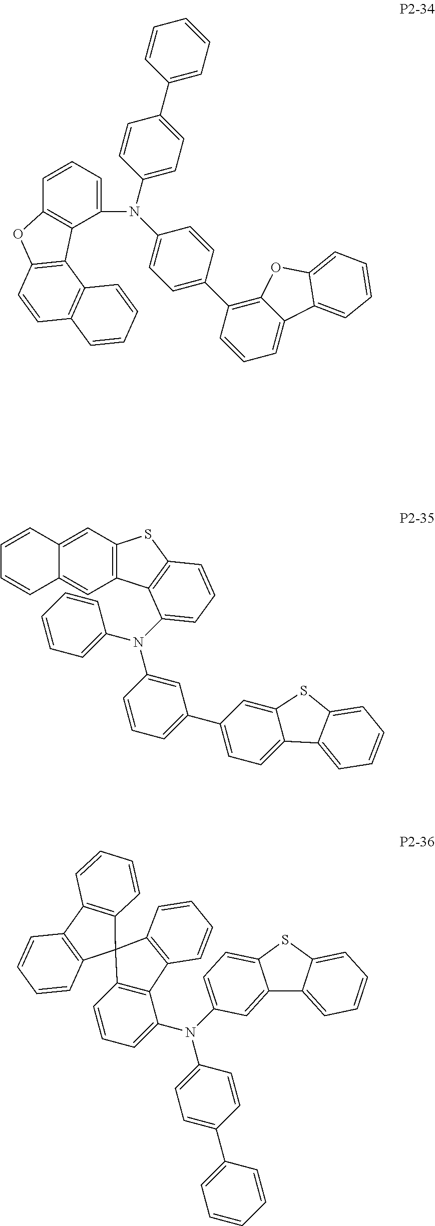 [SMILES: c1ccc(-c2ccc(N(c3ccc(-c4cccc5c4oc4ccccc45)cc3)c3cccc4oc5ccc6ccccc6c5c34)cc2)cc1 ; c1ccc(N(c2cccc(-c3ccc4c(c3)sc3ccccc34)c2)c2cccc3sc4cc5ccccc5cc4c23)cc1 ; c1ccc(-c2ccc(N(c3ccc4sc5ccccc5c4c3)c3cccc4c3-c3ccccc3C43c4ccccc4-c4ccccc43)cc2)cc1]

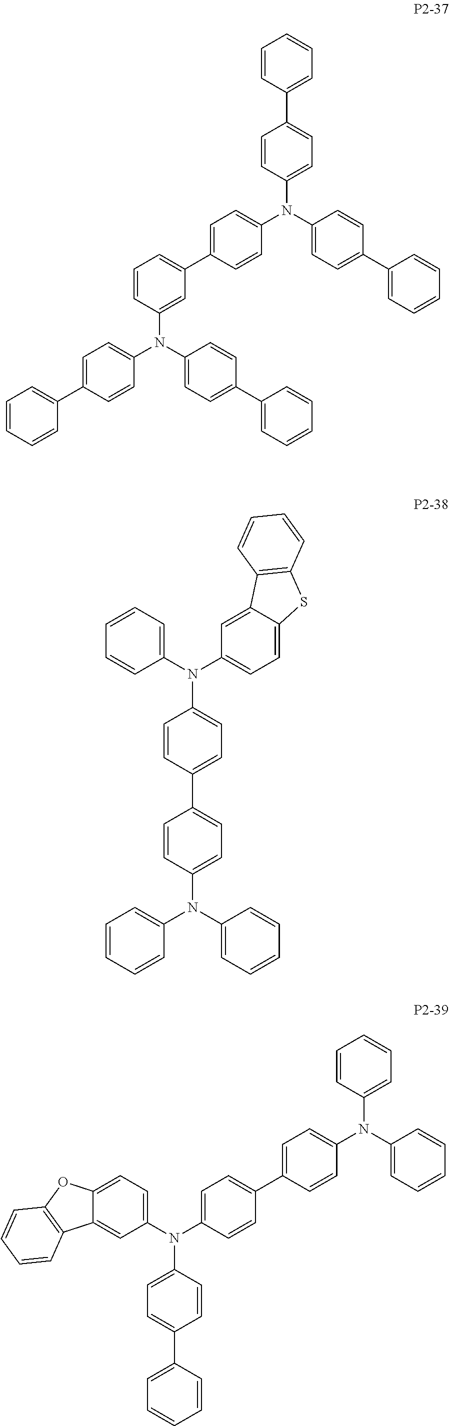 [SMILES: c1ccc(-c2ccc(N(c3ccc(-c4ccccc4)cc3)c3ccc(-c4cccc(N(c5ccc(-c6ccccc6)cc5)c5ccc(-c6ccccc6)cc5)c4)cc3)cc2)cc1 ; c1ccc(N(c2ccccc2)c2ccc(-c3ccc(N(c4ccccc4)c4ccc5sc6ccccc6c5c4)cc3)cc2)cc1 ; c1ccc(-c2ccc(N(c3ccc(-c4ccc(N(c5ccccc5)c5ccccc5)cc4)cc3)c3ccc4oc5ccccc5c4c3)cc2)cc1]

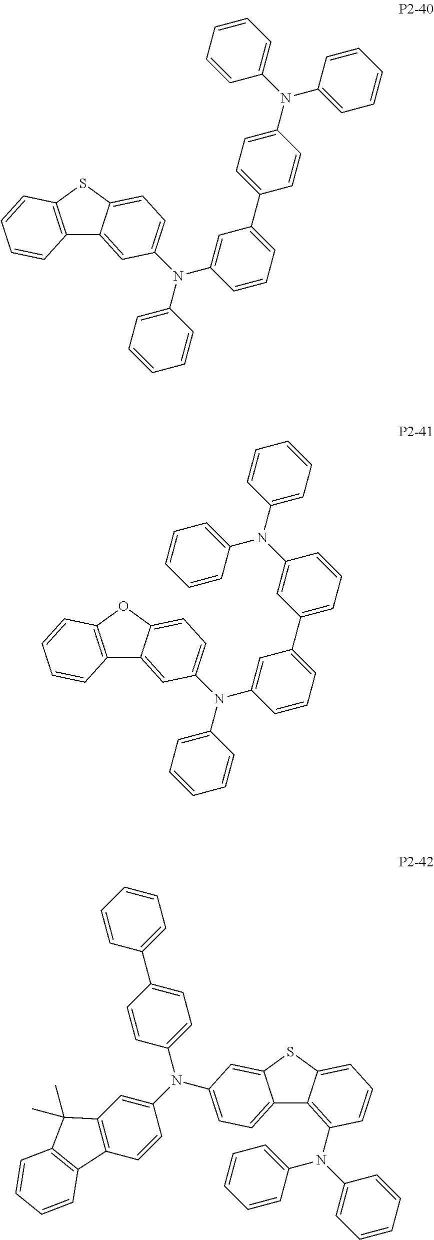 [SMILES: c1ccc(N(c2ccccc2)c2ccc(-c3cccc(N(c4ccccc4)c4ccc5sc6ccccc6c5c4)c3)cc2)cc1 ; c1ccc(N(c2ccccc2)c2cccc(-c3cccc(N(c4ccccc4)c4ccc5oc6ccccc6c5c4)c3)c2)cc1 ; CC1(C)c2ccccc2-c2ccc(N(c3ccc(-c4ccccc4)cc3)c3ccc4c(c3)sc3cccc(N(c5ccccc5)c5ccccc5)c34)cc21]

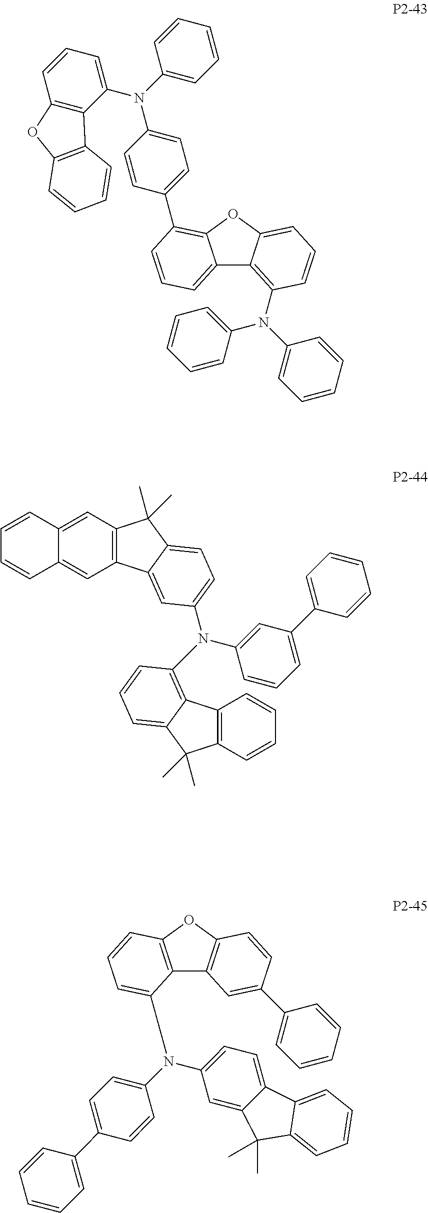 [SMILES: c1ccc(N(c2ccc(-c3cccc4c3oc3cccc(N(c5ccccc5)c5ccccc5)c34)cc2)c2cccc3oc4ccccc4c23)cc1 ; CC1(C)c2ccc(N(c3cccc(-c4ccccc4)c3)c3cccc4c3-c3ccccc3C4(C)C)cc2-c2cc3ccccc3cc21 ; CC1(C)c2ccccc2-c2ccc(N(c3ccc(-c4ccccc4)cc3)c3cccc4oc5ccc(-c6ccccc6)cc5c34)cc21]

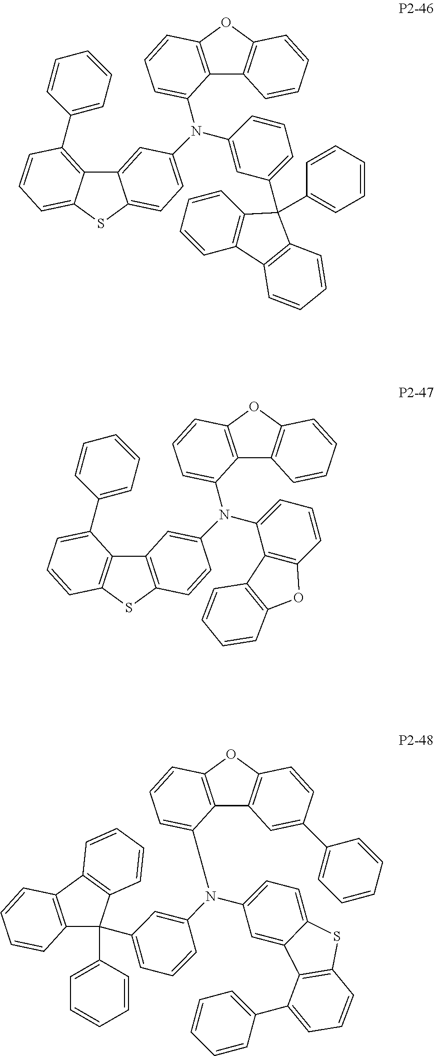 [SMILES: c1ccc(-c2cccc3sc4ccc(N(c5cccc(C6(c7ccccc7)c7ccccc7-c7ccccc76)c5)c5cccc6oc7ccccc7c56)cc4c23)cc1 ; c1ccc(-c2cccc3sc4ccc(N(c5cccc6oc7ccccc7c56)c5cccc6oc7ccccc7c56)cc4c23)cc1 ; c1ccc(-c2ccc3oc4cccc(N(c5cccc(C6(c7ccccc7)c7ccccc7-c7ccccc76)c5)c5ccc6sc7cccc(-c8ccccc8)c7c6c5)c4c3c2)cc1]

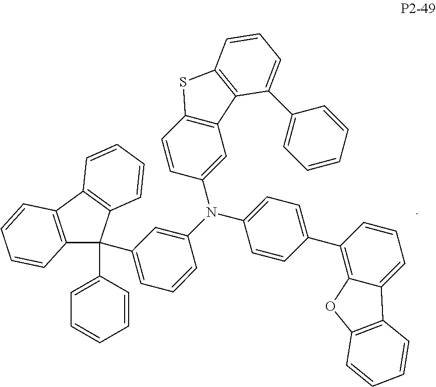 [SMILES: c1ccc(-c2cccc3sc4ccc(N(c5ccc(-c6cccc7c6oc6ccccc67)cc5)c5cccc(C6(c7ccccc7)c7ccccc7-c7ccccc76)c5)cc4c23)cc1]

10: The organic electric element of claim 1, wherein the first light-emitting auxiliary layer has a thickness of 25 to 900 Å, and the second light-emitting auxiliary layer has a thickness of 10 to 300 Å.

11: The organic electric element of claim 1, wherein the hole mobility of the compound represented by Formula 1 in the first light-emitting auxiliary layer is 5.1×10⁻⁵ to 1.3×10⁻³ cm/V−S.

12: The organic electric element of claim 1, wherein T1 energy level of the compound represented by Formula 2 in the second light-emitting auxiliary layer is 2.3 to 3.0.

13: The organic electric element of claim 1, wherein the organic electric element further comprises a layer for improving luminous efficiency, and the layer for improving luminous efficiency is formed on one side of both sides of the anode or the cathode, wherein the one side is not facing the organic material layer.

14: The organic electric element of claim 1, wherein the organic material layer comprises two or more stacks comprising a hole transport layer, a light-emitting auxiliary layer, a light-emitting layer, and an electron transport layer sequentially formed on the first electrode.

15: The organic electric element of claim 14, wherein the organic material layer further comprises a charge generation layer formed between the two or more stacks.

16: An electronic device including a display device and a control unit for driving the display device, wherein the display device includes the organic electric element of claim 1.

17: The electronic device of claim 16, wherein the organic electric element is selected from the group consisting of an organic electroluminescent element, an organic solar cell, an organic photo conductor, an organic transistor, an element for monochromatic illumination and a quantum dot display.
